(19) United States
(12) Patent Application Publication
(10) Pub. No.: US 2024/0155936 A1
(43) Pub. Date: May 9, 2024

(54) LIGHT EMITTING ELEMENT AND NITROGEN-CONTAINING COMPOUND FOR THE SAME

(71) Applicant: Samsung Display Co., LTD., Yongin-si (KR)

(72) Inventors: HYUNAH UM, Yongin-si (KR); HYEONGMIN KIM, Yongin-si (KR); YOUNGJIN PARK, Yongin-si (KR); HEECHOON AHN, Yongin-si (KR); Juhui YUN, Yongin-si (KR); YESEUL LEE, Yongin-si (KR); HYOYOUNG LEE, Yongin-si (KR)

(21) Appl. No.: 18/355,833

(22) Filed: Jul. 20, 2023

(30) Foreign Application Priority Data
Oct. 7, 2022 (KR) 10-2022-0129021

(51) Int. Cl. H10K 85/40; C07F 7/08; C09K 11/06; H10K 50/12; H10K 50/805; H10K 85/30

(52) U.S. Cl. CPC H10K 85/40; C07F 7/0812; C09K 11/06; H10K 50/12; H10K 50/805; H10K 85/346; C07B 2200/05; C09K 2211/1074

(57) ABSTRACT

A light emitting element of an embodiment may include a first electrode, a second electrode on the first electrode, and at least one functional layer between the first electrode and the second electrode and including a first compound represented by Formula 1. The light emitting element including the first compound may show improved color coordinates of light emitted and long-life characteristics.

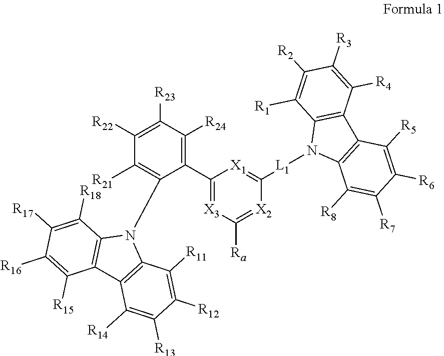

### CROSS-REFERENCE TO RELATED APPLICATION

This application claims priority to and the benefit of Korean Patent Application No. 10-2022-0129021, filed on Oct. 7, 2022, in the Korean Intellectual Property Office, the entire contents of which are hereby incorporated by reference.

### BACKGROUND

### 1. Field

Embodiments of the present disclosure herein relate to a light emitting element and a nitrogen-containing compound used therein.

### 2. Description of Related Art

Recently, the development of an organic electroluminescence display device as an image display device is being actively conducted. The organic electroluminescence display device is a so-called display device including a self-luminescent-type light emitting element in which holes and electrons injected from a first electrode and a second electrode recombine in an emission layer so that a light emitting material in the emission layer emits light to achieve a display.

In the application of a light emitting element to a display device, the increase of lifetime, etc. are required or desired, and development of materials for a light emitting element, stably achieving the desired features or requirements is being consistently required or desired.

### SUMMARY

Embodiments of the present disclosure provide a light emitting element having improved color coordinates of light emitted and increased lifetime.

The present disclosure also provides a nitrogen-containing compound which is a material for a light emitting element that improves the color coordinates of light emitted and increases lifetime.

An embodiment provides a light emitting element including: a first electrode; a second electrode on the first electrode; and at least one functional layer between the first electrode and the second electrode, and including a first compound represented by Formula 1.

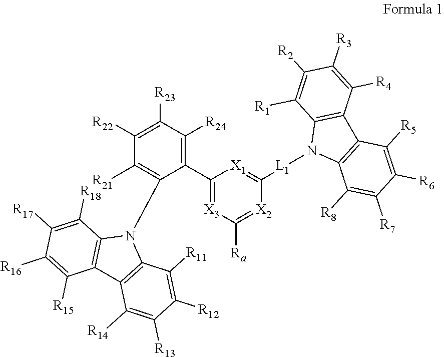

In Formula 1, at least two selected from among X₁ to X₃ are N, and the remainder, if any, is CH, Li is a direct linkage or a substituted or unsubstituted arylene group of 6 to 30 ring-forming carbon atoms, Rₐ, R₁ to R₈, R₁₁ to R₁₈, and R₂₁ to R₂₄ are each independently a hydrogen atom, a deuterium atom, a substituted or unsubstituted silyl group, a substituted or unsubstituted alkyl group of 1 to 30 carbon atoms, a substituted or unsubstituted alkenyl group of 2 to 30 carbon atoms, a substituted or unsubstituted aryl group of 6 to 30 ring-forming carbon atoms, or a substituted or unsubstituted heteroaryl group or 2 to 30 ring-forming carbon atoms, and at least one selected from among Rₐ, R₁ to R₈, R₁₁ to R₁₈, and R₂₁ to R₂₄ is represented by Formula 2, or includes a first substituent substituted with Formula 2.

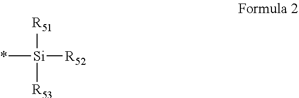

In Formula 2, R₅₁ to R₅₃ are each independently a hydrogen atom, a deuterium atom, a substituted or unsubstituted silyl group, a substituted or unsubstituted alkyl group of 1 to 30 carbon atoms, a substituted or unsubstituted alkenyl group of 2 to 30 carbon atoms, a substituted or unsubstituted aryl group of 6 to ring-forming carbon atoms, or a substituted or unsubstituted heteroaryl group or 2 to ring-forming carbon atoms, and at least one selected from among Rₐ, R₁ to R₈, R₁₁ to R₁₈, R₂₁ to R₂₄, and R₅₁ to R₅₃ is a deuterium atom, or includes a second substituent substituted with a deuterium atom.

In an embodiment, Formula 1 may be represented by Formula 1-A1 or Formula 1-A2.

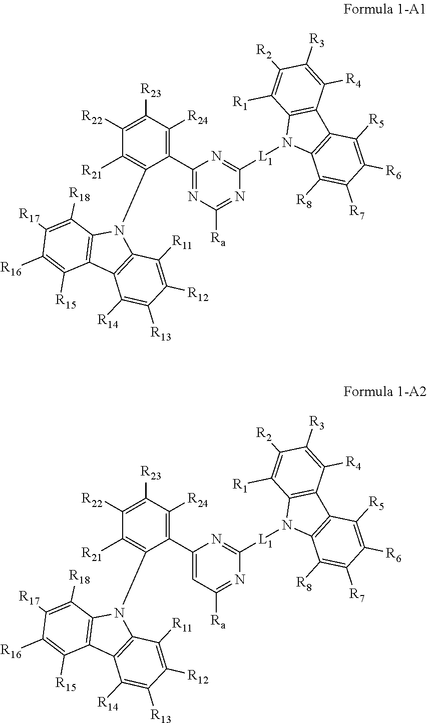

In Formula 1-A1 and Formula 1-A2, L₁, Rₐ, R₁ to R₈, R₁₁ to R₁₈, and R₂₁ to R₂₄ are the same as defined with respect to Formula 1.

In an embodiment, Formula 2 may be represented by Formula 2-1.

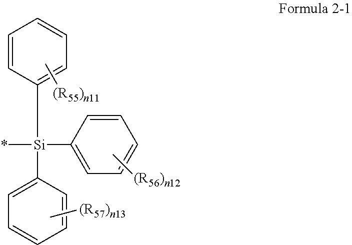

In Formula 2-1, n11 to n13 are each independently an integer of 0 to 5, and R₅₅ to R₅₇ are each independently a hydrogen atom, a deuterium atom, or a substituted or unsubstituted aryl group of 6 to 30 ring-forming carbon atoms.

In an embodiment, Formula 1 may be represented by any one selected from among Formula 1-B1 to Formula 1-64.

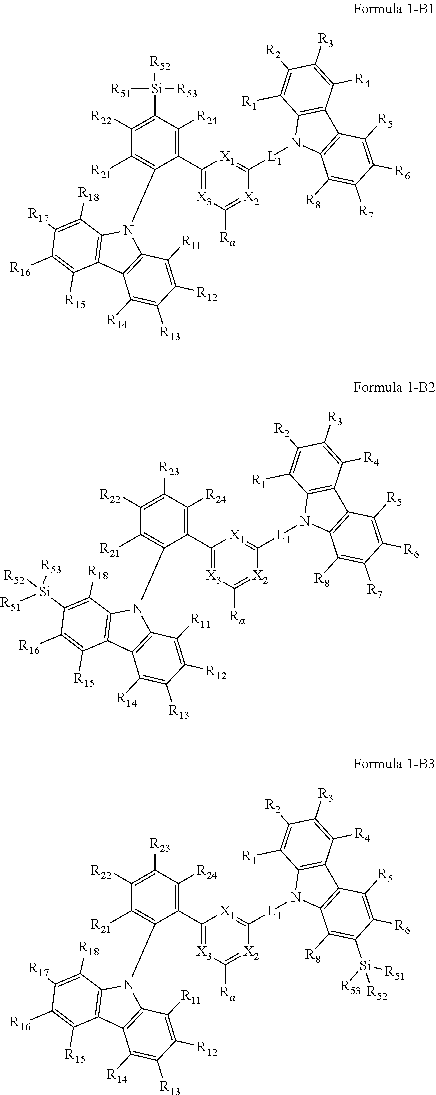

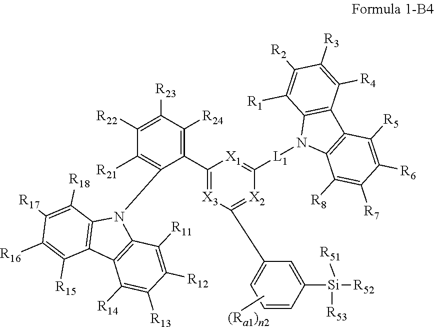

In Formula 1-B4, n2 is an integer of 0 to 4, and Rai is a hydrogen atom, a deuterium atom, or a substituted or unsubstituted aryl group of 6 to 30 ring-forming carbon atoms, and in Formula 1-61 to Formula 1-B4, L₁, Rₐ, R₁ to R₈, R₁₁ to R₁₈, R₂₁ to R₂₄, and R₅₁ to R₅₃ are the same as defined with respect to Formula 1 and Formula 2.

In an embodiment, the second substituent may include at least one selected from among a phenyl group substituted with a deuterium atom, a silyl group substituted with a deuterium atom, and a carbazole group substituted with a deuterium atom.

In an embodiment, the second substituent may be represented by any one selected from among S-1 to S-10.

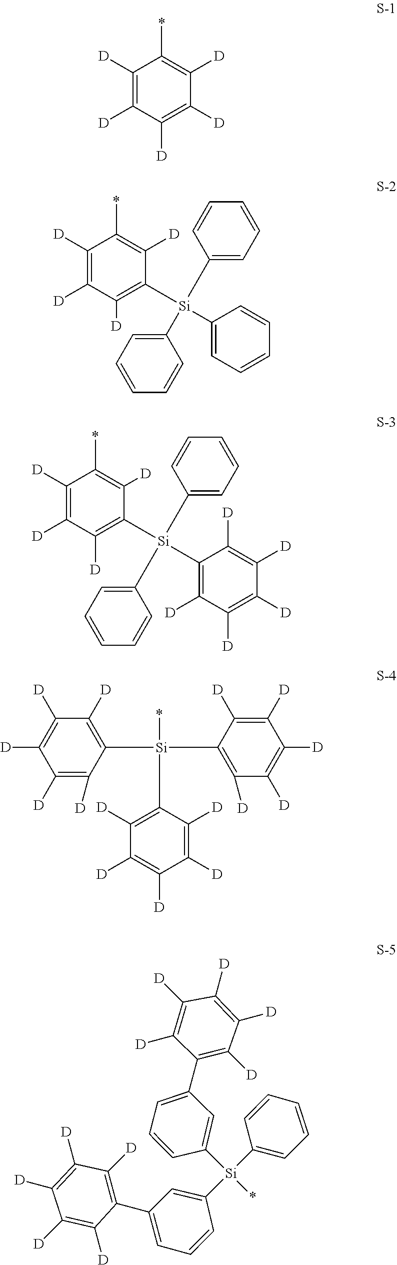

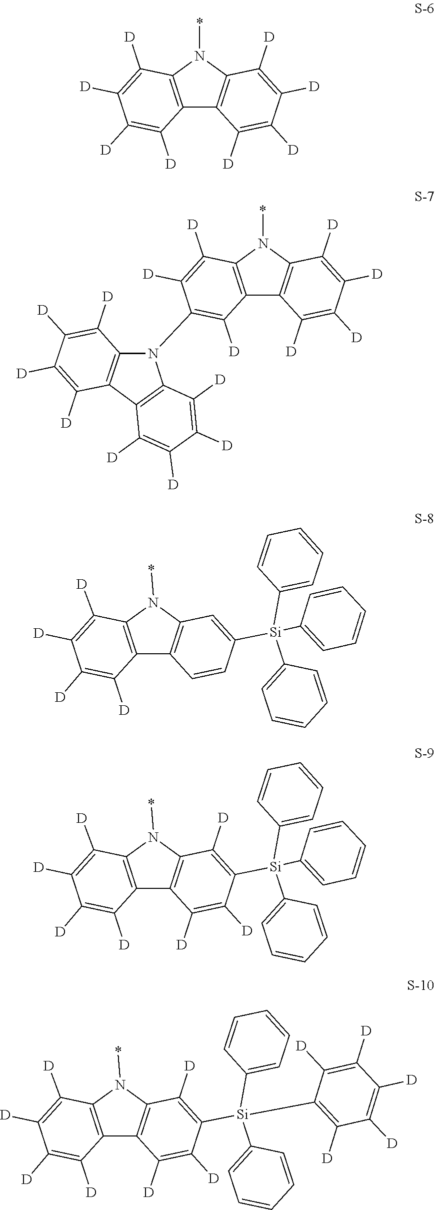

In S-1 to S-10, D is a deuterium atom.

In an embodiment, in Formula 1, L₁ may be a direct linkage or a substituted or unsubstituted phenylene group.

In an embodiment, the at least one functional layer may include an emission layer on the first electrode and an electron transport region on the emission layer, and at least one selected from among the emission layer and the electron transport region may include the first compound.

In an embodiment, the electron transport region may include an electron transport layer on the emission layer, an electron injection layer on the electron transport layer, and an emission auxiliary layer between the emission layer and the electron transport layer, and the emission auxiliary layer may include the first compound.

In an embodiment, the emission layer may further include a second compound represented by Formula HT-1.

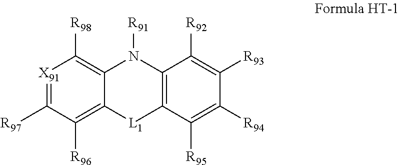

In Formula HT-1, L₁ is a direct linkage, CR₉₉R₁₀₀, or SiR₁₀₁R₁₀₂, X₉₁ is N or CR₁₀₃, and R₉₁ to R₁₀₃ are each independently a hydrogen atom, a deuterium atom, a cyano group, a substituted or unsubstituted silyl group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group from each other to form a ring.

In an embodiment, the emission layer may further include a third compound represented by Formula M-b.

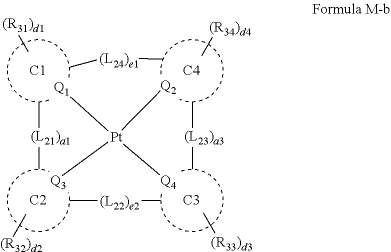

In Formula M-b, Q₁ to Q₄ are each independently C or N, C1 to C4 are each independently a substituted or unsubstituted hydrocarbon ring of 5 to 30 ring-forming carbon atoms, or a substituted or unsubstituted heterocycle of 2 to 30 ring-forming carbon atoms, e1 to e4 are each independently 0 or 1, L₂₁ to L₂₄ are each independently a direct linkage,

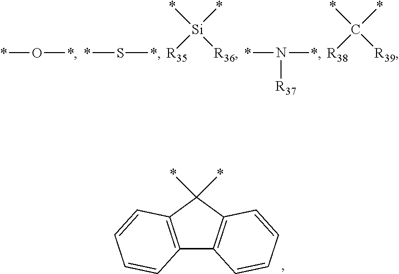

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, d1 to d4 are each independently an integer of 0 to 4, and R₃₁ to R₃₉ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group from each other to form a ring.

In an embodiment, the emission layer may include a host and a dopant, and the host may include the first compound.

In an embodiment, the emission layer may emit phosphorescence or thermally activated delayed fluorescence.

According to one or more embodiments of the present disclosure, a nitrogen-containing compound represented by Formula 1 is provided.

### BRIEF DESCRIPTION OF THE FIGURES

The accompanying drawings are included to provide a further understanding of the subject matter of the present disclosure and are incorporated in and constitute a part of this specification. The drawings illustrate embodiments of the present disclosure and, together with the description, serve to explain principles of the subject matter of the present disclosure. In the drawings:

FIG. 1 is a plan view showing a display device according to an embodiment;

FIG. 2 is a cross-sectional view showing a part corresponding to line I-I″ in FIG. 1;

FIG. 3 is a cross-sectional view schematically showing a light emitting element of an embodiment;

FIG. 4 is a cross-sectional view schematically showing a light emitting element of an embodiment;

FIG. 5 is a cross-sectional view schematically showing a light emitting element of an embodiment;

FIG. 6 is a cross-sectional view schematically showing a light emitting element of an embodiment;

FIG. 7 is a cross-sectional view showing a display device according to an embodiment;

FIG. 8 is a cross-sectional view showing a display device according to an embodiment;

FIG. 9 is a cross-sectional view showing a display device according to an embodiment;

FIG. 10 is a cross-sectional view showing a display device according to an embodiment; and

FIG. 11 is a cross-sectional view showing a display device according to an embodiment.

### DETAILED DESCRIPTION

The subject matter of the present disclosure may have various modifications and may be embodied in different forms, and example embodiments will be explained in more detail with reference to the accompany drawings. The subject matter of the present disclosure may, however, be embodied in different forms and should not be construed as limited to the embodiments set forth herein. Rather, all modifications, equivalents, and substituents which are included in the spirit and technical scope of the present disclosure should be included in the presented disclosure.

In the description, when an element (or a region, a layer, a part, etc.) is referred to as being “on”, “connected with” or “combined with” another element, it can be directly connected with/bonded on the other element, or intervening third elements may also be present.

Like reference numerals refer to like elements throughout. In the drawings, the thicknesses, ratios, and dimensions of elements are exaggerated for effective explanation of technical contents. “and/or” may include one or more combinations that may define relevant elements.

It will be understood that, although the terms first, second, etc. may be used herein to describe various elements, these elements should not be limited by these terms. These terms are only used to distinguish one element from another element. For example, a first element could be termed a second element without departing from the scope of the present disclosure. Similarly, a second element could be termed a first element. As used herein, the singular forms are intended to include the plural forms as well, unless the context clearly indicates otherwise.

In addition, the terms “below”, “beneath”, “on” and “above” are used for explaining the relation of elements shown in the drawings. The terms are a relative concept and are explained based on the direction shown in the drawing.

It will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this disclosure belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly so defined herein.

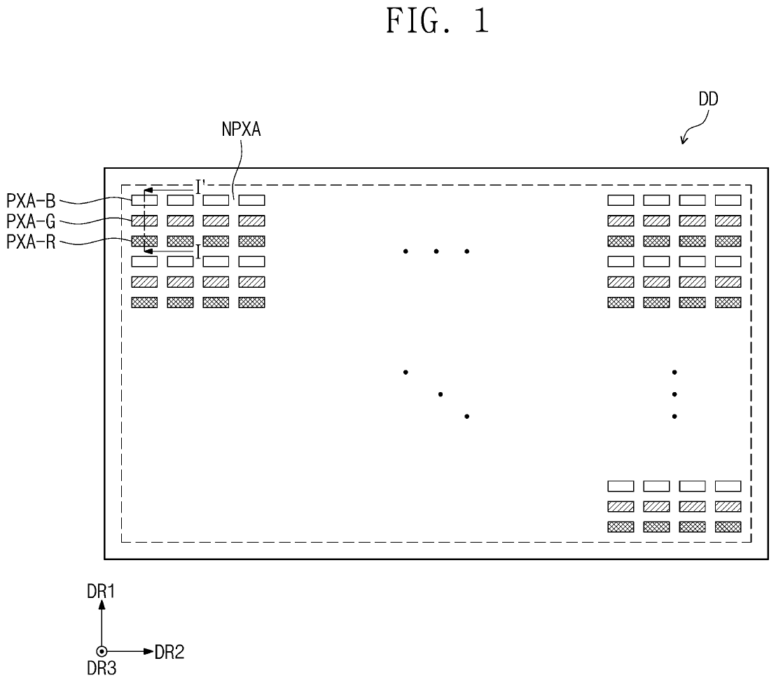

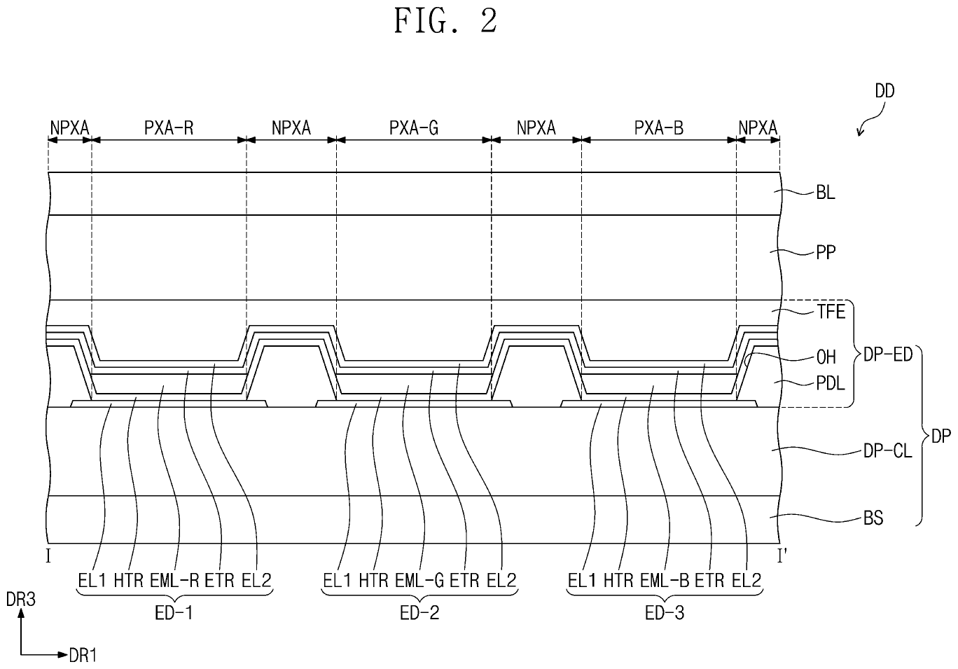

Hereinafter, embodiments of the present disclosure will be explained referring to the drawings. FIG. 1 is a plan view showing an embodiment of a display device DD. FIG. 2 is a cross-sectional view of a display device DD of an embodiment. FIG. 2 is a cross-sectional view showing a part corresponding to line I-I″ of FIG. 1.

The display device DD may include a display panel DP and an optical layer PP on the display panel DP. The display panel DP may include light emitting elements ED-1, ED-2 and ED-3. The display device DD may include a plurality of light emitting elements ED-1, ED-2 and ED-3. The optical layer PP may be on the display panel DP and control reflected light by external light at the display panel DP. The optical layer PP may include, for example, a polarization layer and/or a color filter layer. Different from the drawing shown in FIG. 2, the optical layer PP may be omitted in the display device DD of an embodiment.

A base substrate BL may be on the optical layer PP. The optical layer PP may be on a base surface of the base substrate BL. The base substrate BL may be a glass substrate, a metal substrate, a plastic substrate, etc. However, embodiments of the present disclosure are not limited thereto, and the base substrate BL may be an inorganic layer, an organic layer or a composite material layer. In addition, different from the drawings, the base substrate BL may be omitted in an embodiment.

The display device DD according to an embodiment may further include a plugging layer. The plugging layer may be between a display element layer DP-ED and a base substrate BL. The plugging layer may be an organic layer. The plugging layer may include at least one selected from among an acrylic resin, a silicon-based resin and an epoxy-based resin.

The display panel DP may include a base layer BS, a circuit layer DP-CL provided on the base layer BS and a display element layer DP-ED. The display element layer DP-ED may include a pixel definition layer PDL, light emitting elements ED-1, ED-2 and ED-3 in the pixel definition layer PDL, and an encapsulating layer TFE on the light emitting elements ED-1, ED-2 and ED-3.

The display element layer DP-ED may be on a base surface of the base layer BS. The base layer BS may be a glass substrate, a metal substrate, a plastic substrate, etc. However, embodiments of the present disclosure are not limited thereto, and the base layer BS may be an inorganic layer, an organic layer or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include switching transistors and driving transistors for driving the light emitting elements ED-1, ED-2 and ED-3 of the display element layer DP-ED.

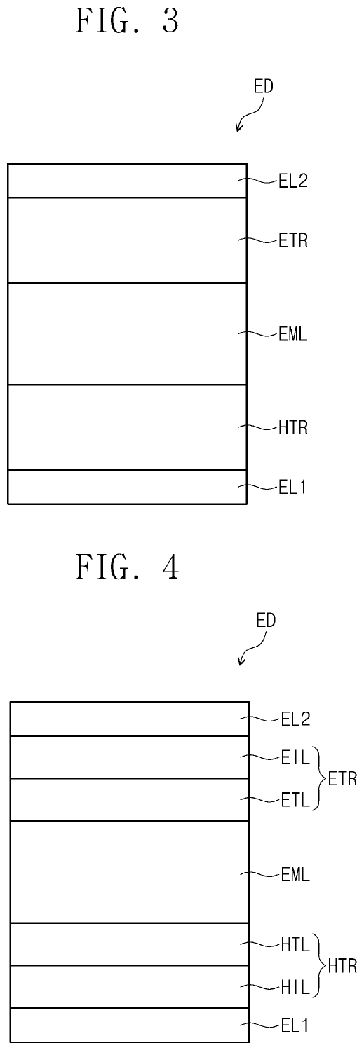

The light emitting elements ED-1, ED-2 and ED-3 may have the structures of the light emitting elements ED of embodiments according to FIG. 3 to FIG. 6, which will be explained later. The light emitting elements ED-1, ED-2 and ED-3 may include a first electrode EL1, a hole transport region HTR, emission layers EML-R, EML-G and EML-B, an electron transport region ETR and a second electrode EL2.

In FIG. 2, shown is an embodiment where the emission layers EML-R, EML-G and EML-B of light emitting elements ED-1, ED-2 and ED-3 are in opening portions OH defined in a pixel definition layer PDL, and a hole transport region HTR, an electron transport region ETR and a second electrode EL2 are provided as common layers in all light emitting elements ED-1, ED-2 and ED-3. However, embodiments of the present disclosure are not limited thereto. Different from FIG. 2, in an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting elements ED-1, ED-2 and ED-3 may be patterned by an ink jet printing method and provided.

An encapsulating layer TFE may cover the light emitting elements ED-1, ED-2 and ED-3. The encapsulating layer TFE may encapsulate the display element layer DP-ED. The encapsulating layer TFE may be a thin film encapsulating layer. The encapsulating layer TFE may be one layer or a stacked layer of a plurality of layers. The encapsulating layer TFE includes at least one insulating layer. The encapsulating layer TFE according to an embodiment may include at least one inorganic layer (hereinafter, encapsulating inorganic layer). In addition, the encapsulating layer TFE according to an embodiment may include at least one organic layer (hereinafter, encapsulating organic layer) and at least one encapsulating inorganic layer.

The encapsulating inorganic layer may protect the display element layer DP-ED from moisture/oxygen, and the encapsulating organic layer may protect the display element layer DP-ED from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be on the second electrode EL2 and may fill the opening portion OH.

Referring to FIG. 1 and FIG. 2, the display device DD may include a non-luminous area NPXA and luminous areas PXA-R, PXA-G and PXA-B. The luminous areas PXA-R, PXA-G and PXA-B may be areas emitting light produced from the light emitting elements ED-1, ED-2 and ED-3, respectively. The luminous areas PXA-R, PXA-G and PXA-B may be separated from each other on a plane.

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In the present disclosure, each of the luminous areas PXA-R, PXA-G and PXA-B may correspond to each pixel. The pixel definition layer PDL may divide the light emitting elements ED-1, ED-2 and ED-3. The emission layers EML-R, EML-G and EML-B of the light emitting elements ED-1, ED-2 and ED-3 may be divided in the opening portions OH defined in the pixel definition layer PDL.

The luminous areas PXA-R, PXA-G and PXA-B may be divided into a plurality of groups according to the color of light produced from the light emitting elements ED-1, ED-2 and ED-3. In the display device DD of an embodiment, shown in FIG. 1 and FIG. 2, three luminous areas PXA-R, PXA-G and PXA-B emitting red light, green light and blue light are illustrated as an embodiment. For example, the display device DD of an embodiment may include a red luminous area PXA-R, a green luminous area PXA-G and a blue luminous area PXA-B, which are separated from each other.

In the display device DD according to an embodiment, a plurality of light emitting elements ED-1, ED-2 and ED-3 may emit light having different wavelength regions. For example, in an embodiment, the display device DD may include a first light emitting element ED-1 emitting red light, a second light emitting element ED-2 emitting green light, and a third light emitting element ED-3 emitting blue light. In one or more embodiments, each of the red luminous area PXA-R, the green luminous area PXA-G, and the blue luminous area PXA-B of the display device DD may correspond to the first light emitting element ED-1, the second light emitting element ED-2, and the third light emitting element ED-3.

However, embodiments of the present disclosure are not limited thereto, and the first to third light emitting elements ED-1, ED-2 and ED-3 may emit light in the same wavelength region, or at least one thereof may emit light in a different wavelength region. For example, all the first to third light emitting elements ED-1, ED-2 and ED-3 may emit blue light.

The luminous areas PXA-R, PXA-G and PXA-B in the display device DD according to an embodiment may be arranged in a stripe shape. Referring to FIG. 1, a plurality of red luminous areas PXA-R, a plurality of green luminous areas PXA-G and a plurality of blue luminous areas PXA-B may be arranged along a second directional axis DR2. In addition, the red luminous area PXA-R, the green luminous area PXA-G and the blue luminous area PXA-B may be arranged by turns along a first directional axis DR1.

In FIG. 1 and FIG. 2, the areas of the luminous areas PXA-R, PXA-G and PXA-B are shown similar, but embodiments of the present disclosure are not limited thereto. The areas of the luminous areas PXA-R, PXA-G and PXA-B may be different from each other according to the wavelength region of light emitted. In one or more embodiments, the areas of the luminous areas PXA-R, PXA-G and PXA-B may mean areas on a plane defined by the first directional axis DR1 and the second directional axis DR2.

In one or more embodiments, the arrangement type (or kind) of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in various suitable combinations according to the properties of display quality required for the display device DD. For example, the arrangement type of the luminous areas PXA-R, PXA-G and PXA-B may be a PENTILE® arrangement structure (e.g., an RGBG matrix, RGBG structure, or RGBG matrix structure), or a diamond (Diamond Pixel™) arrangement structure. PENTILE® is a duly registered trademark of Samsung Display Co., Ltd.

In addition, the areas of the luminous areas PXA-R, PXA-G and PXA-B may be different from each other. For example, in an embodiment, the area of the green luminous area PXA-G may be smaller than the area of the blue luminous area PXA-B, but embodiments of the present disclosure are not limited thereto.

Hereinafter, FIG. 3 to FIG. 7 are cross-sectional views schematically showing light emitting elements according to embodiments. The light emitting element ED according to an embodiment may include a first electrode EL1, a hole transport region HTR, an emission layer EML, an electron transport region ETR, and a second electrode EL2, stacked in order.

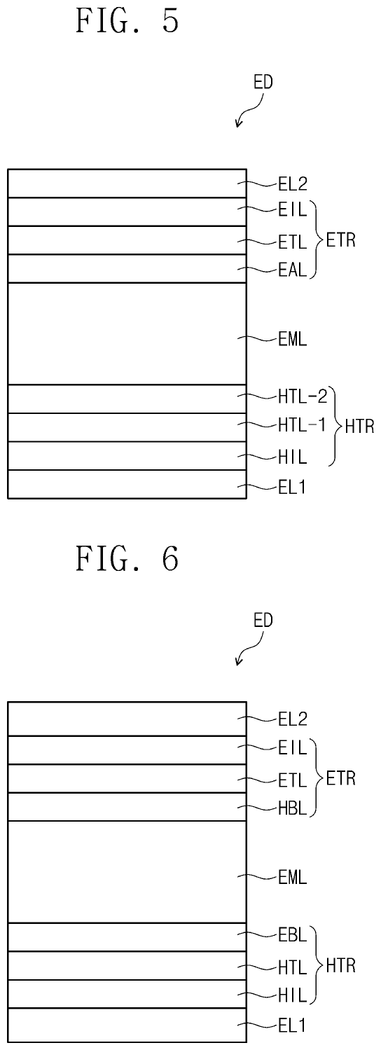

When compared to FIG. 3, FIG. 4 shows the cross-sectional view of a light emitting element ED of an embodiment, wherein a hole transport region HTR includes a hole injection layer HIL and a hole transport layer HTL, and an electron transport region ETR includes an electron injection layer EIL and an electron transport layer ETL. When compared to FIG. 3, FIG. 5 shows the cross-sectional view of a light emitting element ED of an embodiment, wherein a hole transport region HTR includes a hole injection layer HIL, a first hole transport layer HTL-1, and a second hole transport layer HTL-2, and an electron transport region ETR includes an electron injection layer EIL, an electron transport layer ETL, and an emission auxiliary layer EAL. However, different from the drawing, the emission auxiliary layer EAL may be omitted.

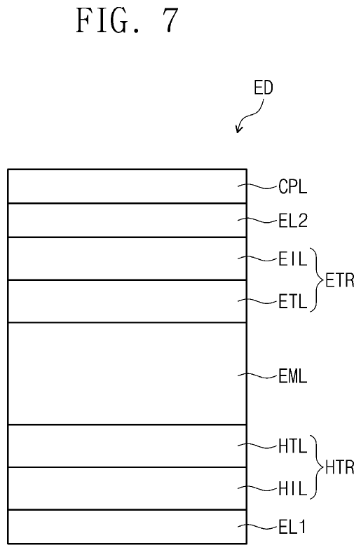

When compared to FIG. 3, FIG. 6 shows the cross-sectional view of a light emitting element ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared to FIG. 4, FIG. 7 shows the cross-sectional view of a light emitting element ED of an embodiment, including a capping layer CPL on the second electrode EL2.

In an embodiment, the light emitting element ED may include a first compound in at least one functional layer between the first electrode EL1 and the second electrode EL2. The at least one functional layer may include an emission layer EML and an electron transport region ETR. For example, at least one selected from among the emission layer EML and the emission auxiliary layer EAL of the electron transport region ETR may include the first compound of an embodiment. In the present description, the first compound is the same as the nitrogen-containing compound. In one or more embodiments, the nitrogen-containing compound may be referred to as the first compound. The nitrogen-containing compound of an embodiment may include a hexagonal monocyclic group including a nitrogen atom as a ring-forming atom, at least one silyl group and at least one deuterium atom directly or indirectly bonded to the hexagonal monocycle. Accordingly, the light emitting element ED including the nitrogen-containing compound of an embodiment may show long-life characteristics and improved color coordinates of light emitted.

In the description, the term “substituted or unsubstituted” corresponds to substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the described substituents may be substituted or unsubstituted. For example, a biphenyl group may be interpreted as an aryl group or a phenyl group substituted with a phenyl group.

In the description, the term “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In addition, the ring formed via the combination with an adjacent group may be combined with another ring to form a spiro structure.

In the description, the term “adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In addition, in 4,5-dimethylphenanthrene, two methyl groups may be interpreted as “adjacent groups” to each other.

In the description, a halogen atom may be a fluorine atom, a chlorine atom, a bromine atom or an iodine atom.

In the description, an alkyl group may be a linear, branched, or cyclic type (or kind). The carbon number of the alkyl group may be 1 to 60, 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, an alkenyl group means a hydrocarbon group including one or more carbon double bonds in the middle or at the terminal of an alkyl group having a carbon number of 2 or more. The alkenyl group may be a linear chain or a branched chain. The carbon number is not specifically limited, but may be 2 to 60, 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

In the description, an alkynyl group means a hydrocarbon group including one or more carbon triple bonds in the middle or at the terminal of an alkyl group having a carbon number of 2 or more. The alkynyl group may be a linear chain or a branched chain. The carbon number is not specifically limited, but may be 2 to 60, 2 to 30, 2 to 20, or 2 to 10. Examples of the alkynyl group include an ethynyl group, a propynyl group, etc., without limitation.

In the description, a hydrocarbon ring group means an optional functional group or substituent derived from an aliphatic hydrocarbon ring. The hydrocarbon ring group may be a saturated hydrocarbon ring group of 5 to 60, or 5 to 30 ring-forming carbon atoms.

In the description, an aryl group means an optional functional group or substituent derived from an aromatic hydrocarbon ring. The aryl group may be a monocyclic aryl group or a polycyclic aryl group. The carbon number for forming rings in the aryl group may be 6 to 60, 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, a fluorenyl group may be substituted, and two substituents may be combined with each other to form a spiro structure. Examples of a substituted fluorenyl group are as follows, but embodiments of the present disclosure are not limited thereto.

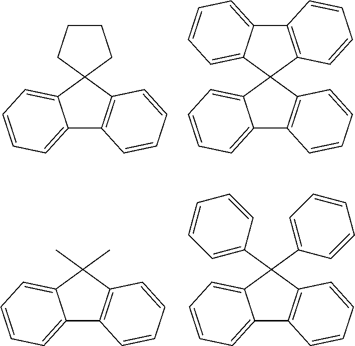

In the description, a heterocyclic group means an optional functional group or substituent derived from a ring including one or more selected from among B, O, N, P, Si, and S as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

In the description, a heterocyclic group may include one or more selected from among B, O, N, P, Si and S as heteroatoms. If the heterocyclic group includes two or more heteroatoms, two or more heteroatoms may be the same or different. The heterocyclic group may be a monocyclic heterocyclic group or polycyclic heterocyclic group and has concept including a heteroaryl group. The carbon number for forming rings of the heterocyclic group may be 2 to 60, 2 to 30, 2 to 20, or 2 to 10.

In the description, an aliphatic heterocyclic group may include one or more selected from among B, O, N, P, Si, and S as heteroatoms. The number of ring-forming carbon atoms of the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the description, a heteroaryl group may include one or more selected from among B, O, N, P, Si, and S as heteroatoms. If the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 60, 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the description, a silyl group may mean the above-defined alkyl group or aryl group bonded to a silicon atom. The carbon number of the silyl group is not specifically limited, but may be 1 to 40, 1 to 30, or 1 to 20. The silyl group includes an alkyl silyl group and an aryl silyl group. Examples of the silyl group include a trimethylsilyl group, a triethylsilyl group, a t-butyldimethylsilyl group, ethyldimethylsilyl group, a propyldimethylsilyl group, a triphenylsilyl group, a diphenylsilyl group, a phenylsilyl group, etc., without limitation.

In the description, the carbon number of a carbonyl group is not specifically limited, but the carbon number may be 1 to 40, 1 to 30, or 1 to 20. For example, the carbonyl group may have the structures below, but is not limited thereto.

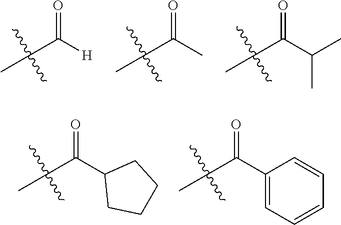

In the description, the carbon numbers of a sulfinyl group and sulfonyl group are not specifically limited, but may be 1 to 40, 1 to 30, or 1 to 20. The sulfinyl group may include an alkyl sulfinyl group and an aryl sulfinyl group. The sulfonyl group may include an alkyl sulfonyl group and an aryl sulfonyl group.

In the description, a thio group may include an alkyl thio group and an aryl thio group. The thio group may mean the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, an oxy group may mean the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not specifically limited but may be, for example, 1 to 30, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, embodiments of the present disclosure are not limited thereto.

In the description, a boron group may mean the above-defined alkyl group or aryl group bonded to a boron atom. The carbon number of the boron group is not specifically limited, but may be 1 to 40, 1 to 30, or 1 to 20. The boron group may include an alkyl boron group and an aryl boron group. Examples of the boron group include a dimethylboron group, a diethylboron group, a t-butylmethylboron group, a diphenylboron group, a phenylboron group, or the like, without limitation.

In the description, the carbon number of an amine group is not specifically limited, but may be 1 to 40, 1 to 30 or 1 to 20. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, a triphenylamine group, etc., without limitation.

In the description, alkyl groups in an alkyl thio group, an alkyl sulfinyl group, an alkyl sulfonyl group, an alkoxy group, an alkyl amine group, an alkyl boron group, an alkyl silyl group, and an alkyl amine group may be the same as the examples of the above-described alkyl group.

In the description, aryl groups in an aryl oxy group, an aryl thio group, an aryl sulfinyl group, an aryl sulfonyl group, an aryl amine group, an aryl boron group, an aryl silyl group, and an aryl amine group may be the same as the examples of the above-described aryl group.

In the description, a direct linkage may mean a single bond. In the description,

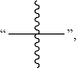

and “-⋅” mean positions to be connected.

The light emitting element ED of an embodiment may include the nitrogen-containing compound of an embodiment. The nitrogen-containing compound of an embodiment may be represented by Formula 1 below.

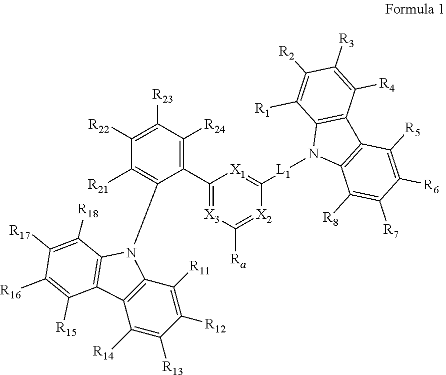

In Formula 1, at least two selected from among X₁ to X₃ may be N, and the remainder may be CH. If any two selected from among X₁ to X₃ are N, the nitrogen-containing compound of an embodiment may include pyridine as a central structure. If all X₁ to X₃ are N, the nitrogen-containing compound of an embodiment may include triazine as a central structure.

L₁ may be a direct linkage or a substituted or unsubstituted arylene group of 6 to 30 ring-forming carbon atoms. If L₁ is an arylene group, L₁ may be a monocyclic arylene group. For example, L₁ may be a direct linkage or a substituted or unsubstituted phenylene group.

Rₐ, R₁ to R₈, R₁₁ to R₁₈, and R₂₁ to R₂₄ may be each independently a hydrogen atom, a deuterium atom, a substituted or unsubstituted silyl group, a substituted or unsubstituted alkyl group of 1 to 30 carbon atoms, a substituted or unsubstituted alkenyl group of 2 to 30 carbon atoms, a substituted or unsubstituted aryl group of 6 to 30 ring-forming carbon atoms, or a substituted or unsubstituted heteroaryl group or 2 to 30 ring-forming carbon atoms. For example, Rₐ may be a substituted or unsubstituted aryl group of 6 to 30 ring-forming carbon atoms, or a substituted or unsubstituted heteroaryl group of 2 to 30 ring-forming carbon atoms.

In an embodiment, at least one selected from among Rₐ, R₁ to R₈, R₁₁ to R₁₈, and R₂₁ to R₂₄ may be represented by Formula 2, or may include a first substituent substituted with Formula 2. Formula 2 may represent a substituted or unsubstituted silyl group. The first substituent may be substituted with a substituted or unsubstituted silyl group.

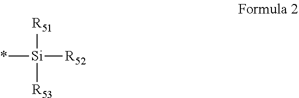

In Formula 2, R₅₁ to R₅₃ may be each independently a hydrogen atom, a deuterium atom, a substituted or unsubstituted silyl group, a substituted or unsubstituted alkyl group of 1 to 30 carbon atoms, a substituted or unsubstituted alkenyl group of 2 to 30 carbon atoms, a substituted or unsubstituted aryl group of 6 to ring-forming carbon atoms, or a substituted or unsubstituted heteroaryl group or 2 to ring-forming carbon atoms. For example, R₅₁ to R₅₃ may be each independently a substituted or unsubstituted aryl group of 6 to 30 ring-forming carbon atoms.

The first substituent may be an aryl group of 6 to 30 ring-forming carbon atoms, which is substituted with a silyl group, or a heteroaryl group of 2 to 30 ring-forming carbon atoms, which is substituted with a silyl group. In one or more embodiments, the nitrogen-containing compound of an embodiment may be an aryl group of 6 to 30 ring-forming carbon atoms, which is substituted with a silyl group, or a heteroaryl group of 2 to 30 ring-forming carbon atoms, which is substituted with a silyl group.

In an embodiment, at least one selected from among Rₐ, R₁ to R₈, R₁₁ to R₁₈, R₂₁ to R₂₄, and R₅₁ to R₅₃ may be a deuterium atom, or may include a second substituent substituted with a deuterium atom. For example, the second substituent may include at least one selected from among a phenyl group substituted with a deuterium atom, a silyl group substituted with a deuterium atom, and a carbazole group substituted with a deuterium atom.

The first substituent and the second substituent may be the same or different. If the first substituent and the second substituent are the same, at least one selected from among Rₐ, R₁ to R₈, R₁₁ to R₁₈, R₂₁ to R₂₄, and R₅₁ to R₅₃ may include a substituent substituted with a deuterium atom and a silyl group.

The second substituent may be represented by any one selected from among S-1 to S-10 below. S-1 to S-3 represent phenyl groups substituted with deuterium atoms, and S-4 and S-5 represent silyl groups substituted with deuterium atoms. S-6 to S-10 represent carbazole groups substituted with deuterium atoms. In S-1 to S-10, D is a deuterium atom.

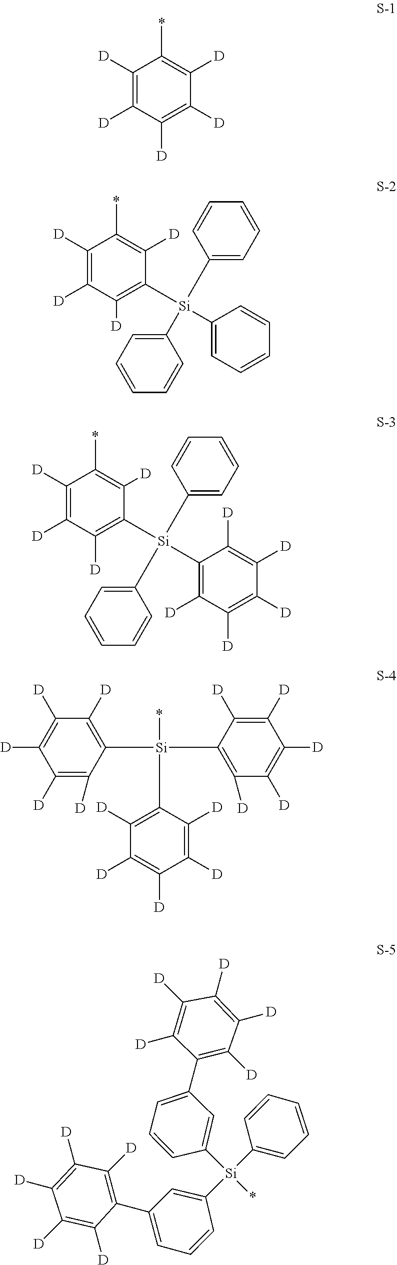

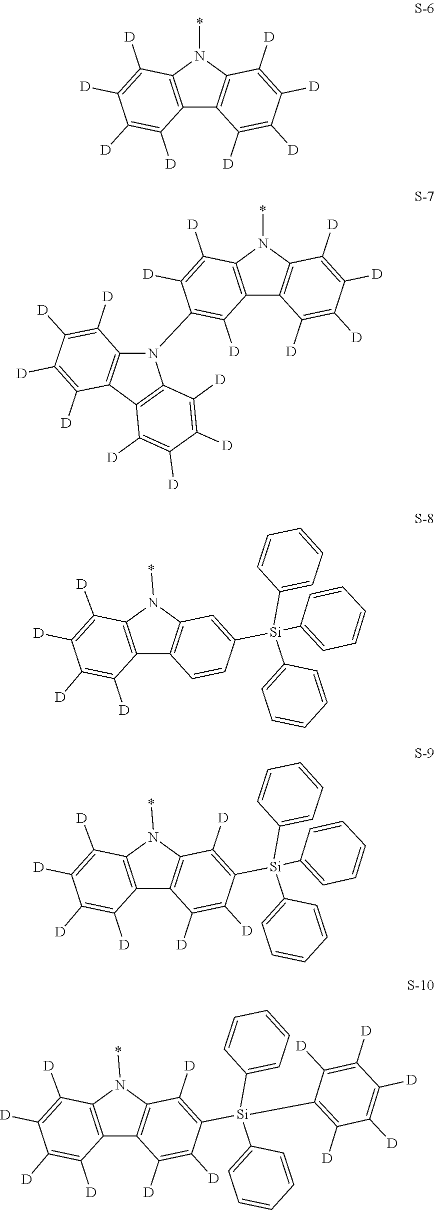

In an embodiment, Formula 2 may be represented by Formula 2-1. Formula 2-1 represents a case of Formula 2 where R₅₁ to R₅₃ are substituted or unsubstituted phenyl groups. Formula 2-1 represents a substituted or unsubstituted triphenylsilyl group. The nitrogen-containing compound of an embodiment may include at least one triphenylsilyl group as a substituent.

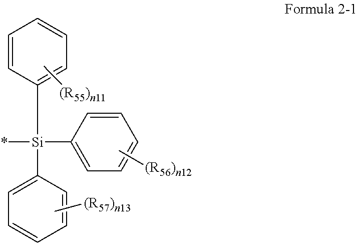

In Formula 2-1, n11 to n13 may be each independently an integer of 0 to 5. If n11 is an integer of 2 or more, a plurality of R₅₅ may be the same, or at least one thereof may be different. If n12 is an integer of 2 or more, a plurality of R₅₆ may be the same, or at least one thereof may be different. If n13 is an integer of 2 or more, a plurality of R₅₇ may be the same, or at least one thereof may be different.

R₅₅ to R₅₇ may be each independently a hydrogen atom, a deuterium atom, or a substituted or unsubstituted aryl group of 6 to 30 ring-forming carbon atoms. For example, R₅₅ to R₅₇ may be each independently a hydrogen atom, a deuterium atom, or a substituted or unsubstituted phenyl group.

Formula 1 may be represented by Formula 1-A1 or Formula 1-A2. Formula 1-A1 and Formula 1-A2 represent Formula 1 where X₁ to X₃ are embodied.

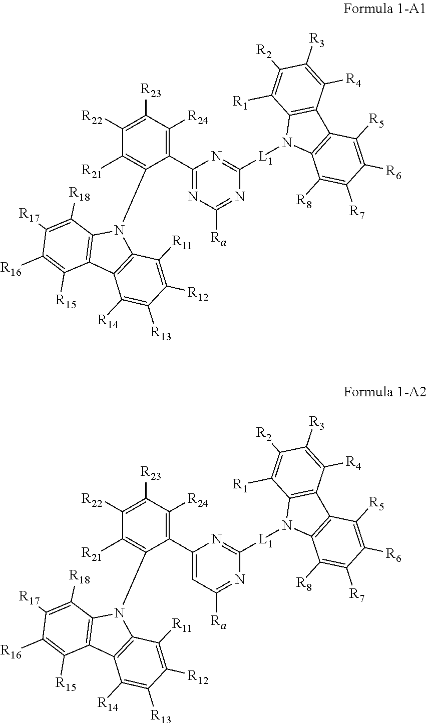

Formula 1-A1 represents a case of Formula 1 where all X₁ to X₃ are N. Formula 1-A2 represents a case of Formula 1 where any two selected from among X₁ to X₃ are N. In Formula 1-A1 and Formula 1-A2, the same contents explained referring to Formula 1 may be applied for L₁, Rₐ, R₁ to R₈, R₁₁ to R₁₈, and R₂₁ to R₂₄.

In an embodiment, Formula 1 may be represented by any one selected from among Formula 1-B1 to Formula 1-64. Formula 1-B1 to Formula 1-B4 represent cases of Formula 1 where at least one selected from among Rₐ, R₁ to R₈, R₁₁ to R₁₈, and R₂₁ to R₂₄ is represented by Formula 2, or includes a first substituent substituted with Formula 2.

Formula 1-B1 represents a case of Formula 1 where R₂₃, which is the substituent of a phenyl group, is represented by Formula 2. Formula 1-B2 represents a case of Formula 1 where R₁₇, which is the substituent of a carbazole group bonded to a phenyl group, is represented by Formula 2. Formula 1-B3 represents a case of Formula 1 where R₇, which is the substituent of a carbazole group bonded to a central structure via L₁, is represented by Formula 2. Formula 1-B4 represents a case of Formula 1 where Rₐ is a substituted phenyl group, and the phenyl group is substituted with Formula 2.

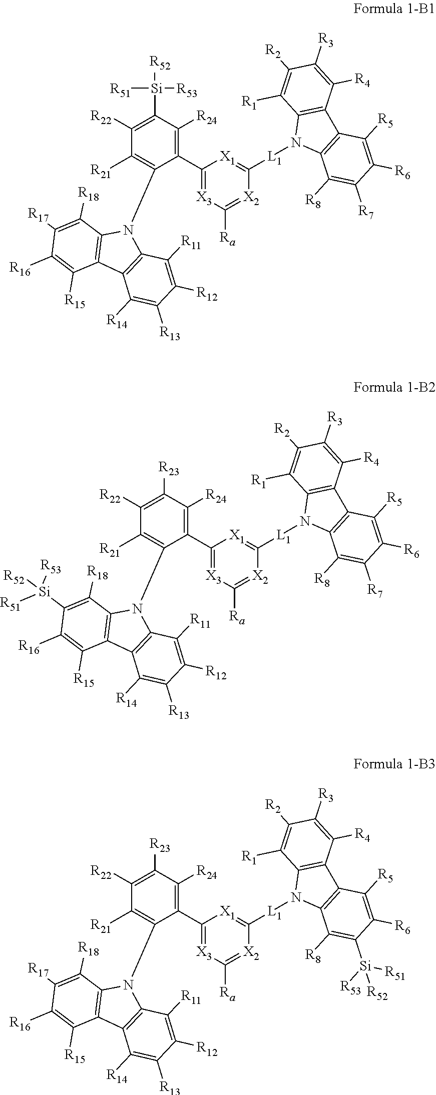

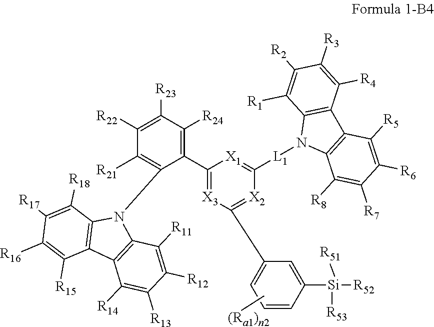

In Formula 1-64, n2 may be an integer of 0 to 4. If n2 is an integer of 2 or more, a plurality of Rai may be the same, or at least one thereof may be different. Rai may be a hydrogen atom, a deuterium atom, or a substituted or unsubstituted aryl group of 6 to 30 ring-forming carbon atoms. In Formula 1-61 to Formula 1-B4, the same contents explained referring to Formula 1 and Formula 2 may be applied for L₁, Rₐ, R₁ to R₈, R₁₁ to R₁₈, R₂₁ to R₂₄, and R₅₁ to R₅₃.

For example, in Formula 1-61, Rₐ may be a substituted or unsubstituted phenyl group or a substituted carbazole group. In Formula 1-61, Rₐ may be represented by the above-explained S-1 to S-3, S-6, or S-9. In addition, in Formula 1-61, at least one selected from among R₁ to R₈ may not be a hydrogen atom. For example, in Formula 1-61, at least one selected from among R₁ to R₈ may be a deuterium atom or a triphenylsilyl group. However, these are examples, and embodiments of the present disclosure are not limited thereto.

The nitrogen-containing compound of an embodiment may be represented by any one selected from among the compounds in Compound Group 1. The light emitting element ED of an embodiment may include at least one selected from among the compounds in Compound Group 1. In Compound Group 1, D is a deuterium atom.

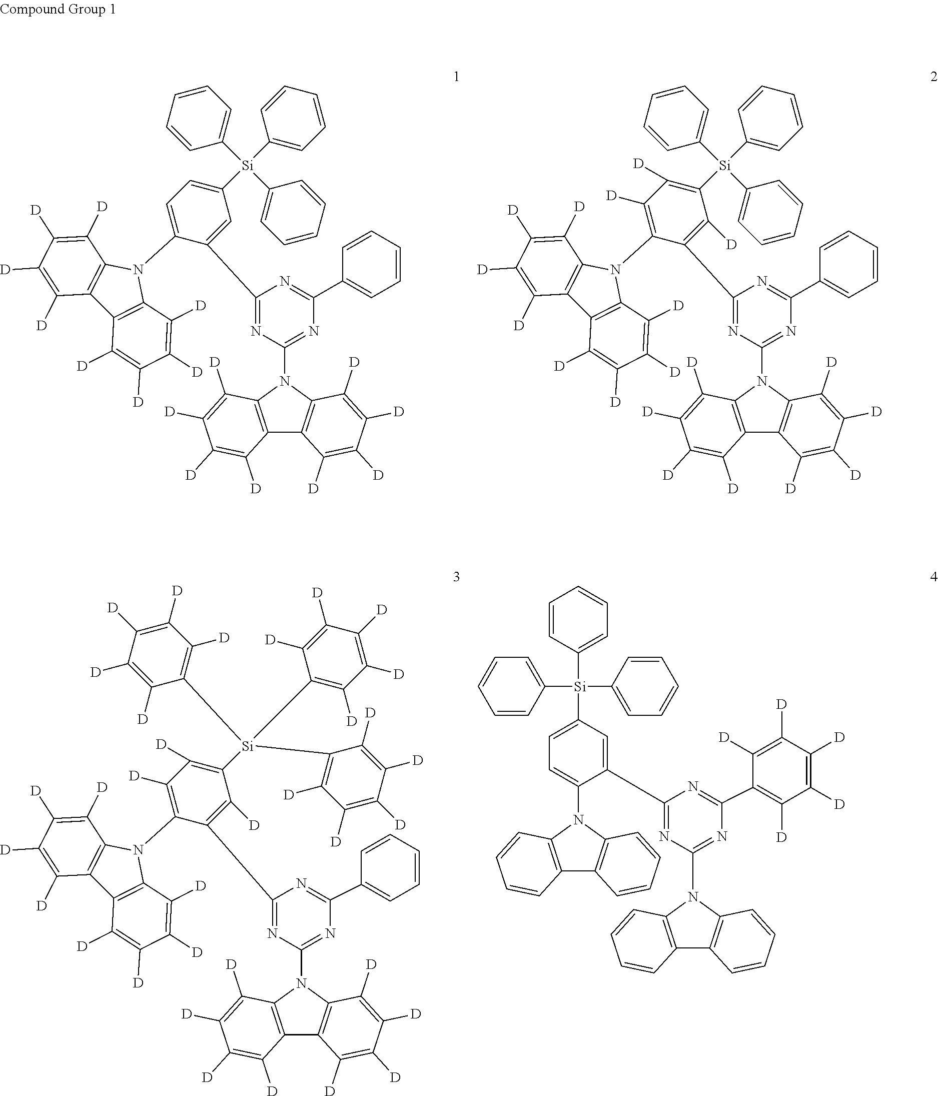

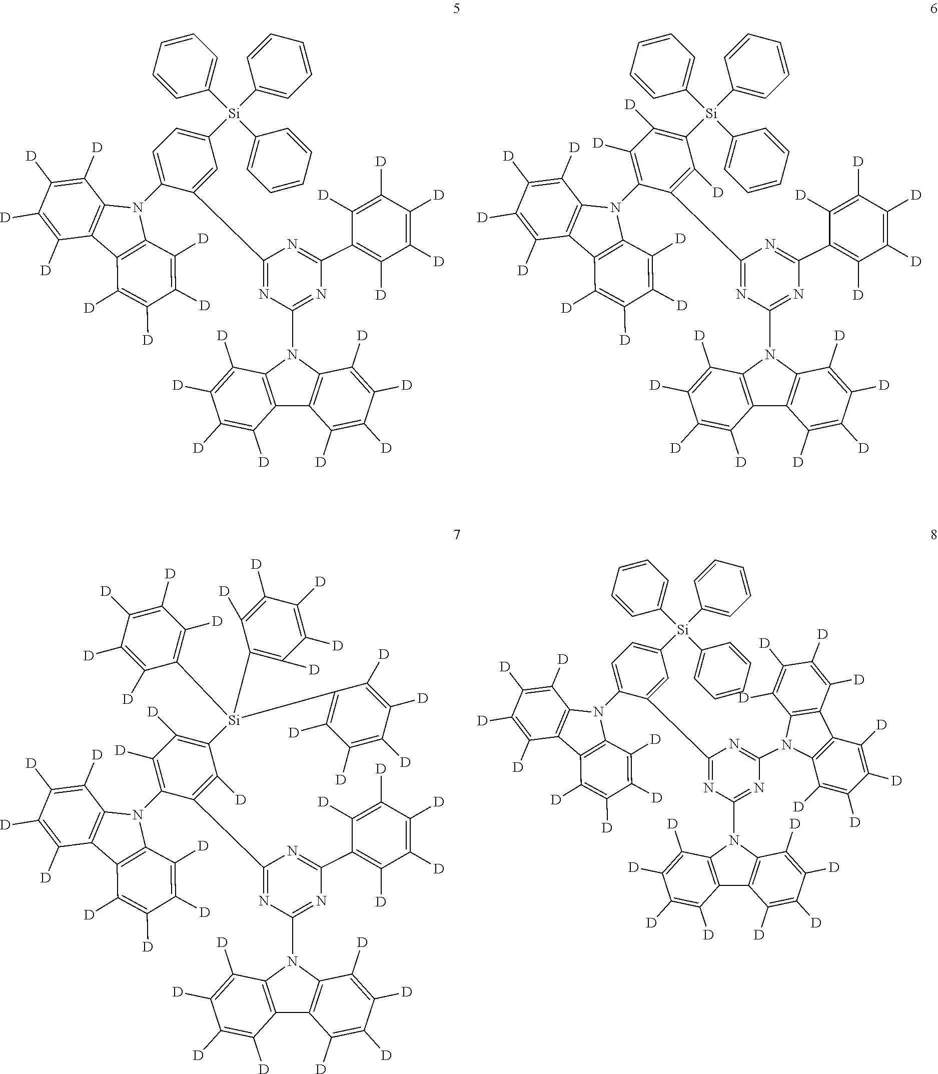

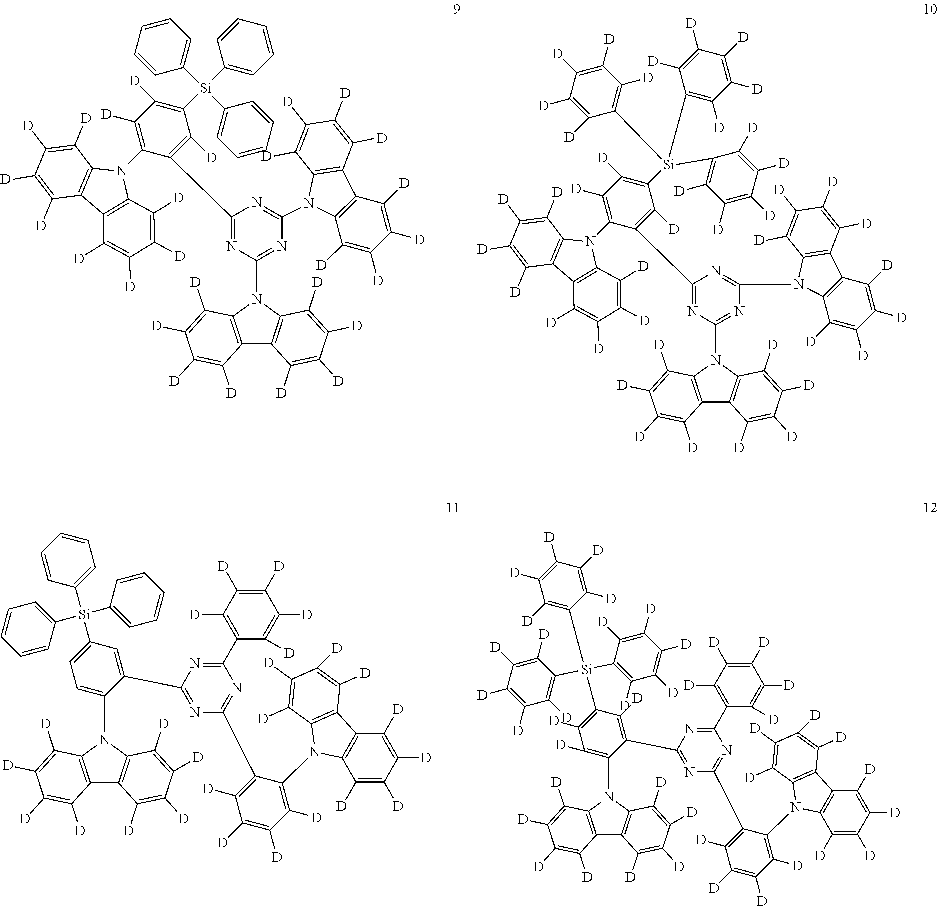

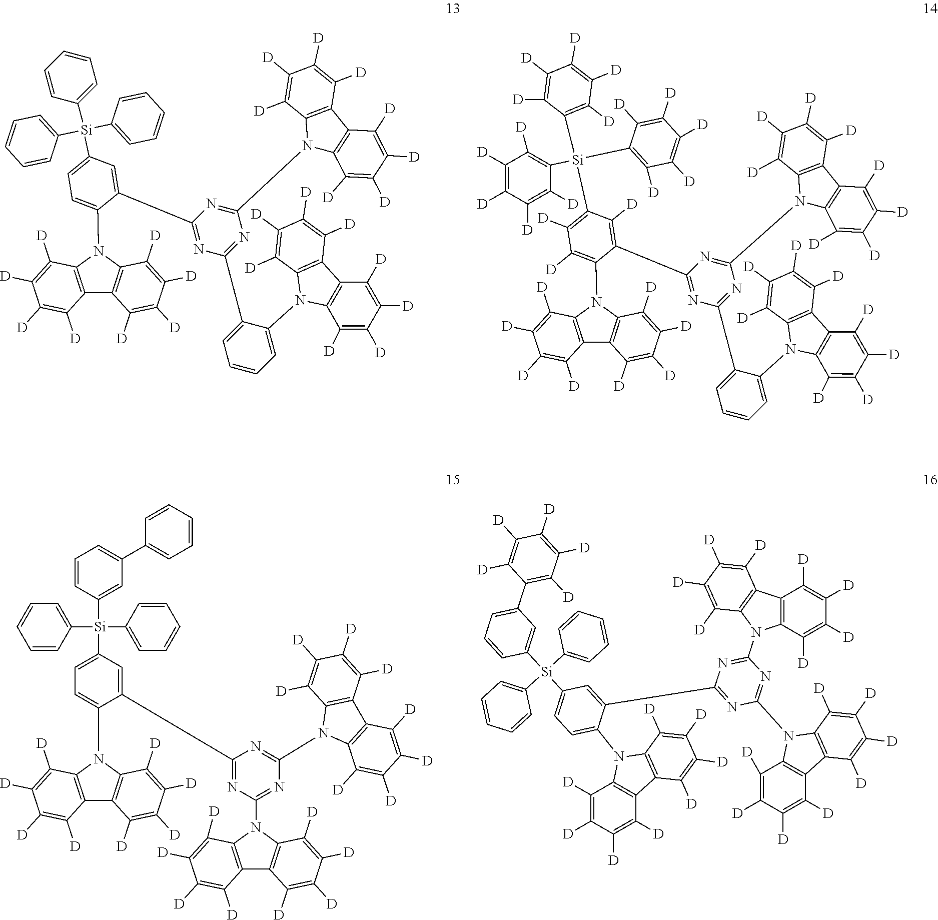

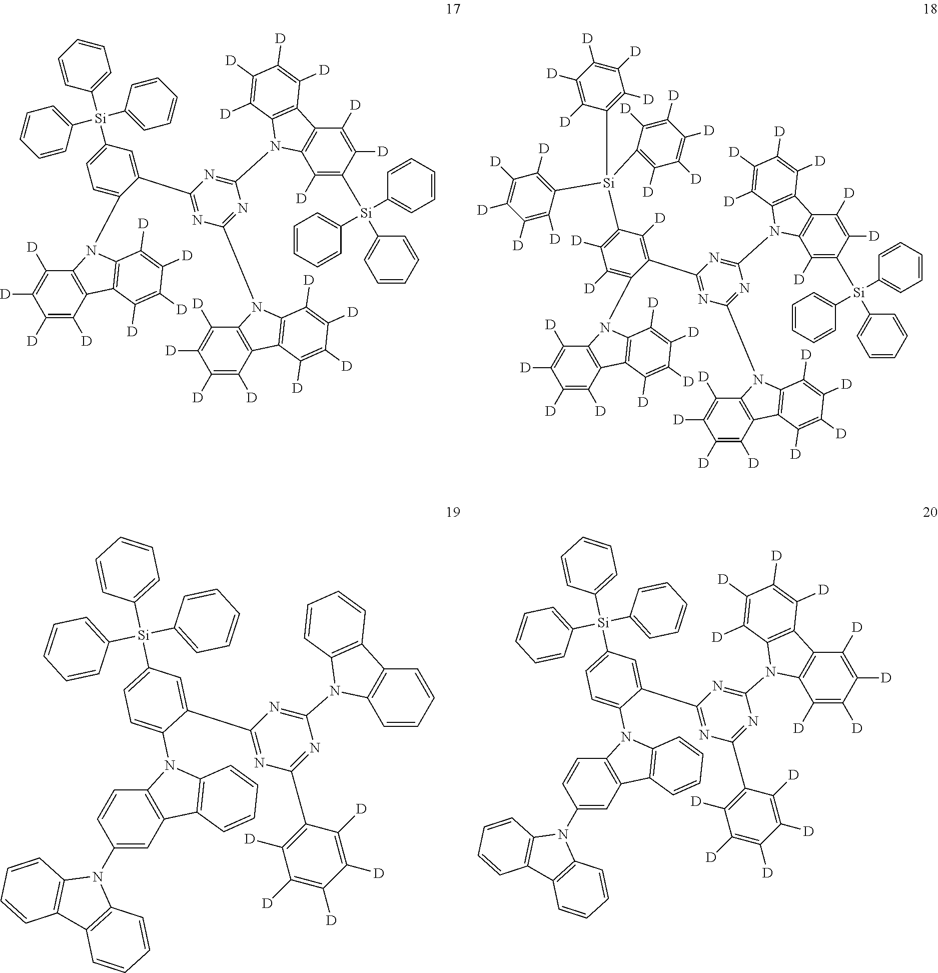

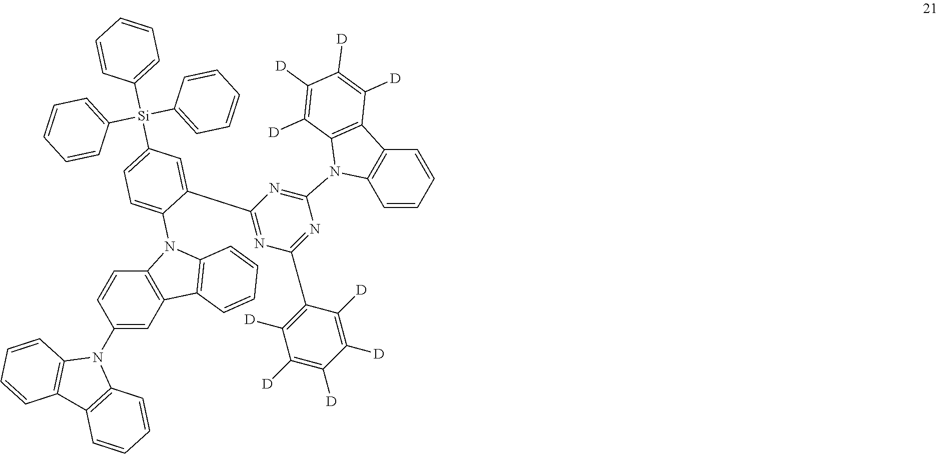 [SMILES: [2H]c1c([2H])c([2H])c(-c2nc(-c3cc([Si](c4ccccc4)(c4ccccc4)c4ccccc4)ccc3-n3c4ccccc4c4cc(-n5c6ccccc6c6ccccc65)ccc43)nc(-n3c4ccccc4c4c([2H])c([2H])c([2H])c([2H])c43)n2)c([2H])c1[2H]]

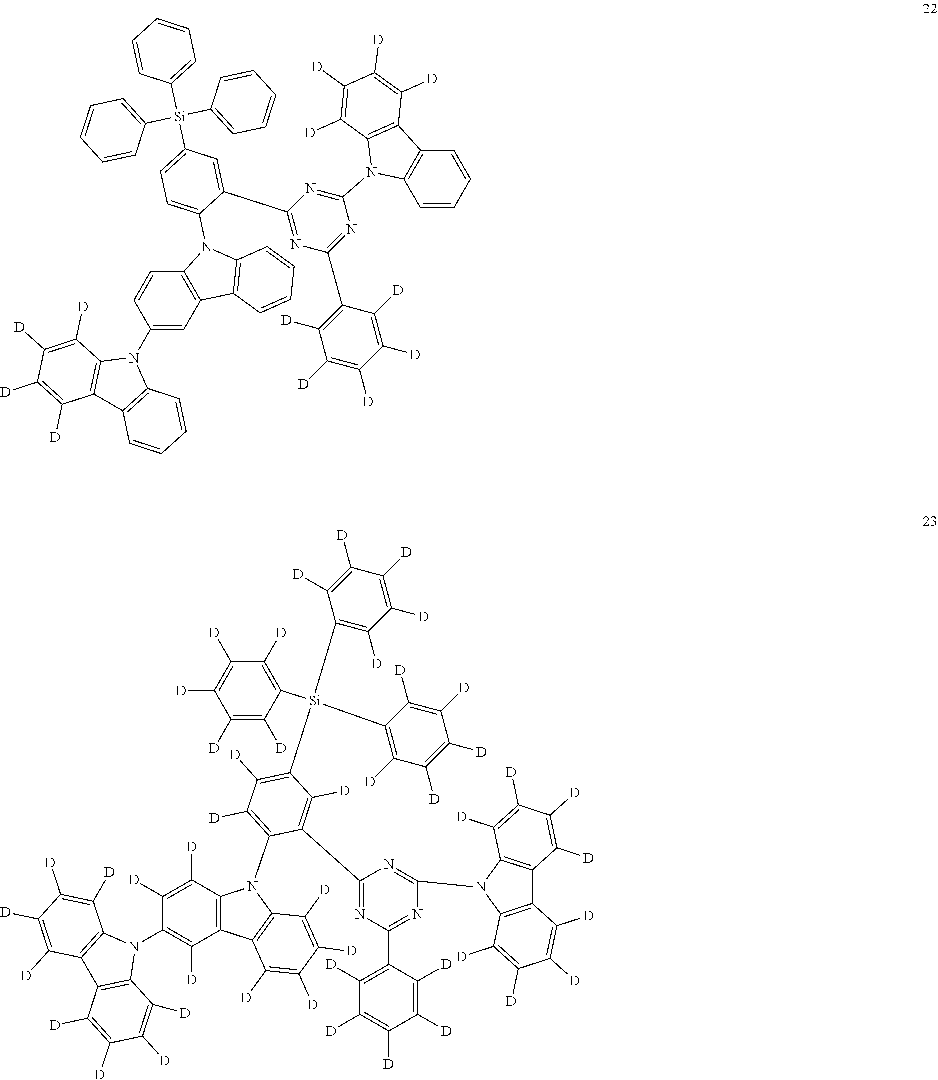

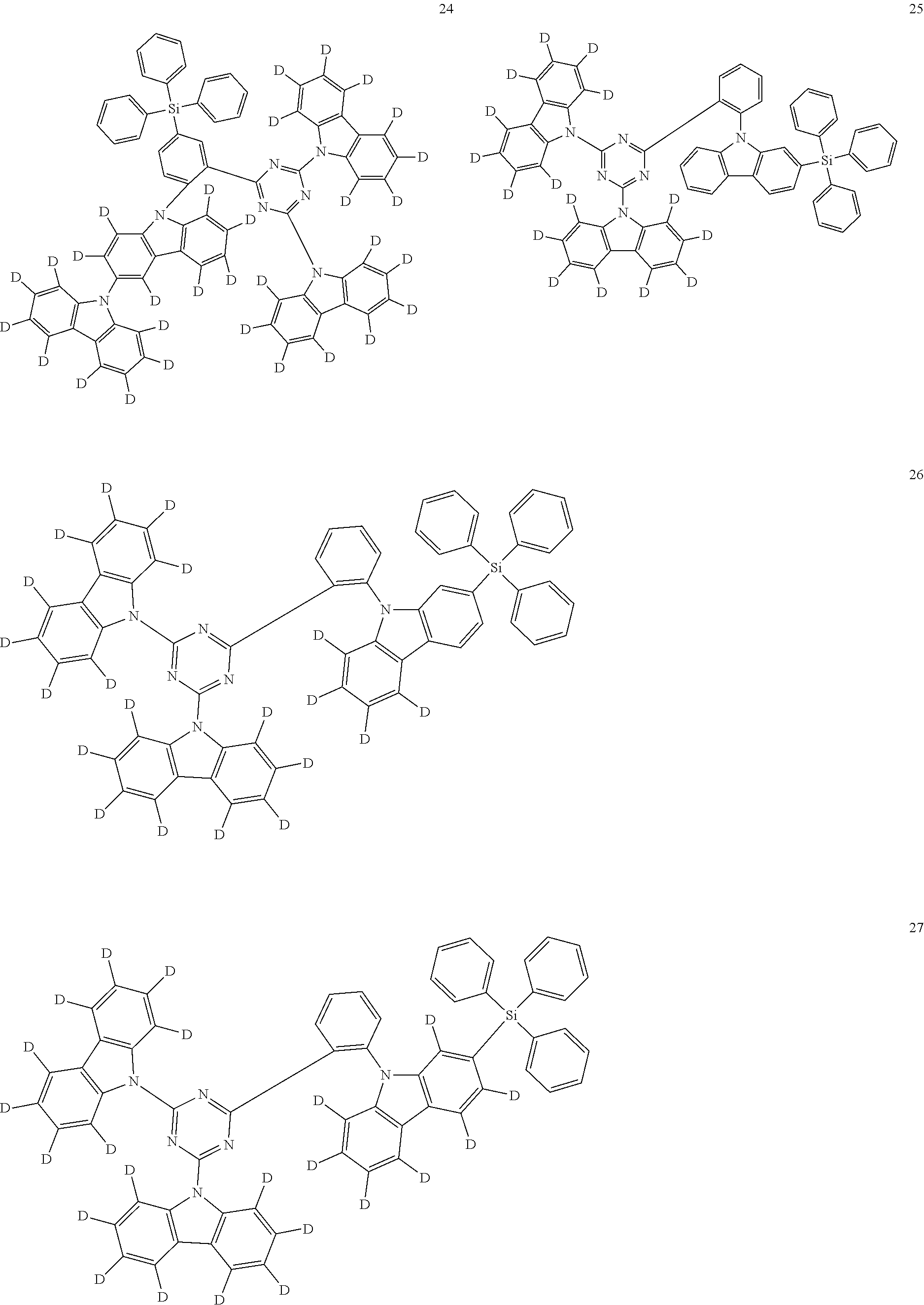

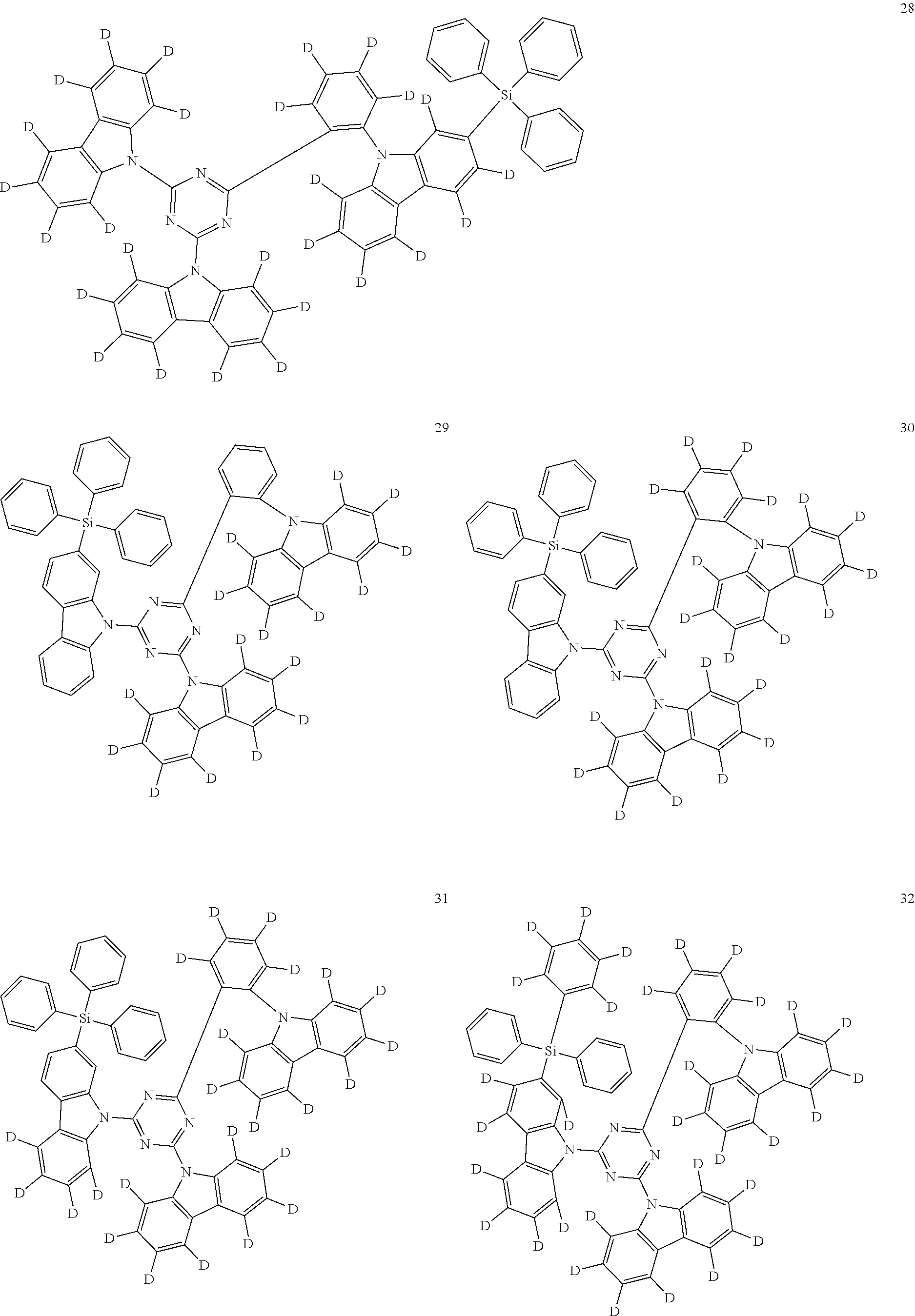

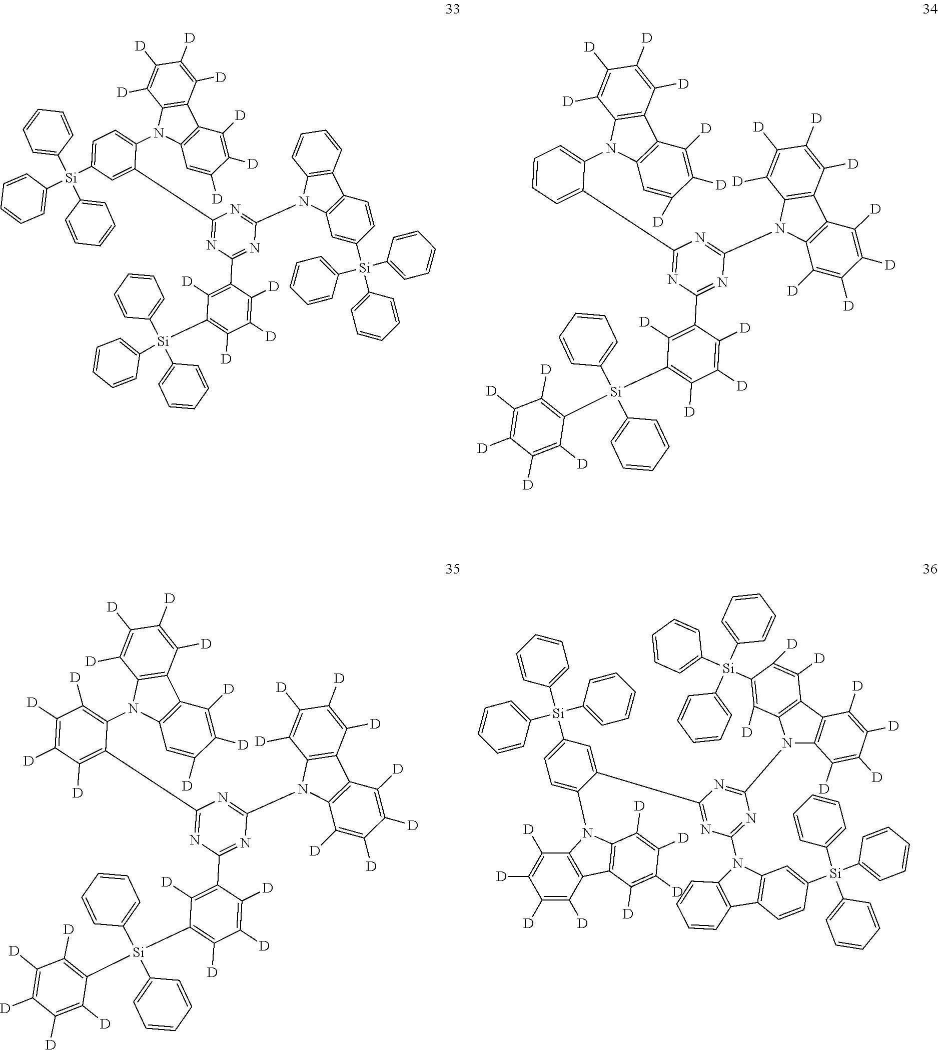

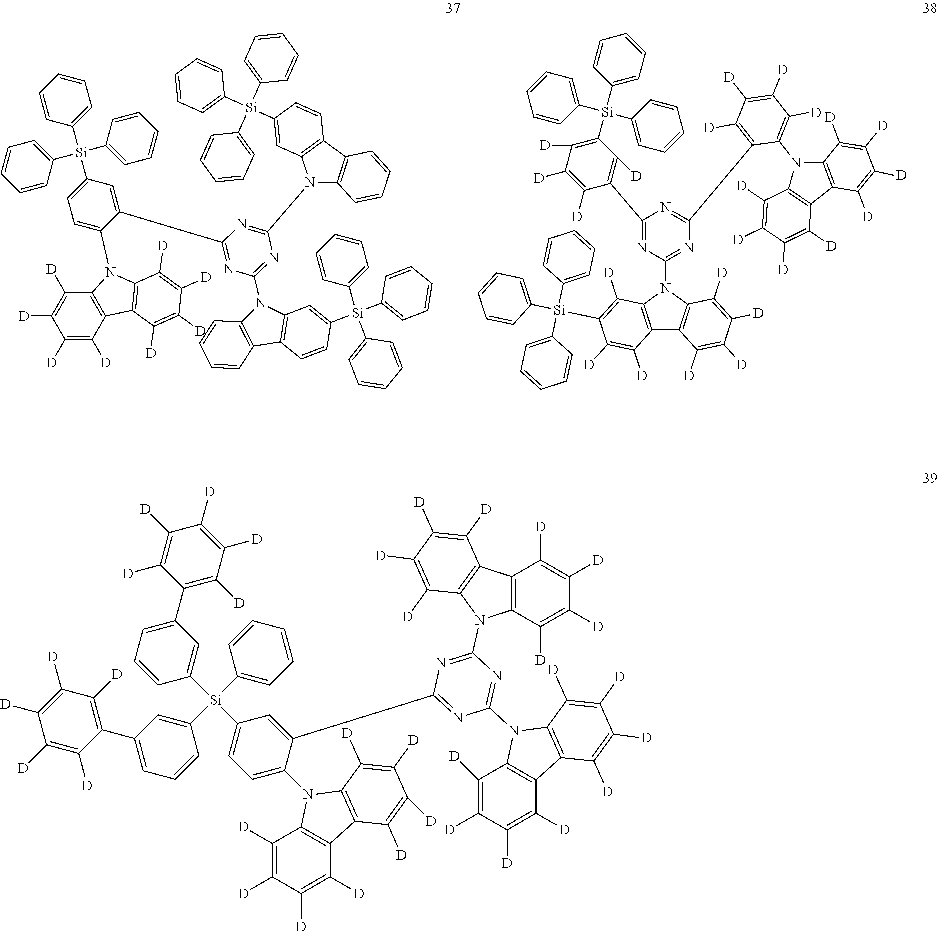

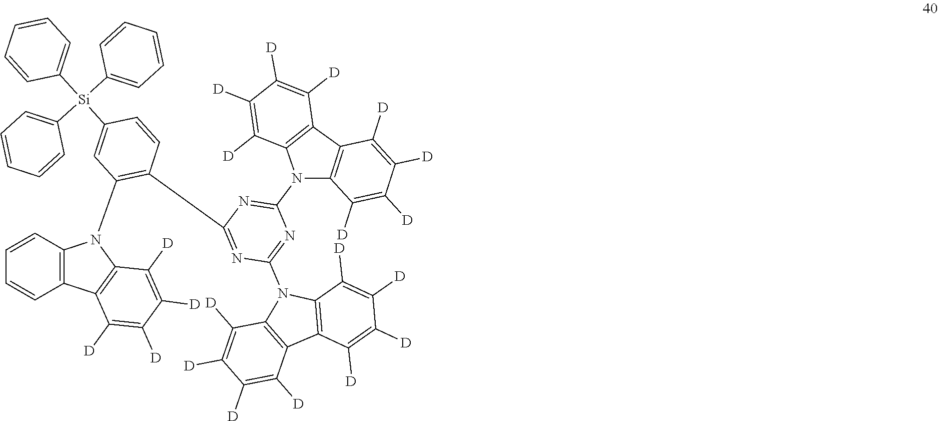 [SMILES: [2H]c1c([2H])c([2H])c2c(c1[2H])c1ccccc1n2-c1cc([Si](c2ccccc2)(c2ccccc2)c2ccccc2)ccc1-c1nc(-n2c3c([2H])c([2H])c([2H])c([2H])c3c3c([2H])c([2H])c([2H])c([2H])c32)nc(-n2c3c([2H])c([2H])c([2H])c([2H])c3c3c([2H])c([2H])c([2H])c([2H])c32)n1]

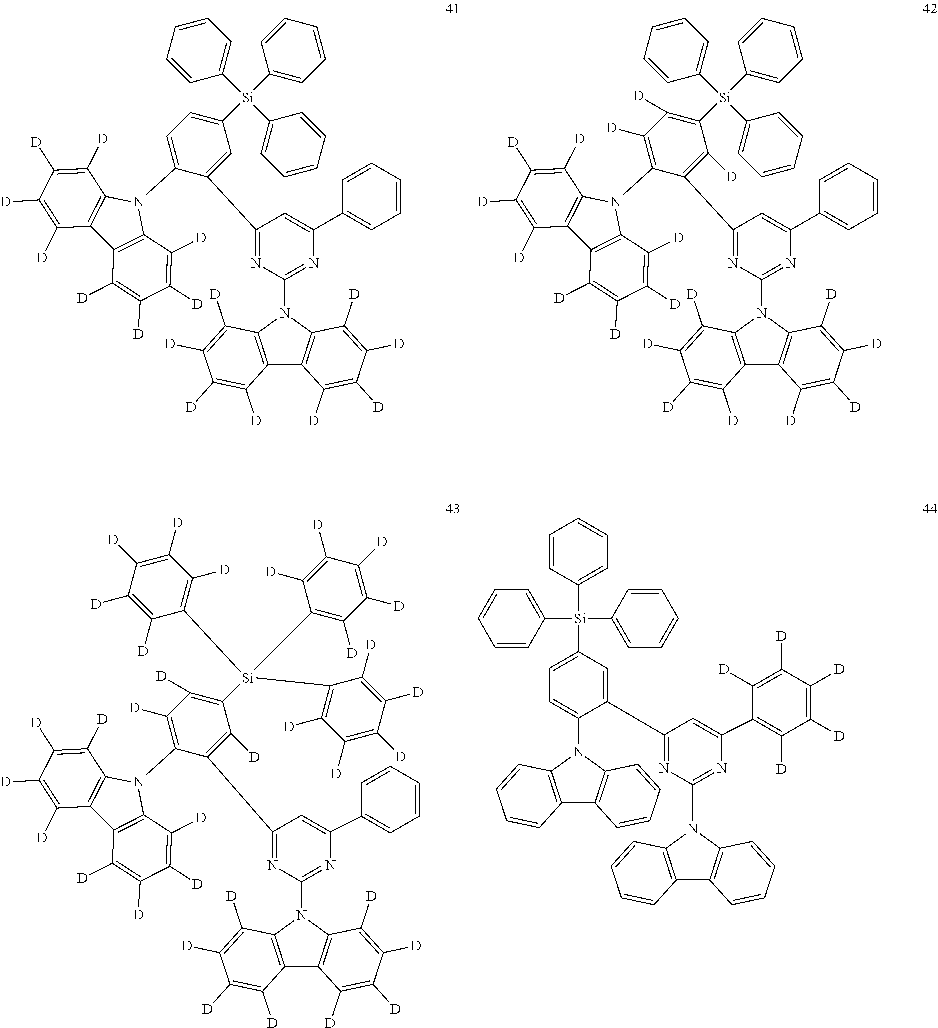

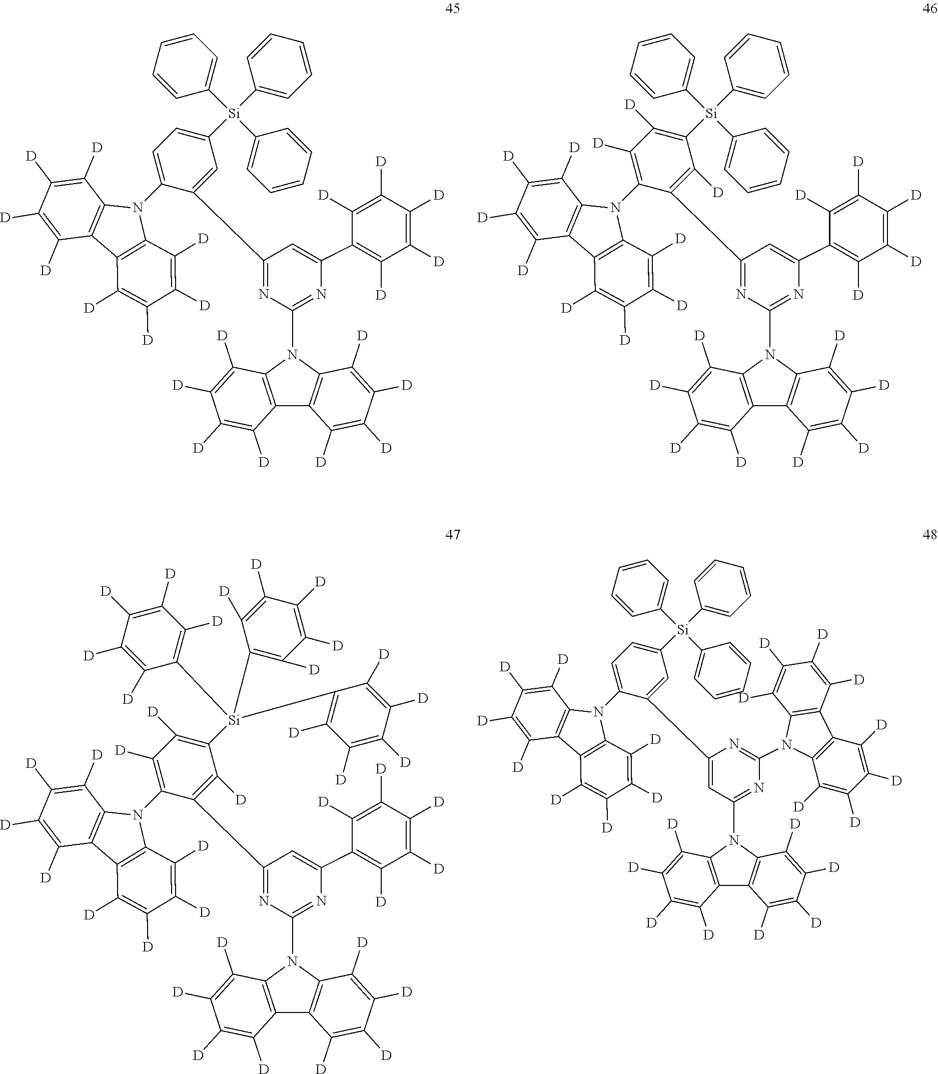

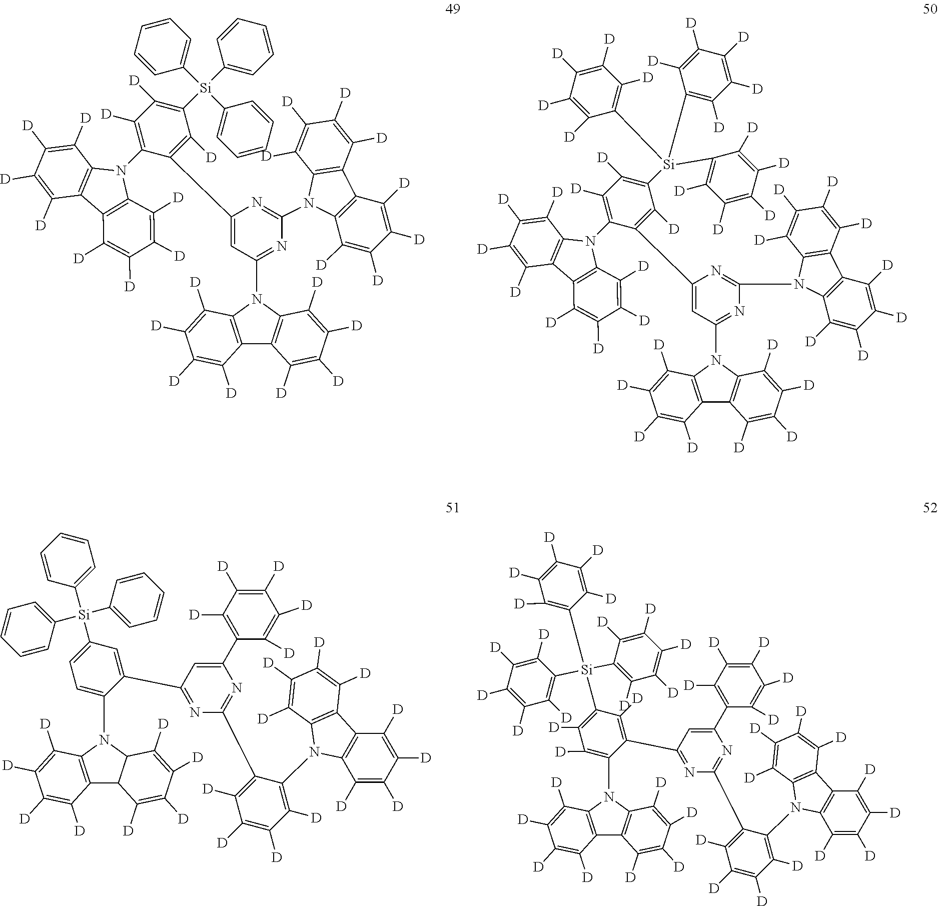

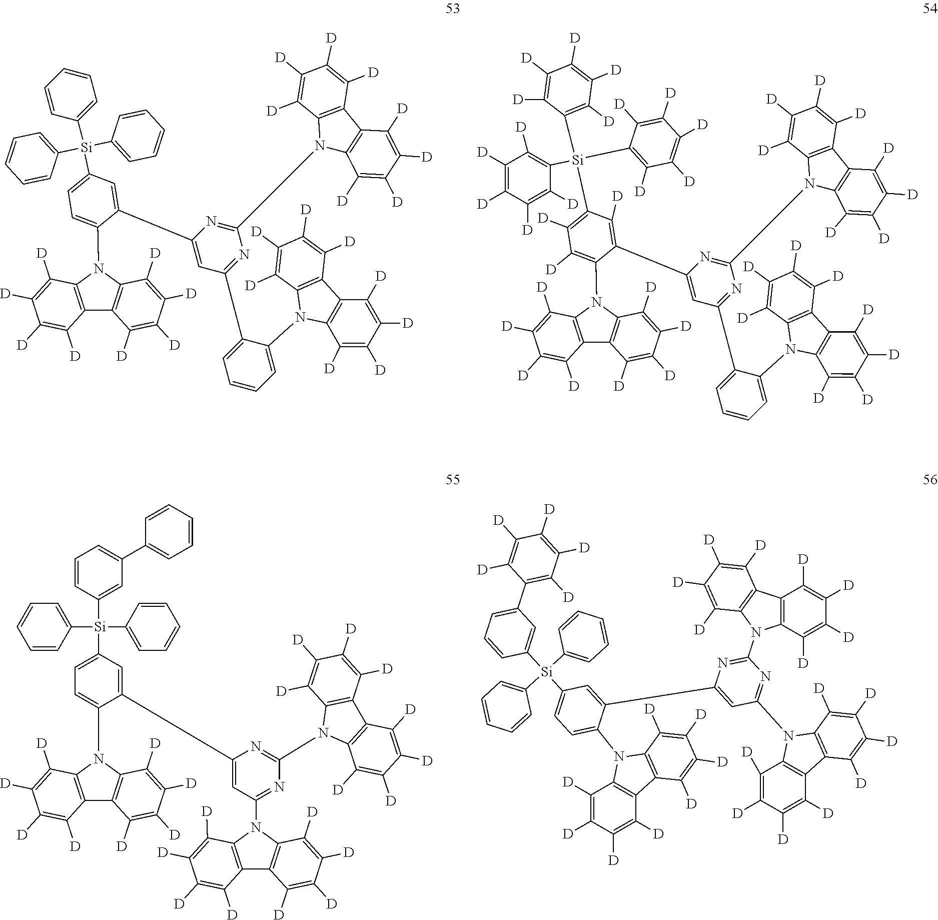

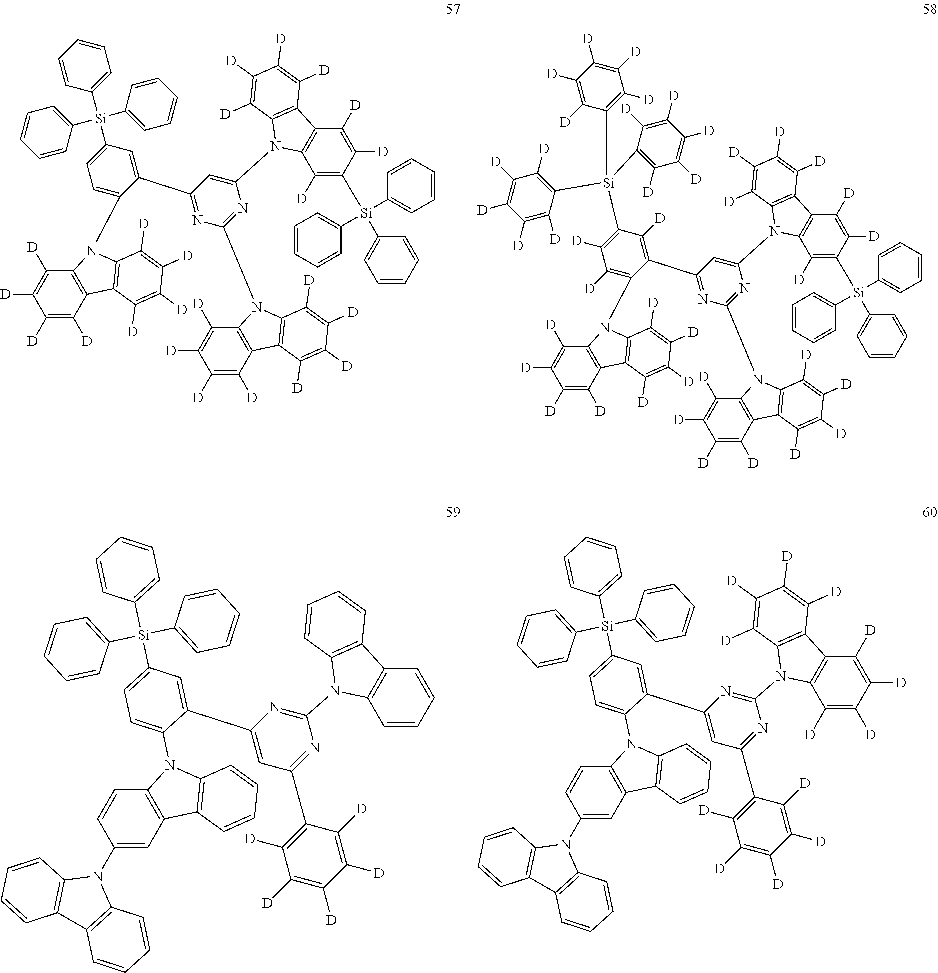

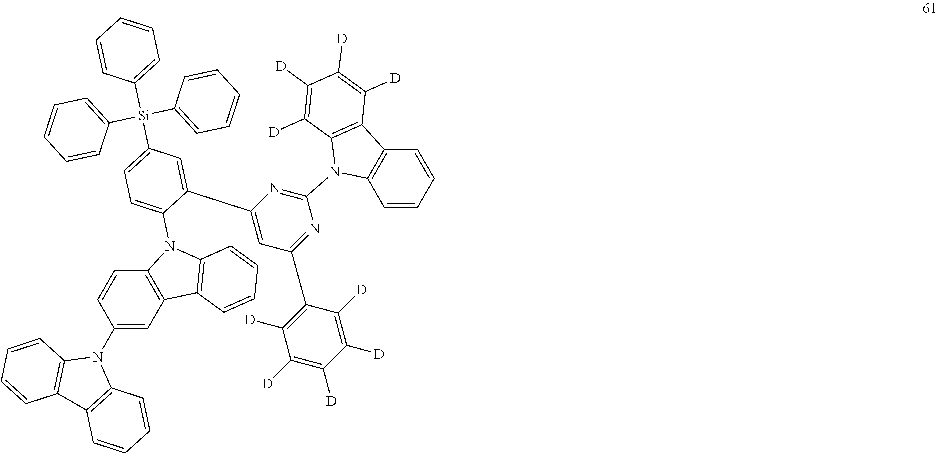 [SMILES: [2H]c1c([2H])c([2H])c(-c2cc(-c3cc([Si](c4ccccc4)(c4ccccc4)c4ccccc4)ccc3-n3c4ccccc4c4cc(-n5c6ccccc6c6ccccc65)ccc43)nc(-n3c4ccccc4c4c([2H])c([2H])c([2H])c([2H])c43)n2)c([2H])c1[2H]]

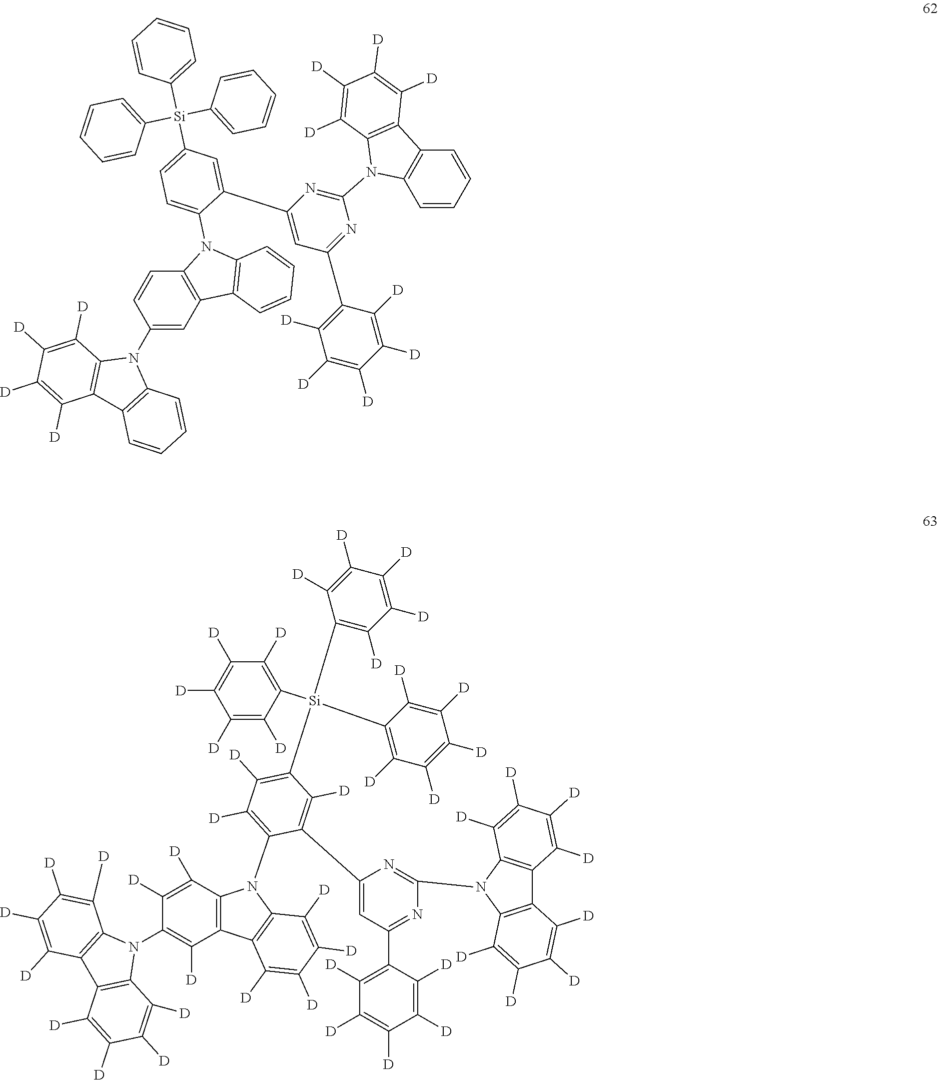

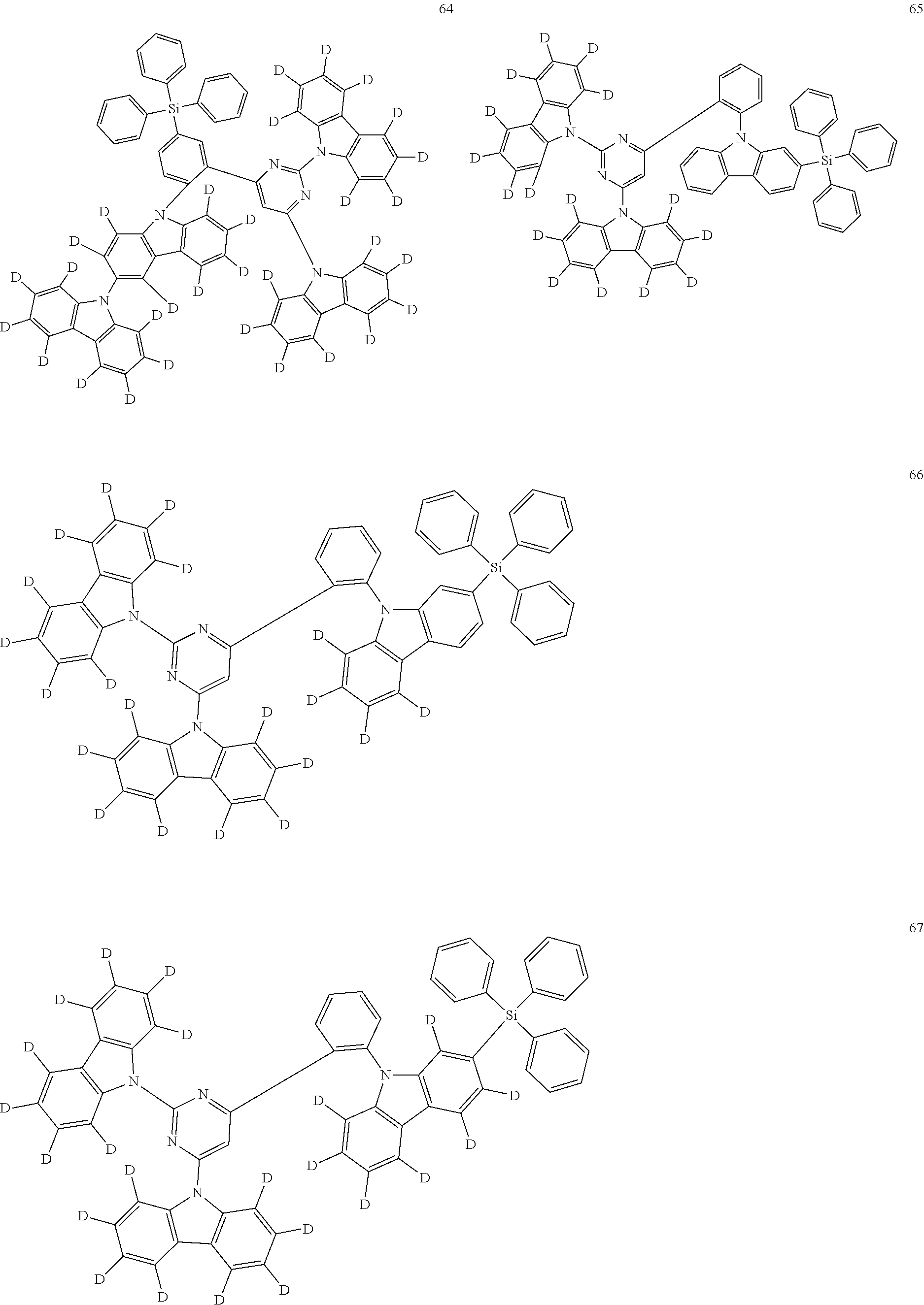

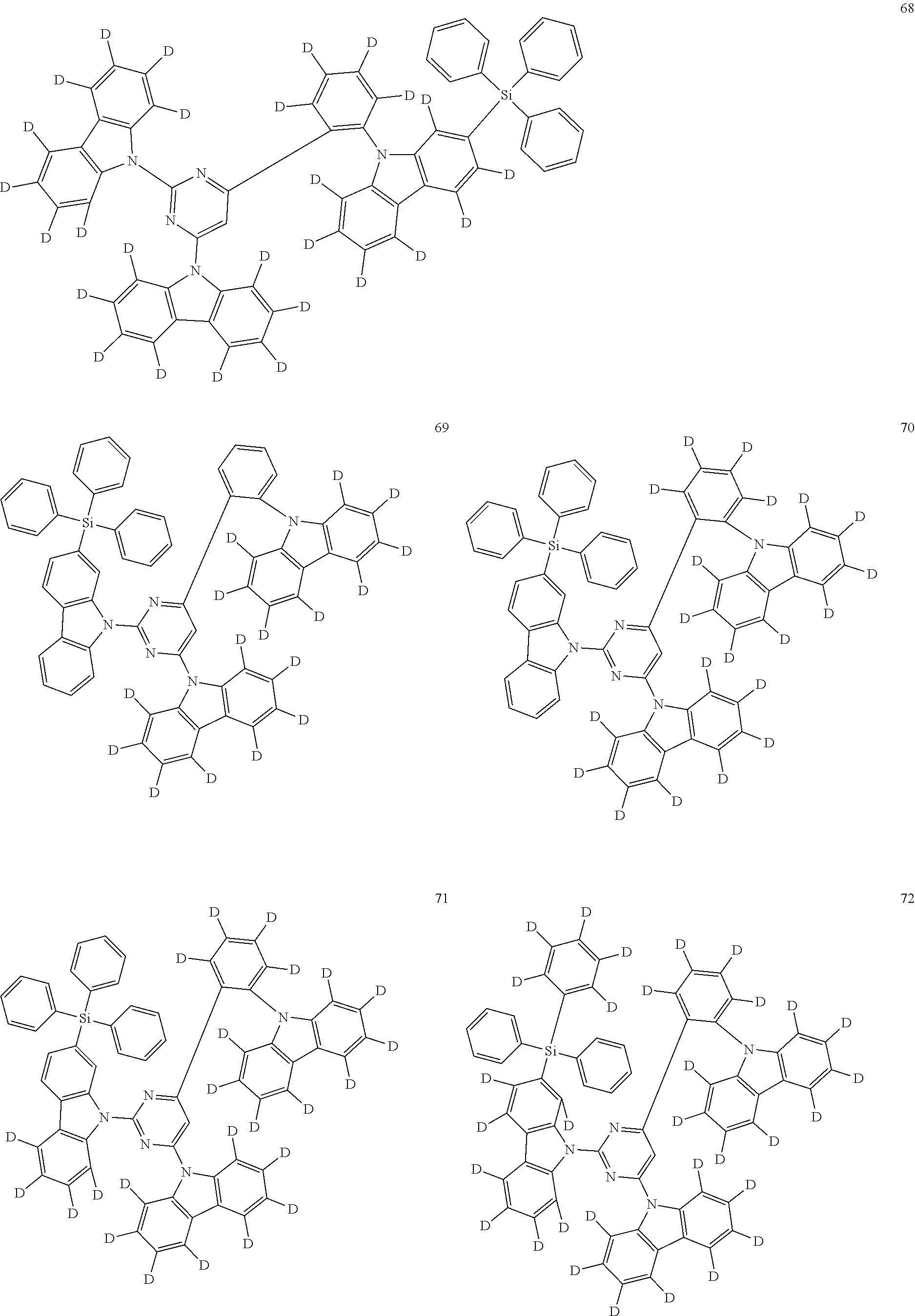

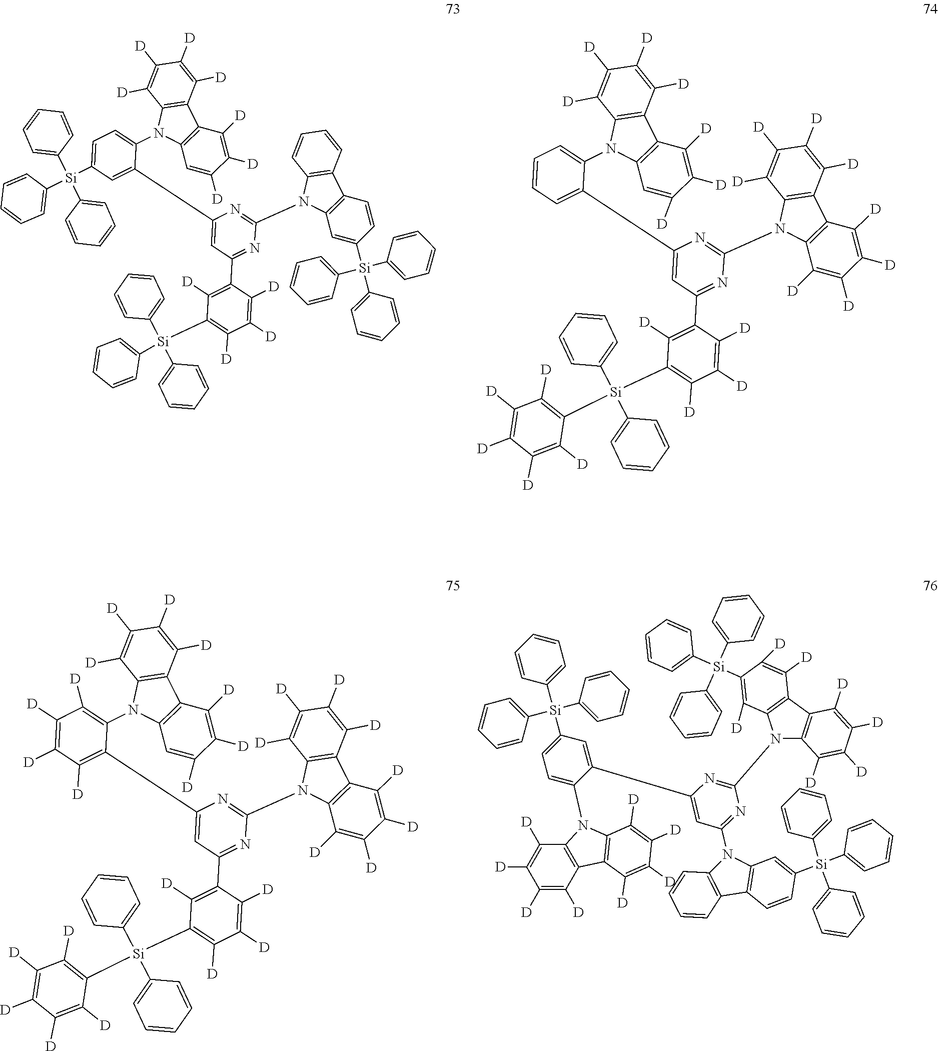

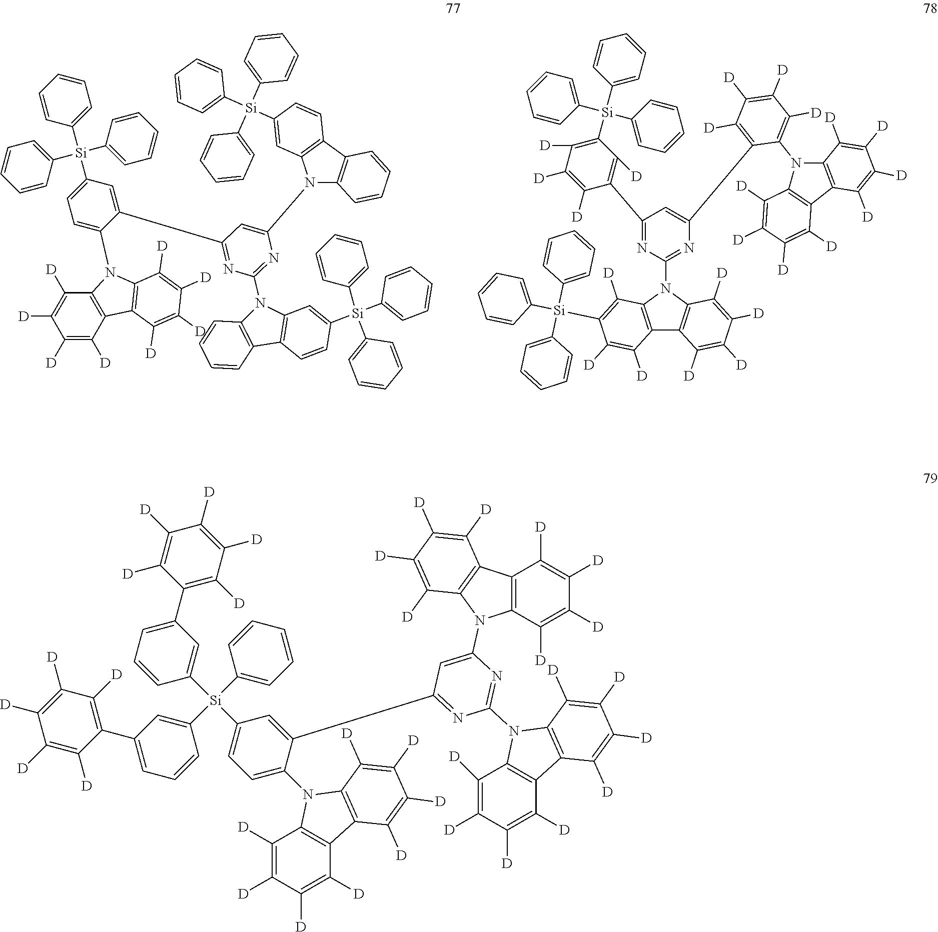

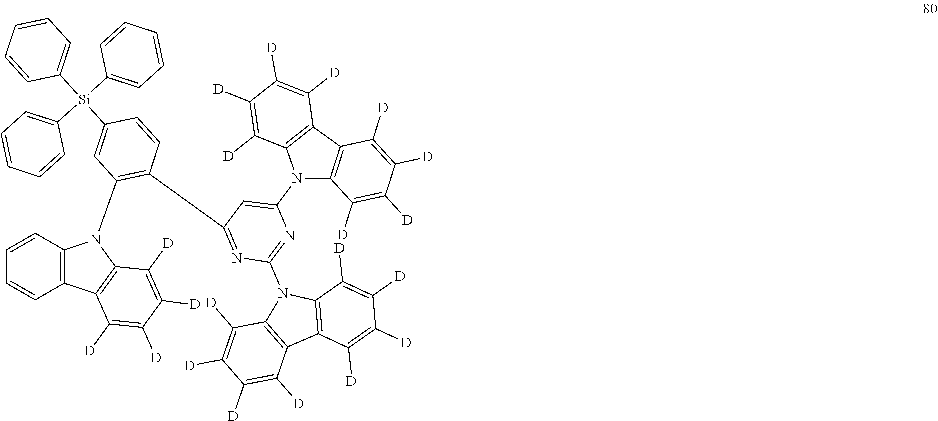 [SMILES: [2H]c1c([2H])c([2H])c2c(c1[2H])c1ccccc1n2-c1cc([Si](c2ccccc2)(c2ccccc2)c2ccccc2)ccc1-c1cc(-n2c3c([2H])c([2H])c([2H])c([2H])c3c3c([2H])c([2H])c([2H])c([2H])c32)nc(-n2c3c([2H])c([2H])c([2H])c([2H])c3c3c([2H])c([2H])c([2H])c([2H])c32)n1]

In an embodiment, the emission layer EML may include a host and a dopant. The nitrogen-containing compound of an embodiment may be used as the host material of the emission layer EML. The emission layer EML may emit phosphorescence or thermally activated delayed fluorescence (TADF). The emission layer EML may include a phosphorescence dopant or a thermally activated delayed fluorescence dopant. For example, the emission layer EML may emit blue light.

The nitrogen-containing compound of an embodiment may include triazine or pyrimidine as a central structure. In an embodiment, the nitrogen-containing compound may be substituted with a silyl group and a deuterium atom. A silyl group or a first substituent substituted with a silyl group may be bonded to the triazine or pyrimidine. The silyl group may be substituted or unsubstituted. In addition, a deuterium atom or a second substituent substituted with a deuterium atom may be bonded to the triazine or pyrimidine.

The interaction of the nitrogen-containing compound of an embodiment, including a silyl group with a dopant is prevented or reduced, and color coordinates of light emitted from a light emitting element ED may be improved. For example, the light emitting element ED may emit blue light, and the color coordinates of the blue light may be improved. If the interaction between a host and a dopant is not prevented or reduced, light emitted from a light emitting element may be light of shifted color coordinates which are not the color coordinates of target blue light. The nitrogen-containing compound of an embodiment, including a deuterium atom may improve the lifetime of a light emitting element ED. When compared to a light emitting element including a compound not containing a deuterium atom, a light emitting element including a nitrogen-containing compound containing a deuterium atom may show long-life characteristics. Accordingly, the nitrogen-containing compound of an embodiment, substituted with a silyl group and a deuterium atom may improve the color coordinates of light emitted by a light emitting element ED and increase the lifetime of the light emitting element ED.

For example, the emission layer EML may include two or more hosts, a sensitizer, and a dopant. The emission layer EML may include a hole transport host and an electron transport host. The emission layer EML may include a thermally activated delayed fluorescence sensitizer or a phosphorescence sensitizer.

In the emission layer EML, the hole transport host and the electron transport host may form exciplex. In this case, the triplet energy of the exciplex formed by the hole transport host and the electron transport host may correspond to the difference between the lowest unoccupied molecular orbital (LUMO) energy level of the electron transport host and the highest occupied molecular orbital (HOMO) energy level of the hole transport host. For example, the absolute value of the triplet energy level (T1) of the exciplex formed by the hole transport host and the electron transport host may be about 2.4 eV to about 3.0 eV. In addition, the triplet energy of the exciplex may be a value smaller than the energy gap of each host material. The exciplex may have a triplet energy of about 3.0 eV or less, which is the energy gap between the hole transport host and the electron transport host. However, these are examples, and embodiments of the present disclosure are not limited thereto.

If the emission layer EML includes a hole transport host, an electron transport host, a sensitizer and a dopant, the hole transport host and the electron transport host may form exciplex, and energy transfer from the exciplex to the sensitizer, and from the sensitizer to the dopant may occur to emit light. However, this is only an example, and materials included in the emission layer EML are not limited thereto. Also, the hole transport host and the electron transport host may not form exciplex.

In an embodiment, the emission layer EML further include a second compound represented by Formula HT-1. The second compound may be used as the host material of the emission layer EML. For example, the emission layer EML may include the nitrogen-containing compound of an embodiment as the electron transport host material and the second compound as the hole transport host material.

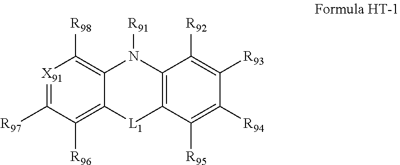

In Formula HT-1, L₁ may be a direct linkage, CR₉₉R₁₀₀, or SiR₁₀₁R₁₀₂. In Formula HT-1, X₉₁ may be N or CR₁₀₃. If L₁ is a direct linkage, and X₉₁ is CR₁₀₃, the second compound represented by Formula HT-1 may include a carbazole group.

R₉₁ to R₁₀₃ may be each independently a hydrogen atom, a deuterium atom, a cyano group, a substituted or unsubstituted silyl group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group from each other to form a ring.

For example, R₉₁ may be a substituted phenyl group, an unsubstituted dibenzofuran group, or a substituted fluorenyl group. Any one selected from among R₉₂ to R₉₈ may be a substituted or unsubstituted carbazole group. R₉₄ and R₉₅ may be combined with each other to form a ring. However, these are only examples, and embodiments of the present disclosure are not limited thereto.

The second compound may be represented by any one selected from among the compounds in Compound Group 2. In Compound Group 2, D is a deuterium atom, and Ph is a phenyl group.

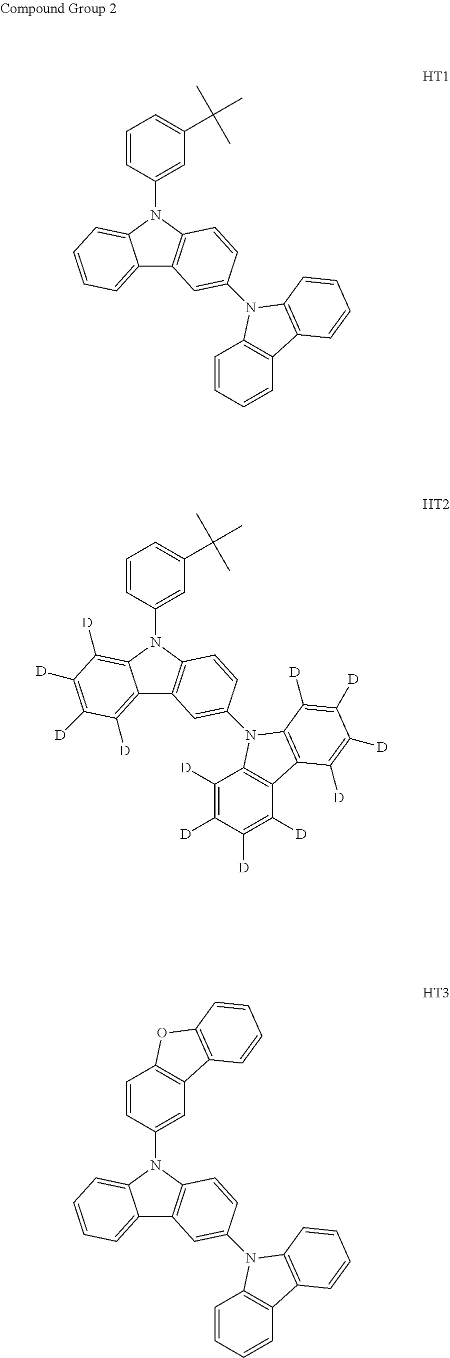 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

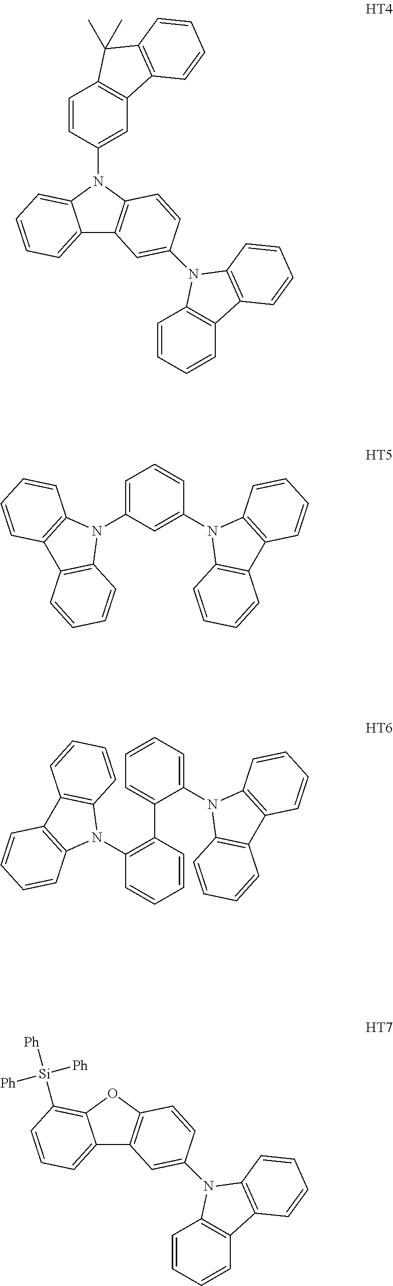 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

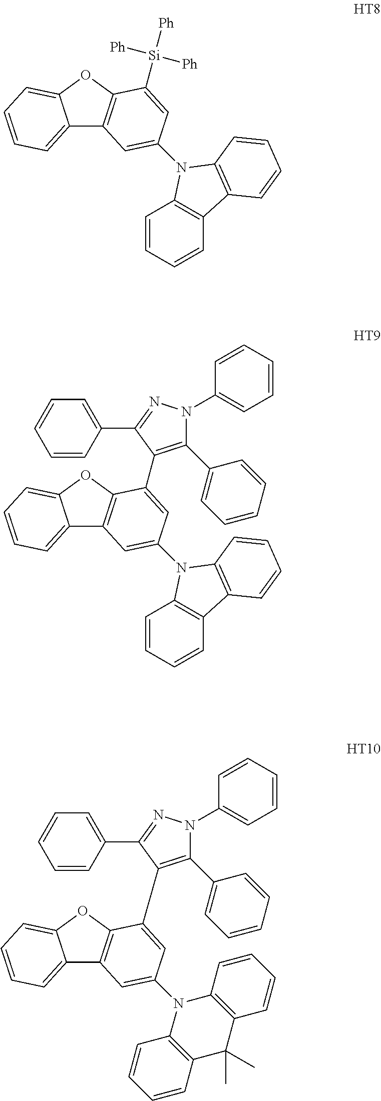 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

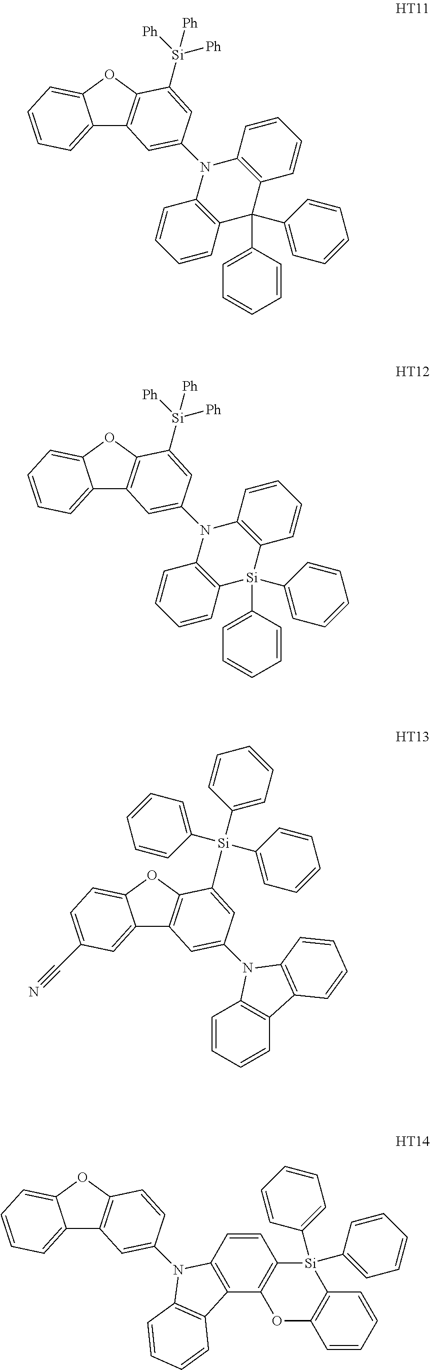 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

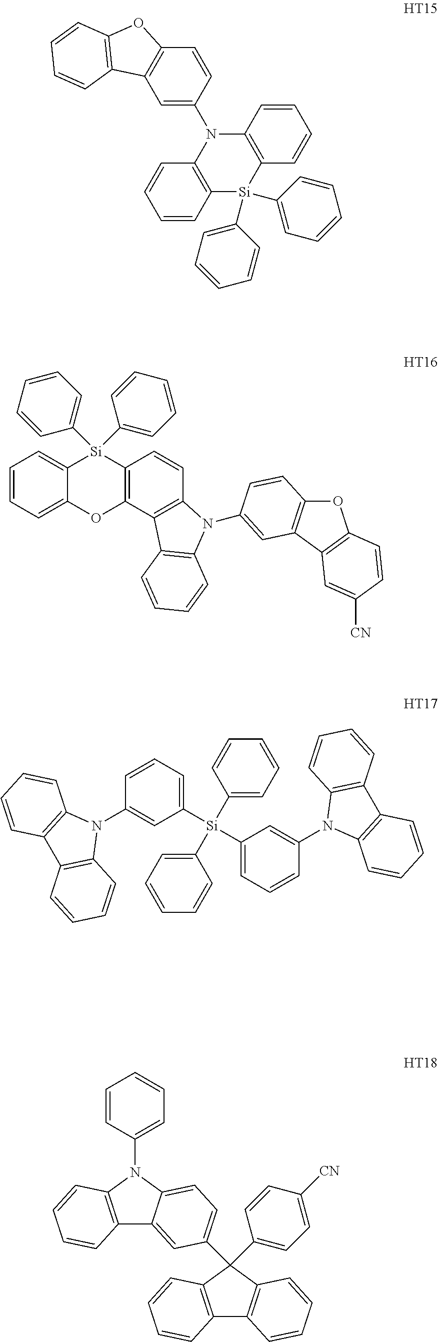 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

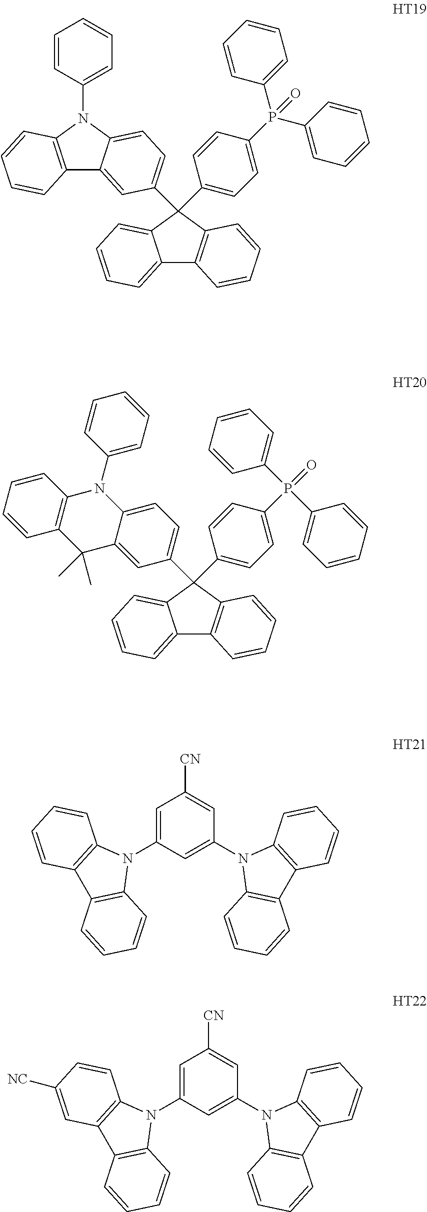 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

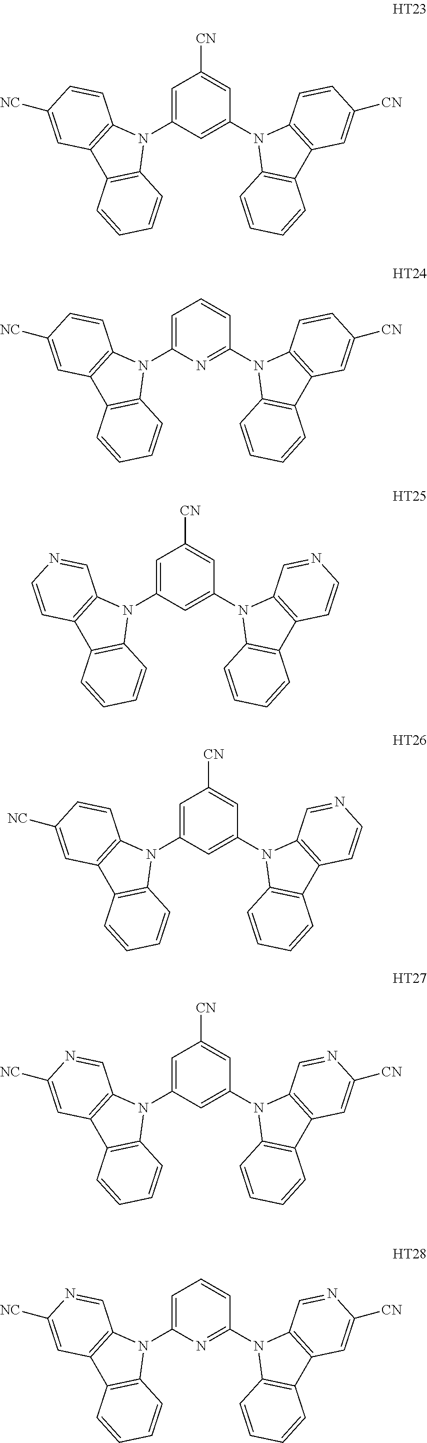 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

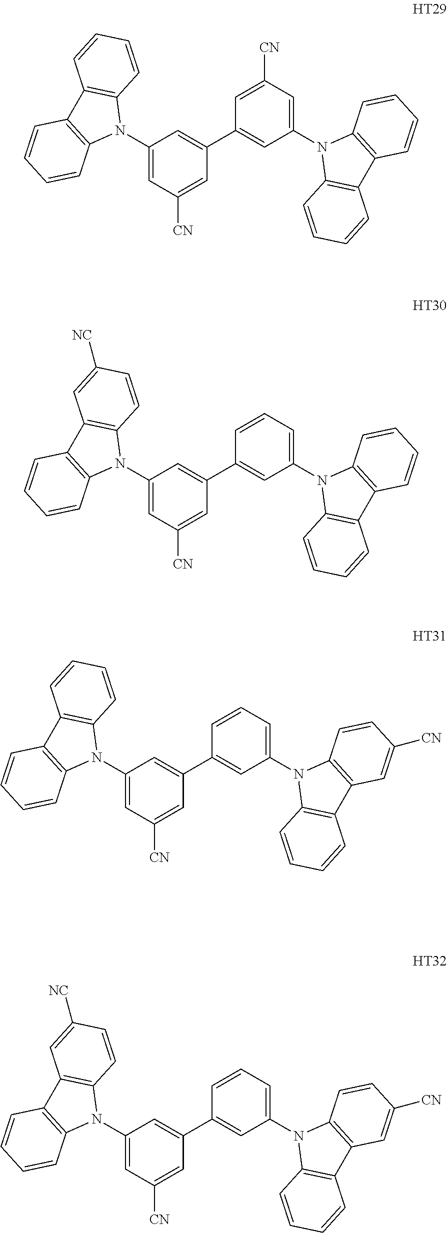 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

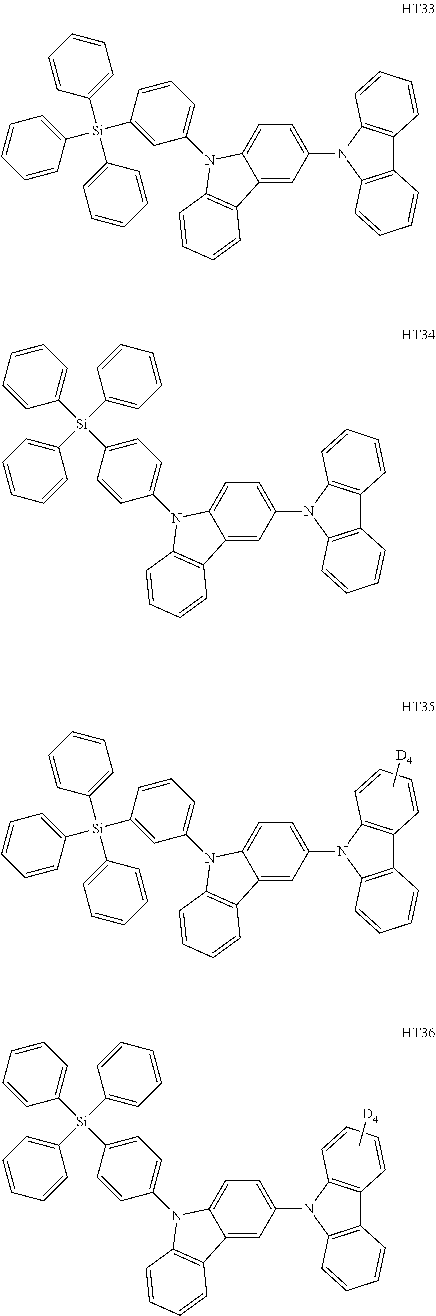

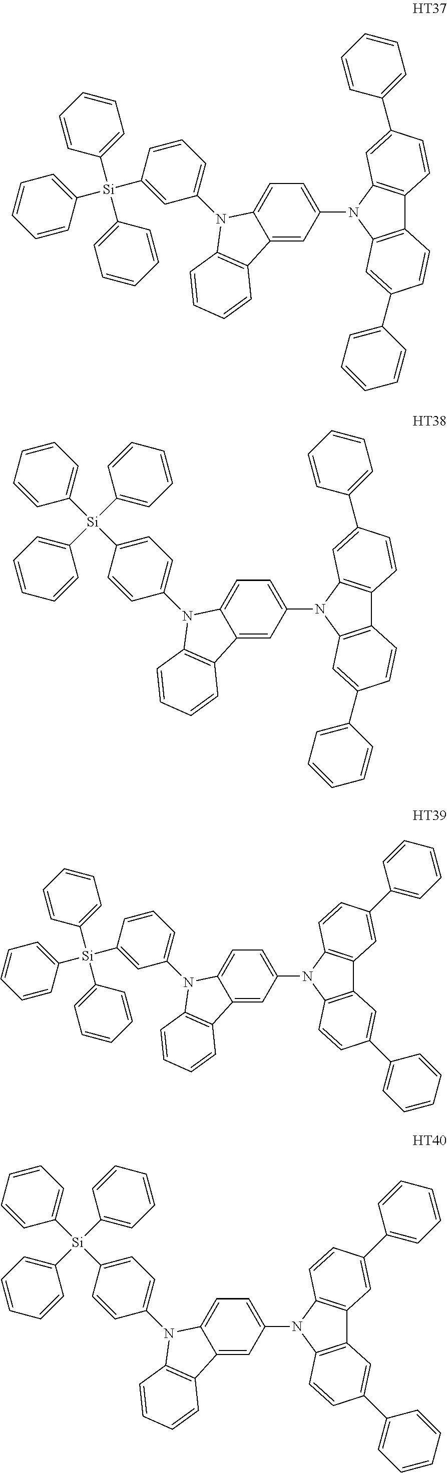 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

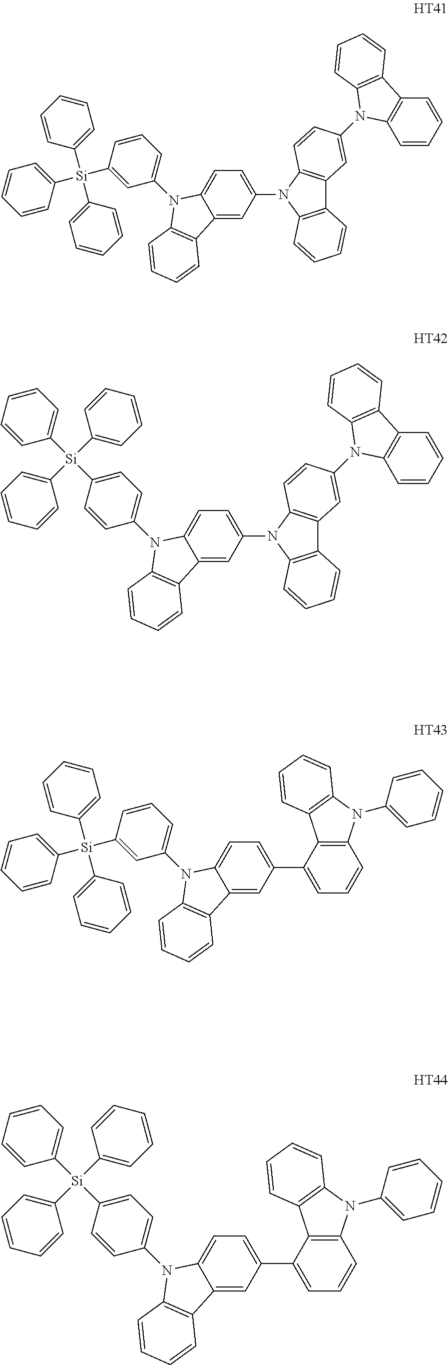 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

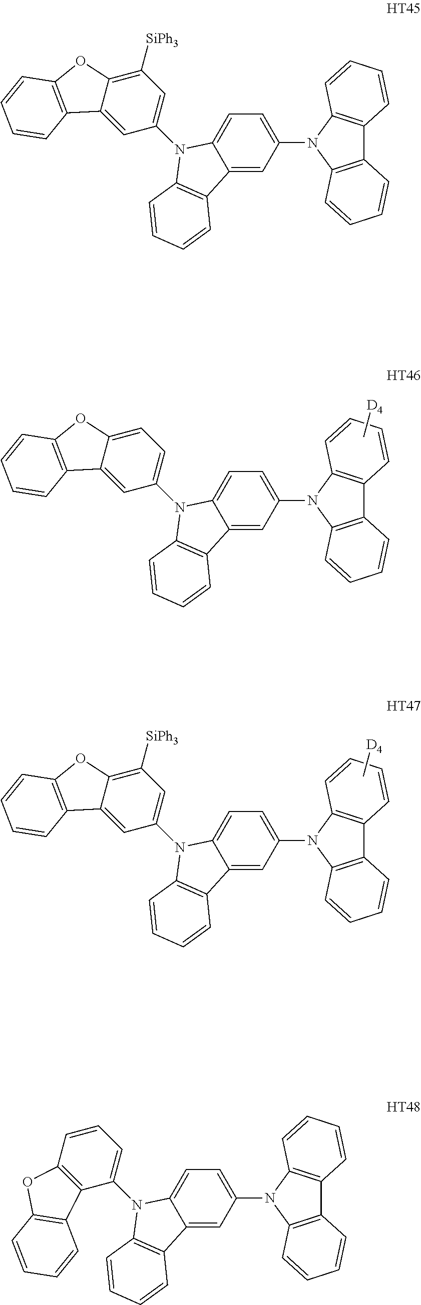

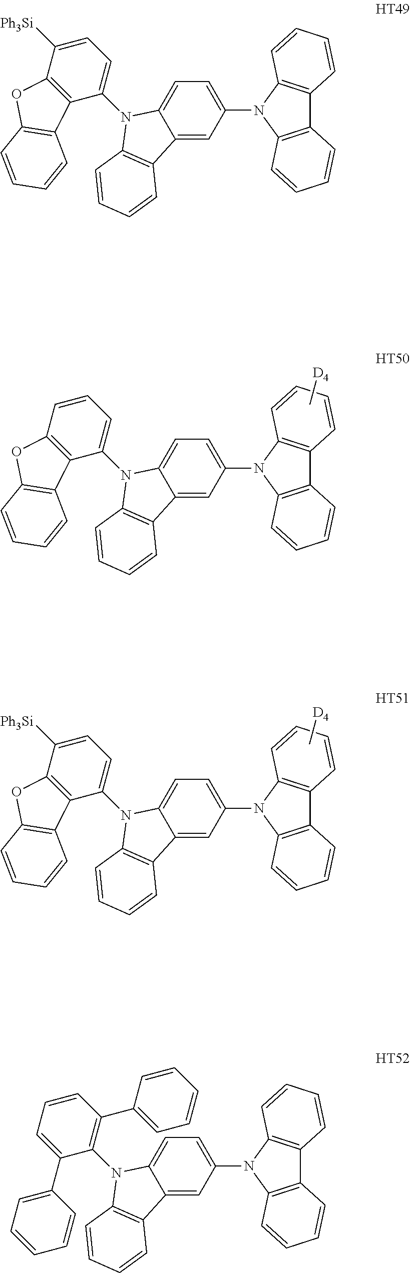

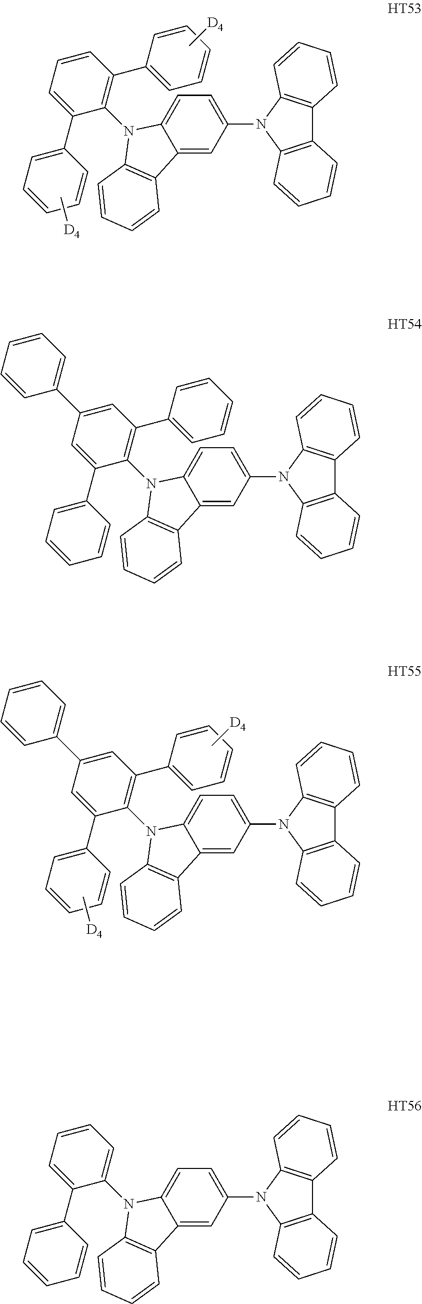

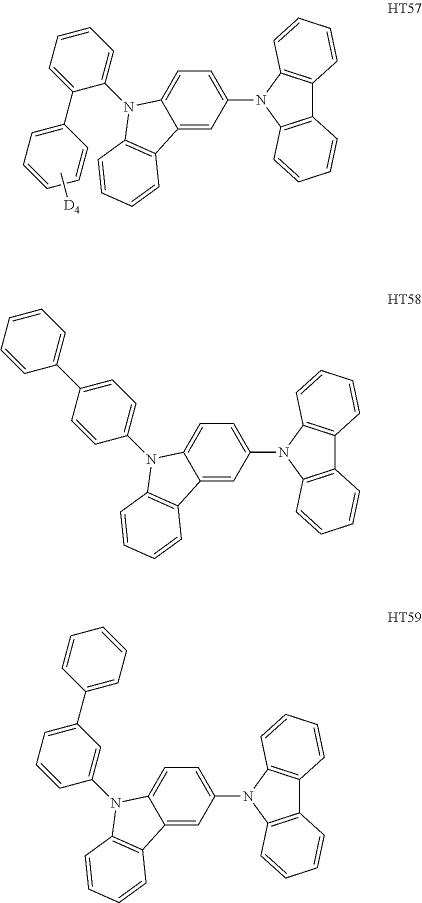

The emission layer EML may further include a third compound represented by Formula M-b. For example, the emission layer EML may include the third compound as a dopant material.

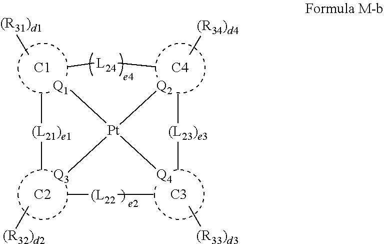

In Formula M-b, Q₁ to Q₄ may be each independently C or N. C1 to C4 may be each independently a substituted or unsubstituted hydrocarbon ring of 5 to 30 ring-forming carbon atoms, or a substituted or unsubstituted heterocycle of 2 to 30 ring-forming carbon atoms.

e1 to e4 may be each independently 0 or 1. L₂₁ to L₂₄ may be each independently a direct linkage,

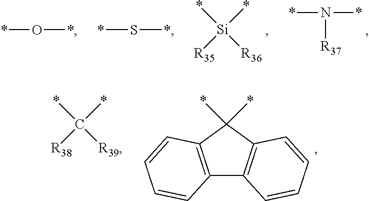

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms.

d1 to d4 may be each independently an integer of 0 to 4. If d1 is an integer of 2 or more, a plurality of R₃₁ may be the same, or at least one thereof may be different. Similarly, if d2 to d4 are integers of 2 or more, a plurality of R₃₂ to R₃₄ may be the same, or at least one thereof may be different. R₃₁ to R₃₉ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group from each other to form a ring.

For example, the third compound may be used as a blue phosphorescence dopant or a green phosphorescence dopant. The third compound may be represented by any one selected from among the compounds in Compound Group 3. However, the compounds are only examples, and the third compound is not limited to the compounds represented below.

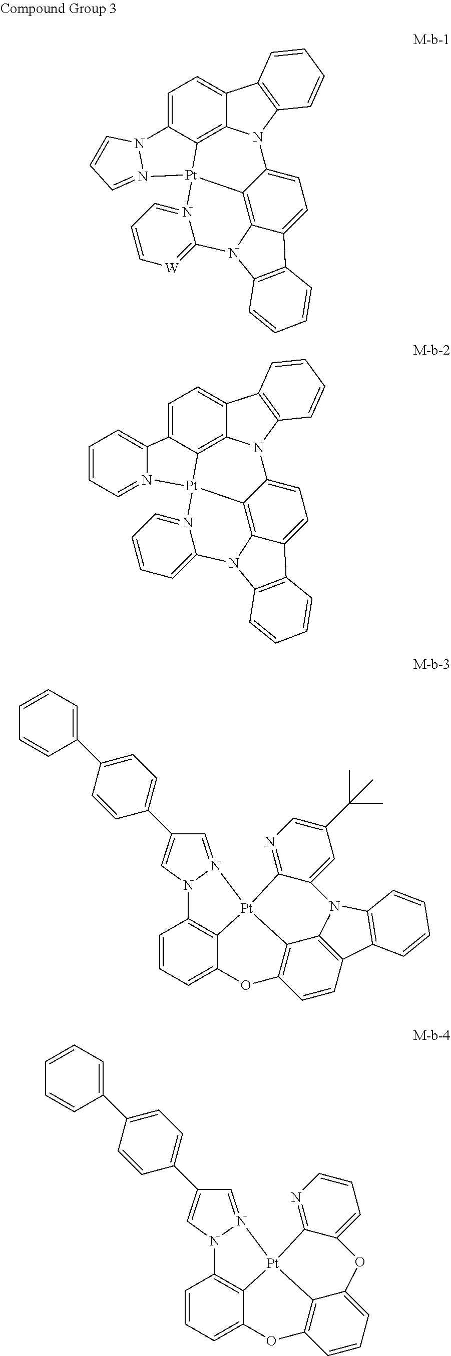

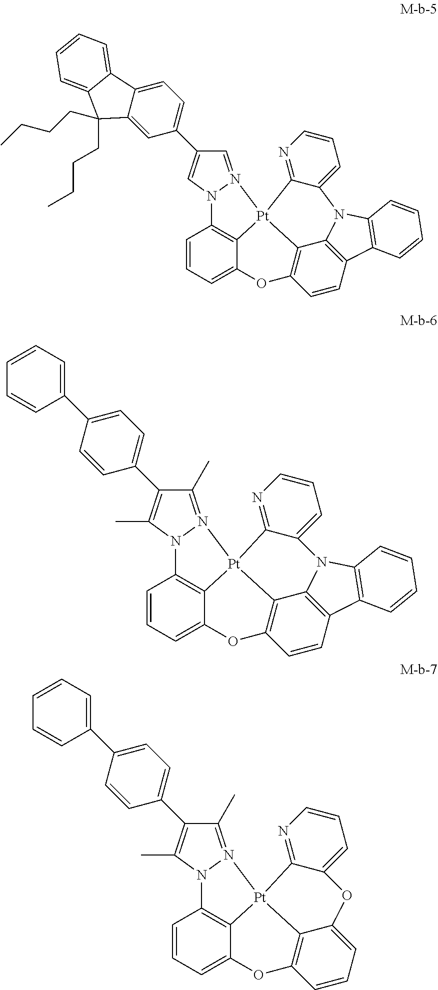

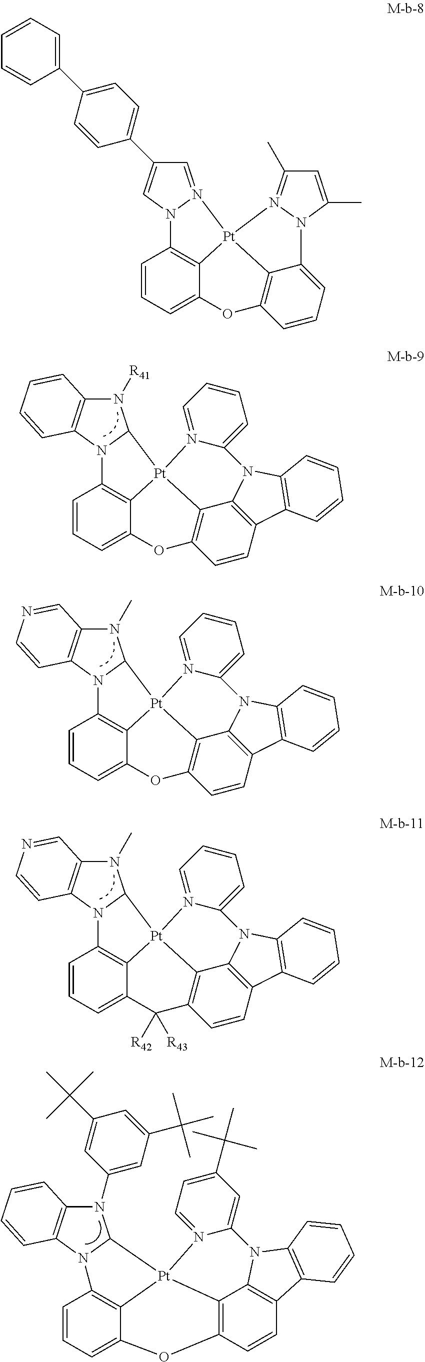

In Compound Group 3, R₄₁, R₄₂, and R₄₃ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the light emitting element ED of an embodiment, at least one selected from among an emission layer EML and an electron transport region ETR may include the nitrogen-containing compound of an embodiment. For example, the emission layer EML may include the nitrogen-containing compound of an embodiment, the second compound represented by Formula H-1, and the third compound represented by Formula M-b. In an embodiment, the light emitting element ED including the nitrogen-containing compound may show long-life characteristics and improved color coordinates of light emitted.

The emission layer EML may be provided on the hole transport region HTR. The emission layer EML may have a thickness of, for example, about 100 Å to about 1,000 Å or about 100 Å to about 300 Å. The emission layer EML may have a single layer formed using a single material, a single layer formed using a plurality of different materials, or a multilayer structure having a plurality of layers formed using a plurality of different materials.

The emission layer EML may further include the compounds explained below in addition to the nitrogen-containing compound, the second compound and the third compound explained above. For example, the emission layer EML may include anthracene derivatives, pyrene derivatives, fluoranthene derivatives, chrysene derivatives, dihydrobenzanthracene derivatives, and/or triphenylene derivatives. In one or more embodiments, the emission layer EML may include anthracene derivatives and/or pyrene derivatives.

The emission layer EML may include a compound represented by Formula E-1 below. The compound represented by Formula E-1 below may be used as a fluorescence host material.

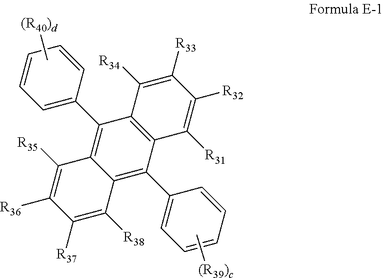

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In one or more embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may be each independently an integer of 0 to 5. If “c” is an integer of 2 or more, a plurality of R₃₉ may be the same, or at least one thereof may be different. If “d” is an integer of 2 or more, a plurality of R₄₀ may be the same, or at least one thereof may be different. Formula E-1 may be represented by any one selected from among Compound E1 to Compound E19 below.

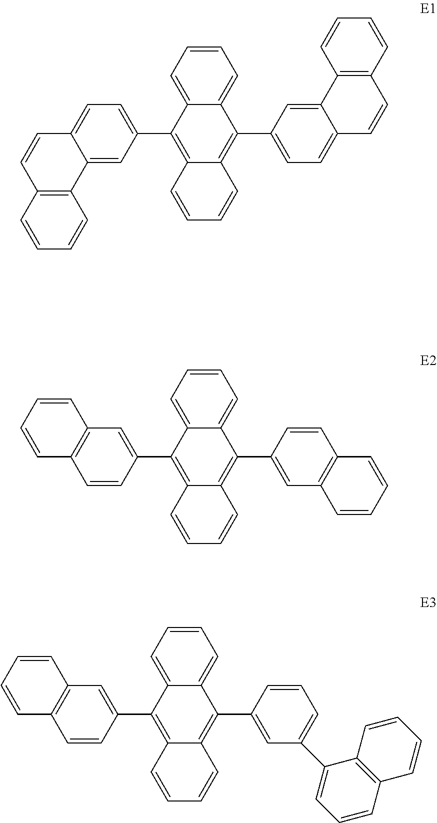

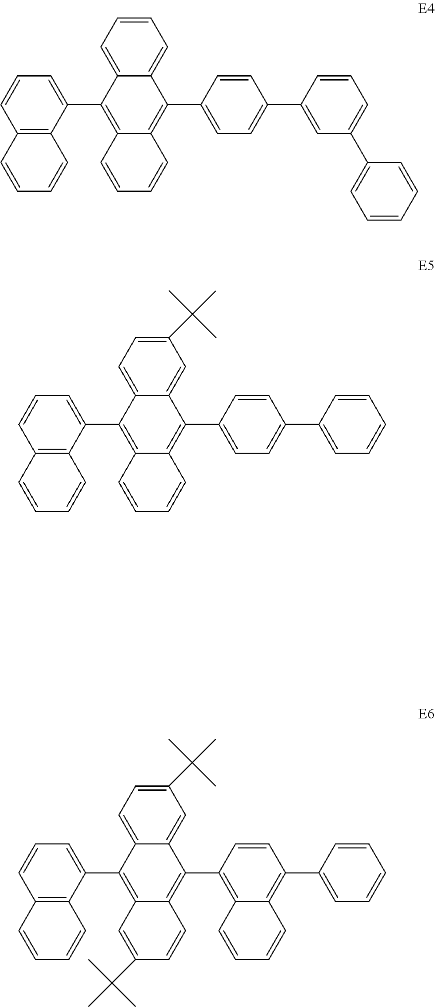

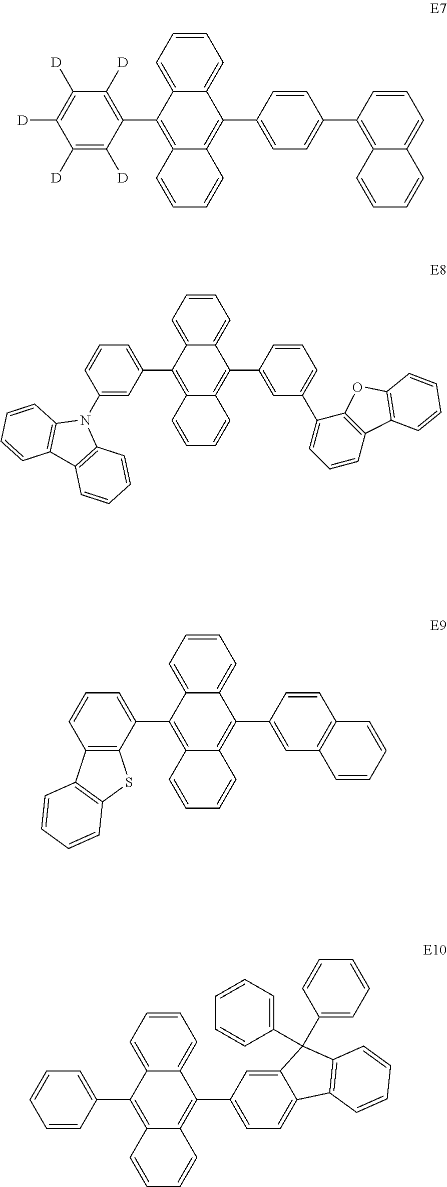

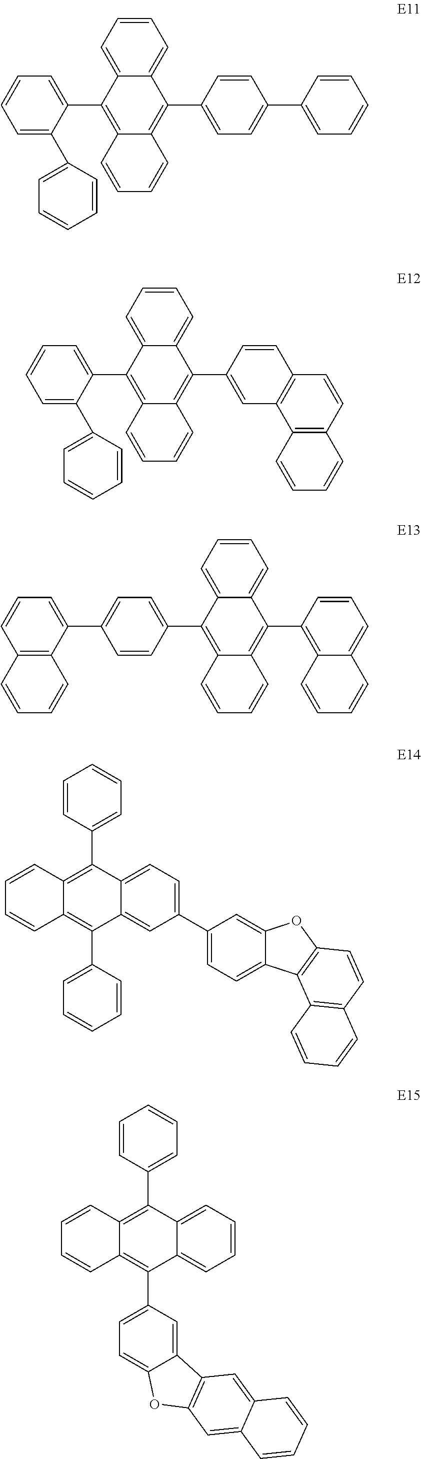

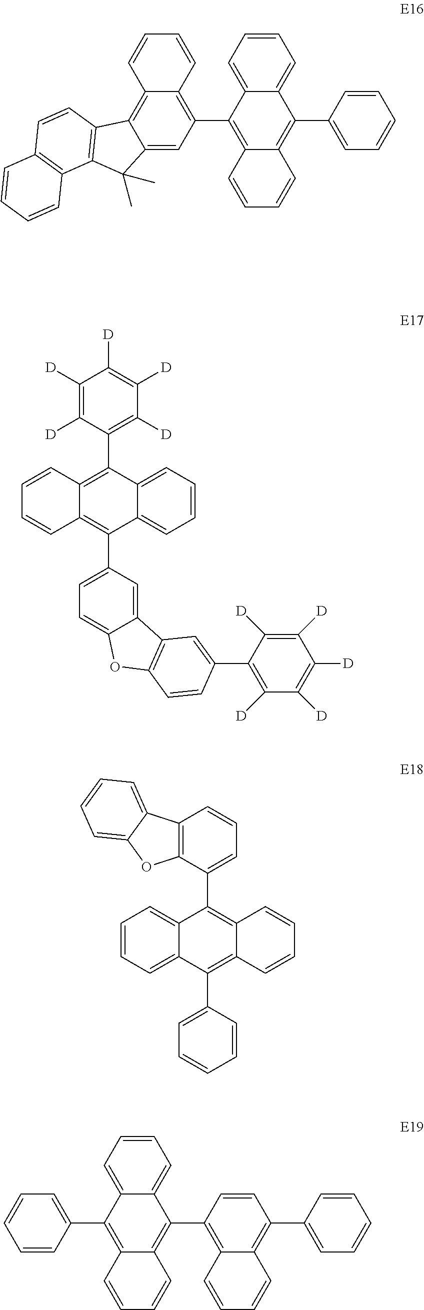

In an embodiment, the emission layer EML may include a compound represented by Formula E-2a or Formula E-2b below. The compound represented by Formula E-2a or Formula E-2b may be used as a phosphorescence host material.

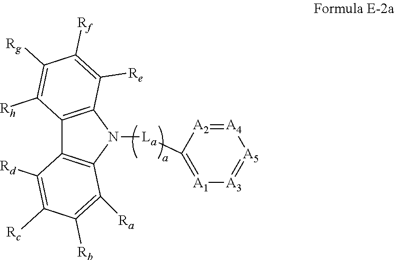

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if “a” is an integer of 2 or more, a plurality of La may be each independently a substituted or unsubstituted arylene group of 6 to 30 ring-forming carbon atoms, or a substituted or unsubstituted heteroarylene group of 2 to 30 ring-forming carbon atoms.

In addition, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, etc. as ring-forming atoms.

In one or more embodiments, in Formula E-2a, two or three selected from A₁ to A5 may be N, and the remainder may be CRᵢ.

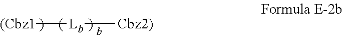

In Formula E-2b, Cbz1 and Cbz2 may be each independently an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if “b” is an integer of 2 or more, a plurality of L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2 below. However, the compounds listed in Compound Group E-2 below are only examples, and the compound represented by Formula E-2a or Formula E-2b is not limited to the compounds represented in Compound Group E-2 below.

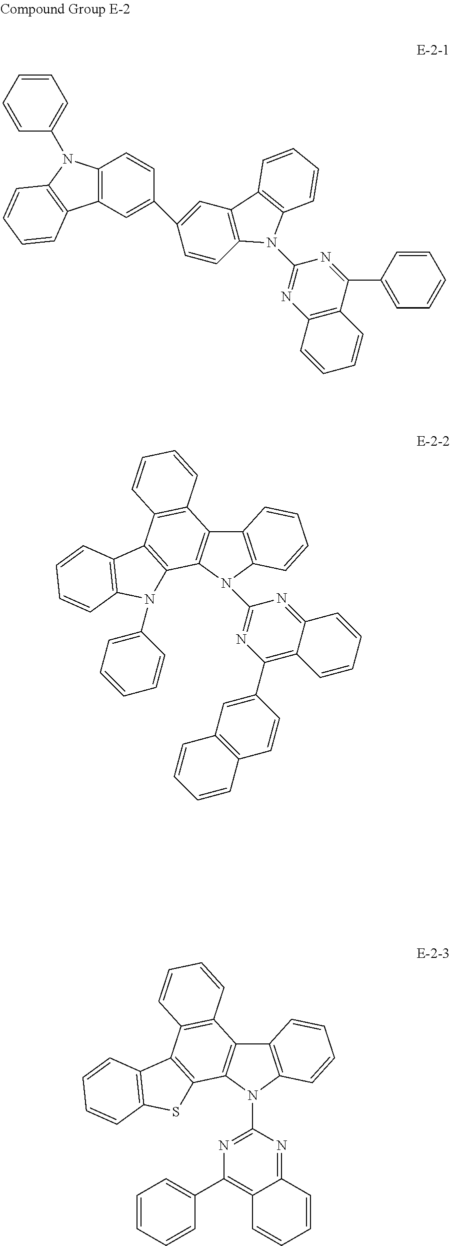 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

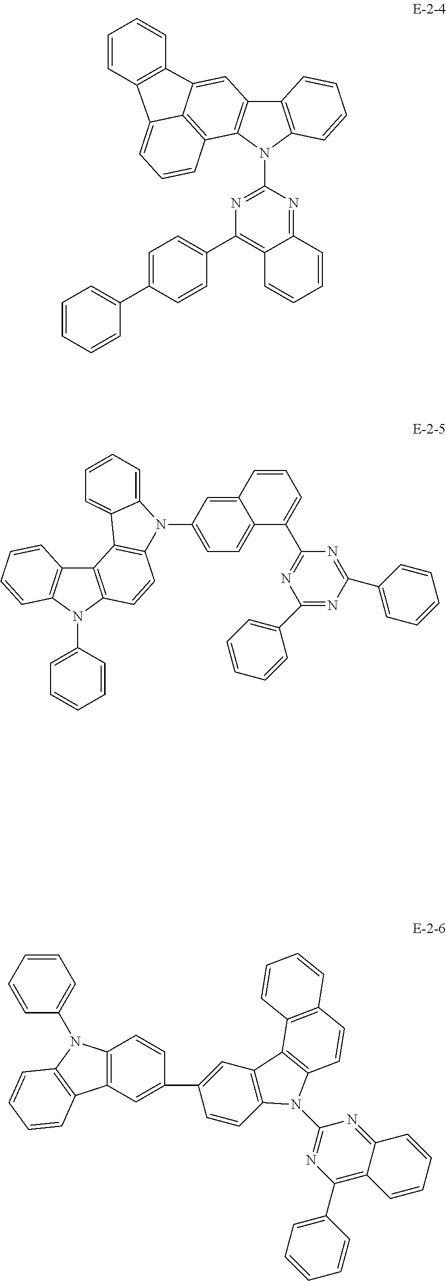 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

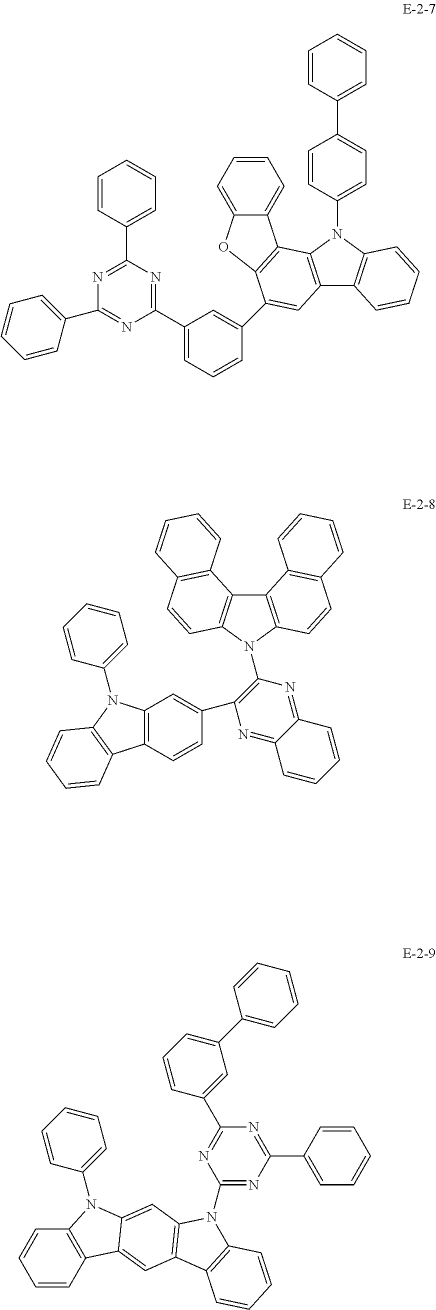 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

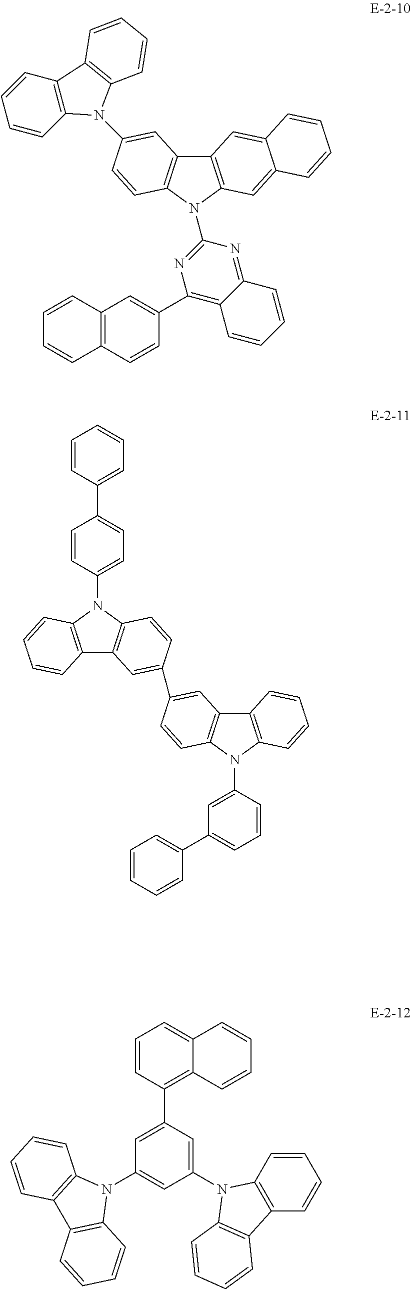 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

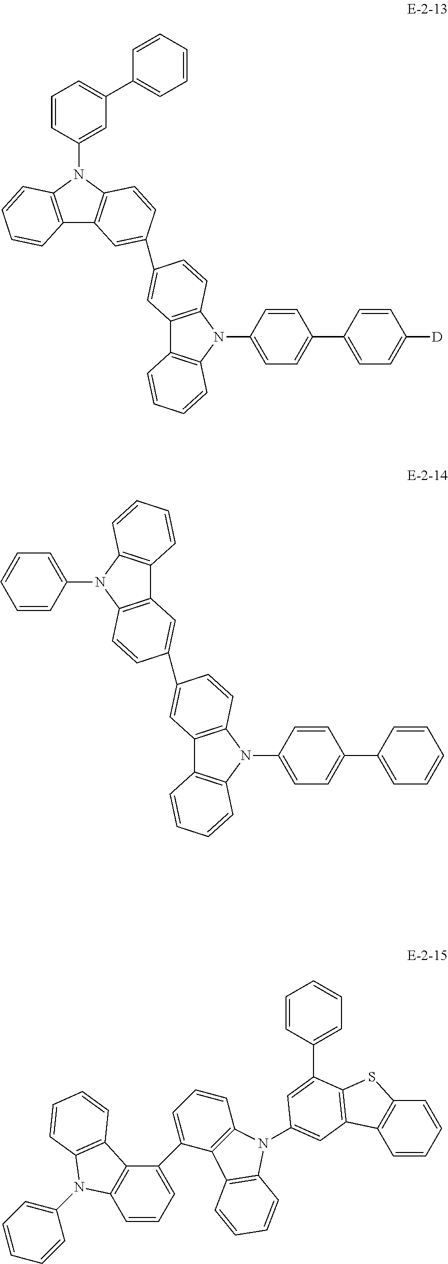 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

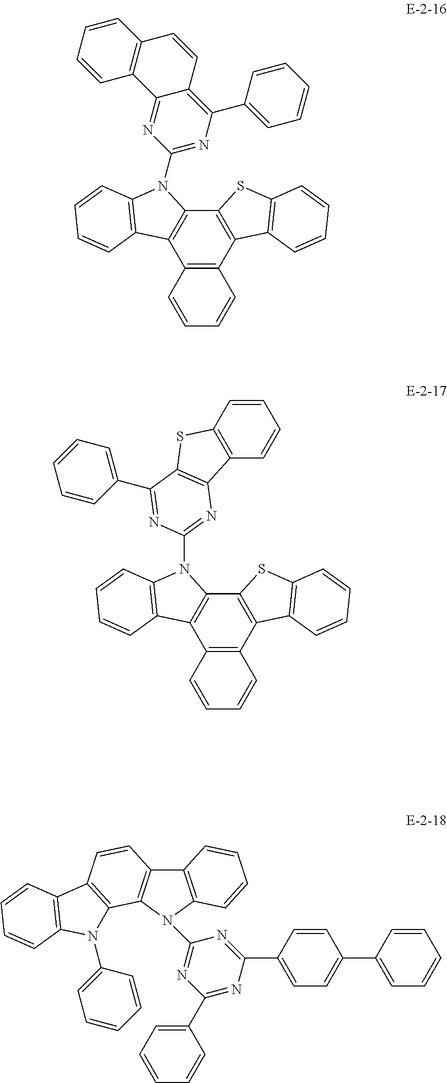 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

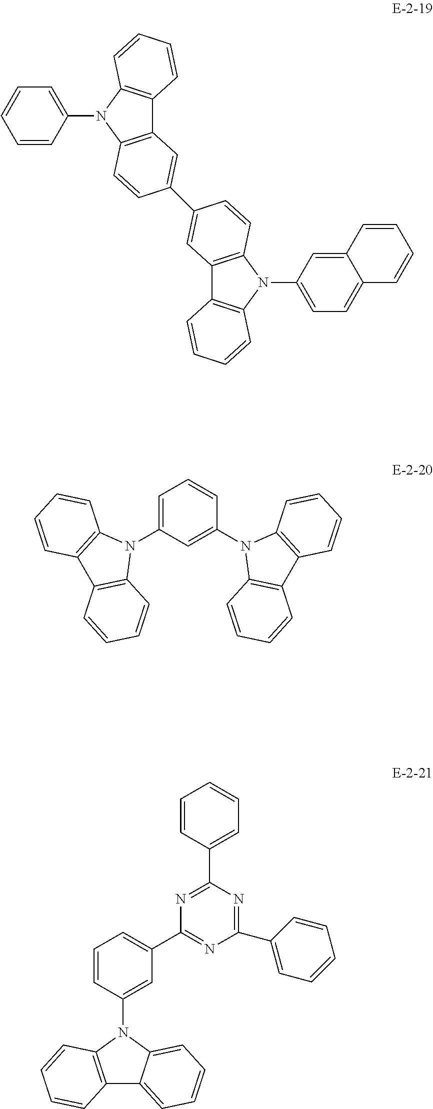 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

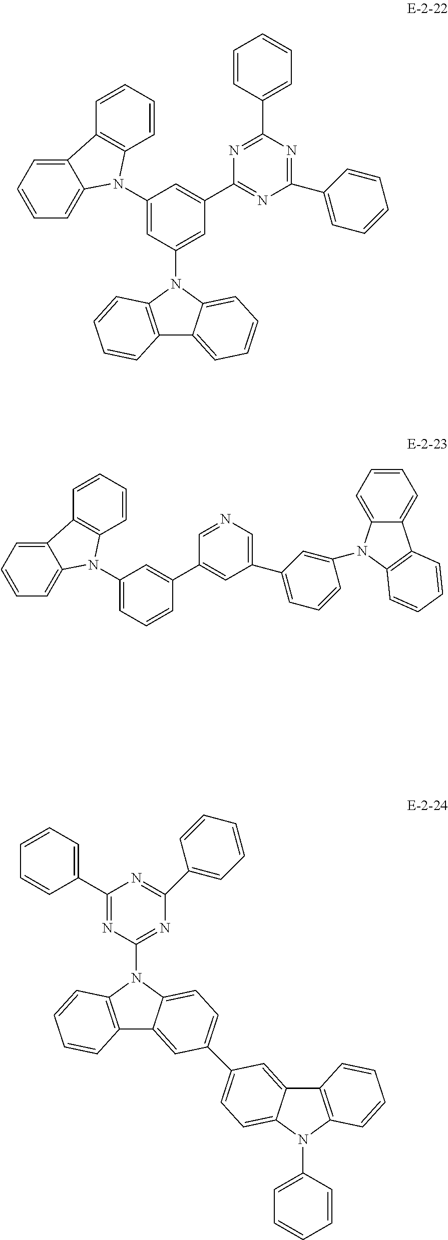 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include any suitable material generally used in the art as a host material. In one or more embodiments, the emission layer EML may include as a host material, at least one selected from bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments of the present disclosure are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The emission layer EML may include a compound represented by Formula M-a. The compound represented by Formula M-a may be used as a phosphorescence dopant material.

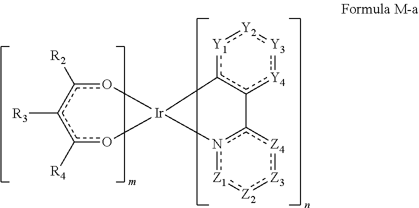

In Formula M-a, Y₁ to Y₄, and Z₁ to Z₄ may be each independently CR₁ or N. R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula M-a, “m” may be 0 or 1, and “n” may be 2 or 3. In Formula M-a, if “m” is 0, “n” may be 3, and if “m” is 1, “n” may be 2.

The compound represented by Formula M-a may be represented by any one selected from among Compounds M-a1 to M-a25 below. However, Compounds M-a1 to M-a25 are examples, and the compound represented by Formula M-a is not limited to those represented by Compounds M-a1 to M-a25 below.

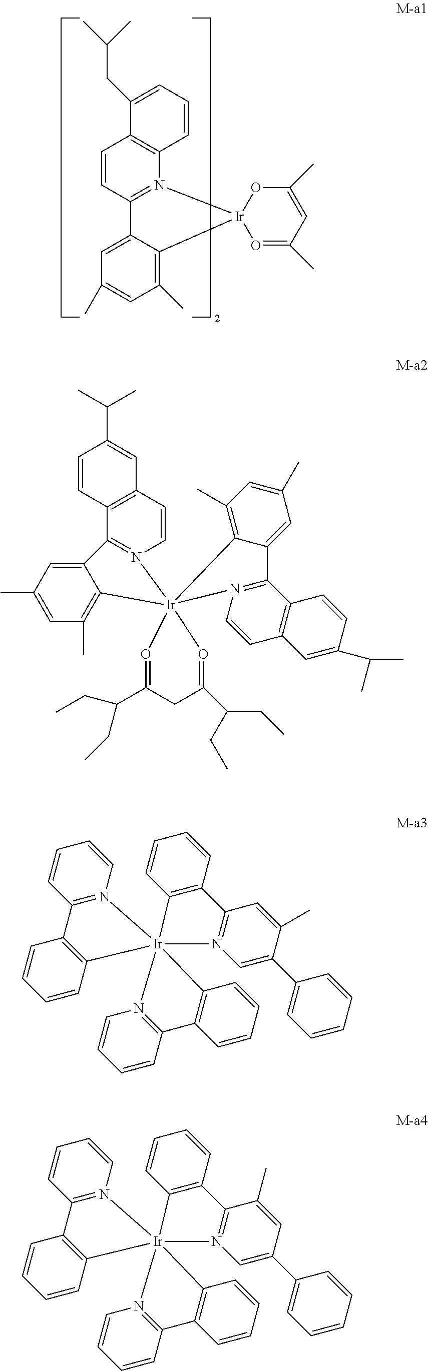

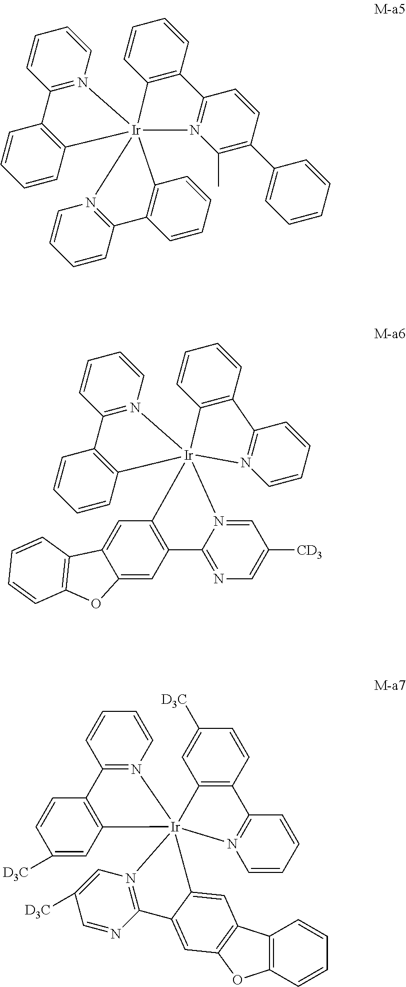

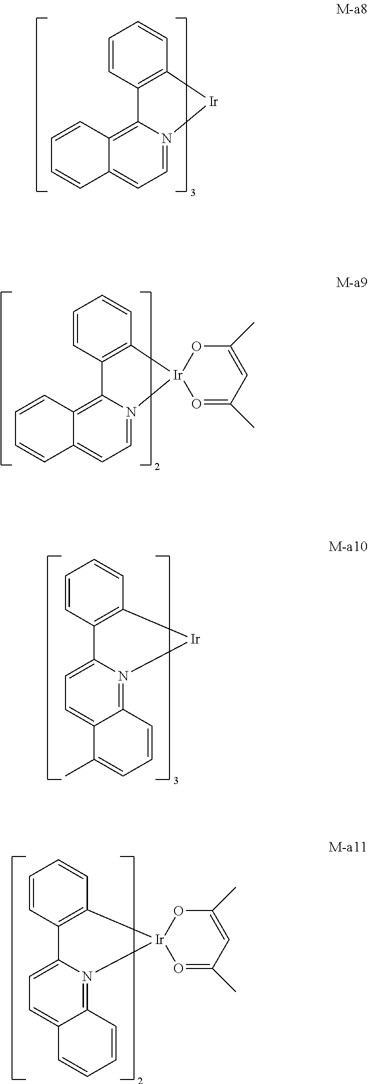

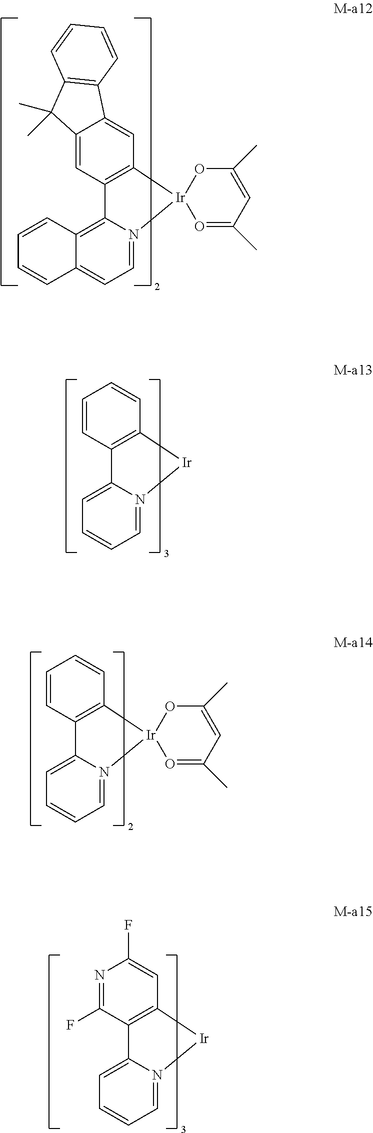

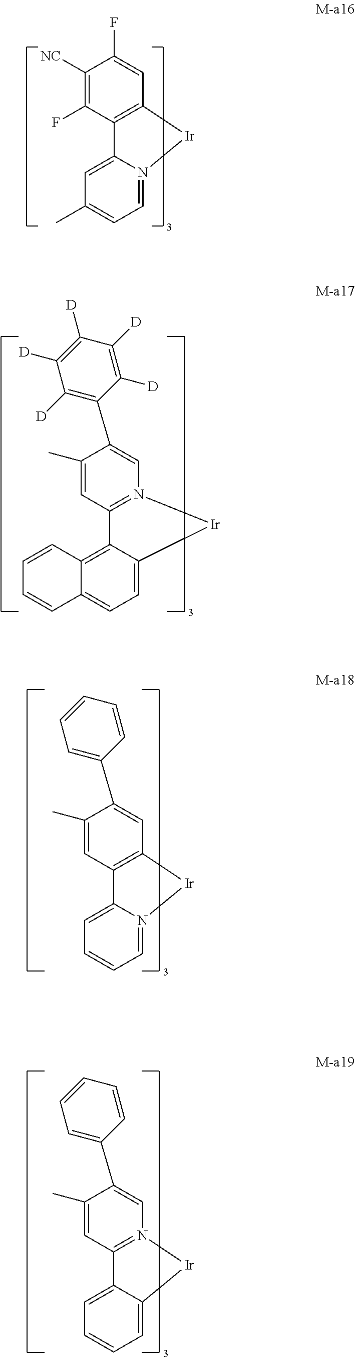

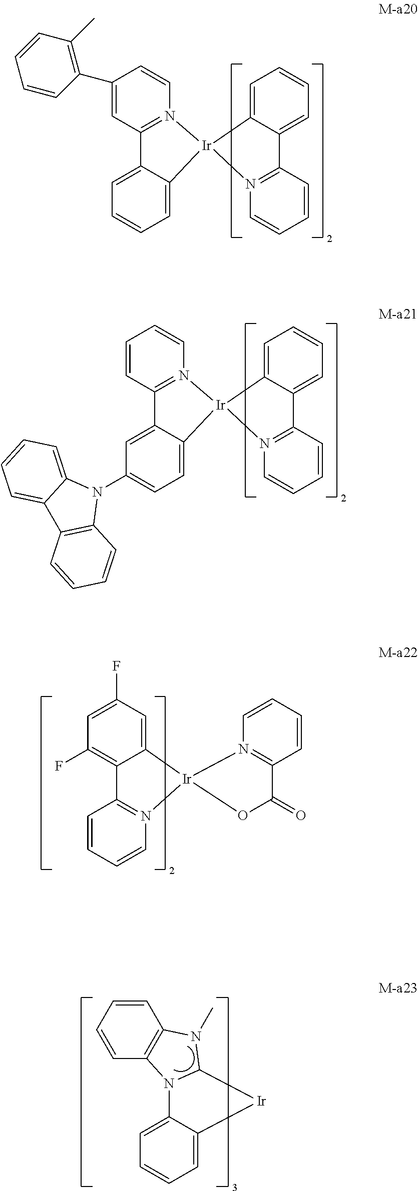

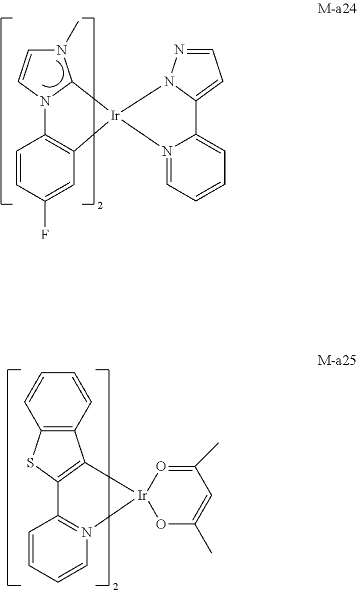

For example, Compound M-a1 and Compound M-a2 may be used as red dopant materials, and Compound M-a3 to Compound M-a7 may be used as green dopant materials.

The emission layer EML may further include a compound represented by any one selected from among Formula F-a to Formula F-c below. The compounds represented by Formula F-a to Formula F-c may be used as fluorescence dopant materials.

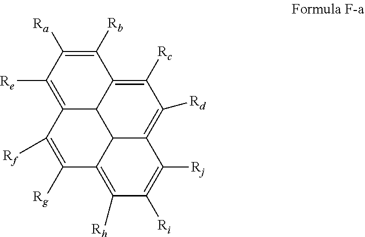

In Formula F-a, two selected from Rₐ to Rⱼ may be each independently substituted with *—NAr₁Ar₂. The remainder not substituted with *—NAr₁Ar₂ selected from among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

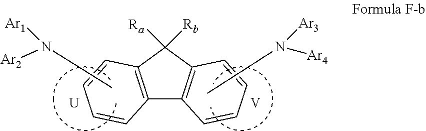

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. An to Ara may be each independently a substituted or unsubstituted aryl group of 6 to 30 ring-forming carbon atoms, or a substituted or unsubstituted heteroaryl group of 2 to 30 ring-forming carbon atoms. In Formula F-b, U and V may be each independently a substituted or

unsubstituted hydrocarbon ring of 5 to 30 ring-forming carbon atoms, or a substituted or unsubstituted heterocycle of 2 to 30 ring-forming carbon atoms. In Formula F-b, the number of rings represented by U and V may be each independently 0 or 1.

For example, in Formula F-b, if the number of U or V is 1, one ring forms a fused ring at the designated part by U or V, and if the number of U or V is 0, a ring is not present at the designated part by U or V. In one or more embodiments, if the number of U is 0, and the number of V is 1, or if the number of U is 1, and the number of V is 0, a fused ring having the fluorene core of Formula F-b may be a ring compound with four rings. In addition, if the number of both U and V is 0, the fused ring having a fluorene core of Formula F-b may be a ring compound with three rings. In addition, if the number of both U and V is 1, a fused ring having the fluorene core of Formula F-b may be a ring compound with five rings.

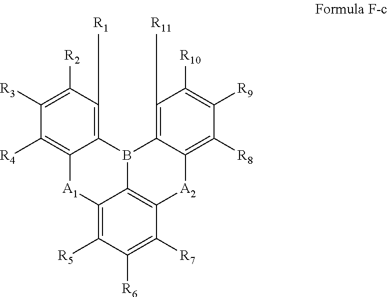

In Formula F-c, A₁ and A₂ may be each independently O, S, Se, or NRₘ. Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

R₁ to R₁₁ may be each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may be each independently combined with the substituents of an adjacent ring to form a fused ring. For example, if A₁ and A₂ are each independently NRₘ, A₁ may be combined with R₄ or R₅ to form a ring. In addition, A2 may be combined with R₇ or R₈ to form a ring.

In an embodiment, the emission layer EML may include any suitable dopant material generally used in the art. In one or more embodiments, the emission layer EML may include styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and/or the derivatives thereof (for example, 2,5,8,11-tetra-t-butylperylene (TBP)), pyrene and/or the derivatives thereof (for example, 1,1′-dipyrene, 1,4-dipyrenylbenzene, and/or 1,4-bis(N,N-diphenylamino)pyrene), etc.

The emission layer EML may include any suitable phosphorescence dopant material generally used in the art. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). In one or more embodiments, iridium(III) bis(4,6-difluorophenylpyridinato-N,C2′)picolinate (Flrpic), bis(2,4-difluorophenylpyridinato)-tetrakis(1-pyrazolyl)borate (Flr6), and/or platinum octaethyl porphyrin (PtOEP) may be used as the phosphorescence dopant. However, embodiments of the present disclosure are not limited thereto.

The emission layer EML may include a quantum dot material. The core of the quantum dot may be selected from II-VI group compounds, III-VI group compounds, I-III-VI group compounds, III-V group compounds, III-II-V group compounds, IV-VI group compounds, IV group elements, IV group compounds, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof.

The III-V group compound may include a binary compound such as In₂S₃, and/or In₂Se₃, a ternary compound such as InGaS₃, and/or InGaSe₃, or optional combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof, and/or a quaternary compound such as AgInGaS₂, and CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In one or more embodiments, the III-V group compound may further include a II group metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In this case, the binary compound, the ternary compound or the quaternary compound may be present at uniform (e.g., substantially uniform) concentration in a particle or may be present at a partially different concentration distribution state in the same particle. In addition, a core/shell structure in which one quantum dot wraps another quantum dot may be possible. The interface of the core and the shell may have a concentration gradient in which the concentration of an element present in the shell is decreased along a direction toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal and/or non-metal oxide, a semiconductor compound, or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, and/or a ternary compound such as MgAl₂O₄, CoFe₂O₄, NiFe₂O₄ and/or CoMn₂O₄, but embodiments of the present disclosure are not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have a full width of half maximum (FWHM) of emission wavelength spectrum of about 45 nm or less, about 40 nm or less, or, for example, about 30 nm or less. Within this range, color purity and/or color reproducibility may be improved. In addition, light emitted via such quantum dot is emitted in all (e.g., substantially all) directions, and light view angle properties may be improved.

In addition, the shape of the quantum dot may be generally used shapes in the art, without specific limitation. For example, the shape of spherical, pyramidal, multi-arm, and/or cubic nanoparticle, nanotube, nanowire, nanofiber, nanoplate particle, etc. may be used.

The quantum dot may control the color of light emitted according to the particle size, and accordingly, the quantum dot may have various suitable emission colors such as blue, red, or green.

Referring to FIG. 3 to FIG. 7 again, the first electrode EL1 may have conductivity. The first electrode EL1 may be formed using a metal material, a metal alloy and/or a conductive compound (e.g., an electrically conductive compound). The first electrode EL1 may be an anode or a cathode. However, embodiments of the present disclosure are not limited thereto. In addition, the first electrode EL1 may be a pixel electrode. The first electrode EU may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, and/or oxides thereof.

If the first electrode EL1 is the transmissive electrode, the first electrode EL1 may include a transparent metal oxide such as indium tin oxide (ITO), indium zinc oxide (IZO), zinc oxide (ZnO), and indium tin zinc oxide (ITZO). If the first electrode EL1 is the transflective electrode or the reflective electrode, the first electrode EU may include Ag, Mg, Cu, A1, Pt, Pd, Au, Ni, Nd, Ir, Cr, L₁, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). Also, the first electrode EU may have a structure including a plurality of layers including a reflective layer or a transflective layer formed using the above materials, and a transmissive conductive layer formed using ITO, IZO, ZnO, or ITZO. For example, the first electrode EL1 may have a three-layer structure of ITO/Ag/ITO, without limitation. In addition, the first electrode EL1 may include the above-described metal materials, combinations of two or more metal materials selected from the above-described metal materials, or oxides of the above-described metal materials. However, embodiments of the present disclosure are not limited thereto. The thickness of the first electrode EL1 may be from about 700 Å to about 10,000 Å. For example, the thickness of the first electrode EU may be from about 1,000 Å to about 3,000 Å.

The hole transport region HTR may be provided on the first electrode EL1. The hole transport region HTR may include at least one selected from a hole injection layer HIL, a hole transport layer HTL, a first buffer layer or a first emission auxiliary layer, or an electron blocking layer EBL. For example, the hole transport region HTR may include two hole transport layers HTL-1 and HTL-2 as shown in FIG. 5. Hereinafter, the same explanation of the hole transport layer HTL may be applied to the first and second hole transport layers HTL-1 and HTL-2.

The hole transport region HTR may have a single layer formed using a single material, a single layer formed using a plurality of different materials, or a multilayer structure including a plurality of layers formed using a plurality of different materials. For example, the hole transport region HTR may have the structure of a single layer of a hole injection layer HIL or a hole transport layer HTL, and may have a structure of a single layer formed using a hole injection material and a hole transport material.

In addition, the hole transport region HTR may have a structure of a single layer formed using a plurality of different materials, or a structure stacked from the first electrode EL1 of hole injection layer HIL/hole transport layer HTL, hole injection layer HTL/hole transport layer HTL/first buffer layer, hole injection layer HIL/first buffer layer, hole transport layer HTL/first buffer layer, or hole injection layer HIL/hole transport layer HTL/electron blocking layer EBL. However, these are examples, and embodiments of the present disclosure are not limited thereto.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1 below.

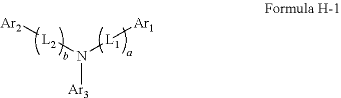

In Formula H-1 above, L₁ and L₂ may be each independently a direct linkage, a substituted or unsubstituted arylene group of 6 to 30 ring-forming carbon atoms, or a substituted or unsubstituted heteroarylene group of 2 to 30 ring-forming carbon atoms. “a” and “b” may be each independently an integer of 0 to 10. In one or more embodiments, if “a” or “b” is an integer of 2 or more, a plurality of L₁ and L₂ may be each independently a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. In addition, in Formula H-1, Ar₃ may be a substituted or unsubstituted aryl group of 6 to 30 ring-forming carbon atoms.

The compound represented by Formula H-1 may be a monoamine compound. Otherwise, the compound represented by Formula H-1 may be a diamine compound in which at least one selected from among Ar₁ to Ar₃ includes an amine group as a substituent. In addition, the compound represented by Formula H-1 may be a carbazole-based compound in which at least one selected from among Ar₁ and Ar₂ includes a substituted or unsubstituted carbazole group, or a fluorene-based compound in which at least one selected from among Ar₁ and Ar₂ includes a substituted or unsubstituted fluorene group.

The compound represented by Formula H-1 may be represented by any one selected from among the compounds in Compound Group H below. However, the compounds listed in Compound Group H are only examples, and the compound represented by Formula H-1 is not limited to the compounds represented in Compound Group H below.

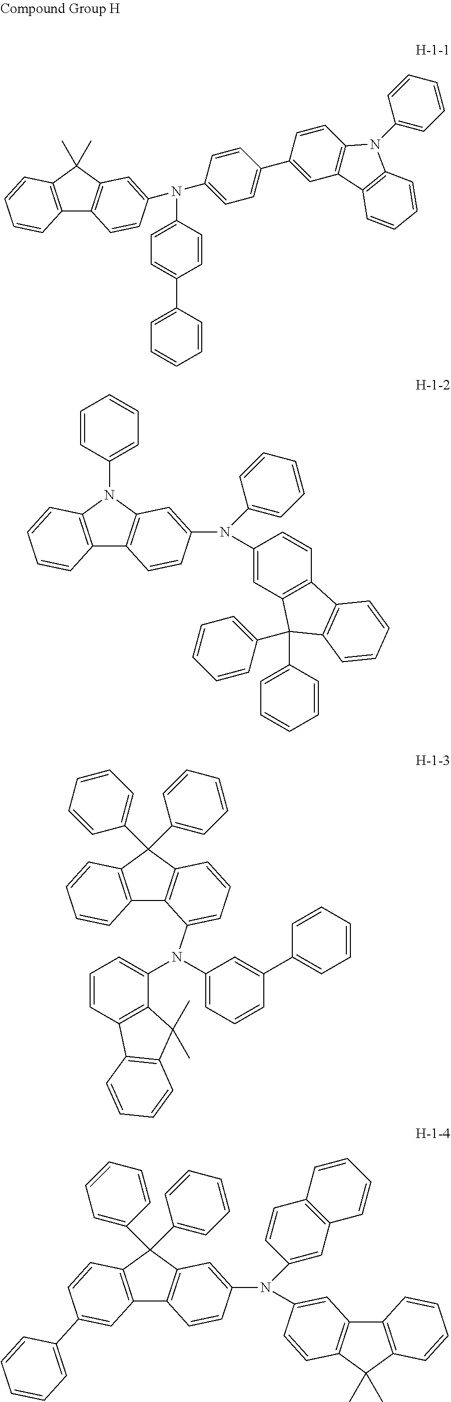 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

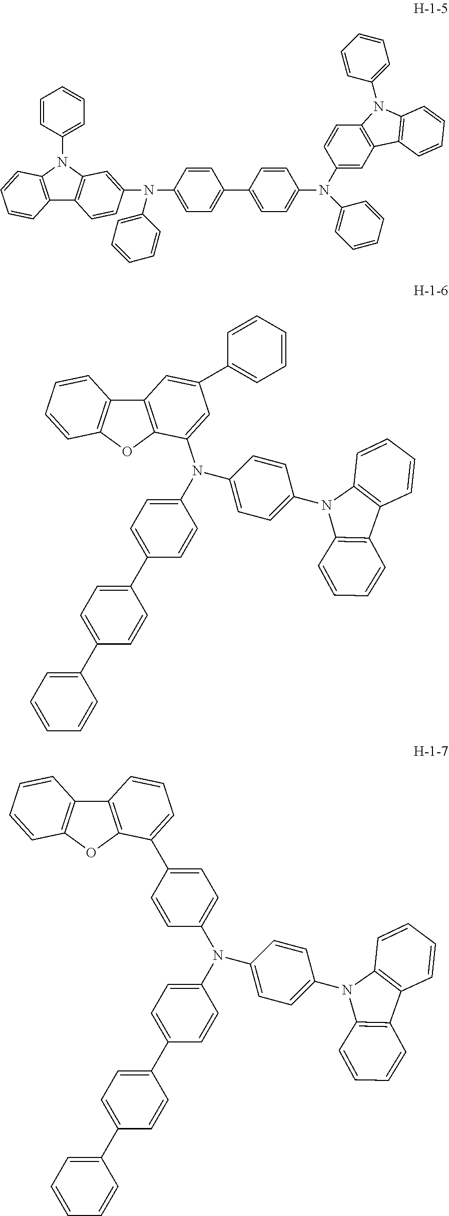

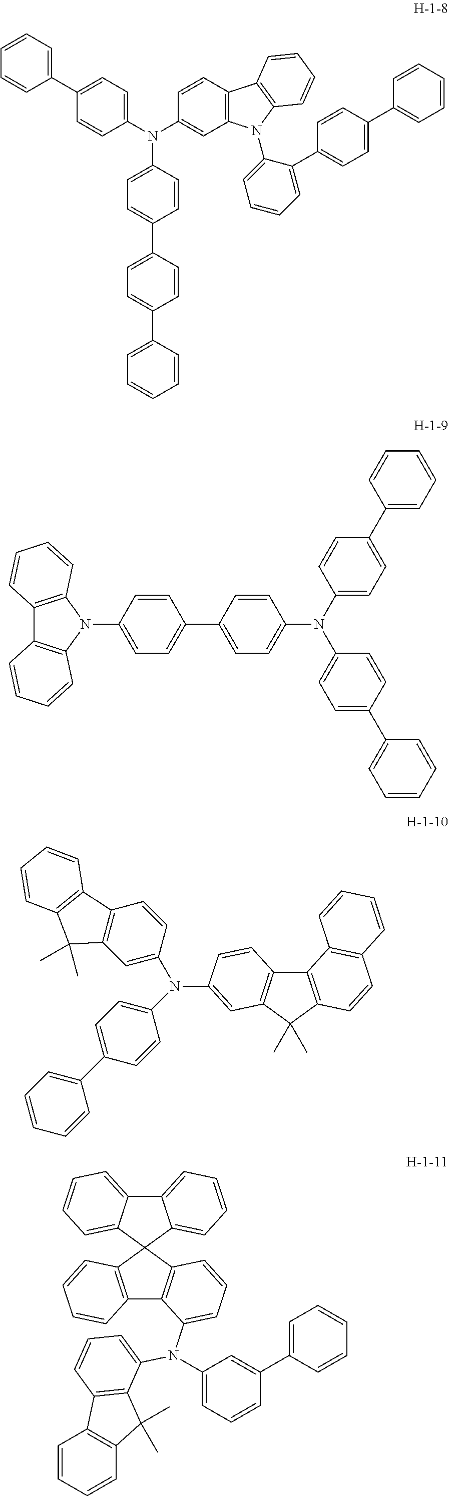

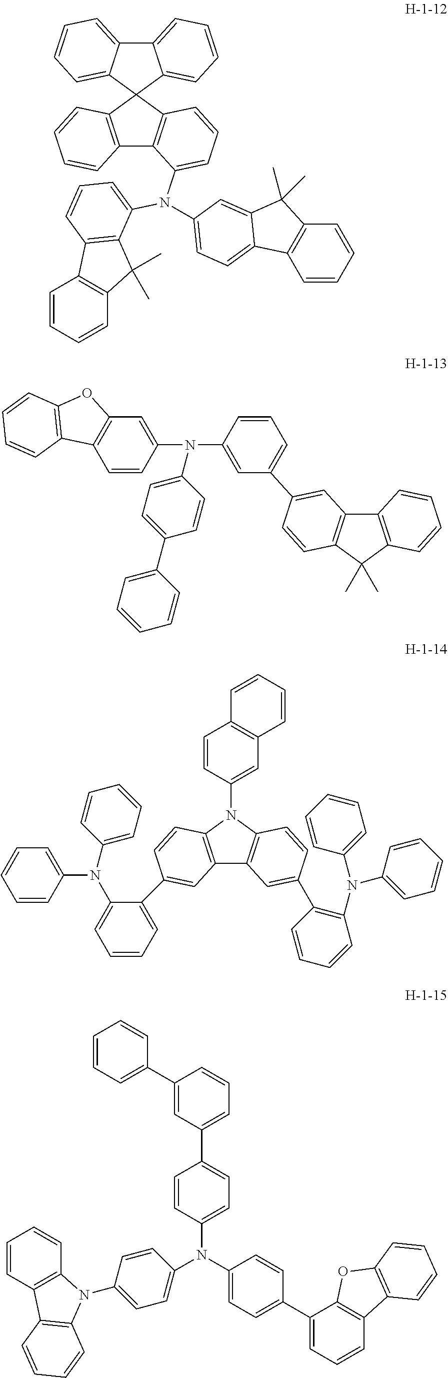 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

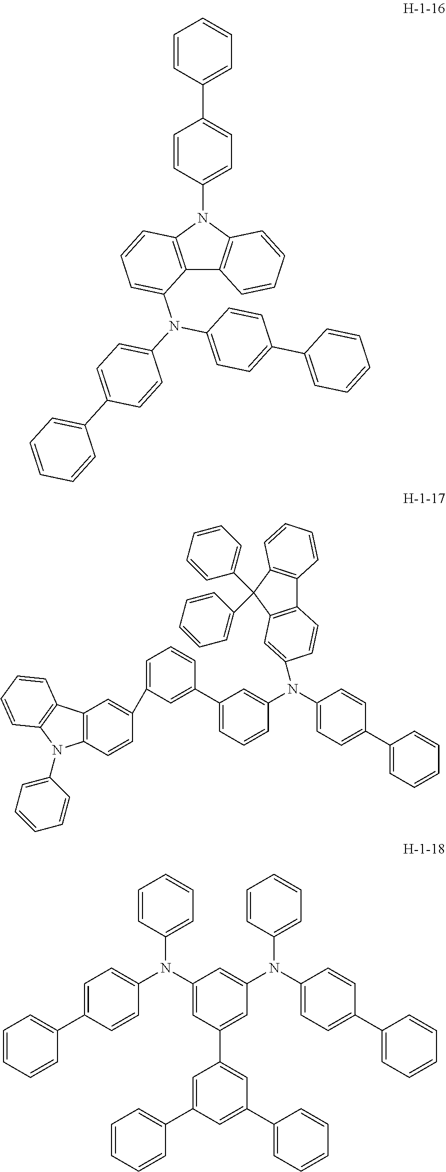 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

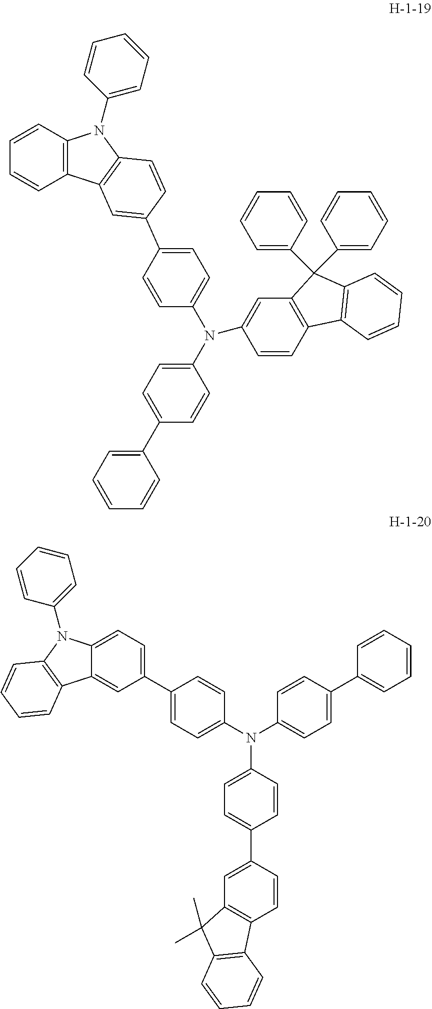 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(-c3ccc(N(c4ccc(-c5ccccc5)cc4)c4ccc(-c5ccc6c(c5)c5ccccc5n6-c5ccccc5)cc4)cc3)cc21]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HATCN).

In addition, the hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), and/or 1,3-bis(1,8-dimethyl-9H-carbazol-9-Abenzene (mDCP), etc.

The hole transport region HTR may include the compounds of the hole transport region in at least one selected from among the hole injection layer HIL, hole transport layer HTL, and electron blocking layer EBL.

The thickness of the hole transport region HTR may be from about 50 Å to about 15,000 Å. The thickness of the hole transport region HTR may be from about 100 Å to about 10,000 Å, for example, from about 100 Å to about 5,000 Å. In case where the hole transport region HTR includes a hole injection layer HIL, the thickness of the hole injection region HIL may be, for example, from about 30 Å to about 1,000 Å. In case where the hole transport region HTR includes a hole transport layer HTL, the thickness of the hole transport layer HTL may be from about 30 Å to about 1,000 Å. For example, in case where the hole transport region HTR includes an electron blocking layer EBL, the thickness of the electron blocking layer EBL may be from about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without substantial increase of a driving voltage.

The hole transport region HTR may further include a charge generating material to increase conductivity (e.g., electrical conductivity), in addition to the above-described materials. The charge generating material may be dispersed uniformly or non-uniformly in the hole transport region HTR. The charge generating material may be, for example, a p-dopant. The p-dopant may include at least one selected from metal halide compounds, quinone derivatives, metal oxides, and cyano group-containing compounds, without limitation. For example, the p-dopant may include metal halide compounds such as CuI and/or RbI, quinone derivatives such as tetracyanoquinodimethane (TCNQ) and/or 2,3,5,6-tetrafluoro-7,7,8,8-tetracyanoquinodimethane (F4-TCNQ), metal oxides such as tungsten oxide and/or molybdenum oxide, cyano group-containing compounds such as dipyrazino[2′3-′: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one selected from among a first buffer layer and an electron blocking layer EBL in addition to the hole injection layer HIL and the hole transport layer HTL. The first buffer layer may compensate resonance distance according to the wavelength of light emitted from an emission layer EML and may increase emission efficiency. As materials included in the first buffer layer, materials which may be included in the hole transport region HTR may be used. The electron blocking layer EBL is a layer playing the role of preventing or reducing the injection of electrons from the electron transport region ETR to the hole transport region HTR.

In the light emitting elements ED of embodiments, as shown in FIG. 3 to FIG. 7, the electron transport region ETR may be provided on the emission layer EML. The electron transport region ETR may include at least one selected from a hole blocking layer HBL, an electron transport layer ETL, an electron injection layer EIL, a second buffer layer, and an emission auxiliary layer EAL (hereinafter, second emission auxiliary layer). However, embodiments of the present disclosure are not limited thereto.

The electron transport region ETR may have a single layer formed using a single material, a single layer formed using a plurality of different materials, or a multilayer structure having a plurality of layers formed using a plurality of different materials. For example, the electron transport region ETR may have a single layer structure of an electron injection layer EIL or an electron transport layer ETL, or a single layer structure formed using an electron injection material and an electron transport material.

Further, the electron transport region ETR may have a single layer structure formed using a plurality of different materials, or a structure stacked from the emission layer EML of electron transport layer ETL/electron injection layer EIL, hole blocking layer HBL/electron transport layer ETL/electron injection layer EIL, second emission auxiliary layer EAL/electron transport layer ETL/electron injection layer EIL, or second buffer layer/electron transport layer ETL/electron injection layer EIL, without limitation.

Any one selected from among the second emission auxiliary layer EAL and the second buffer layer may be between the emission layer EML and the electron transport layer ETL. For example, the second emission auxiliary layer EAL and/or the second buffer layer may include the nitrogen-containing compound of an embodiment.

The second emission auxiliary layer EAL may play the role of adjusting the balance between holes and electrons.

The thickness of the electron transport region ETR may be, for example, from about 1,000 Å to about 1,500 Å. The electron transport region ETR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1.

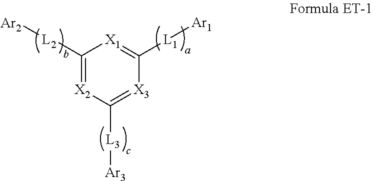

In Formula ET-1, at least one selected from among X₁ to X₃ may be N, and the remainder may be CRₐ. The compound represented by Formula E-1 may include a hexagonal ring group including at least one N as a ring-forming atom, as a central structure.

Rₐ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ari to Ara may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₁ and Ar₂ may be each independently a phenyl group substituted with a silyl group, and Ara may be an unsubstituted phenyl group. However, this is only an example, and the compound represented by Formula ET-1 is not limited thereto.

In Formula ET-1, “a” to “c” may be each independently an integer of 0 to 10. In Formula ET-1, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if “a” to “c” are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, embodiments of the present disclosure are not limited thereto. The electron transport region ETR may include at least one selected from, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and mixtures thereof, without limitation.

In addition, the electron transport region ETR may include a metal halide such as LiF, NaCl, CsF, RbCl, RbI, CuI and/or KI, a metal in lanthanoides such as Yb, and/or a co-depositing material of the metal halide and the metal in lanthanoides. For example, the electron transport region ETR may include KI:Yb, RbI:Yb, LiF:Yb, etc., as the co-depositing material. In one or more embodiments, the electron transport region ETR may use a metal oxide such as Li₂O and BaO, and/or 8-hydroxy-lithium quinolate (Liq). However, embodiments of the present disclosure are not limited thereto. The electron transport region ETR also may be formed using a mixture material of an electron transport material and an insulating organo metal salt. The organo metal salt may be a material having an energy band gap of about 4 eV or more. In one or more embodiments, the organo metal salt may include, for example, metal acetates, metal benzoates, metal acetoacetates, metal acetylacetonates, and/or metal stearates. The electron transport region ETR may include at least one selected from 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the aforementioned materials. However, embodiments of the present disclosure are not limited thereto.

The electron transport region ETR may include the compounds of the electron transport region in at least one selected from among an electron injection layer EIL, an electron transport layer ETL, and a hole blocking layer HBL.

If the electron transport region ETR includes the electron transport layer ETL, the thickness of the electron transport layer ETL may be from about 100 Å to about 1,000 Å, for example, from about 150 Å to about 500 Å. If the thickness of the electron transport layer ETL satisfies the above-described range, suitable or satisfactory electron transport properties may be obtained without substantial increase of a driving voltage. If the electron transport region ETR includes the electron injection layer EIL, the thickness of the electron injection layer EIL may be from about 1 Å to about 100 Å, and from about 3 Å to about 90 Å. If the thickness of the electron injection layer EIL satisfies the above described range, suitable or satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, if the first electrode EL1 is an anode, the second cathode EL2 may be a cathode, and if the first electrode EL1 is a cathode, the second electrode EL2 may be an anode. The second electrode EL2 may include at least one selected from among Ag, Mg, Cu, Al, Pt, Pd, Au, Ni, Nd, Ir, Cr, Li, Ca, LiF, Mo, Ti, W, In, Sn, and Zn, compounds of two or more selected therefrom, mixtures of two or more selected therefrom, and/or oxides thereof.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds including thereof, or mixtures thereof (for example, AgMg, AgYb, or MgYb). Otherwise, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, and/or oxides of the aforementioned metal materials.

In one or more embodiments, the second electrode EL2 may be connected with an auxiliary electrode. If the second electrode EL2 is connected with the auxiliary electrode, the resistance of the second electrode EL2 may decrease.

A capping layer CPL may be further on the second electrode EL2 in the light emitting element ED of an embodiment. The capping layer CPL may include a multilayer or a single layer.

In an embodiment, the capping layer CPL may be an organic layer and/or an inorganic layer. For example, if the capping layer CPL includes an inorganic material, the inorganic material may include an alkali metal compound such as LiF, an alkaline earth metal compound such as SiON, SiNₓ, SiO_{y}, etc.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., and/or includes an epoxy resin, and/or acrylate such as methacrylate. In addition, a capping layer CPL may include at least one selected from among Compounds P1 to P5 below, but embodiments of the present disclosure are not limited thereto.

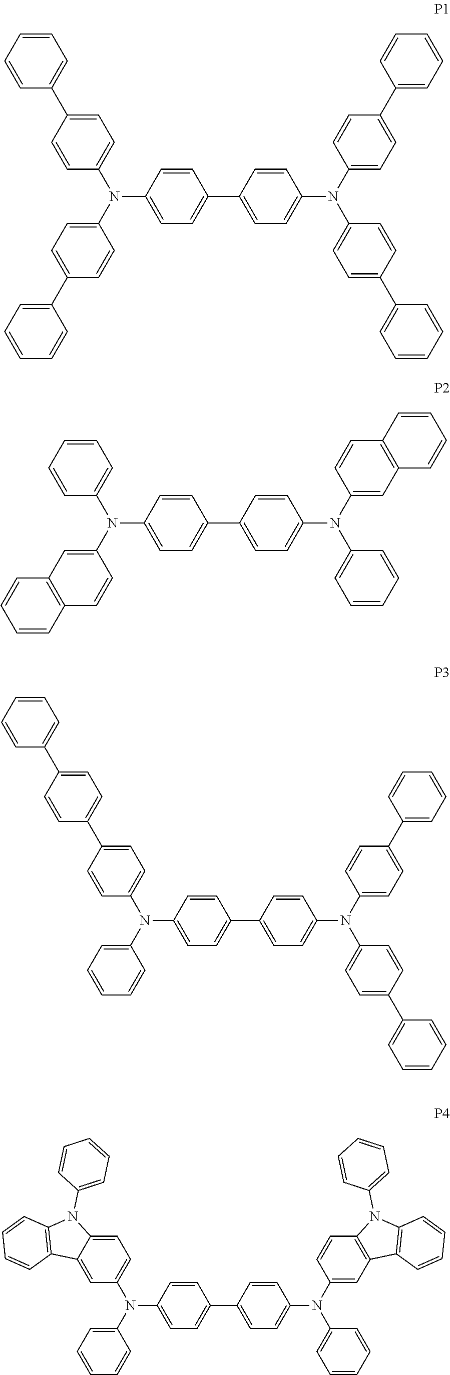 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

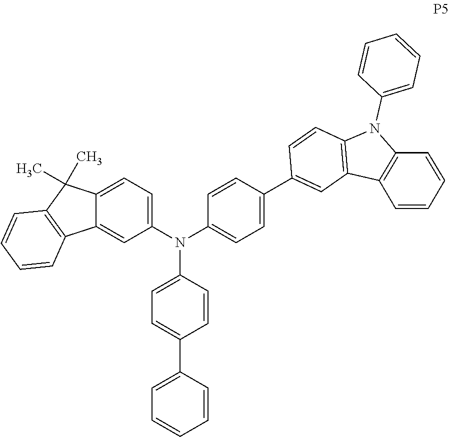 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL with respect to light in a wavelength range of about 550 nm to about 660 nm may be about 1.6 or more.

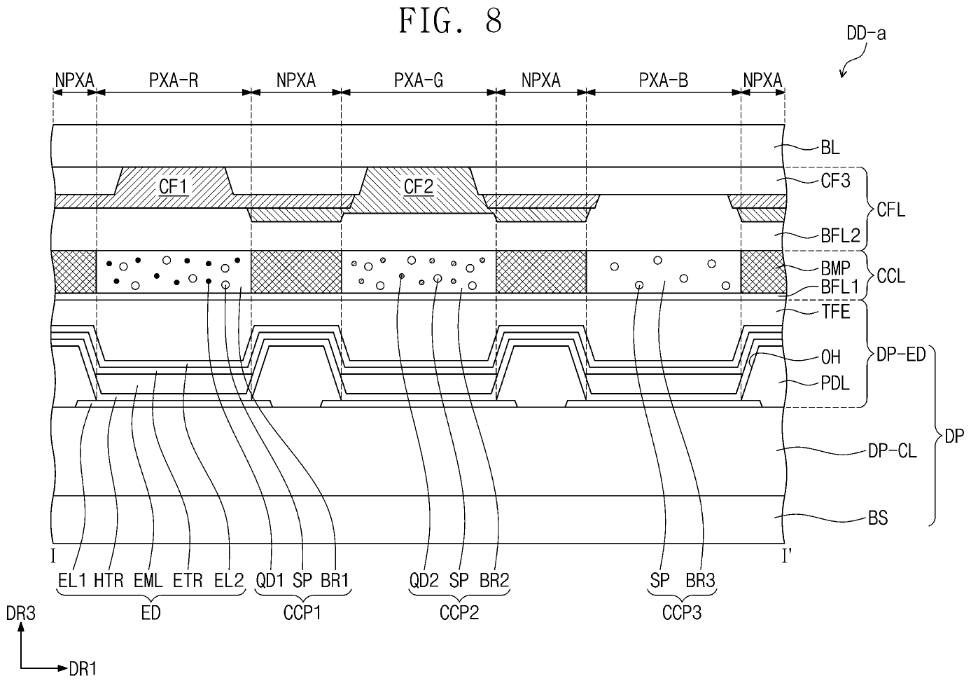

FIG. 8 to FIG. 11 are cross-sectional views on display devices according to embodiments. Hereinafter, in the explanation on the display devices of embodiments, referring to FIG. 8 to FIG. 11, the overlapping parts with the explanation on FIG. 1 to FIG. 7 will not be explained again here, and the different features will be explained chiefly.

Referring to FIG. 8, a display device DD-a according to an embodiment may include a display panel DP including a display element layer DP-ED, a light controlling layer CCL on the display panel DP, and a color filter layer CFL.

In an embodiment shown in FIG. 8, the display panel DP includes a base layer BS, a circuit layer DP-CL provided on the base layer BS and a display element layer DP-ED, and the display element layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In at least one selected from among the emission layer EML and the electron transport region ETR, shown in FIG. 8, the nitrogen-containing compound of an embodiment may be included. The structures of the light emitting elements of FIG. 3 to FIG. 7 may be applied to the structure of the light emitting element ED shown in FIG. 8.

Referring to FIG. 8, the emission layer EML may be in an opening part OH defined in a pixel definition layer PDL. For example, the emission layer EML divided by the pixel definition layer PDL and correspondingly provided to each of luminous areas PXA-R, PXA-G and PXA-B may emit light in the same wavelength region. In the display device DD-a of an embodiment, the emission layer EML may emit blue light. In one or more embodiments, different from the drawings, the emission layer EML may be provided as a common layer for all luminous areas PXA-R, PXA-G and PXA-B.

The light controlling layer CCL may be on the display panel DP. The light controlling layer CCL may include a light converter. The light converter may be a quantum dot and/or a phosphor. The light converter may transform the wavelength of light provided and then emit. In one or more embodiments, the light controlling layer CCL may be a layer including a quantum dot and/or a layer including a phosphor.

The light controlling layer CCL may include a plurality of light controlling parts CCP1, CCP2 and CCP3. The light controlling parts CCP1, CCP2 and CCP3 may be separated from one another.

Referring to FIG. 8, a partition pattern BMP may be between the separated light controlling parts CCP1, CCP2 and CCP3, but embodiments of the present disclosure are not limited thereto. In FIG. 8, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 that converts a first color light provided from the light emitting element ED into a second color light, a second light controlling part CCP2 including a second quantum dot QD2 that converts the first color light into a third color light, and a third light controlling part CCP3 that transmits the first color light.

In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting element ED. For example, the first quantum dot QD1 may be a red quantum dot, and the second quantum dot QD2 may be a green quantum dot. On the quantum dots QD1 and QD2, the same contents as those described above may be applied.

In addition, the light controlling layer CCL may further include a scatterer SP (e.g., a light scatterer SP). The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, and/or may be a mixture of two or more materials selected from among TiO₂, ZnO, Al₂O₃, SiO₂, and hollow silica.

Each of the first light controlling part CCP1, the second light controlling part CCP2, and the third light controlling part CCP3 may include base resins BR1, BR2 and BR3 dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2 and BR3 are mediums in which the quantum dots QD1 and QD2 and the scatterer SP are dispersed, and may be composed of various suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking or reducing the penetration of moisture and/or oxygen (hereinafter, will be referred to as “humidity/oxygen”). The barrier layer BFL1 may block or reduce the exposure of the light controlling parts CCP1, CCP2 and CCP3 to humidity/oxygen. In one or more embodiments, the barrier layer BFL1 may cover the light controlling parts CCP1, CCP2 and CCP3. In addition, the barrier layer BFL2 may be provided between the light controlling parts CCP1, CCP2 and CCP3 and a color filter layer CFL.

The barrier layers BFL1 and BFL2 may include at least one inorganic layer. In one or more embodiments, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride and/or a metal thin film securing light transmittance. In one or more embodiments, the barrier layers BFL1 and BFL2 may further include an organic layer. The barrier layers BFL1 and BFL2 may be composed of a single layer of a plurality of layers.

In the display device DD-a of an embodiment, the color filter layer CFL may be on the light controlling layer CCL. For example, the color filter layer CFL may be directly on the light controlling layer CCL. In this case, the barrier layer BFL2 may be omitted.

The color filter layer CFL may include first to third filters CF1, CF2 and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye. Embodiments of the present disclosure, however, are not limited thereto, and the third filter CF3 may not include the pigment or dye. The third filter CF3 may include a polymer photosensitive resin and not include a pigment or dye. The third filter CF3 may be transparent. The third filter CF3 may be formed using a transparent photosensitive resin. The first to third filters CF1, CF2 and CF3 may be correspond to the red luminous area PA-R, green luminous area PXA-G and blue luminous area PXA-B, respectively.

In addition, in an embodiment, the first filter CF1 and the second filter CF2 may be yellow filters. The first filter CF1 and the second filter CF2 may be provided in one body without distinction.

In one or more embodiments, the color filter layer CFL may further include a light blocking part. The light blocking part may be a black matrix. The light blocking part may be formed by including an organic light blocking material and/or an inorganic light blocking material, including a black pigment and/or black dye. The light blocking part may prevent or reduce light leakage and may divide the boundaries among adjacent filters CF1, CF2 and CF3.

A base substrate BL may be on the color filter layer CFL. The color filter layer CFL, the light controlling layer CCL, etc. may be on a base surface of the base substrate BL. The base substrate BL may be a glass substrate, a metal substrate, a plastic substrate, etc. However, embodiments of the present disclosure are not limited thereto, and the base substrate BL may be an inorganic layer, an organic layer or a composite material layer. In addition, different from the drawing, the base substrate BL may be omitted in an embodiment.

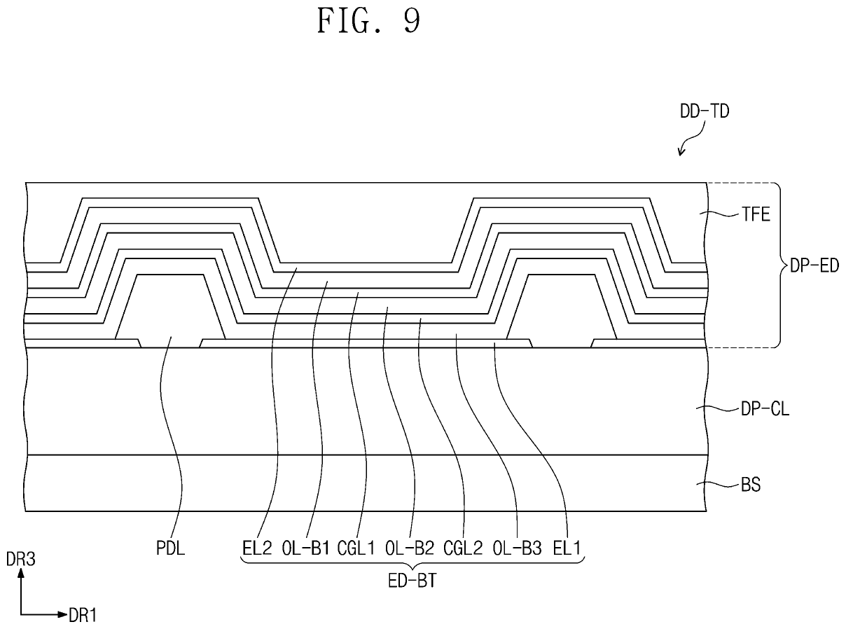

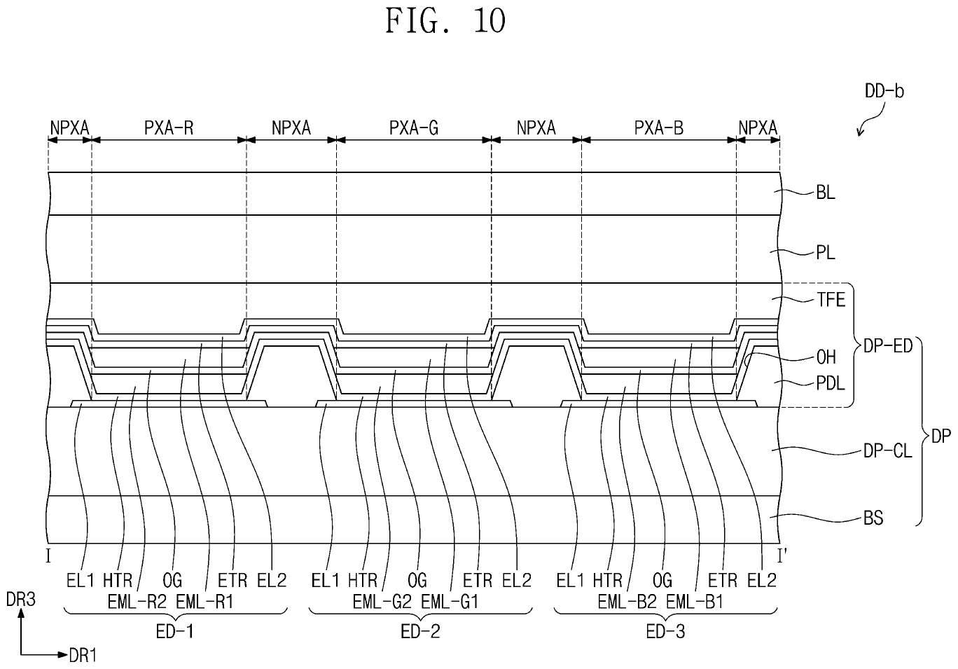

FIG. 9 is a cross-sectional view showing a part of the display device according to an embodiment. FIG. 9 shows another embodiment of a part corresponding to the display panel DP in FIG. 8. In a display device DD-TD of an embodiment, the light emitting element ED-BT may include a plurality of light emitting structures OL-B1, OL-B2 and OL-B3. At least one selected from among a plurality of light emitting structures OL-B1, OL-B2 and OL-B3 may include the nitrogen-containing compound of an embodiment.

The light emitting element ED-BT may include a first electrode EL1 and a second electrode EL2 opposite to each other, and the plurality of light emitting structures OL-B1, OL-B2 and OL-B3 stacked in order in a thickness direction and provided between the first electrode EL1 and the second electrode EL2. Each of the light emitting structures OL-B1, OL-B2 and OL-B3 may include an emission layer EML (FIG. 7), and a hole transport region HTR and an electron transport region ETR with the emission layer EML (FIG. 7) therebetween. In one or more embodiments, the light emitting element ED-BT included in the display device DD-TD of an embodiment may be a light emitting element of a tandem structure including a plurality of emission layers.

In an embodiment shown in FIG. 9, light emitted from the light emitting structures OL-B1, OL-B2 and OL-B3 may be all blue light. However, embodiments of the present disclosure are not limited thereto, and the wavelength regions of light emitted from the light emitting structures OL-B1, OL-B2 and OL-B3 may be different from each other. For example, the light emitting element ED-BT including the a plurality of light emitting structures OL-B1, OL-B2 and OL-B3 emitting light in different wavelength regions may emit white light.

Charge generating layers CGL1 and CGL2 may be between neighboring light emitting structures OL-B1, OL-B2 and OL-B3. The charge generating layers CGL1 and CGL2 may include a p-type charge generating layer and/or an n-type charge generating layer.

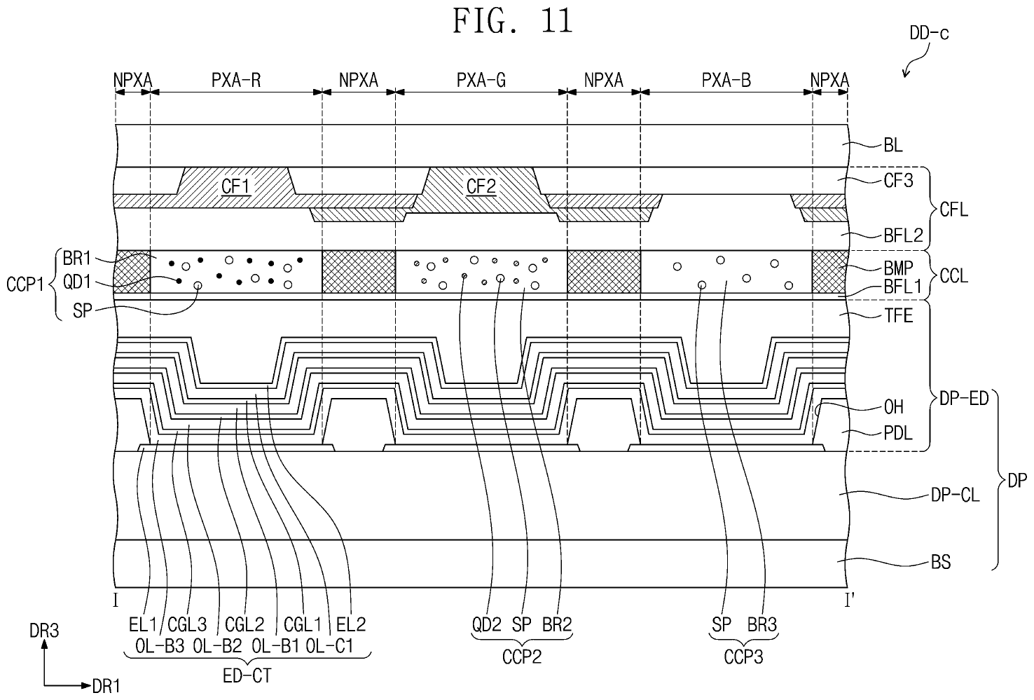

Referring to FIG. 10, a display device DD-b according to an embodiment may include light emitting elements ED-1, ED-2 and ED-3, formed by stacking two emission layers. Compared to the display device DD of an embodiment, shown in FIG. 2, an embodiment shown in FIG. 10 is different in that first to third light emitting elements ED-1, ED-2 and ED-3 include two emission layers stacked in a thickness direction, each. In the first to third light emitting elements ED-1, ED-2 and ED-3, two emission layers may emit light in the same wavelength region.

The first light emitting element ED-1 may include a first red emission layer EML-R₁ and a second red emission layer EML-R₂. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

At least one selected from among the first to third light emitting elements ED-1, ED-2 and ED-3 may include the nitrogen-containing compound of an embodiment. For example, at least one selected from among the first blue emission layer EML-B1, and the second blue emission layer EML-B2 may include the nitrogen-containing compound of an embodiment. However, this is only an example, and embodiments of the present disclosure are not limited thereto.

The emission auxiliary part OG may include a single layer or a multilayer. The emission auxiliary part OG may include a charge generating layer. For example, the emission auxiliary part OG may include an electron transport region, a charge generating layer, and a hole transport region stacked in order. The emission auxiliary part OG may be provided as a common layer in all of the first to third light emitting elements ED-1, ED-2 and ED-3. However, embodiments of the present disclosure are not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be between the emission auxiliary part OG and the electron transport region ETR. The second red emission layer EML-R₂, the second green emission layer EML-G2 and the second blue emission layer EML-B2 may be between the hole transport region HTR and the emission auxiliary part OG.

In one or more embodiments, the first light emitting element ED-1 may include the first electrode EL1, the hole transport region HTR, the second red emission layer EML-R₂, the emission auxiliary part OG, the first red emission layer EML-R₁, the electron transport region ETR, and the second electrode EL2, stacked in order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, stacked in order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, stacked in order.

In one or more embodiments, an optical auxiliary layer PL may be on a display element layer DP-ED. The optical auxiliary layer PL may include a polarization layer. The optical auxiliary layer PL may be on a display panel DP and may control reflected light at the display panel DP by external light. Different from the drawings, the optical auxiliary layer PL may be omitted from the display device according to an embodiment.

Different from FIG. 9 and FIG. 10, a display device DD-c in FIG. 11 is shown to include four light emitting structures OL-B1, OL-B2, OL-B3 and OL-C1. A light emitting element ED-CT may include a first electrode EL1 and a second electrode EL2 opposite to each other, and first to fourth light emitting structures OL-B1, OL-B2, OL-B3 and OL-C1 stacked in order in a thickness direction between the first electrode EL1 and the second electrode EL2. At least one selected from among the first to fourth light emitting structures OL-B1, OL-B2, OL-B3 and OL-C1 may include the nitrogen-containing compound of an embodiment.

Among the four light emitting structures, the first to third light emitting structures OL-B1, OL-B2 and OL-B3 may emit blue light, and the fourth light emitting structure OL-C1 may emit green light. However, embodiments of the present disclosure are not limited thereto, and the first to fourth light emitting structures OL-B1, OL-B2, OL-B3 and OL-C1 may emit different wavelengths of light.

Charge generating layers CGL1, CGL2 and CGL3 may be between the first to fourth light emitting structures OL-B1, OL-B2, OL-B3. The charge generating layers CGL1, CGL2 and CGL3 between neighboring light emitting structures OL-B1, OL-B2, OL-B3 may include a p-type charge generating layer and/or an n-type charge generating layer.

Hereinafter, referring to embodiments and comparative embodiments, the nitrogen-containing compound according to an embodiment and the light emitting element according to embodiments of the present disclosure will be explained in more detail. In addition, the embodiments below are examples to assist the understanding of the subject matter of the present disclosure, but the scope of the present disclosure is not limited thereto.

### EXAMPLES

### 1. Synthesis of Nitrogen-Containing Compounds of Embodiments

The synthetic method of the nitrogen-containing compound according to an embodiment will be explained in more detail by illustrating the synthetic methods of Compounds 8, 10, 13, 16, 30 and 35. In addition, the synthetic methods of the nitrogen-containing compounds explained hereinafter are embodiments, and the synthetic method of the compound according to embodiments of the present disclosure are not limited to the Examples below.

### (1) Synthesis of Nitrogen-Containing Compound 8

Nitrogen-containing Compound 8 according to an embodiment may be synthesized by, for example, the steps of Reaction 1 below.

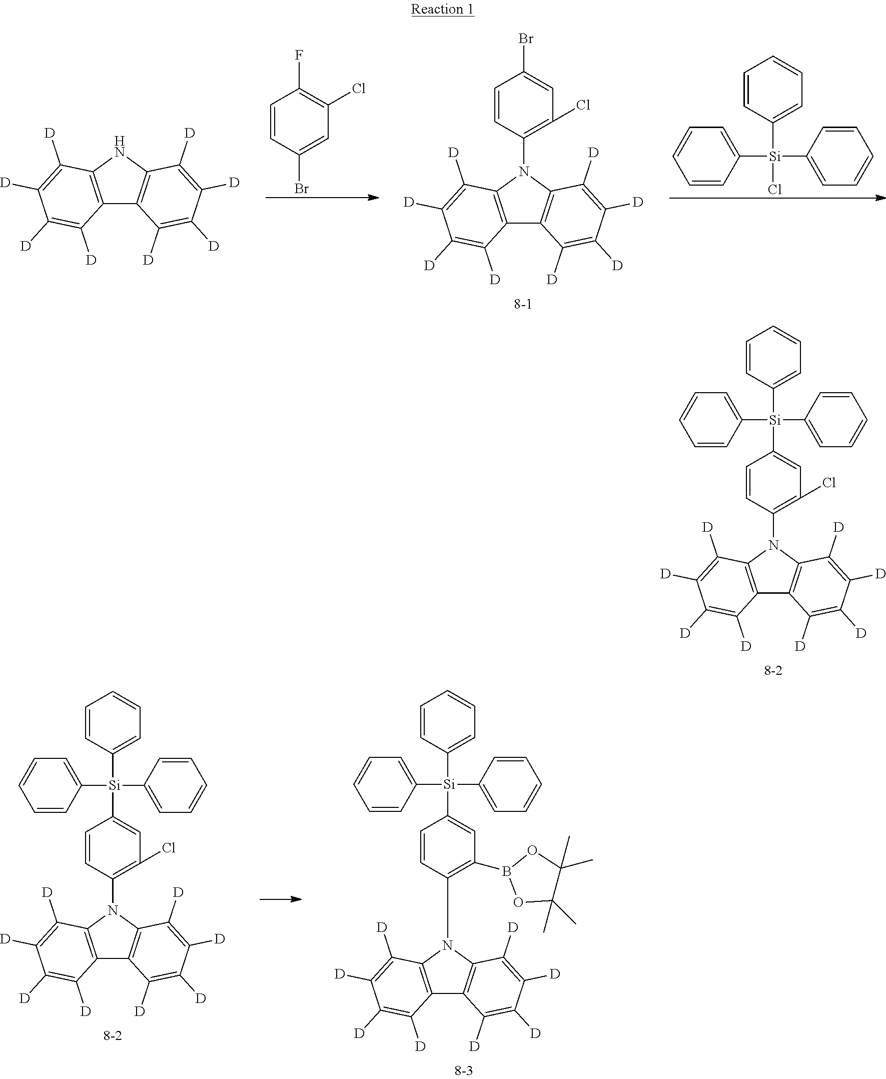

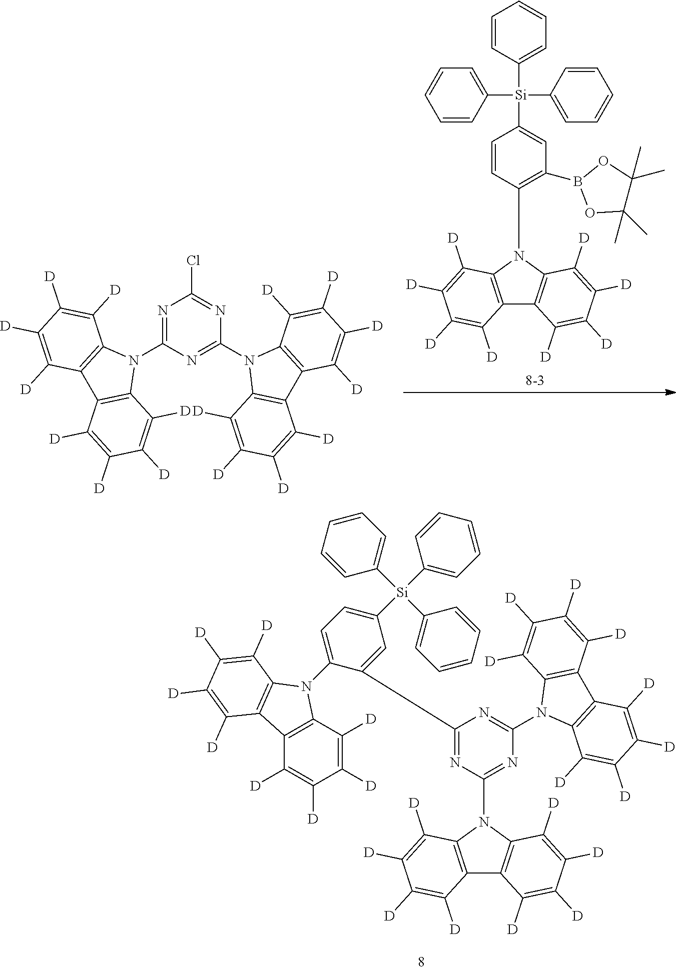

### Synthesis of Intermediate 8-1

After dissolving 10 g of 9H-carbazole-1,2,3,4,5,6,7,8-d8 (CAS: 38537-24-5), 11.95 g of 4-bromo-2-chloro-1-fluorobenzene, and 24.22 g of potassium phosphate tribasic (K₃PO₄) in 250 mL of dimethylformamide (DMF), the reactants were stirred at about 160° C. for about 12 hours. After finishing the reaction, the resultant reaction solution was extracted, and an organic layer obtained was dried. The residue was separated and purified by column chromatography to obtain 19.35 g (yield 93%) of Intermediate 8-1. Intermediate 8-1 was identified by LC-MS (C₁₈H₃D₈BrClN: M+1 364.70).

### Synthesis of Intermediate 8-2

19.35 g of Intermediate 8-1 was dissolved in 300 mL of a tetrahydrofuran (THF) solvent, and stirred at about −78° C. After slow and dropwise addition of 21 mL of 2.5 M n-BuLi, the resultant was stirred at about −78° C. for about 1 hour. Then, a solution obtained by dissolving 8.13 g of chlorotriphenylsilane in 130 mL of THF was slowly and dropwisely added thereto at about −78° C., and then, stirred at room temperature for 12 hours. After finishing the reaction, the resultant reaction solution was extracted, and an organic layer obtained was dried. The residue was separated and purified by column chromatography to obtain 23 g (yield 80%) of Intermediate 8-2. Intermediate 8-2 was identified by LC-MS (C₃₆H₁₈D₈ClNSi: M+1 544.19).

### Synthesis of Intermediate 8-3

23 g of Intermediate 8-2, 10.73 g of bis(pinacolato)diboron, 6.22 g of potassium acetate (KOAc), 2.34 g of 1,1′-bis(diphenylphosphino)ferrocene, and 0.47 g of palladium acetate (Pd(OAc)₂) were dissolved in 200 mL of 1,4-dioxane, and stirred at about 120° C. for about 12 hours. After finishing the reaction, the resultant reaction solution was extracted, and an organic layer obtained was dried. The residue was separated and purified by column chromatography to obtain 20.15 g (yield 75%) of Intermediate 8-3. Intermediate 8-3 was identified by LC-MS (C₄₂H₃₀D₈BNO₂Si: M+1 635.71).

### Synthesis of Compound 8

2 g of 9,9′-(6-Chloro-1,3,5-triazine-2,4-diyl)bis(9H-carbazole-1,2,3,4,5,6,7,8-d8) (CAS: 2778147-34-3), 2.75 g of Intermediate 8-3, 3.24 mL of a 2M potassium carbonate (K₂CO₃) aqueous solution, and 0.15 g of tetrakis(triphenylphosphine)palladium(0) (Pd(PPh₃)₄) were dissolved in 15 mL of toluene and 3.24 mL of ethanol solvents, and stirred at about 110° C. for about 12 hours. After finishing the reaction, the resultant reaction solution was extracted, and an organic layer obtained was dried. The residue was separated and purified by column chromatography, recrystallization and sublimation purification to obtain 2.99 g (yield 74%) of Compound 8 with high purity. Compound 8 was identified by LC-MS and ¹H-NMR.

### (2) Synthesis of Nitrogen-Containing Compound 10

Nitrogen-containing Compound 10 according to an embodiment may be synthesized by, for example, the steps of Reaction 2 below.

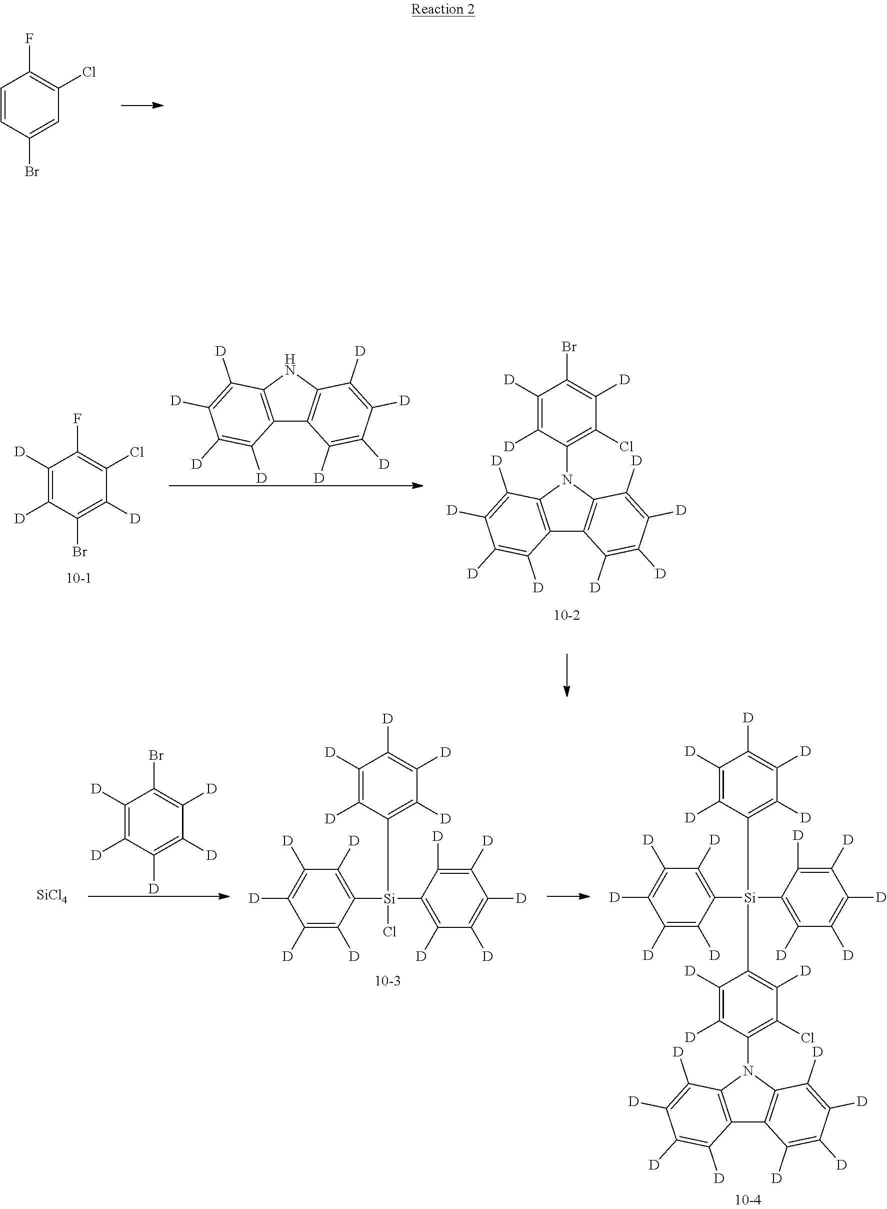

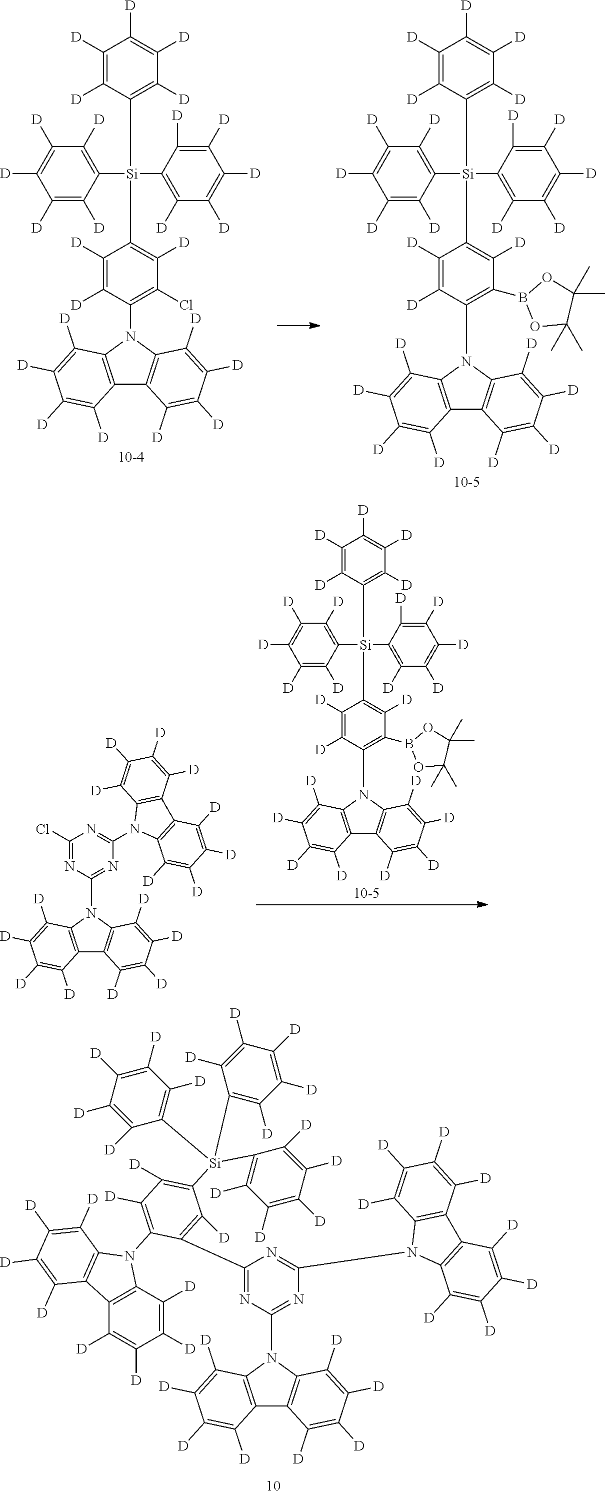

### Synthesis of Intermediate 10-1

After dissolving 10 g of 4-bromo-2-chloro-1-fluorobenzene, 2.63 g of silver carbonate, and 5.07 g of cyclohexyldiphenylphosphine in 0.5 mL of toluene and 9 mL of D₂O solvents, the reactants were stirred at about 120° C. for about 12 hours. After finishing the reaction, the resultant reaction solution was extracted, and an organic layer obtained was dried. The residue was separated and purified by column chromatography to obtain 10.04 g (yield 99%, average D substitution ratio of 93%) of Intermediate 10-1. Intermediate 10-1 was identified by LC-MS (C₆D₃BrClF: M+1 212.46).

### Synthesis of Intermediate 10-2

g of Intermediate 10-1, 8.25 g of 9H-carbazole-1,2,3,4,5,6,7,8-d8 (CAS: 38537-24-5), and 19.98 g of K₃PO₄ were dissolved in 200 mL of a DMF solvent, and stirred at about 160° C. for about 12 hours. After finishing the reaction, the resultant reaction solution was extracted, and an organic layer obtained was dried. The residue was separated and purified by column chromatography to obtain 15.96 g (yield 93%) of Intermediate 10-2. Intermediate 10-2 was identified by LC-MS (C₁₈H₁₁BrClN: M+1 367.71).

### Synthesis of Intermediate 10-4

The synthesis of Intermediate 10-4 was performed by in-situ reaction.

### Reaction 10-4A

After dissolving 10 g of 1-bromobenzene-2,3,4,5,6-d5 in 100 mL of a THF solvent, the resultant was stirred at about −78° C. 74 mL of 2.5 M n-BuLi was slowly and dropwisely added thereto, followed by stirring at about −78° C. for about 1 hour. Then, a solution of 7.08 mL of SiCl₄ dissolved in 30 mL of THF was slowly and dropwisely added thereto at about −78° C., followed by stirring at room temperature. Reaction 10-4A includes the synthesis of Intermediate 10-3.

### Reaction 10-4B

After dissolving 10.14 g of Intermediate 10-2 in 130 mL of a THF solvent, the resultant was stirred at about −78° C. 24.68 mL of 2.5 M n-BuLi was slowly and dropwisely added thereto, followed by stirring at about −78° C. for about 1 hour. Then, Reaction 10-4B was added to Reaction 10-4A using a cannula, and the resultant was subjected to stirring at room temperature for 12 hours. After finishing the reaction, the resultant reaction solution was extracted, and an organic layer obtained was dried. The residue was separated and purified by column chromatography to obtain 13.9 g (yield 40%) of Intermediate 10-4. Intermediate 10-4 was identified by LC-MS (C₃₆D₂₆ClNSi: M+1 562.30).

### Synthesis of Intermediate 10-5

13.9 g of Intermediate 10-4, 6.27 g of bis(pinacolato)diboron, 7.29 g of KOAc, 1.37 g of 1,1′-bis(diphenylphosphino)ferrocene, and 0.28 g of Pd(OAc)₂ were dissolved in 120 mL of a 1,4-dioxane solvent, and stirred at about 120° C. for about 12 hours. After finishing the reaction, the resultant reaction solution was extracted, and an organic layer obtained was dried. The residue was separated and purified by column chromatography to obtain 12.12 g (yield 75%) of Intermediate 10-5. Intermediate 10-5 was identified by LC-MS (C₄₂H₁₂D₂₆BNO₂Si: M+1 653.82).

### Synthesis of Compound 10

2 g of 9,9′-(6-Chloro-1,3,5-triazine-2,4-diyl)bis(9H-carbazole-1,2,3,4,5,6,7,8-d8) (CAS: 2778147-34-3), 2.83 g of Intermediate 10-5, 3.24 mL of a 2 M K₂CO₃ aqueous solution, and 0.15 g of Pd(PPh₃)₄ were dissolved in 20 mL of toluene and 3.24 mL of ethanol solvents, and stirred at about 110° C. for about 12 hours. After finishing the reaction, the resultant reaction solution was extracted, and an organic layer obtained was dried. The residue was separated and purified by column chromatography, recrystallization and sublimation purification to obtain 3.05 g (yield 74%) of Compound 10 with high purity. Compound 10 was identified by LC-MS and ¹H-NMR.

### (3) Synthesis of Nitrogen-Containing Compound 13

Nitrogen-containing Compound 13 according to an embodiment may be synthesized by, for example, the steps of Reaction 3 below.

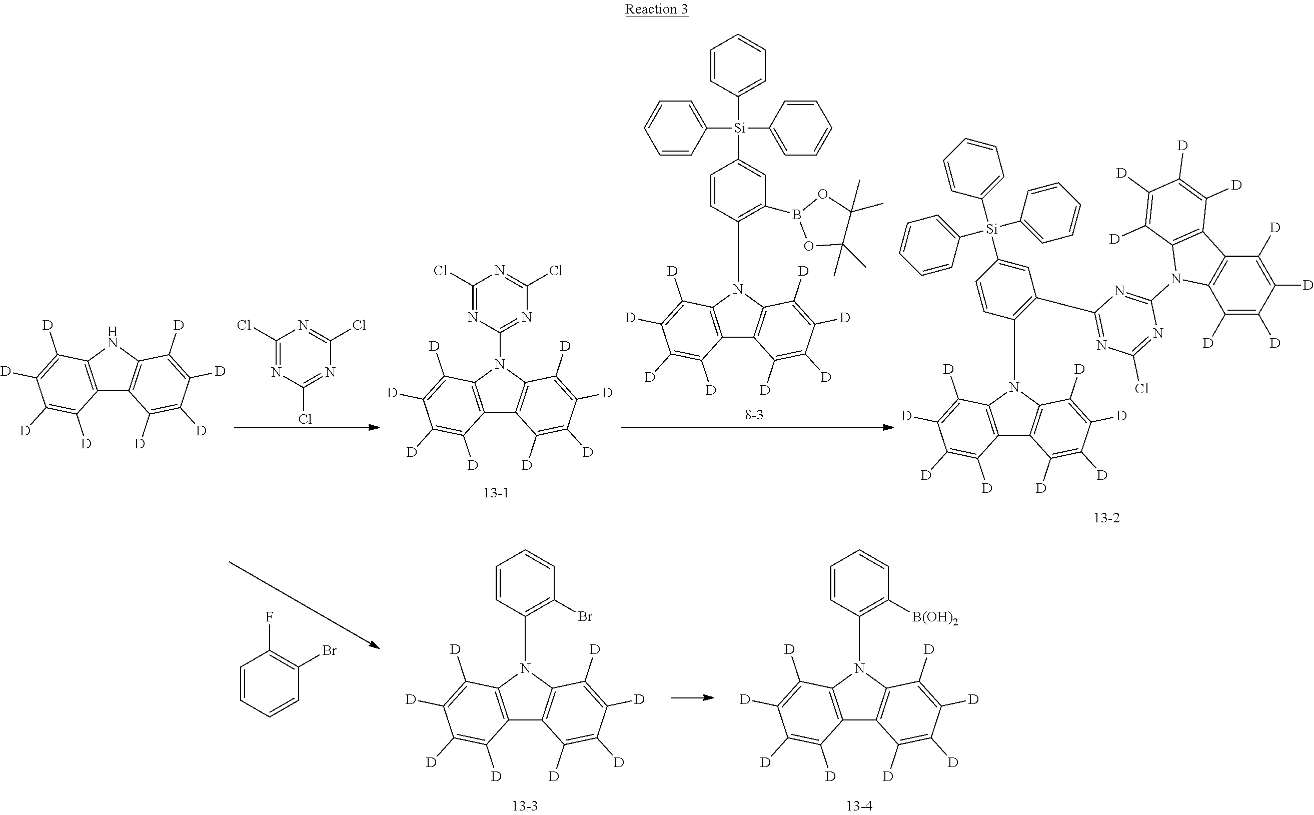

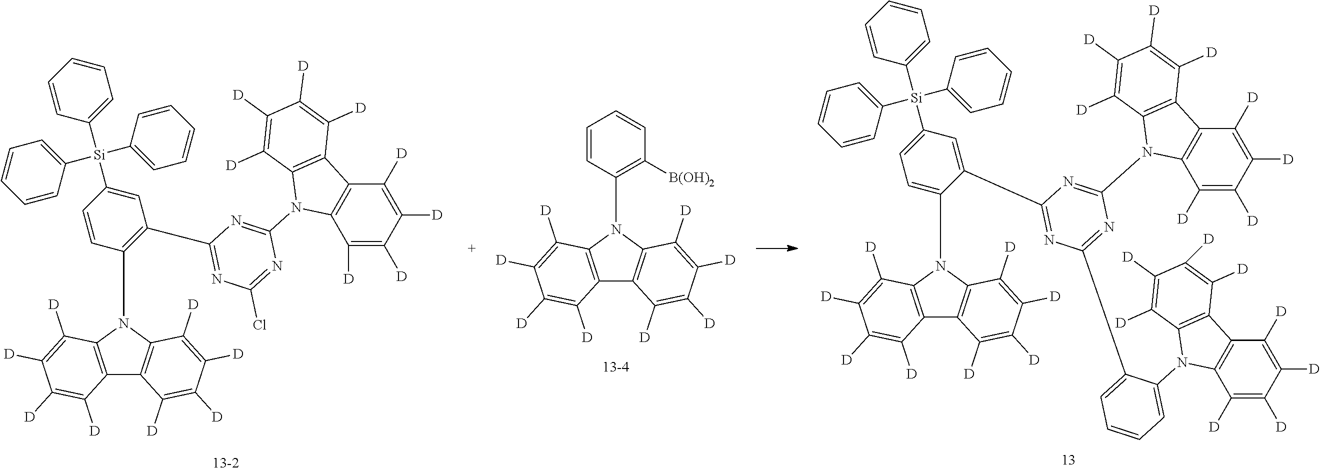

### Synthesis of Intermediate 13-1

After dissolving 10 g of 9H-carbazole-1,2,3,4,5,6,7,8-d8 (CAS: 38537-24-5) in 200 mL of a THF solvent, the resultant was stirred at about 0° C. for about 30 minutes. 22.82 mL of 2.5 M n-BuLi was slowly and dropwisely added thereto at about 0° C., followed by stirring for about 30 minutes. Then, a solution of 6.55 g of 2,4,6-trichloro-1,3,5-triazine dissolved in 50 mL of THF was rapidly added to the resultant reaction solution dropwisely, followed by stirring at about 80° C. for about 12 hours. After finishing the reaction, the resultant reaction solution was extracted, and an organic layer obtained was dried. The residue was purified by sublimation purification to obtain 11.8 g (yield 64%) of Intermediate 13-1. Intermediate 13-1 was identified by LC-MS (C₁₅D₈Cl₂N₄: M+1 323.21).

### Synthesis of Intermediate 13-2

11.8 g of Intermediate 13-1, 23.2 g of Intermediate 8-3, 27.38 mL of a 2 M K₂CO₃ aqueous solution, and 0.26 g of Pd(PPh₃)₄ were dissolved in 200 mL of a THF solvent, and stirred at about 80° C. for about 12 hours. After finishing the reaction, the resultant reaction solution was extracted, and an organic layer obtained was dried. The residue was separated and purified by column chromatography to obtain 24.13 g (yield 83%) of Intermediate 13-2. Intermediate 13-2 was identified by LC-MS (C₅₁H₁₈D₁₆ClN₅Si: M+1 796.50).

### Synthesis of Intermediate 13-3

10 g of 9H-Carbazole-1,2,3,4,5,6,7,8-d8 (CAS: 38537-24-5), 9.98 g of 1-bromo-2-fluorobenzene, and 24.22 g of K₃PO₄ were dissolved in 280 mL of DMF, and stirred at about 160° C. for about 12 hours. After finishing the reaction, the resultant reaction solution was extracted, and an organic layer obtained was dried. The residue was separated and purified by column chromatography to obtain 18.84 g (yield 93%) of Intermediate 13-3. Intermediate 13-3 was identified by LC-MS (C18H4D8BrN: M+1 331.25).

### Synthesis of Intermediate 13-4

After dissolving 18.84 g of Intermediate 13-3 in 300 mL of THF, 27.38 mL of 2.5 M n-BuLi was slowly and dropwisely added at about −78° C. After stirring at about −78° C. for about 1 hour, 9.54 mL of trimethyl borate was rapidly added thereto, followed by stirring at room temperature for about 12 hours. After finishing the reaction, the resultant reaction solution was extracted, and an organic layer obtained was dried. The residue was separated and purified by column chromatography to obtain 13.8 g (yield 82%) of Intermediate 13-4. Intermediate 13-4 was identified by LC-MS (C₁₈H₆D₈BNO₂: M+1 295.17).

### Synthesis of Compound 13

5.39 g of Intermediate 13-2, 2 g of Intermediate 13-4, 5.08 mL of a 2 M K₂CO₃ aqueous solution, and 0.05 g of Pd(PPh₃)₄ were dissolved in 40 mL of toluene and 5.08 mL of ethanol solvents, and stirred at about 110° C. for about 12 hours. After finishing the reaction, the resultant reaction solution was extracted, and an organic layer obtained was dried. The residue was separated and purified by column chromatography, recrystallization and sublimation purification to obtain 5.68 g (yield 83%) of Compound 13 with high purity. Compound 13 was identified by LC-MS and ¹H-NMR.

### (4) Synthesis of Nitrogen-Containing Compound 16

Nitrogen-containing Compound 16 according to an embodiment may be synthesized by, for example, the steps of Reaction 4 below.

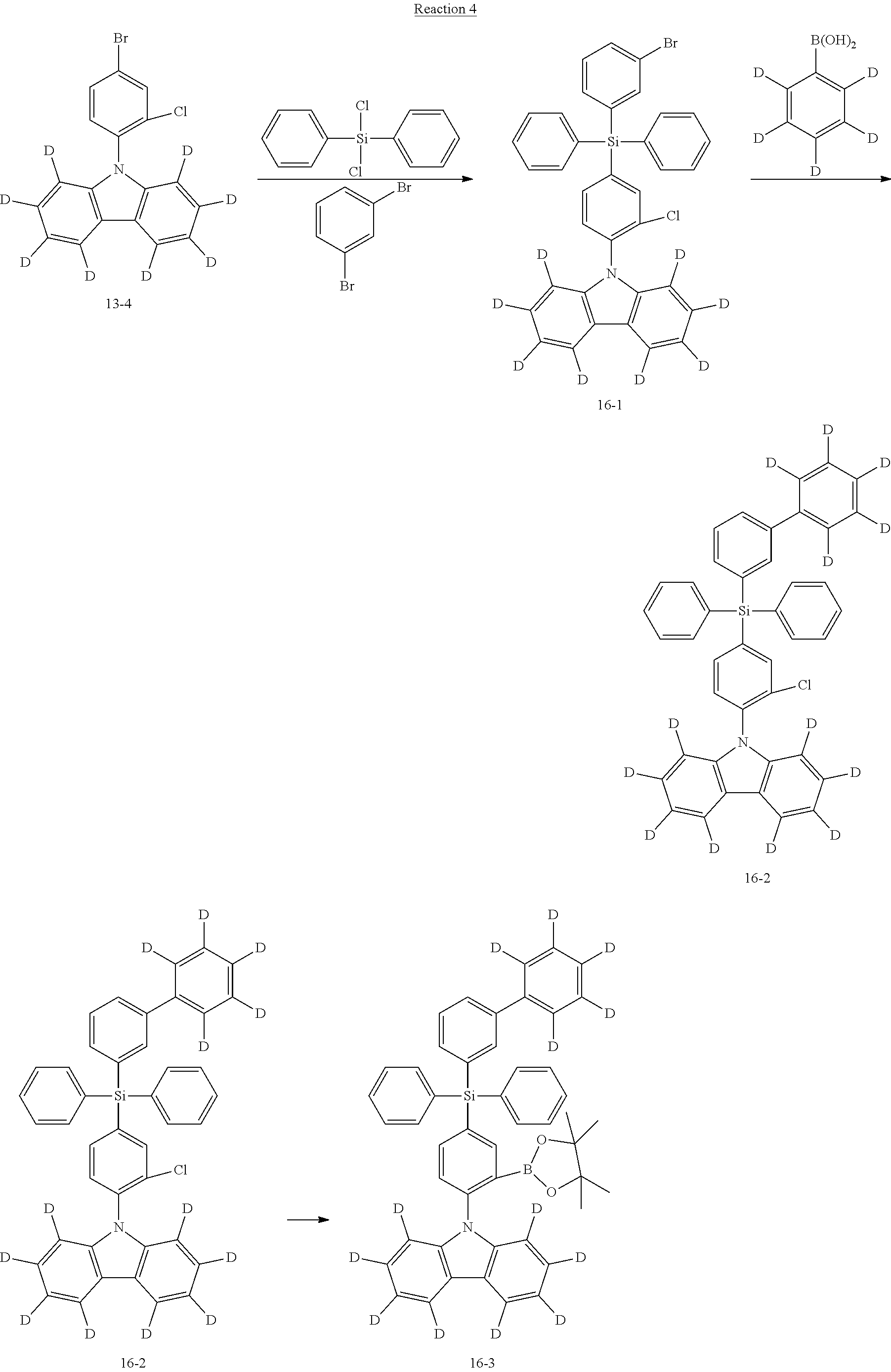

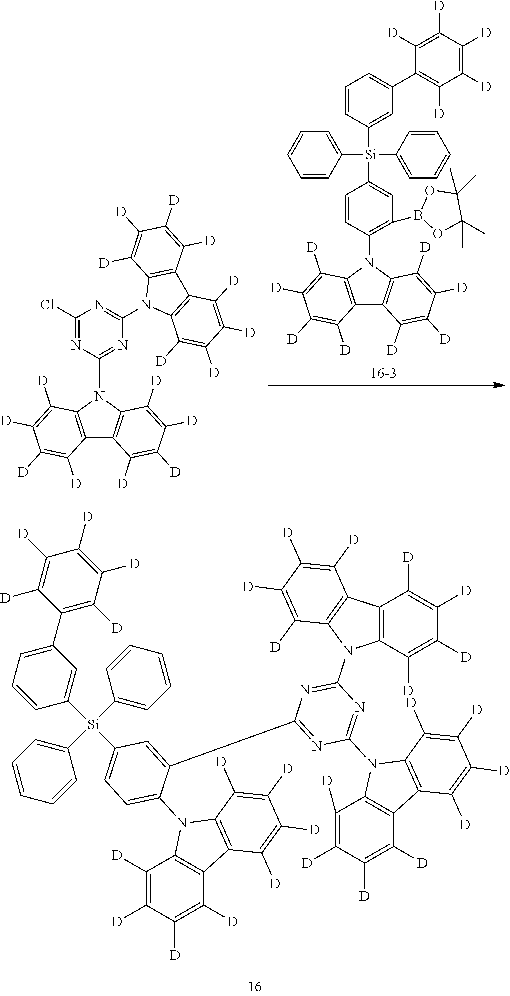

### Synthesis of Intermediate 16-1

The synthesis of Intermediate 16-1 was performed by in-situ reaction.

### Reaction 16-1A

After dissolving 10 g of 1,3-dibromobenzene in 80 mL of diethyl ether, 16.95 mL of 2.5 M n-BuLi was slowly and dropwisely added at about −78° C. Stirring was performed at about −78° C. for about 2 hours.

### Reaction 16-1B

After dissolving 4.87 mL of dichlorodiphenylsilane in 40 mL of THF, stirring was performed at about −78° C. The total amount of Reaction 16-1A was added to Reaction 16-1B using a cannula.

### Reaction 16-1C

10.06 g of Intermediate 13-4 was dissolved in 100 mL of THF, and 16.95 mL of 2.5 M n-BuLi was slowly and dropwisely added at about −78° C., followed by stirring at about −78° C. for about 1 hour. The total amount of Reaction 16-1C was added to Reaction 16-1B using a cannula. Then, the reaction was performed at room temperature for about 12 hours.

After finishing the reaction, the resultant reaction solution was extracted, and an organic layer obtained was dried. The residue was separated and purified by column chromatography to obtain 20.07 g (yield 76%) of Intermediate 16-1. Intermediate 16-1 was identified by LC-MS (C₃₆H₁₇D₈BrClNSi: M+1 623.09).

### Synthesis of Intermediate 16-2

After dissolving 20.07 g of Intermediate 16-1, 4.1 g of (phenyl-d5)boronic acid, 24.27 mL of a 2 M K₂CO₃ aqueous solution, and 0.23 g of Pd(PPh₃)₄ were dissolved in 160 mL of THF, followed by stirring at about 80° C. for about 12 hours. After finishing the reaction, the resultant reaction solution was extracted, and an organic layer obtained was dried. The residue was separated and purified by column chromatography to obtain 16.19 g (yield 80%) of Intermediate 16-2. Intermediate 16-2 was identified by LC-MS (C₄₂H₁₇D₁₃ClNSi: M+1 625.35).

### Synthesis of Intermediate 16-3

16.19 g of Intermediate 16-2, 6.57 g of bis(pinacolato)diboron, 7.62 g of KOAc, 1.44 g of 1,1′-bis(diphenylphosphino)ferrocene, and 0.29 g of Pd(OAc)₂ were dissolved in 130 mL of a 1,4-dioxane solvent, and stirred at about 120° C. for about 12 hours. After finishing the reaction, the resultant reaction solution was extracted, and an organic layer obtained was dried. The residue was separated and purified by column chromatography to obtain 13.9 g (yield 75%) of Intermediate 16-3. Intermediate 16-3 was identified by LC-MS (C₄₈H₂₉D₁₃BNO₂Si: M+1 716.84).

### Synthesis of Compound 16

2 g of 9,9′-(6-chloro-1,3,5-triazine-2,4-diyl)bis(9H-carbazole-1,2,3,4,5,6,7,8-d8) (CAS: 2778147-34-3), 1.29 g of Intermediate 16-3, 2.09 mL of a 2 M K₂CO₃ aqueous solution, and 0.1 g of Pd(PPh₃)₄ were dissolved in 10 mL of toluene and 2.09 mL of ethanol solvents, and stirred at about 110° C. for about 12 hours. After finishing the reaction, the resultant reaction solution was extracted, and an organic layer obtained was dried. The residue was separated and purified by column chromatography, recrystallization and sublimation purification to obtain 2.27 g (yield 80%) of Compound 16 with high purity. Compound 16 was identified by LC-MS and ¹H-NMR.

### (5) Synthesis of Nitrogen-Containing Compound 30

Nitrogen-containing Compound 30 according to an embodiment may be synthesized by, for example, the steps of Reaction 5 below.

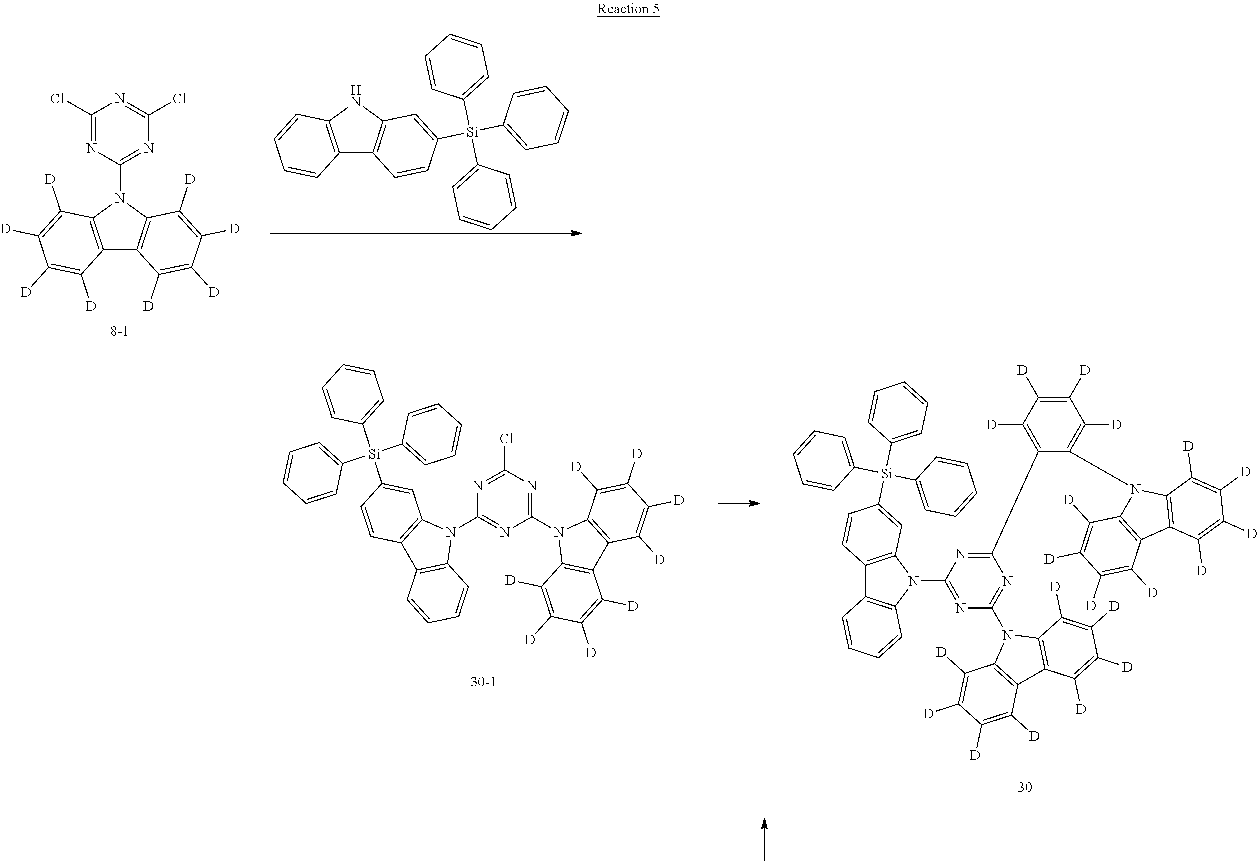

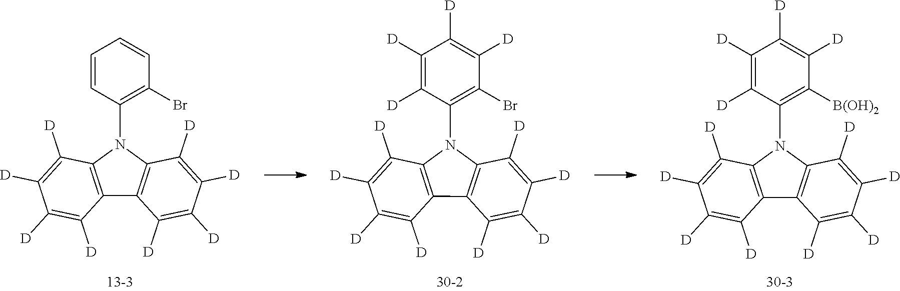 [SMILES: [2H]c1c([2H])c([2H])c2c(c1[2H])c1c([2H])c([2H])c([2H])c([2H])c1n2-c1ccccc1Br ; [2H]c1c([2H])c([2H])c(-n2c3c([2H])c([2H])c([2H])c([2H])c3c3c([2H])c([2H])c([2H])c([2H])c32)c(Br)c1[2H] ; [2H]c1c([2H])c([2H])c(-n2c3c([2H])c([2H])c([2H])c([2H])c3c3c([2H])c([2H])c([2H])c([2H])c32)c(B(O)O)c1[2H]]

### Synthesis of Intermediate 30-1

After dissolving 10 g of 2-(triphenylsilyl)-9H-carbazole (CAS: 1262866-95-4) in 110 mL of THF, 9.39 mL of 2.5 M n-BuLi was slowly and dropwisely added at about 0° C., followed by stirring at about 0° C. for about 30 minutes. Then, 7.59 g of Intermediate 8-1 was dissolved in 110 mL of THF, and the resultant was rapidly added dropwisely thereto, followed by stirring at about 80° C. for about 12 hours. After finishing the reaction, the resultant reaction solution was extracted, and an organic layer obtained was dried. The residue was separated and purified by sublimation purification to obtain 10.54 g (yield 63%) of Intermediate 30-1. Intermediate 30-1 was identified by LC-MS (C₄₅H₂₂D₈ClN₅Si: M+1 712.35).

### Synthesis of Intermediate 30-2

g of Intermediate 13-3, 1.67 g of silver carbonate and 3.21 g of cyclohexyldiphenylphosphine were dissolved in 0.3 mL of toluene and 6.06 mL of D₂O solvents, followed by stirring at about 120° C. for about 12 hours. After finishing the reaction, the resultant reaction solution was extracted, and an organic layer obtained was dried. The residue was separated and purified by column chromatography to obtain 10.02 g (yield 99%, average D substitution ratio of 90%) of Intermediate 30-2. Intermediate 30-2 was identified by LC-MS (C₁₈D₁₂BrN: M+1 334.28).

### Synthesis of Intermediate 30-3

After dissolving 10.02 g of Intermediate 30-2 in 150 mL of THF, 14.39 mL of 2.5 M n-BuLi was slowly and dropwisely added at about −78° C. After stirring at −78° C. for about 1 hour, 5.01 mL of trimethyl borate was rapidly added thereto, followed by stirring at room temperature for about 12 hours. After finishing the reaction, the resultant reaction solution was extracted, and an organic layer obtained was dried. The residue was separated and purified by column chromatography to obtain 8.43 g (yield 94%) of Intermediate 30-3. Intermediate 30-3 was identified by LC-MS (C₁₈H₂D₁₂BNO₂: M+1 299.20).

### Synthesis of Compound 30

2 g of Intermediate 30-1, 0.84 g of Intermediate 30-3, and 2.1 mL of a 2 M K₂CO₃ aqueous solution were dissolved in 10 mL of toluene and 2.1 mL of ethanol solvents, and stirred at about 110° C. for about 12 hours. After finishing the reaction, the resultant reaction solution was extracted, and an organic layer obtained was dried. The residue was separated and purified by column chromatography, recrystallization and sublimation purification to obtain 2.24 g (yield 86%) of Compound 30 with high purity. Compound 30 was identified by LC-MS and ¹H-NMR.

### (6) Synthesis of Nitrogen-Containing Compound 35

Nitrogen-containing Compound 35 according to an embodiment may be synthesized by, for example, the steps of Reaction 6 below.

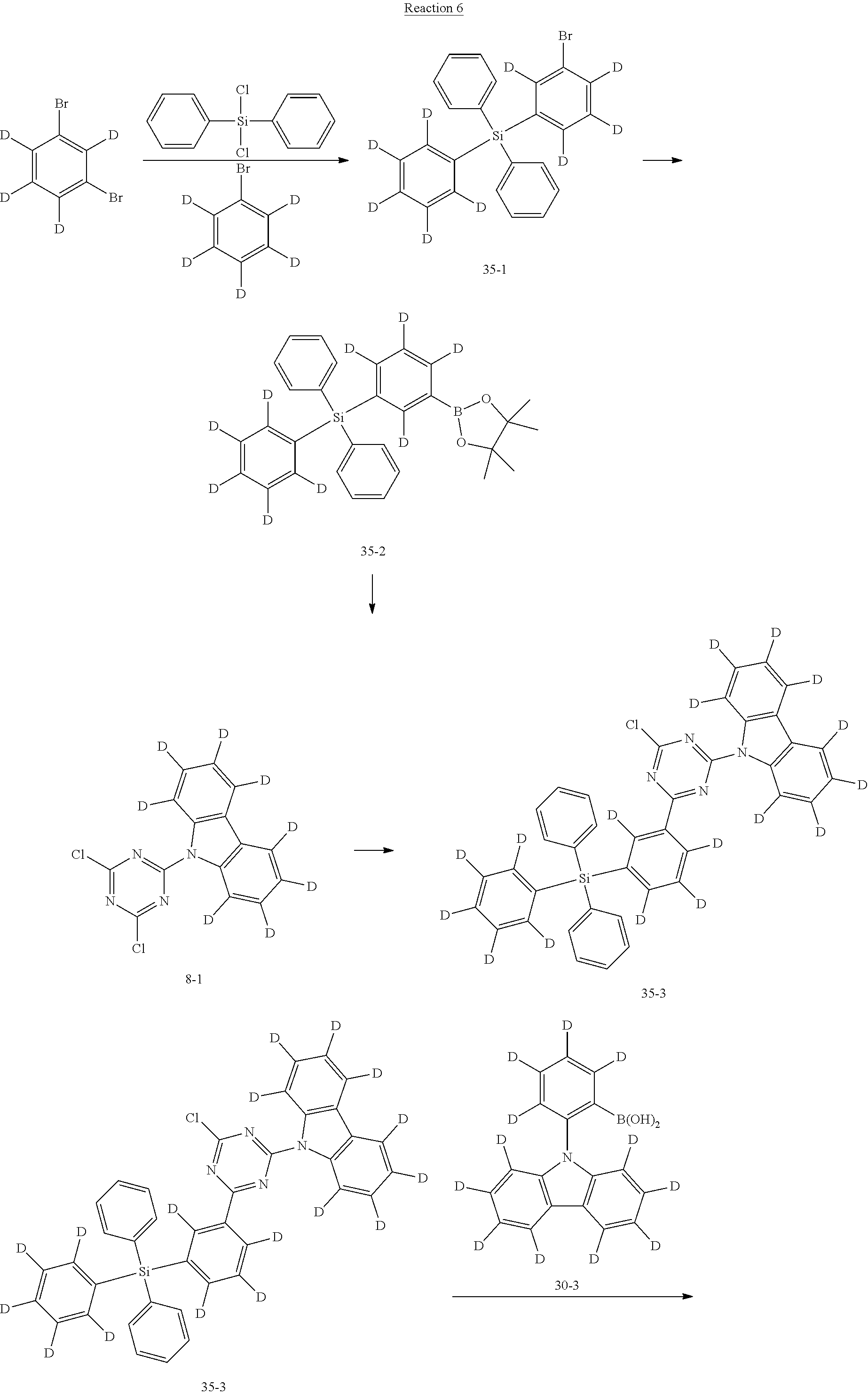

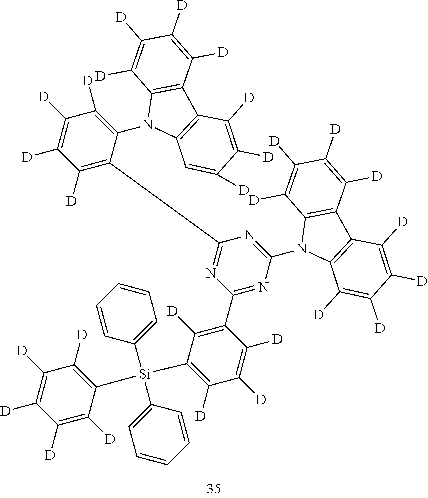 [SMILES: [2H]c1cc2c(c([2H])c1[2H])c1c([2H])c([2H])c([2H])c([2H])c1n2-c1c([2H])c([2H])c([2H])c([2H])c1-c1nc(-c2c([2H])c([2H])c([2H])c([Si](c3ccccc3)(c3ccccc3)c3c([2H])c([2H])c([2H])c([2H])c3[2H])c2[2H])nc(-n2c3c([2H])c([2H])c([2H])c([2H])c3c3c([2H])c([2H])c([2H])c([2H])c32)n1]

### Synthesis of Intermediate 35-1

The synthesis of Intermediate 35-1 was performed by in-situ reaction.

### Reaction 35-1A

After dissolving 10 g of 1,3-dibromobenzene-2,4,5,6-d4 in 80 mL of diethyl ether, 16.67 mL of 2.5 M n-BuLi was slowly and dropwisely added at about −78° C. Stirring was performed at about −78° C. for about 2 hours.

### Reaction 35-1B

After dissolving 4.78 mL of dichlorodiphenylsilane in 40 mL of a diethyl ether solvent, stirring was performed at about −78° C. The total amount of Reaction 35-1A was added to Reaction 35-1B using a cannula.

### Reaction 35-1C

4.47 g of 1-bromobenzene-2,3,4,5,6-d5 was dissolved in 80 mL of THF, and 16.67 mL of 2.5 M n-BuLi was slowly and dropwisely added at about −78° C., followed by stirring at about −78° C. for about 1 hour. The total amount of Reaction 35-1C was added to Reaction 35-1B using a cannula. Then, the reaction was performed at room temperature for about 12 hours.

After finishing the reaction, the resultant reaction solution was extracted, and an organic layer obtained was dried. The residue was separated and purified by column chromatography to obtain 13.8 g (yield 78%) of Intermediate 35-1. Intermediate 35-1 was identified by LC-MS (C₂₄H₁₀D₉BrSi: M+1 424.46).

### Synthesis of Intermediate 35-2

After dissolving 13.8 g of Intermediate 35-1, 8.26 g of bis(pinacolato)diboron, 9.57 g of KOAc, 1.8 g of 1,1′-bis(diphenylphosphino)ferrocene, and 0.36 g of Pd(OAc)₂ in 150 mL of a 1,4-dioxane solvent, the resultant was stirred at about 120° C. for about 12 hours. After finishing the reaction, the resultant reaction solution was extracted, and an organic layer obtained was dried. The residue was separated and purified by sublimation purification to obtain 11.49 g (yield 75%) of Intermediate 35-2. Intermediate 35-2 was identified by LC-MS (C₃₀H₂₂D₉BO₂Si: M+1 471.53).

### Synthesis of Intermediate 35-3

g of Intermediate 8-1, 7.29 g of Intermediate 35-2, 11.6 mL of a 2 M K₂CO₃ aqueous solution, and 0.1 g of Pd(PPh₃)₄ were dissolved in 50 mL of toluene and 11.6 mL of ethanol, and stirred at about 110° C. for about 12 hours. After finishing the reaction, the resultant reaction solution was extracted, and an organic layer obtained was dried. The residue was separated and purified by column chromatography to obtain 8.41 g (yield 86%) of Intermediate 35-3. Intermediate 35-3 was identified by LC-MS (C₃₉H₁₀D₁₇ClN₄Si: M+1 632.31).

### Synthesis of Compound 35

2 g of Intermediate 35-3, 0.95 g of Intermediate 30-3, 2.37 mL of a 2 M K₂CO₃ aqueous solution, and 0.11 g of Pd(PPh₃)₄ were dissolved in 15 mL of toluene and 2.37 mL of ethanol, and stirred at about 110° C. for about 12 hours. After finishing the reaction, the resultant reaction solution was extracted, and an organic layer obtained was dried. The residue was separated and purified by column chromatography, recrystallization and sublimation purification to obtain 2.18 g (yield 81%) of Compound 35 with high purity. Compound 35 was identified by LC-MS and ¹H-NMR.

Table 1 shows the results of ¹H-NMR (proton nuclear magnetic resonance spectroscopy) and LC-MS (liquid chromatography mass spectrometry) of the compounds synthesized, Compounds 8, 10, 13, 16, 30 and 35. Compound 10 does not include a hydrogen atom, and ¹H-NMR was not measured.

TABLE 1

HR LC-MS (m/z)
[M+]

| Compound | ¹H-NMR (CDCl₃, 500 MHz) | found | calc. |
|---|---|---|---|
| Compound 8 | 8.02(d, 2H), 7.38-7.46 (m, 16H) | 935.30 | 934.47 |
| Compound 10 | — | 953.41 | 952.59 |
| Compound 13 | 8.02(d, 2H), 7.91-7.92(d, 2H), 7.80(t, | 1011.40 | 1010.51 |
| | 1H), 7.70(m, 1H), 7.38-7.46(m, 16H) | | |
| Compound 16 | 8.02(d, 2H), 7.88(s, 1H), 7.61-7.70(m, | 1016.43 | 1015.54 |
| | 4H), 7.38-7.46(m, 10H) | | |
| Compound 30 | 8.55(d, 1H), 8.22(d, 1H), 7.94(d, 1H), | 931.28 | 930.45 |
| | 7.68(s, 1H), 7.35-7.46(m, 18H) | | |
| Compound 35 | 7.81(s, 1H), 7.36-7.46(m, 10H) | 850.23 | 849.47 |

### 2. Evaluation of Light Emitting Elements

### (1) Manufacture of Light Emitting Elements

Light emitting elements including the nitrogen-containing compounds of embodiments or the Comparative Compounds in an emission layer were manufactured by a method below. Light emitting elements of Example 1 to Example 6 were manufactured using the nitrogen-containing compounds of Compounds 8, 10, 13, 16, and 35 as the host materials of an emission layer. The light emitting elements of Comparative Examples 1 to 6 were manufactured using Comparative Compounds CX1 to CX6 as the host materials of an emission layer.

An ITO glass substrate of about 15 Ω/cm² (about 1200 Å) of Corning Co. was cut into a size of 50 mm×50 mm×0.5 mm, and washed by ultrasonic waves using isopropyl alcohol and pure water for about 5 minutes each. Then, the glass substrate was cleansed by irradiating ultraviolet rays for about 30 minutes and exposing to ozone, and was installed in a vacuum deposition apparatus.

On the substrate, HATCN was formed to a thickness of about 100 Å as a hole injection layer. Then, a first hole transport material of BCFN was vacuum deposited to a thickness of about 600 Å to form a first hole transport layer, and a second hole transport material of SiCzCz was vacuum deposited to a thickness of about 50 Å to form a second hole transport layer.

On the hole transport layer, two hosts and a dopant in a weight ratio of about 60:27:13 were deposited simultaneously to form an emission layer with a thickness of about 350 Å. Among the two hosts, SiCzCz was provided as a hole transport host material, and the Example Compound or Comparative Compound was provided as an electron transport host material. As the dopant material, a phosphorescence dopant of PtON-TBBI was provided.

Then, on the emission layer, mSiTrz and LiQ were deposited simultaneously in a weight ratio of about 1:1 to form an electron transport layer with a thickness of about 350 Å. On the electron transport layer, an alkali metal halide of LiF was deposited to a thickness of about 15 Å as an electron injection layer, and A1 was vacuum deposited to a thickness of about 80 Å to form a LiF/Al electrode, to finally manufacture a light emitting element.

### Materials Used for the Manufacture of Light Emitting Elements

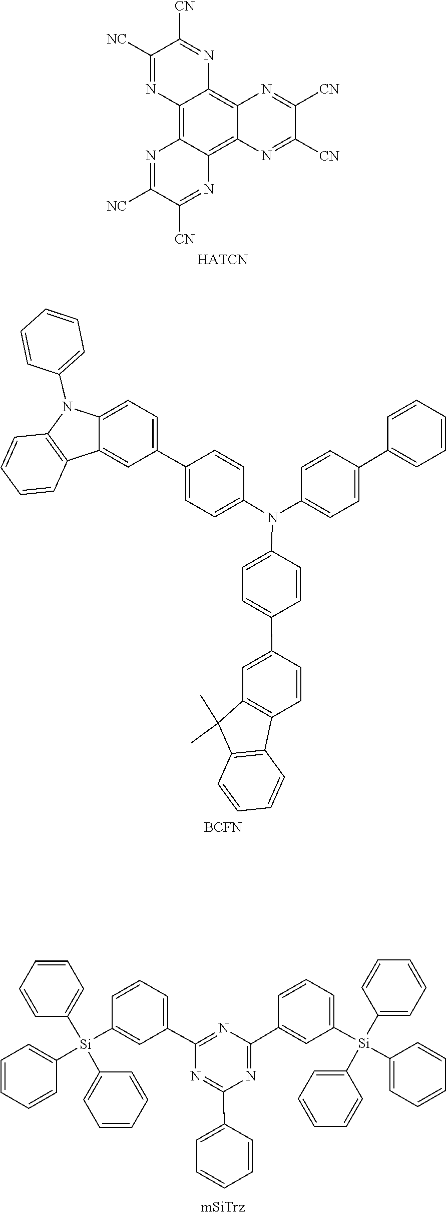

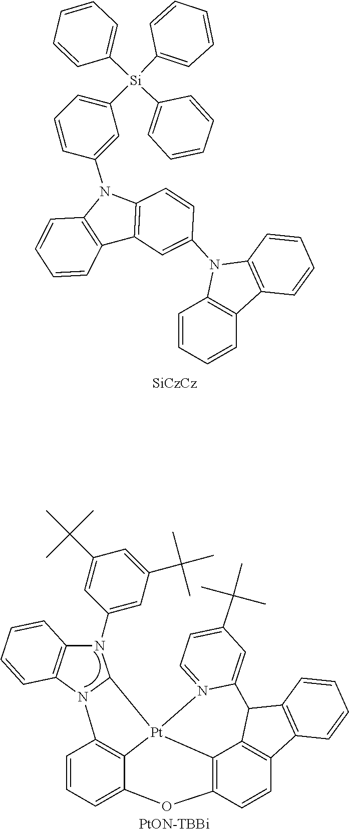

In the light emitting elements of the Examples and Comparative Examples, the compounds provided for forming the emission layer are shown in Table 2.

TABLE 2

| | |
|---|---|
| Comparative Compound CX1 | 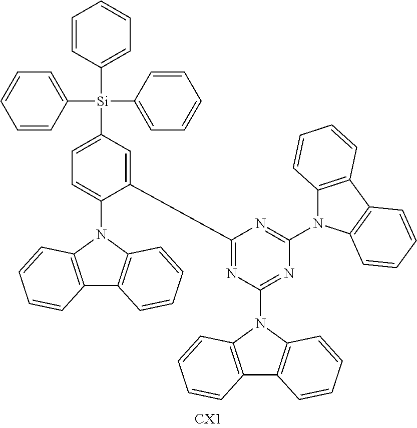 [SMILES: c1ccc([Si](c2ccccc2)(c2ccccc2)c2ccc(-n3c4ccccc4c4ccccc43)c(-c3nc(-n4c5ccccc5c5ccccc54)nc(-n4c5ccccc5c5ccccc54)n3)c2)cc1] |
| Comparative Compound CX2 | 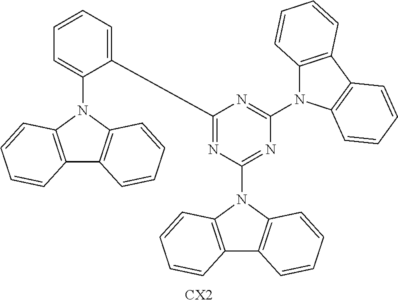 [SMILES: c1ccc(-n2c3ccccc3c3ccccc32)c(-c2nc(-n3c4ccccc4c4ccccc43)nc(-n3c4ccccc4c4ccccc43)n2)c1] |
| Comparative Compound CX3 | 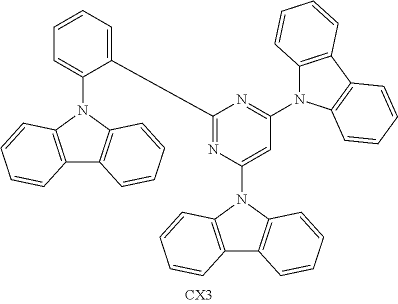 [SMILES: c1ccc(-n2c3ccccc3c3ccccc32)c(-c2nc(-n3c4ccccc4c4ccccc43)cc(-n3c4ccccc4c4ccccc43)n2)c1] |
| Comparative Compound CX4 | 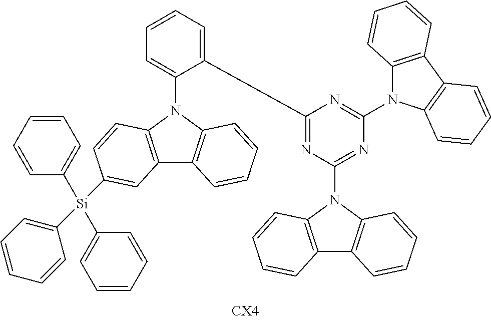 [SMILES: c1ccc([Si](c2ccccc2)(c2ccccc2)c2ccc3c(c2)c2ccccc2n3-c2ccccc2-c2nc(-n3c4ccccc4c4ccccc43)nc(-n3c4ccccc4c4ccccc43)n2)cc1] |
| Comparative Compound CX5 | 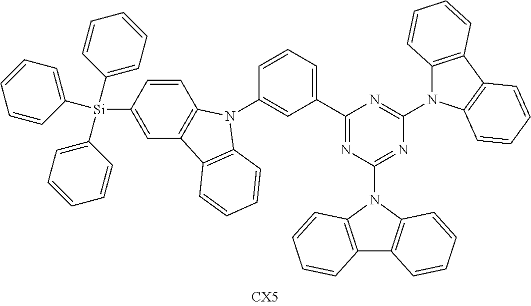 [SMILES: c1ccc([Si](c2ccccc2)(c2ccccc2)c2ccc3c(c2)c2ccccc2n3-c2cccc(-c3nc(-n4c5ccccc5c5ccccc54)nc(-n4c5ccccc5c5ccccc54)n3)c2)cc1] |
| Comparative Compound CX6 | 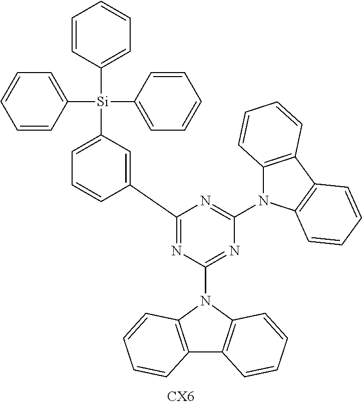 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1] |
| Compound 8 | 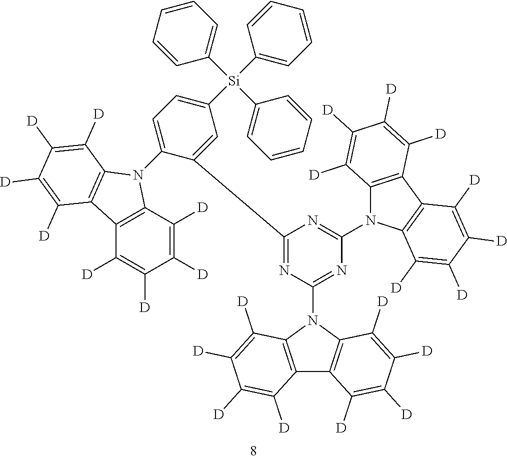 [SMILES: [2H]c1c([2H])c([2H])c2c(c1[2H])c1c([2H])c([2H])c([2H])c([2H])c1n2-c1nc(-c2cc([Si](c3ccccc3)(c3ccccc3)c3ccccc3)ccc2-n2c3c([2H])c([2H])c([2H])c([2H])c3c3c([2H])c([2H])c([2H])c([2H])c32)nc(-n2c3c([2H])c([2H])c([2H])c([2H])c3c3c([2H])c([2H])c([2H])c([2H])c32)n1] |
| Compound 10 | 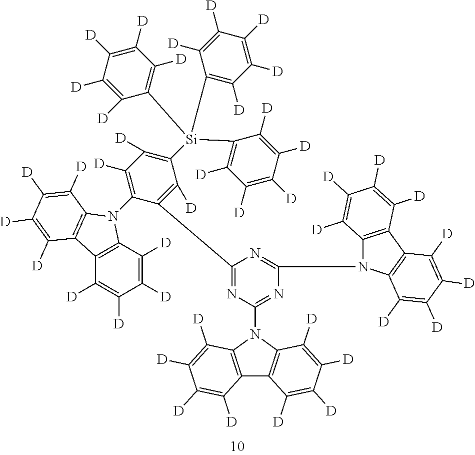 [SMILES: [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c(-n3c4c([2H])c([2H])c([2H])c([2H])c4c4c([2H])c([2H])c([2H])c([2H])c43)c(-c3nc(-n4c5c([2H])c([2H])c([2H])c([2H])c5c5c([2H])c([2H])c([2H])c([2H])c54)nc(-n4c5c([2H])c([2H])c([2H])c([2H])c5c5c([2H])c([2H])c([2H])c([2H])c54)n3)c2[2H])c([2H])c1[2H]] |
| Compound 13 | 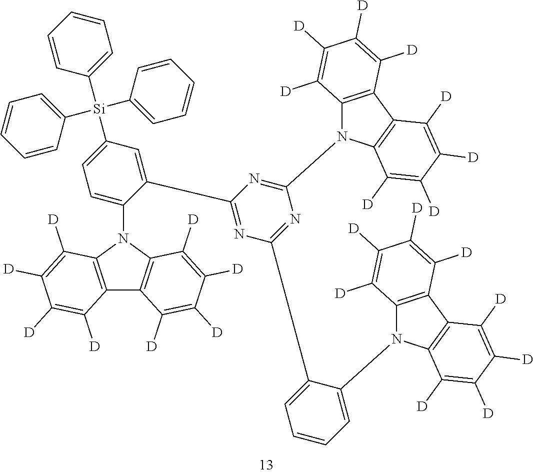 [SMILES: [2H]c1c([2H])c([2H])c2c(c1[2H])c1c([2H])c([2H])c([2H])c([2H])c1n2-c1nc(-c2ccccc2-n2c3c([2H])c([2H])c([2H])c([2H])c3c3c([2H])c([2H])c([2H])c([2H])c32)nc(-c2cc([Si](c3ccccc3)(c3ccccc3)c3ccccc3)ccc2-n2c3c([2H])c([2H])c([2H])c([2H])c3c3c([2H])c([2H])c([2H])c([2H])c32)n1] |
| Compound 16 | 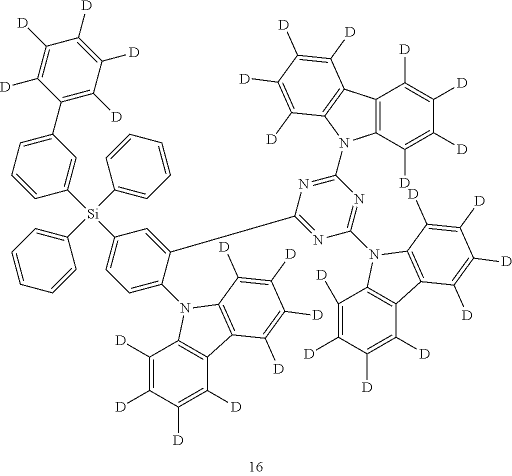 [SMILES: [2H]c1c([2H])c([2H])c(-c2cccc([Si](c3ccccc3)(c3ccccc3)c3ccc(-n4c5c([2H])c([2H])c([2H])c([2H])c5c5c([2H])c([2H])c([2H])c([2H])c54)c(-c4nc(-n5c6c([2H])c([2H])c([2H])c([2H])c6c6c([2H])c([2H])c([2H])c([2H])c65)nc(-n5c6c([2H])c([2H])c([2H])c([2H])c6c6c([2H])c([2H])c([2H])c([2H])c65)n4)c3)c2)c([2H])c1[2H]] |
| Compound 30 | 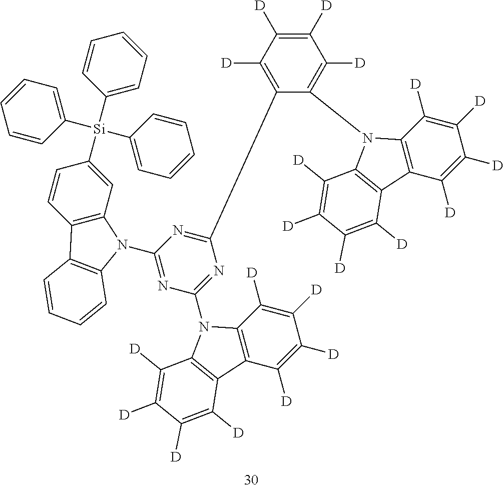 [SMILES: [2H]c1c([2H])c([2H])c(-n2c3c([2H])c([2H])c([2H])c([2H])c3c3c([2H])c([2H])c([2H])c([2H])c32)c(-c2nc(-n3c4ccccc4c4ccc([Si](c5ccccc5)(c5ccccc5)c5ccccc5)cc43)nc(-n3c4c([2H])c([2H])c([2H])c([2H])c4c4c([2H])c([2H])c([2H])c([2H])c43)n2)c1[2H]] |
| Compound 35 | 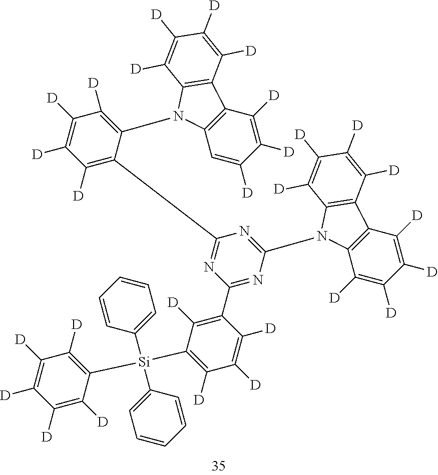 [SMILES: [2H]c1cc2c(c([2H])c1[2H])c1c([2H])c([2H])c([2H])c([2H])c1n2-c1c([2H])c([2H])c([2H])c([2H])c1-c1nc(-c2c([2H])c([2H])c([2H])c([Si](c3ccccc3)(c3ccccc3)c3c([2H])c([2H])c([2H])c([2H])c3[2H])c2[2H])nc(-n2c3c([2H])c([2H])c([2H])c([2H])c3c3c([2H])c([2H])c([2H])c([2H])c32)n1] |

### (2) Evaluation of Properties of Light Emitting Elements

In Table 3, the driving voltage, CIE color coordinates, maximum quantum efficiency, and lifetime of the light emitting elements of the Examples and Comparative Examples are evaluated and shown. The driving voltage and the maximum quantum efficiency were evaluated based on a current density of about 10 mA/cm². The driving voltage and the CIE color coordinates were measured using a source meter (Keithley Instrument Co., 2400 series), and the maximum quantum efficiency was measured using an external quantum efficiency measurement apparatus of C9920-2-12 of Hamamatsu Photonics Co. For the evaluation of the maximum quantum efficiency, luminance/current density was measured using a luminance meter of which wavelength sensitivity was calibrated, and converting to the maximum quantum efficiency supposing angular luminance distribution (Lambertian) assuming full diffusion reflective surface.

The lifetime was obtained by measuring time consumed for reducing initial luminance to 95% based on a luminance of about 1000 cd/m², and was calculated as relative values with the time measured for the light emitting element of Comparative Example 1 as 100%. The lifetime was measured using M6000 Plus of Mcscience Co.

TABLE 3

| | | | | Maximum | |
|---|---|---|---|---|---|
| Element | | Driving | CIE color | quantum | |
| manufacturing | Emission layer | voltage | coordinates_y | efficiency | Lifetime |
| example | (host) | (V) | (x, y) | (%) | (%) |
| Comparative | Comparative | 4.9 | 0.191 | 16.7 | 115 |
| Example 1 | Compound CX1 | | | | |
| Comparative | Comparative | 4.8 | 0.223 | 16.6 | 100 |
| Example 2 | Compound CX2 | | | | |
| Comparative | Comparative | 5.0 | 0.210 | 16.0 | 63 |
| Example 3 | Compound CX3 | | | | |
| Comparative | Comparative | 5.3 | 0.193 | 16.0 | 78 |
| Example 4 | Compound CX4 | | | | |
| Comparative | Comparative | 5.4 | 0.197 | 16.2 | 60 |
| Example 5 | Compound CX5 | | | | |
| Comparative | Comparative | 4.6 | 0.185 | 16.6 | 104 |
| Example 6 | Compound CX6 | | | | |
| Example 1 | Compound 8 | 4.7 | 0.177 | 17.2 | 140 |
| Example 2 | Compound 10 | 4.6 | 0.179 | 17.5 | 150 |
| Example 3 | Compound 13 | 4.7 | 0.175 | 17.6 | 125 |
| Example 4 | Compound 16 | 4.7 | 0.179 | 17.5 | 135 |
| Example 5 | Compound 30 | 4.9 | 0.181 | 17.4 | 119 |
| Example 6 | Compound 35 | 4.8 | 0.176 | 17.4 | 119 |

Referring to Table 3, it can be seen that the light emitting elements of Examples 1 to 6 showed excellent efficiency when compared to the light emitting elements of Comparative Examples 1 to 6. When compared to the light emitting elements of Comparative Examples 3 to 5, it can be seen that the light emitting elements of Examples 1 to 6 showed reduced driving voltages. In the light emitting elements of Examples 1 to 6, it can be seen that the y-values of the CIE color coordinates were about 0.175 to about 0.181. Differently, it can be seen that the y-values of the CIE color coordinates of Comparative Examples 1 to 6 were shifted values to about 0.185 to about 0.223. When compared to the light emitting elements of Comparative Examples 1 to 6, it can be seen that the light emitting elements of Examples 1 to 6 showed relatively longer lifetime. The light emitting elements of Examples 1 to 6 included Compounds 8, 10, 13, 16, 30 and 35, and Compounds 8, 10, 13, 16, 30 and 35 are nitrogen-containing compounds according to embodiments. Accordingly, the nitrogen-containing compound of an embodiment includes a silyl group and a deuterium atom, and may improve the color coordinates of light emitted by the light emitting element and may increase the lifetime of the light emitting element. The light emitting element including the nitrogen-containing compound of an embodiment may show improved color coordinates and long-life characteristics.

The light emitting element of Comparative Example 1 includes Comparative Compound CX1, and the light emitting elements of Comparative Examples 4 to 6 include Comparative Compounds CX4 to CX6. Comparative Compounds CX1 and CX4 to CX6 include a silyl group but do not include a deuterium atom. In addition, Comparative Compound CX6 is different from the nitrogen-containing compound of an embodiment in the bonding position of the silyl group. Comparative Compound CX6 is a compound in which a silyl group is bonded to a carbon atom at a meta position with respect to the carbon atom of a phenyl group bonded to a triazine central structure, and the nitrogen-containing compound of an embodiment is a compound in which a silyl group is bonded at the carbon atom of an ortho position with respect to the carbon atom of a phenyl group bonded to a central structure (for example, triazine or pyrimidine). Accordingly, the light emitting elements of Comparative Examples 1 and 4 to 6 showed relatively shorter lifetime than the light emitting elements of Examples 1 to 6.

The light emitting element of Comparative Example 2 includes Comparative Compound CX2, and the light emitting element of Comparative Example 3 includes Comparative Compound CX3. Comparative Compounds CX2 and CX3 do not include a silyl group and a deuterium atom. Accordingly, the light emitting elements of Comparative Examples 2 and 3 showed relatively largely shifted values of the color coordinates of light emitted, and relatively short lifetime.

The light emitting element of an embodiment may include a first electrode, a second electrode on the first electrode, and at least one functional layer between the first electrode and the second electrode. At least one functional layer may include the nitrogen-containing compound of an embodiment. The nitrogen-containing compound of an embodiment may include triazine or pyrimidine as a central structure. Triazine or pyrimidine may be substituted with at least one deuterium atom and at least one triphenylsilyl group. The at least one deuterium atom and at least one triphenylsilyl group may be directly or indirectly bonded to triazine or pyrimidine. Accordingly, the light emitting element including the nitrogen-containing compound of an embodiment may show improved color coordinates of light emitted and increased lifetime.

The light emitting element of an embodiment includes the nitrogen-containing compound of an embodiment and may show increased lifetime and improved color coordinates of light emitted.

The nitrogen-containing compound of an embodiment may contribute to the increase of the lifetime of a light emitting element and the improvement of the color coordinates of light emitted.

Although example embodiments of the present disclosure have been described, it is understood that the present disclosure should not be limited to these embodiments, but various changes and modifications can be made by one ordinary skilled in the art within the spirit and scope of the present disclosure as defined by the appended claims, and equivalents thereof.

What is claimed is:

1. A light emitting element, comprising:
a first electrode;
a second electrode on the first electrode; and
at least one functional layer between the first electrode and the second electrode, and comprising a first compound represented by the following Formula 1: 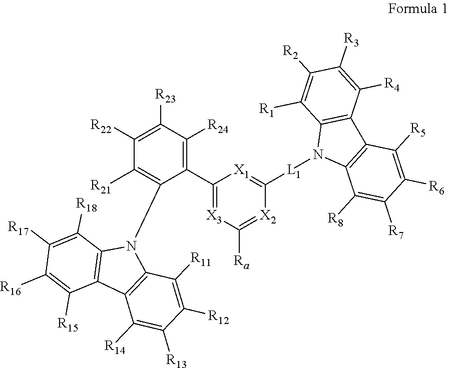
in Formula 1,
at least two selected from among X₁ to X₃ are N, and the remainder is CH,
L₁ is a direct linkage or a substituted or unsubstituted arylene group of 6 to 30 ring-forming carbon atoms,
Rₐ, R₁ to R₈, R₁₁ to R₁₈, and R₂₁ to R₂₄ are each independently a hydrogen atom, a deuterium atom, a substituted or unsubstituted silyl group, a substituted or unsubstituted alkyl group of 1 to 30 carbon atoms, a substituted or unsubstituted alkenyl group of 2 to 30 carbon atoms, a substituted or unsubstituted aryl group of 6 to ring-forming carbon atoms, or a substituted or unsubstituted heteroaryl group or 2 to ring-forming carbon atoms, and
at least one selected from among Rₐ, R₁ to R₈, R₁₁ to R₁₈, and R₂₁ to R₂₄ is represented by the following Formula 2, or comprises a first substituent substituted with the following Formula 2: 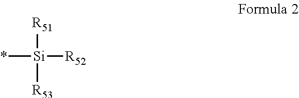
in Formula 2,
R₅₁ to R₅₃ are each independently a hydrogen atom, a deuterium atom, a substituted or unsubstituted silyl group, a substituted or unsubstituted alkyl group of 1 to 30 carbon atoms, a substituted or unsubstituted alkenyl group of 2 to 30 carbon atoms, a substituted or unsubstituted aryl group of 6 to 30 ring-forming carbon atoms, or a substituted or unsubstituted heteroaryl group or 2 to 30 ring-forming carbon atoms, and
at least one selected from among Rₐ, R₁ to R₈, R₁₁ to R₁₈, R₂₁ to R₂₄, and R₅₁ to R₅₃ is a deuterium atom, or comprises a second substituent substituted with a deuterium atom.

2. The light emitting element of claim 1, wherein Formula 1 is represented by the following Formula 1-A1 or Formula 1-A2: 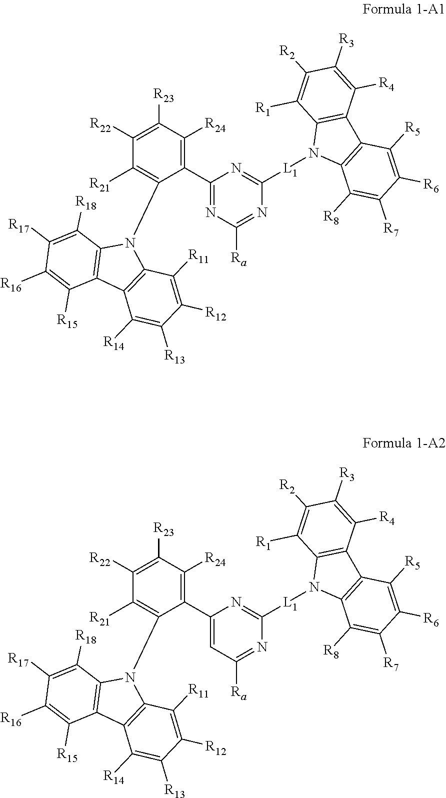
in Formula 1-A1 and Formula 1-A2,
L₁, Rₐ, R₁ to R₈, R₁₁ to R₁₈, and R₂₁ to R₂₄ are the same as defined with respect to Formula 1.

3. The light emitting element of claim 1, wherein Formula 2 is represented by the following Formula 2-1: 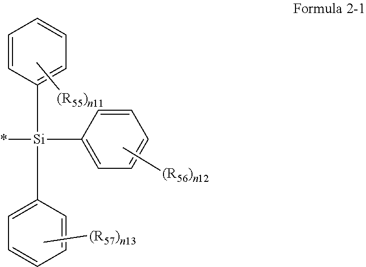
in Formula 2-1,
n11 to n13 are each independently an integer of 0 to 5, and
R₅₅ to R₅₇ are each independently a hydrogen atom, a deuterium atom, or a substituted or unsubstituted aryl group of 6 to 30 ring-forming carbon atoms.

4. The light emitting element of claim 1, wherein Formula 1 is represented by any one selected from among the following Formula 1-61 to Formula 1-64: 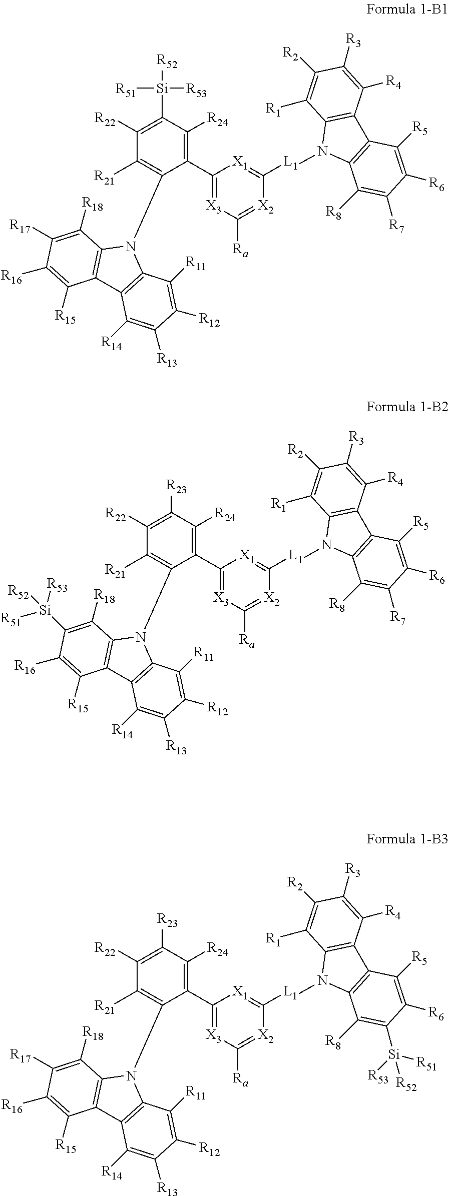 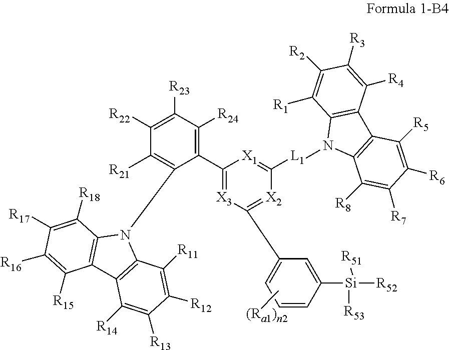
in Formula 1-B4,
n2 is an integer of 0 to 4, and
Rₐ₁ is a hydrogen atom, a deuterium atom, or a substituted or unsubstituted aryl group of 6 to 30 ring-forming carbon atoms, and
in Formula 1-61 to Formula 1-B4,
L₁, Rₐ, R₁ to R₈, R₁₁ to R₁₈, R₂₁ to R₂₄, and R₅₁ to R₅₃ are the same as defined with respect to Formula 1 and Formula 2.

5. The light emitting element of claim 1, wherein the second substituent comprises at least one selected from among a phenyl group substituted with a deuterium atom, a silyl group substituted with a deuterium atom, and a carbazole group substituted with a deuterium atom.

6. The light emitting element of claim 1, wherein the second substituent is represented by any one selected from among the following S-1 to S-10: 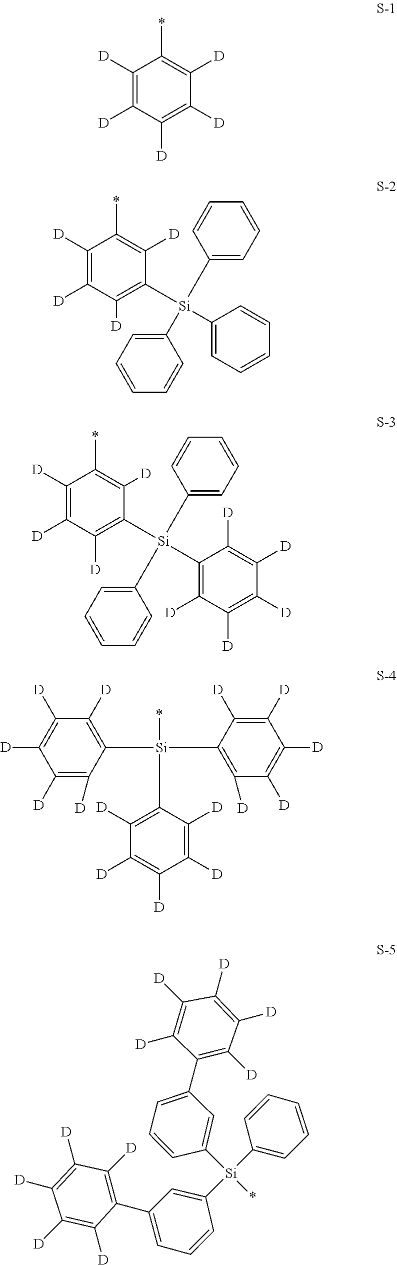 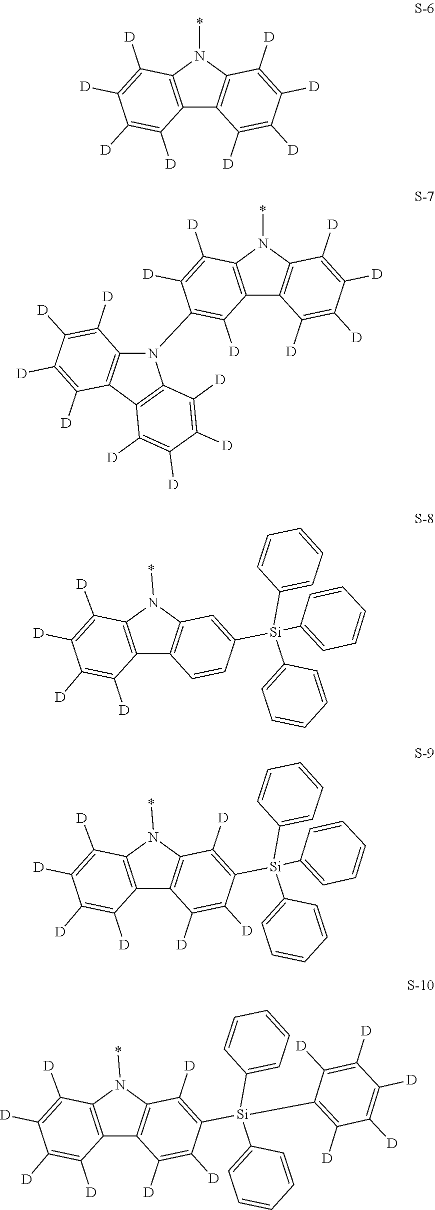
in S-1 to S-10, D is a deuterium atom.

7. The light emitting element of claim 1, wherein, in Formula 1, L₁ is a direct linkage or a substituted or unsubstituted phenylene group.

8. The light emitting element of claim 1, wherein the at least one functional layer comprises an emission layer on the first electrode and an electron transport region on the emission layer, and
at least one selected from among the emission layer and the electron transport region comprises the first compound.

9. The light emitting element of claim 8, wherein the electron transport region comprises an electron transport layer on the emission layer, an electron injection layer on the electron transport layer, and an emission auxiliary layer between the emission layer and the electron transport layer, and
the emission auxiliary layer comprises the first compound.

10. The light emitting element of claim 8, wherein the emission layer further comprises a second compound represented by the following Formula HT-1: 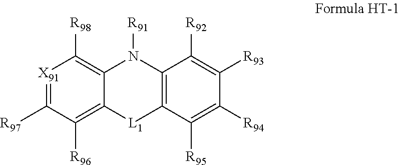
in Formula HT-1,
L₁ is a direct linkage, CR₉₉R₁₀₀, or SiR₁₀₁R₁₀₂,
X₉₁ is N or CR₁₀₃, and
R₉₁ to R₁₀₃ are each independently a hydrogen atom, a deuterium atom, a cyano group, a substituted or unsubstituted silyl group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group from each other to form a ring.

11. The light emitting element of claim 8, wherein the emission layer further comprises a third compound represented by the following Formula M-b: Formula M-b 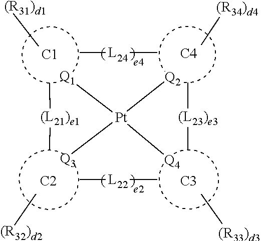
in Formula M-b,
Q₁ to Q₄ are each independently C or N,
C₁ to C₄ are each independently a substituted or unsubstituted hydrocarbon ring of 5 to 30 ring-forming carbon atoms, or a substituted or unsubstituted heterocycle of 2 to 30 ring-forming carbon atoms,
e1 to e4 are each independently 0 or 1,
L₂₁ to L₂₄ are each independently a direct linkage, 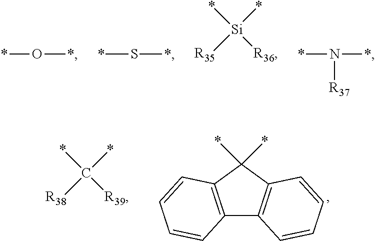
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
d1 to d4 are each independently an integer of 0 to 4, and
R₃₁ to R₃₉ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group from each other to form a ring.

12. The light emitting element of claim 8, wherein the emission layer comprises a host and a dopant, and
the host comprises the first compound.

13. The light emitting element of claim 8, wherein the emission layer emits phosphorescence or thermally activated delayed fluorescence.

14. The light emitting element of claim 1, wherein the first compound is represented by any one selected from among compounds in the following Compound Group 1: 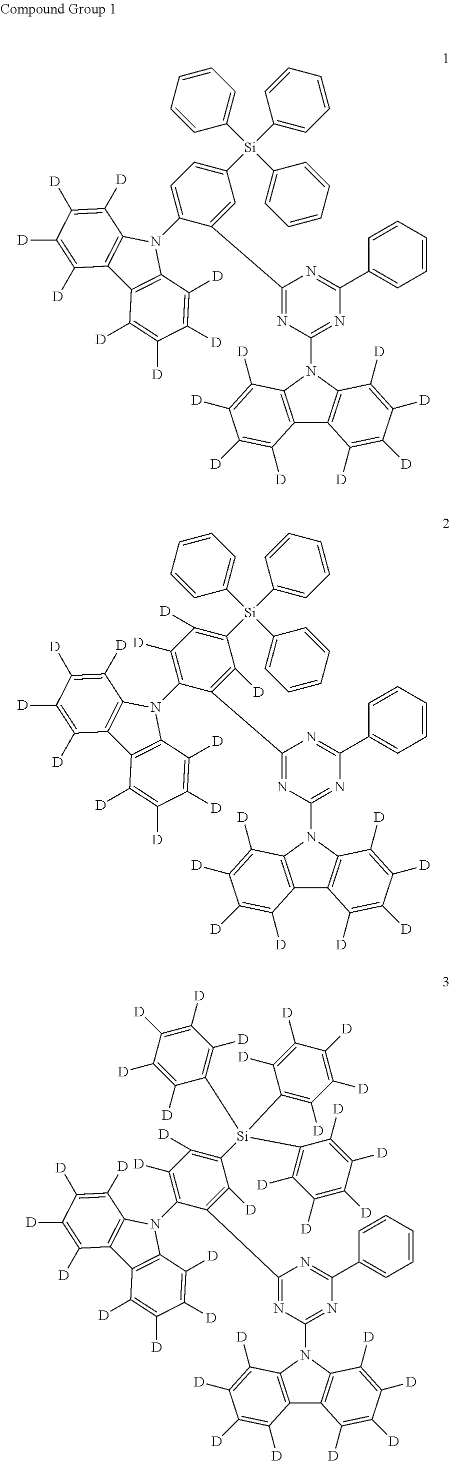 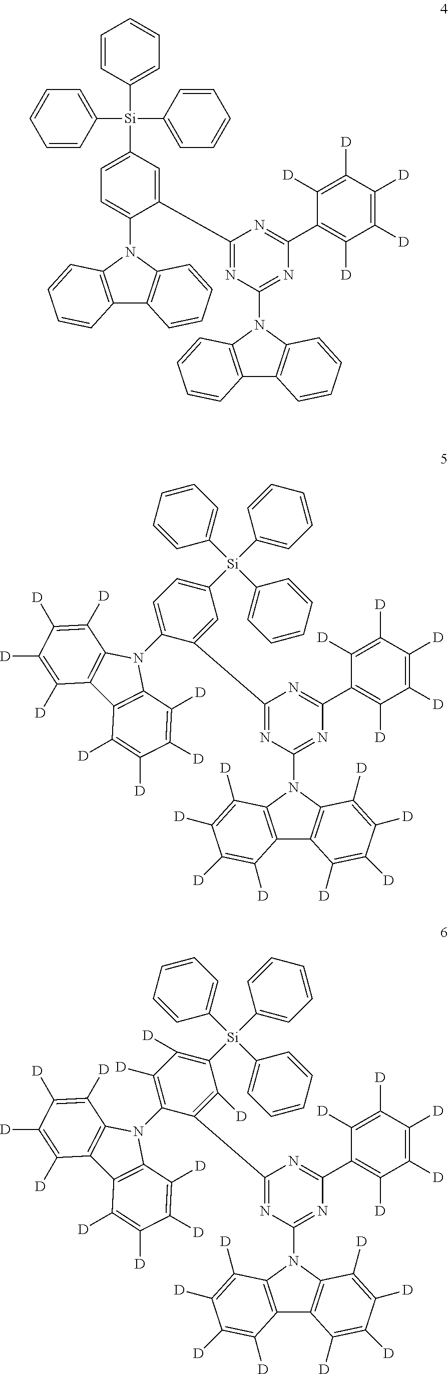 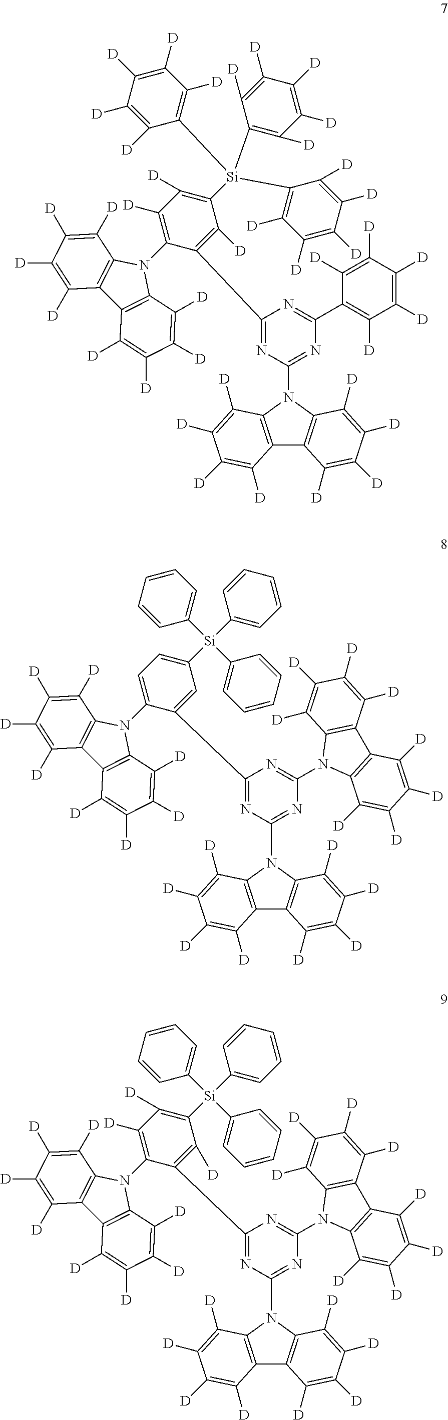 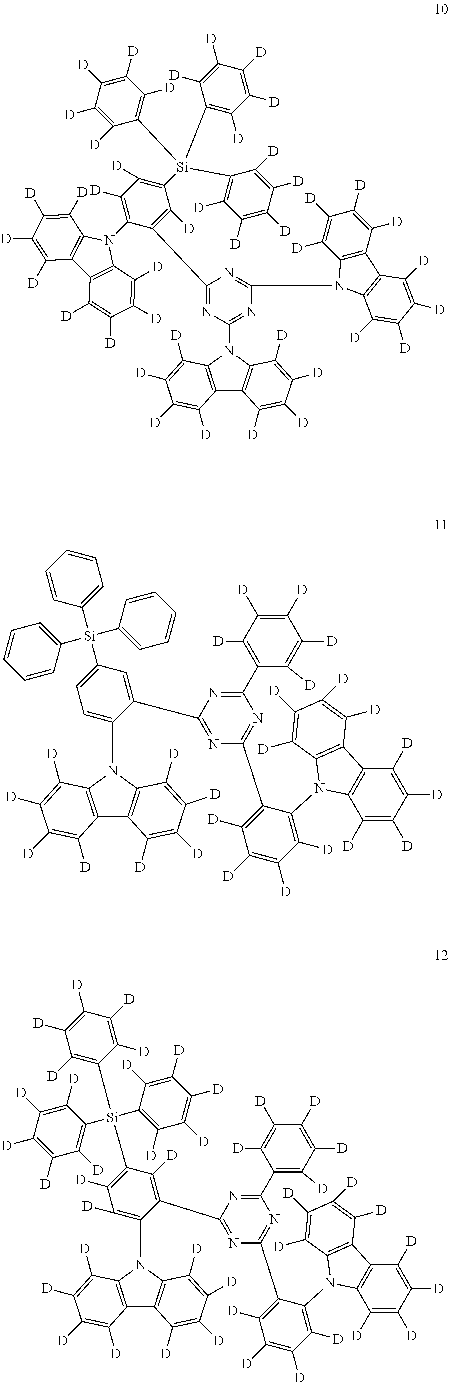 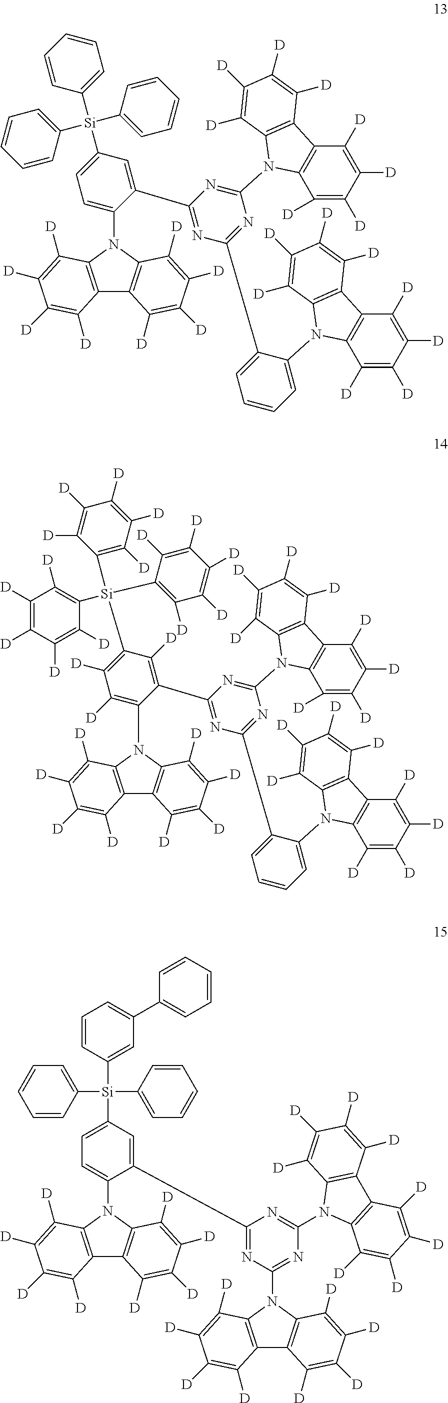 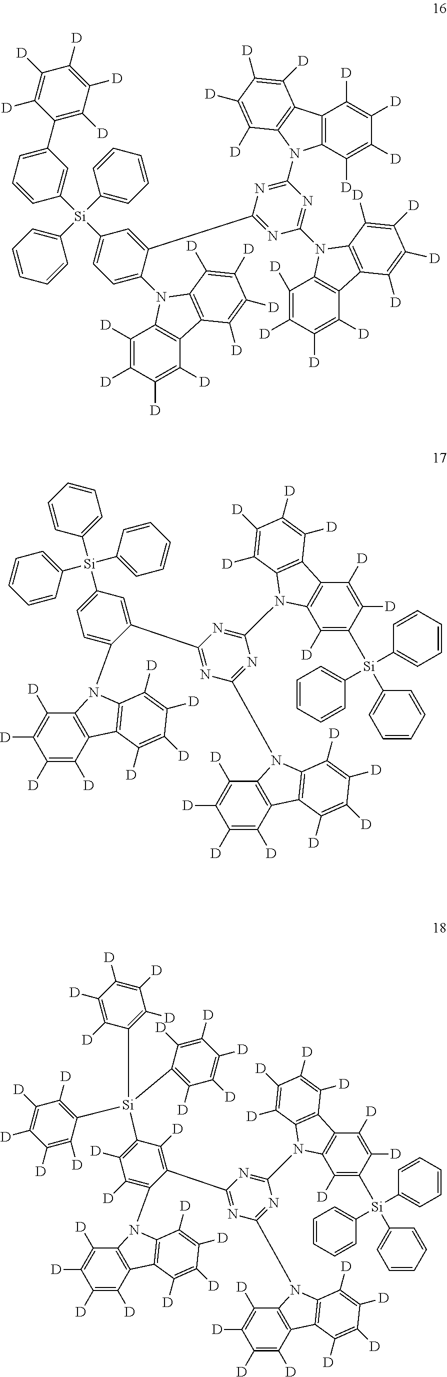 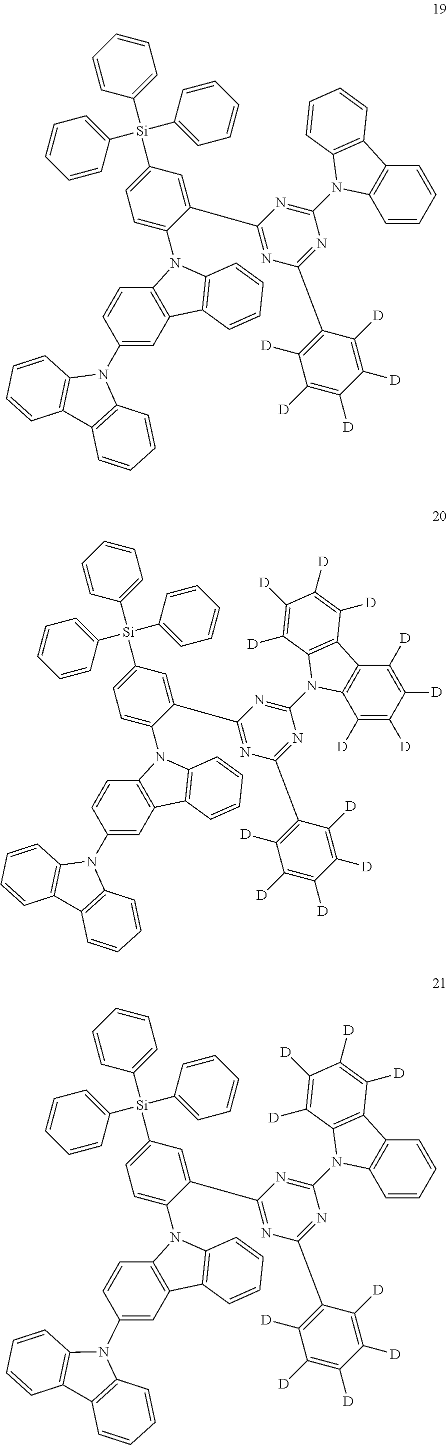 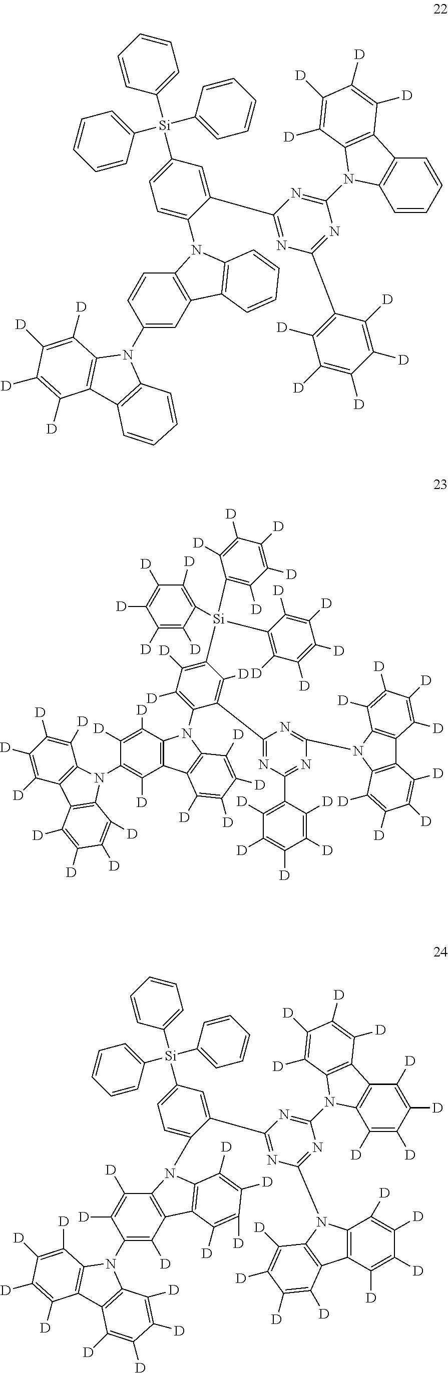 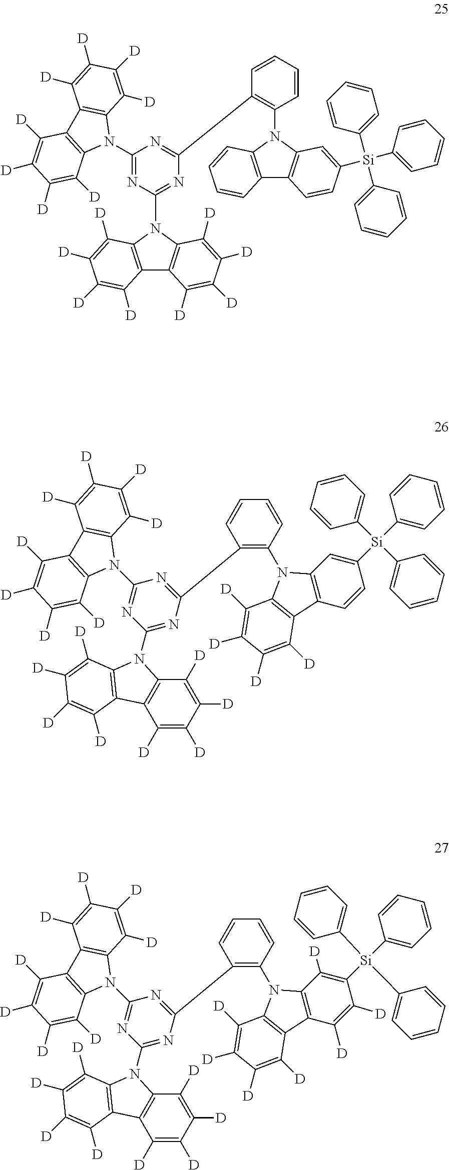 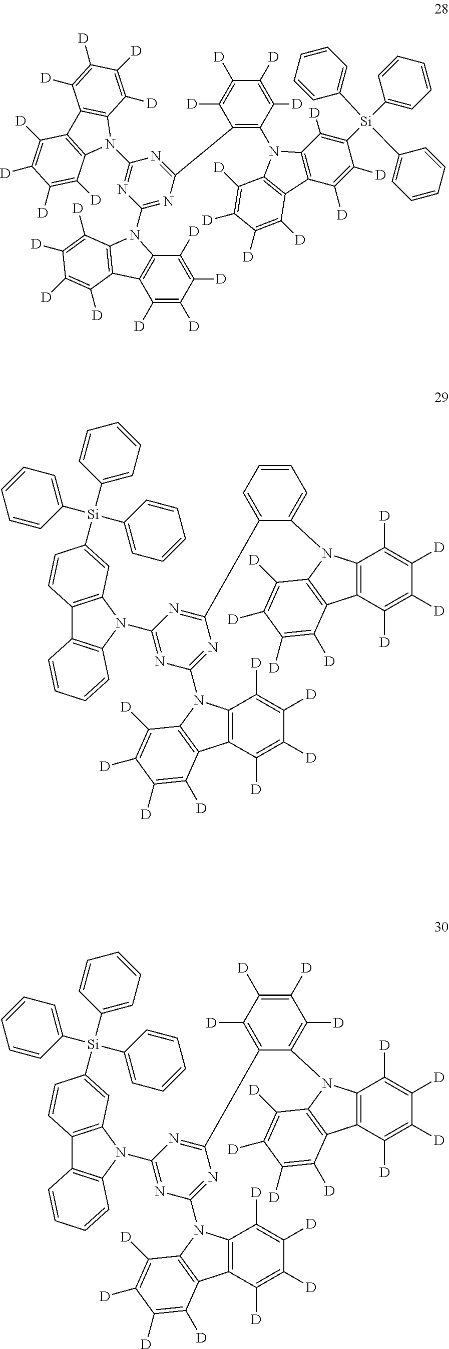 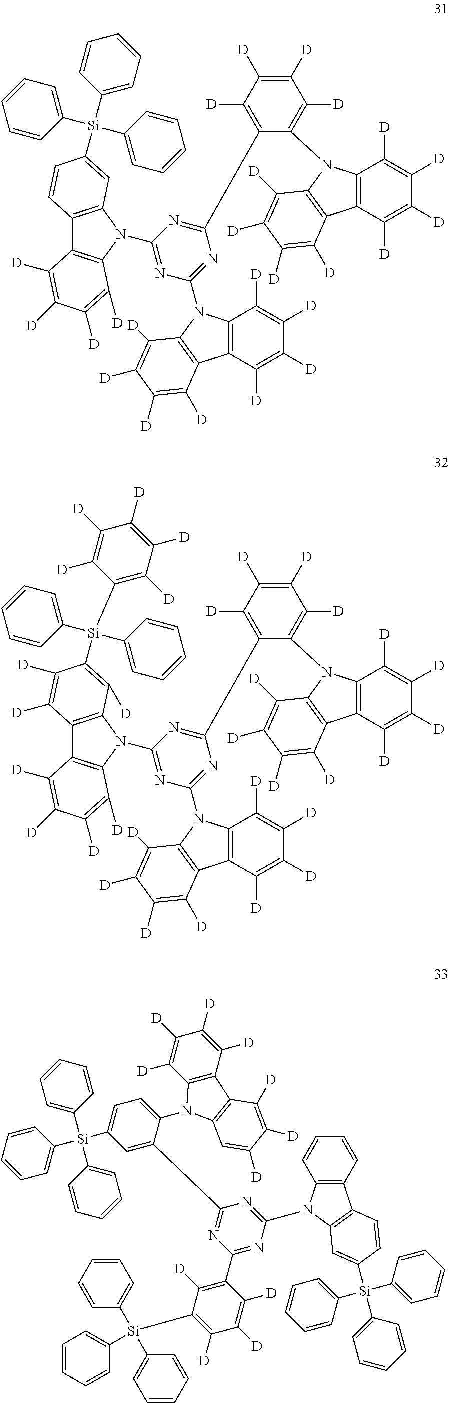 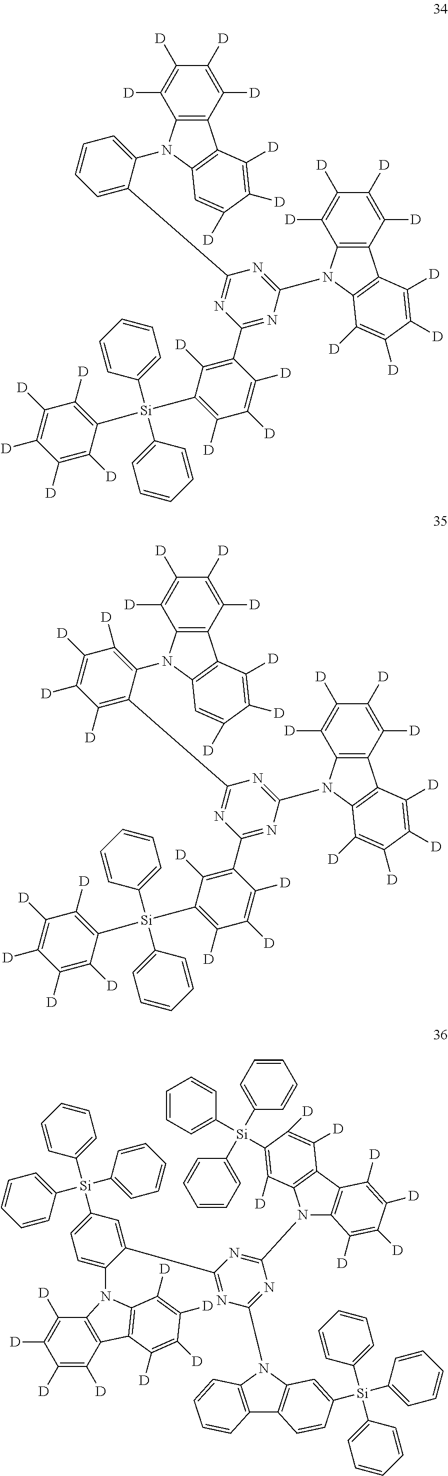 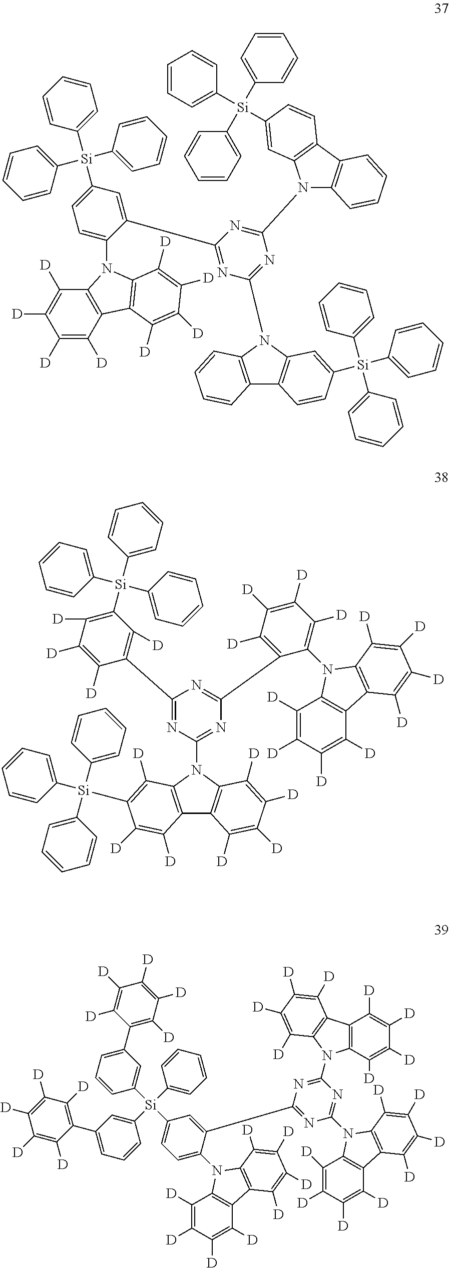 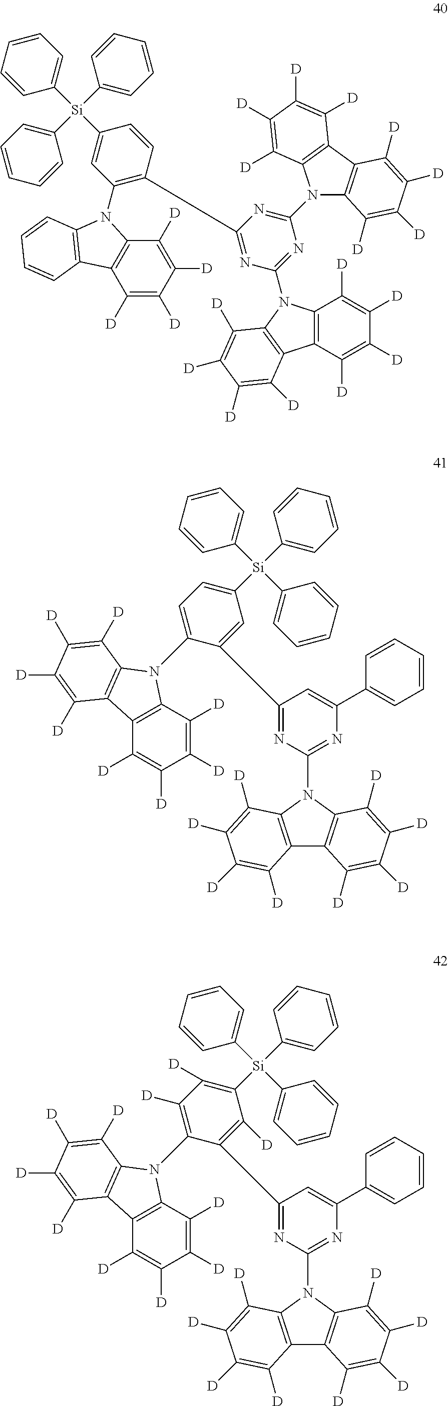 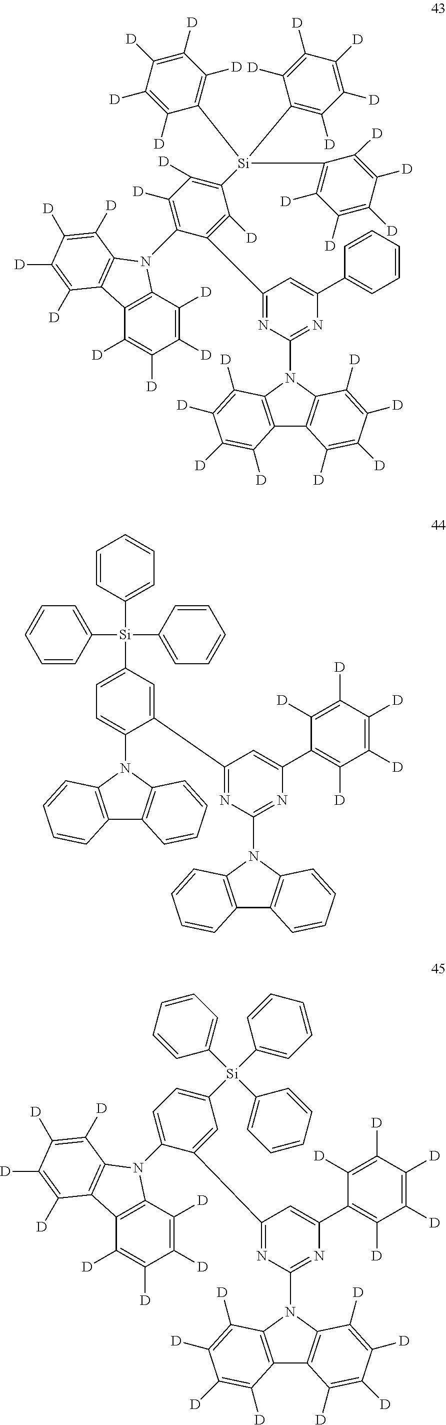 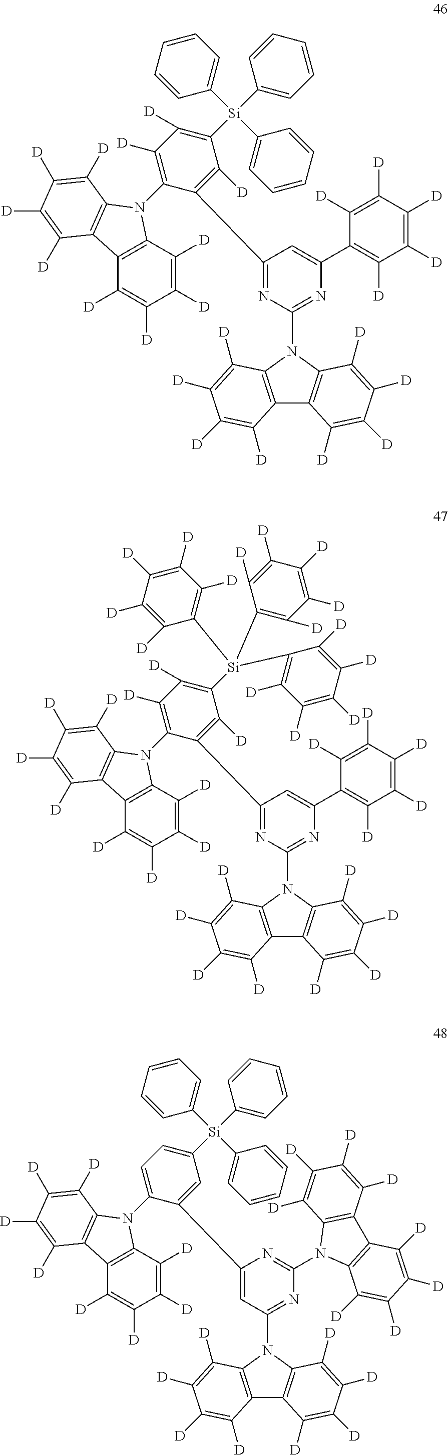 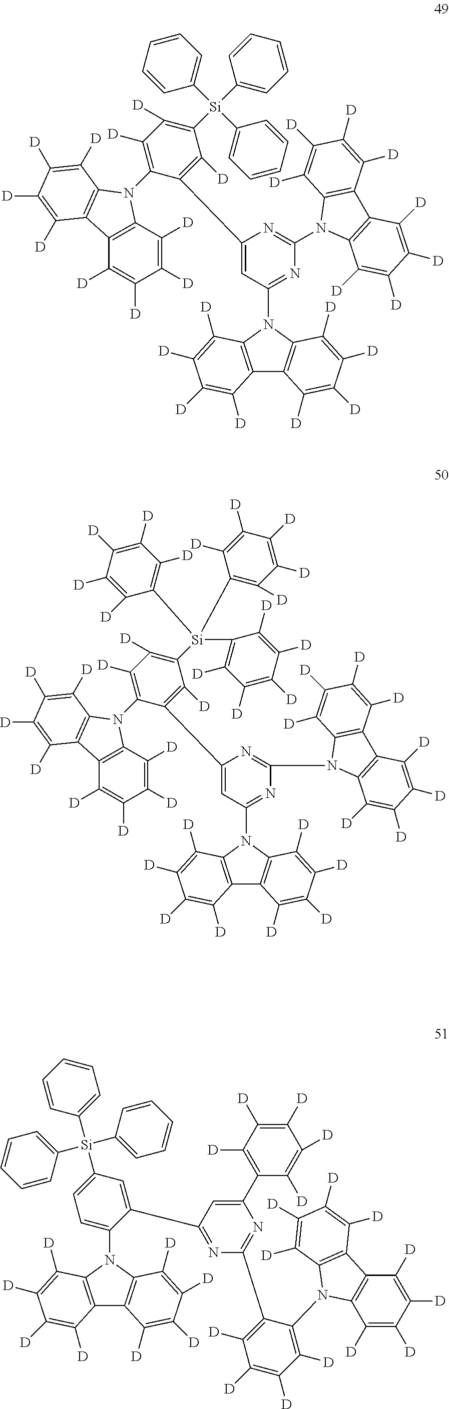 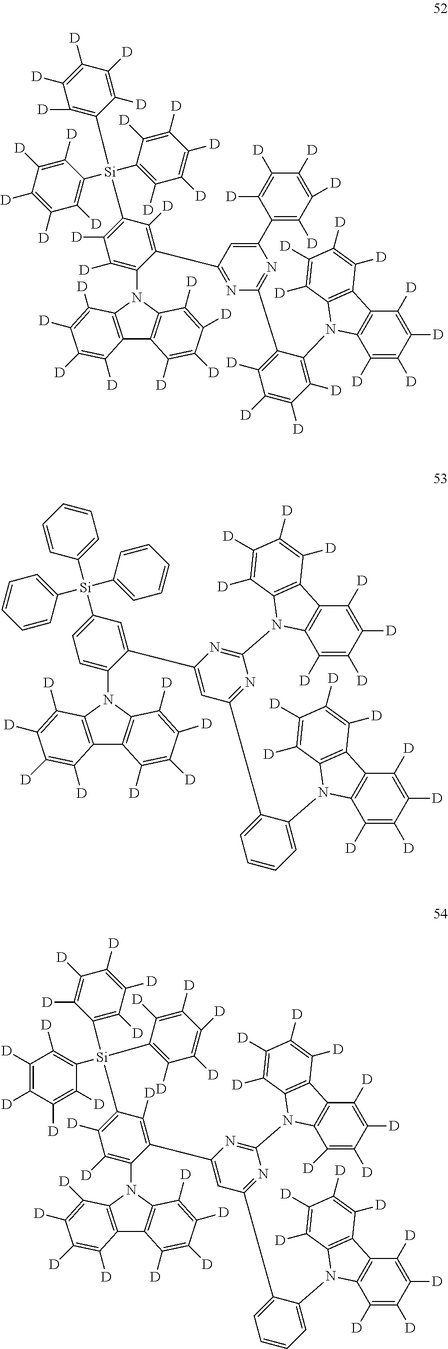 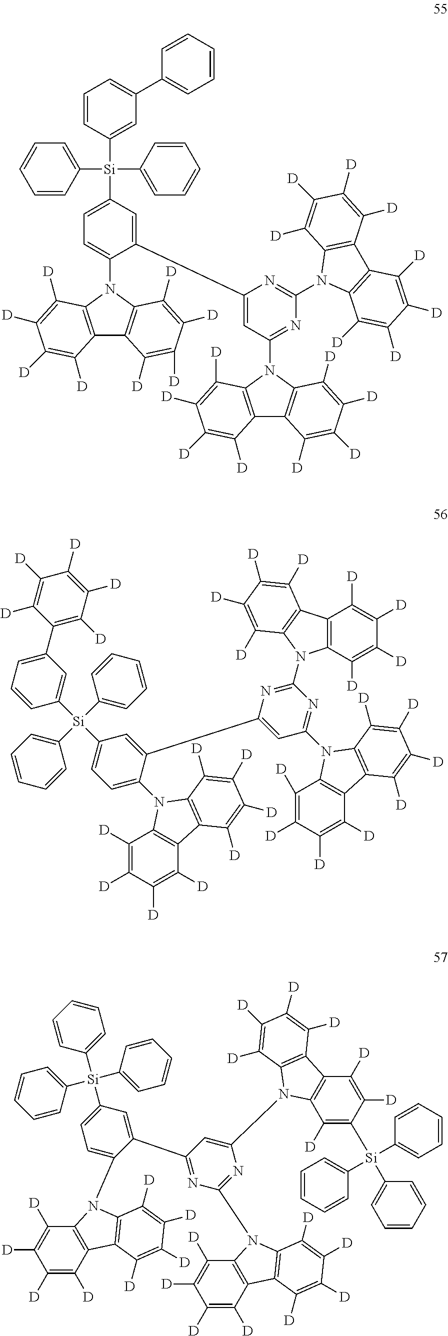 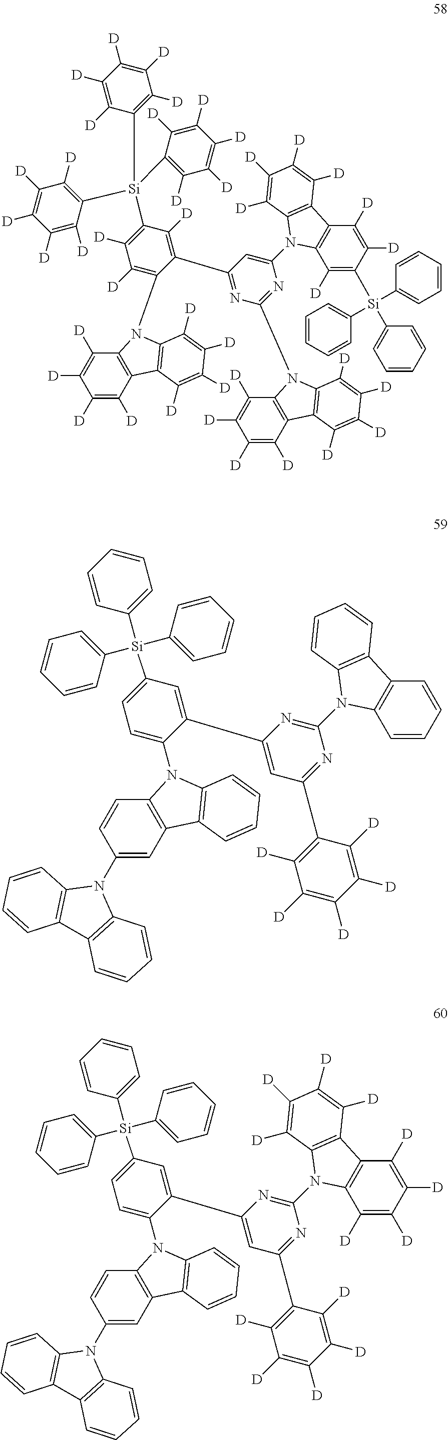 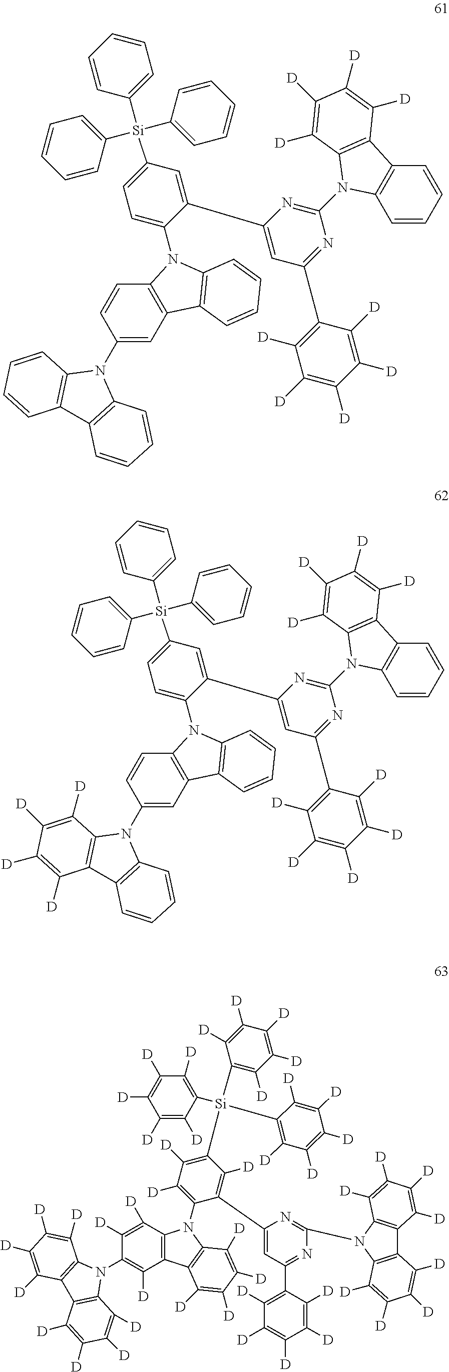 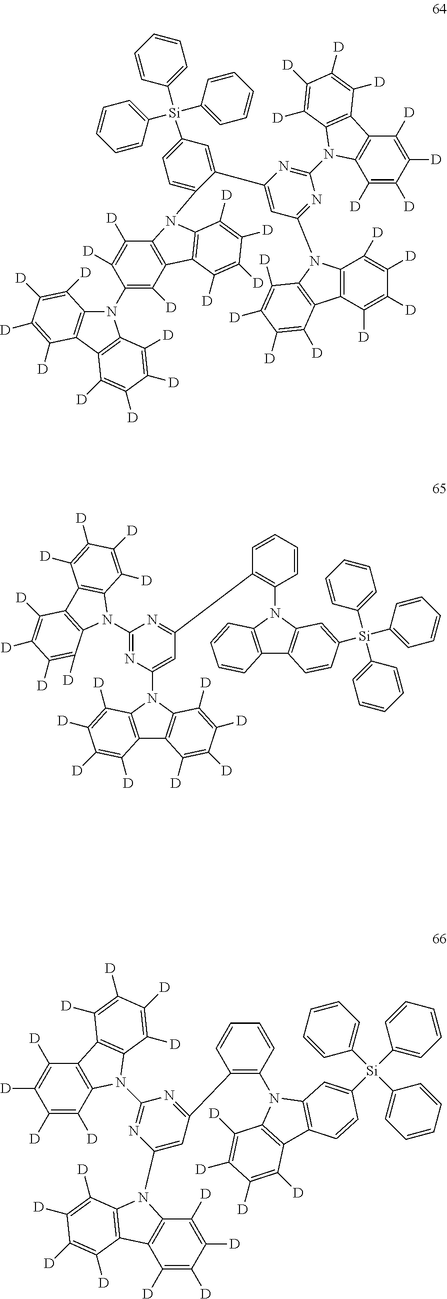 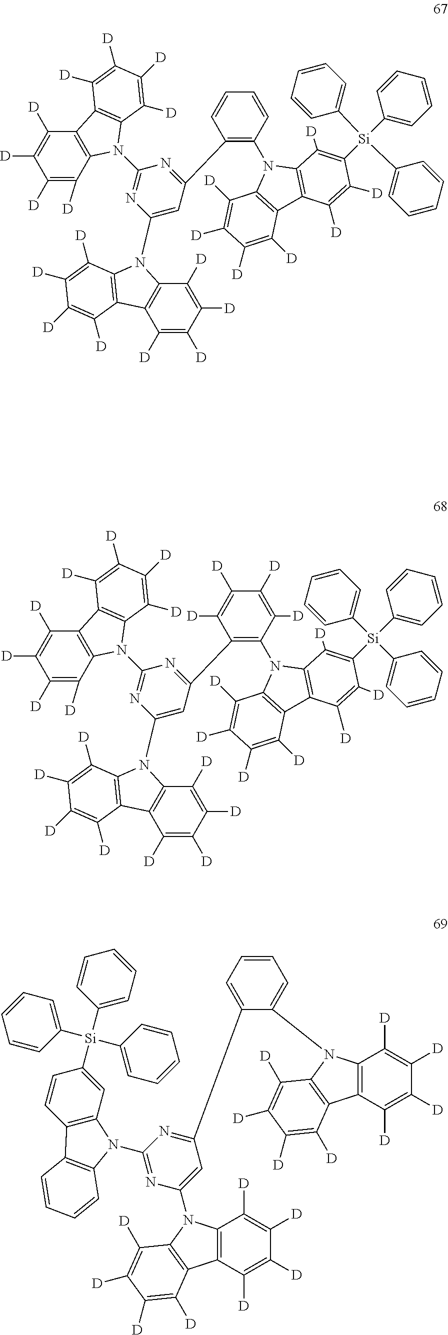 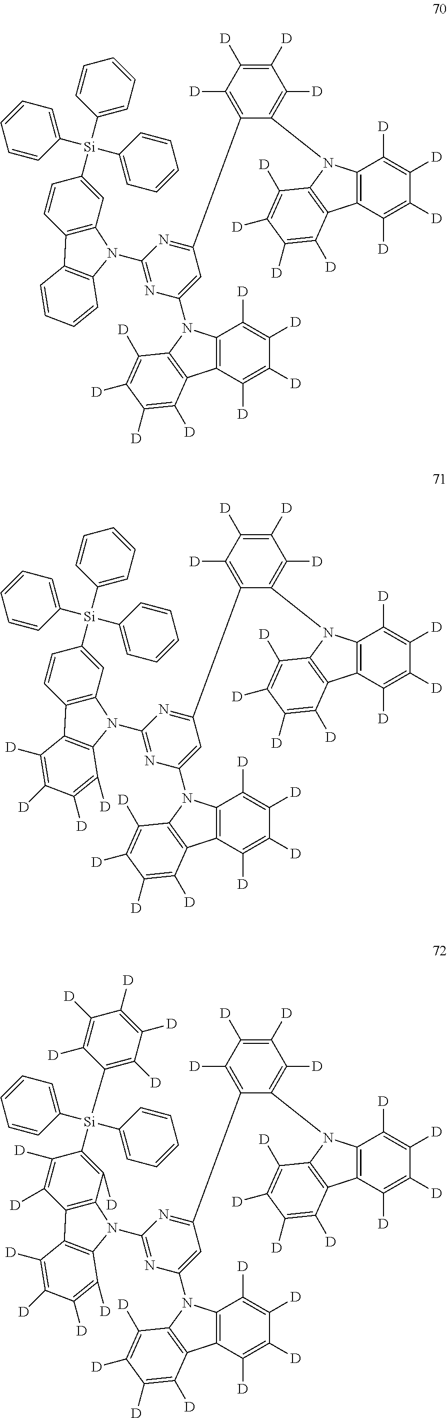 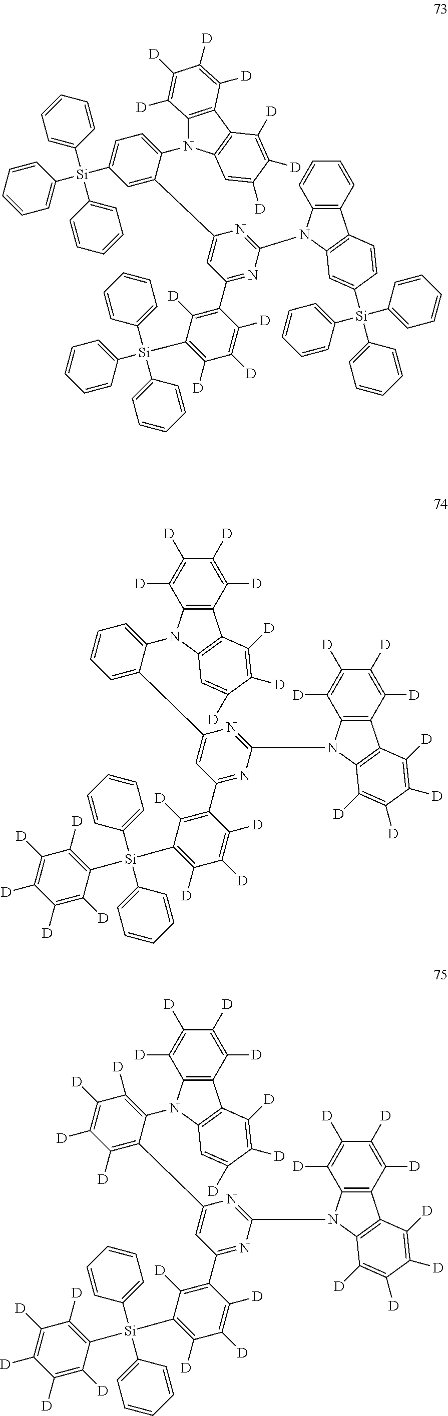 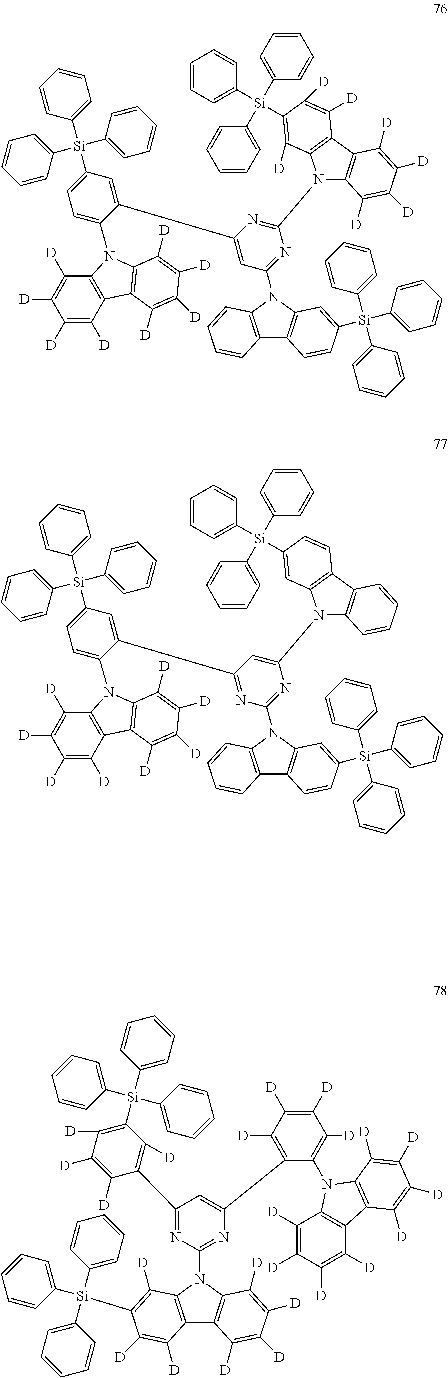 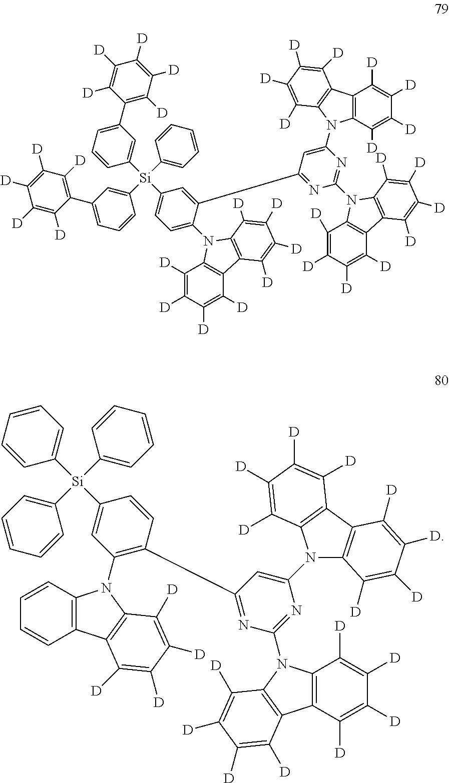
in Compound Group 1, D is a deuterium atom.

15. A nitrogen-containing compound represented by the following Formula 1: 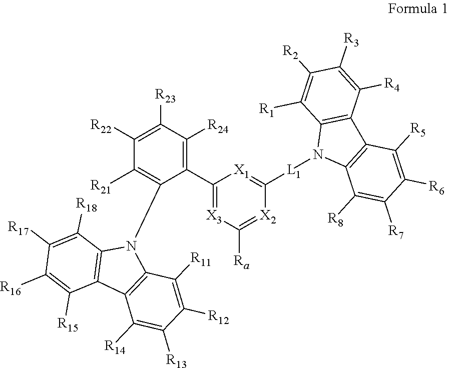
in Formula 1,
at least two selected from among X₁ to X₃ are N, and the remainder is CH,
L₁ is a direct linkage or a substituted or unsubstituted arylene group of 6 to 30 ring-forming carbon atoms,
Rₐ, R₁ to R₈, R₁₁ to R₁₈, and R₂₁ to R₂₄ are each independently a hydrogen atom, a deuterium atom, a substituted or unsubstituted silyl group, a substituted or unsubstituted alkyl group of 1 to 30 carbon atoms, a substituted or unsubstituted alkenyl group of 2 to 30 carbon atoms, a substituted or unsubstituted aryl group of 6 to ring-forming carbon atoms, or a substituted or unsubstituted heteroaryl group or 2 to ring-forming carbon atoms, and
at least one selected from among Rₐ, R₁ to R₈, R₁₁ to R₁₈, and R₂₁ to R₂₄ is represented by the following Formula 2, or comprises a first substituent substituted with the following Formula 2: 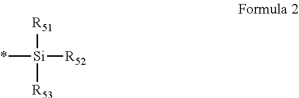
in Formula 2,
R₅₁ to R₅₃ are each independently a hydrogen atom, a deuterium atom, a substituted or unsubstituted silyl group, a substituted or unsubstituted alkyl group of 1 to 30 carbon atoms, a substituted or unsubstituted alkenyl group of 2 to 30 carbon atoms, a substituted or unsubstituted aryl group of 6 to 30 ring-forming carbon atoms, or a substituted or unsubstituted heteroaryl group or 2 to 30 ring-forming carbon atoms, and
at least one selected from among Rₐ, R₁ to R₈, R₁₁ to R₁₈, R₂₁ to R₂₄, and R₅₁ to R₅₃ is a deuterium atom, or comprises a second substituent substituted with a deuterium atom.

16. The nitrogen-containing compound of claim 15, wherein Formula 1 is represented by the following Formula 1-A1 or Formula 1-A2: 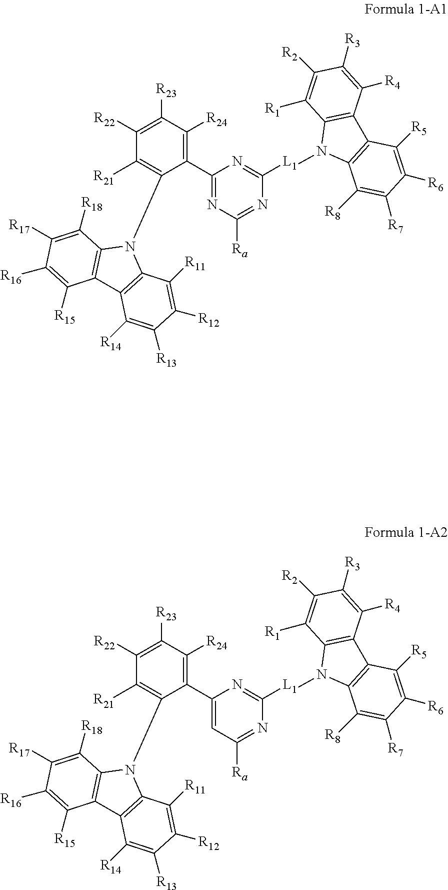
in Formula 1-A1 and Formula 1-A2,
L₁, Rₐ, R₁ to R₈, R₁₁ to R₁₈, and R₂₁ to R₂₄ are the same as defined with respect to Formula 1.

17. The nitrogen-containing compound of claim 15, wherein Formula 2 is represented by the following Formula 2-1: 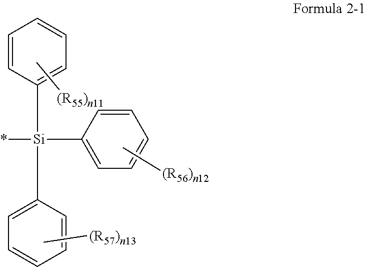
in Formula 2-1,
n11 to n13 are each independently an integer of 0 to 5, and
R₅₅ to R₅₇ are each independently a hydrogen atom, a deuterium atom, or a substituted or unsubstituted aryl group of 6 to 30 ring-forming carbon atoms.

18. The nitrogen-containing compound of claim 15, wherein Formula 1 is represented by any one selected from among the following Formula 1-B1 to Formula 1-B4: 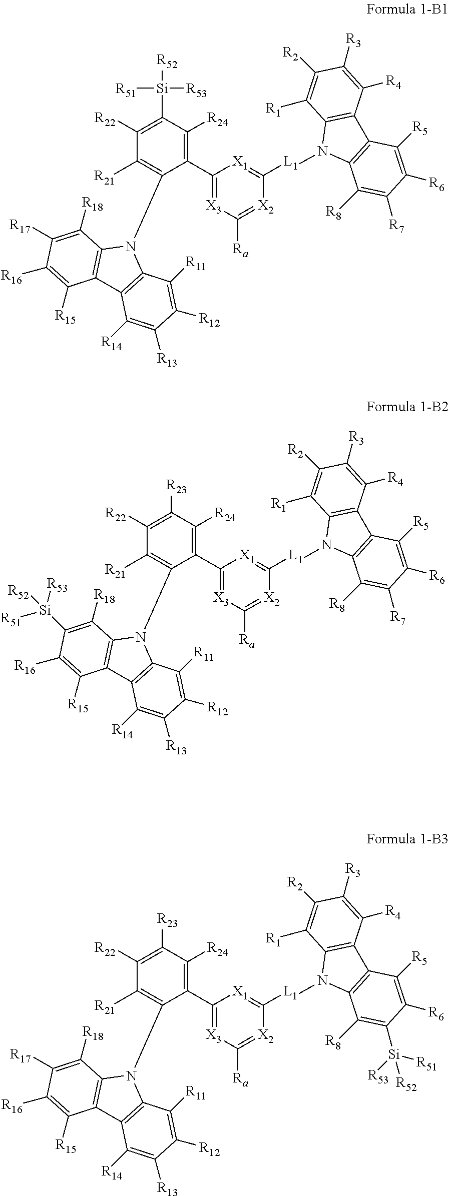 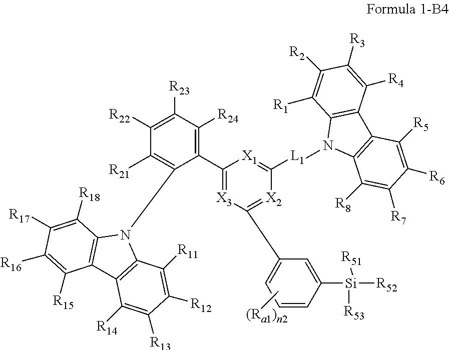
in Formula 1-B4,
n2 is an integer of 0 to 4, and
Rₐ₁ is a hydrogen atom, a deuterium atom, or a substituted or unsubstituted aryl group of 6 to 30 ring-forming carbon atoms,
in Formula 1-61 to Formula 1-B4,
L₁, Rₐ, R₁ to R₈, R₁₁ to R₁₈, R₂₁ to R₂₄, and R₅₁ to R₅₃ are the same as defined with respect to Formula 1 and Formula 2.

19. The nitrogen-containing compound of claim 15, wherein the second substituent comprises at least one selected from among a phenyl group substituted with a deuterium atom, a silyl group substituted with a deuterium atom, and a carbazole group substituted with a deuterium atom.

20. The nitrogen-containing compound of claim 15, wherein the second substituent is represented by any one selected from among the following S-1 to S-10: 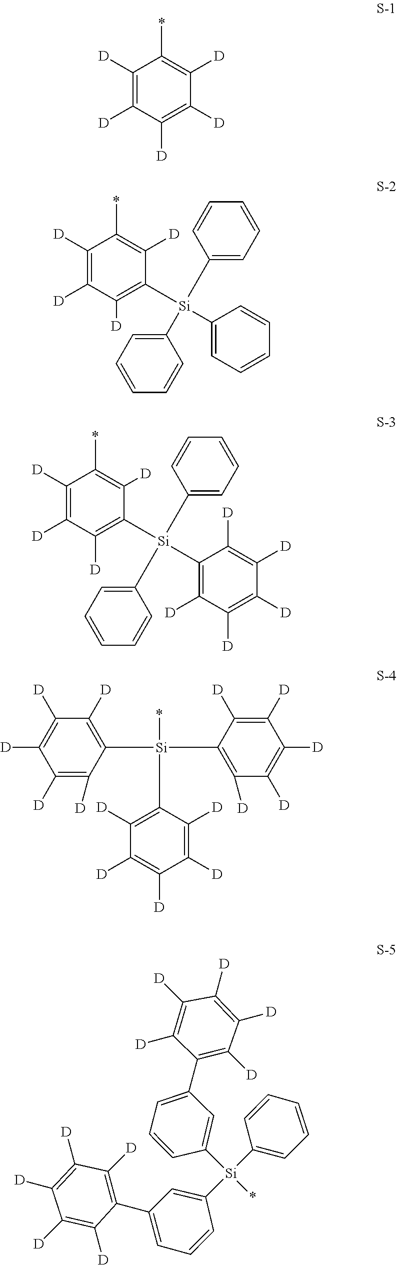 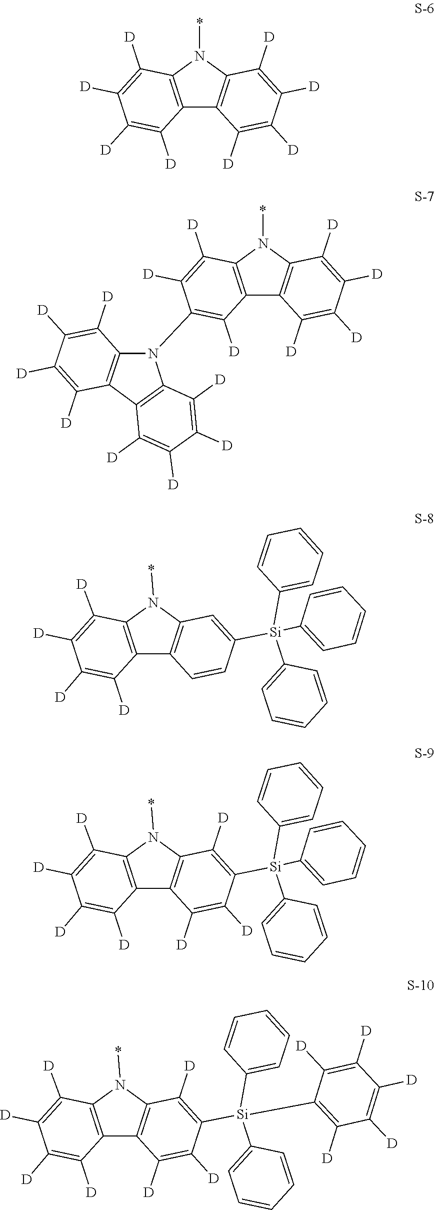
in S-1 to S-10, D is a deuterium atom.

21. The nitrogen-containing compound of claim 15, wherein, in Formula 1, L₁ is a direct linkage or a substituted or unsubstituted phenylene group.

22. The nitrogen-containing compound of claim 15, wherein Formula 1 is represented by any one selected from among compounds in the following Compound Group 1: 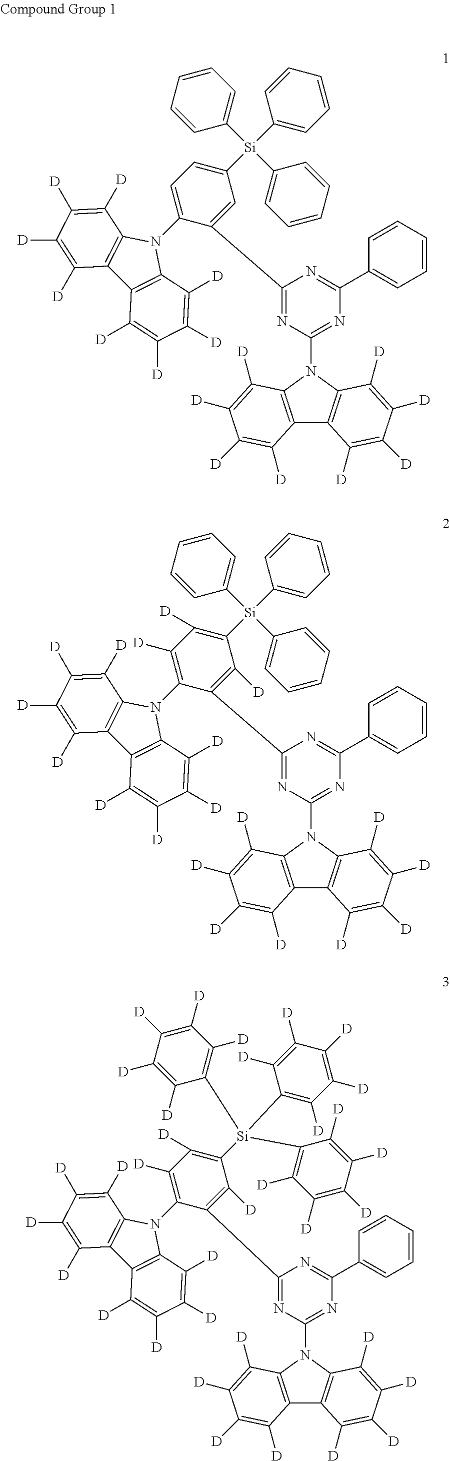 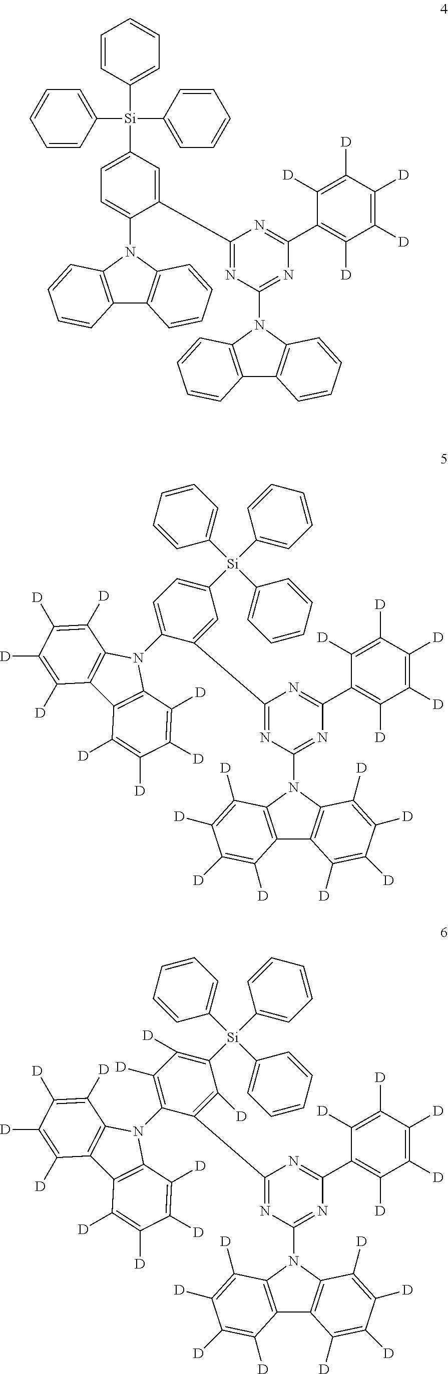 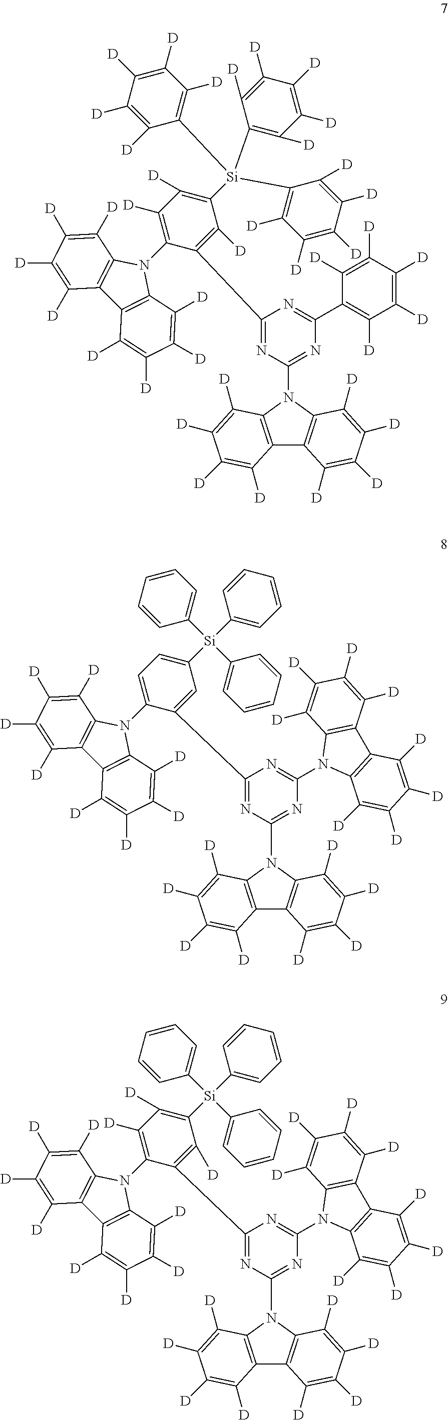 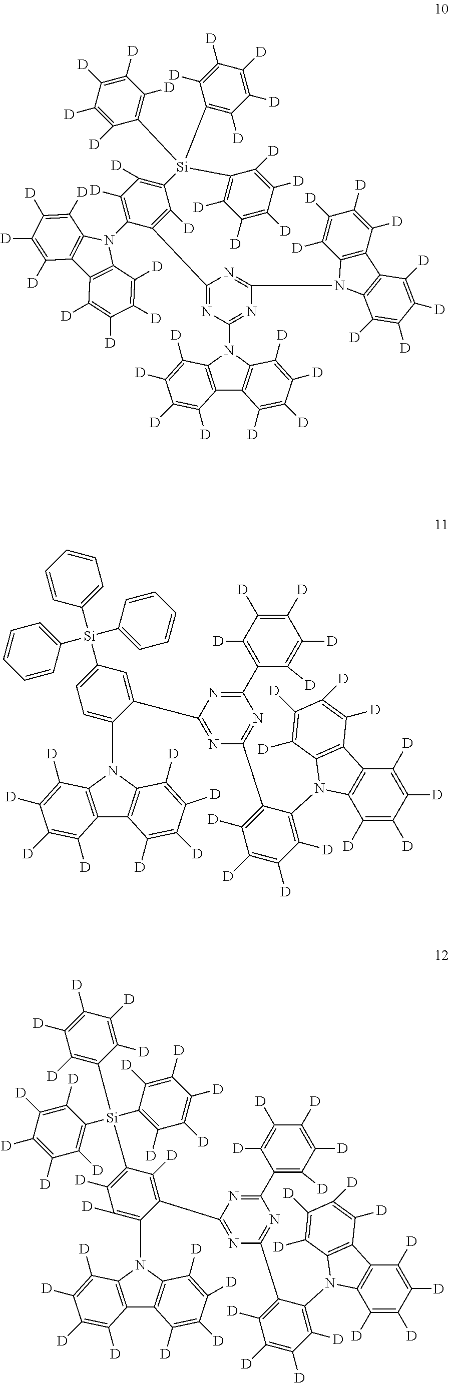 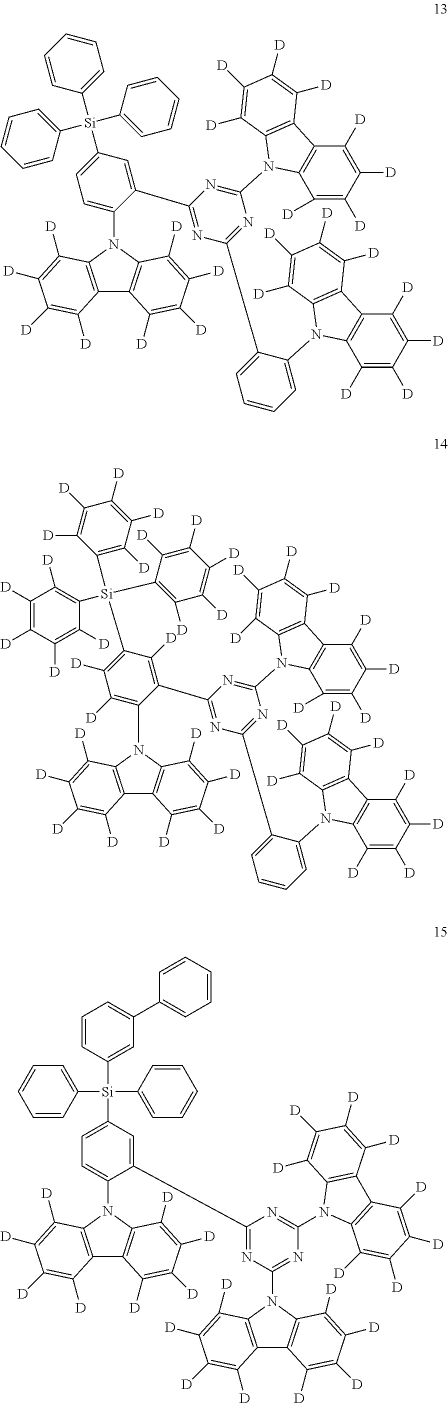 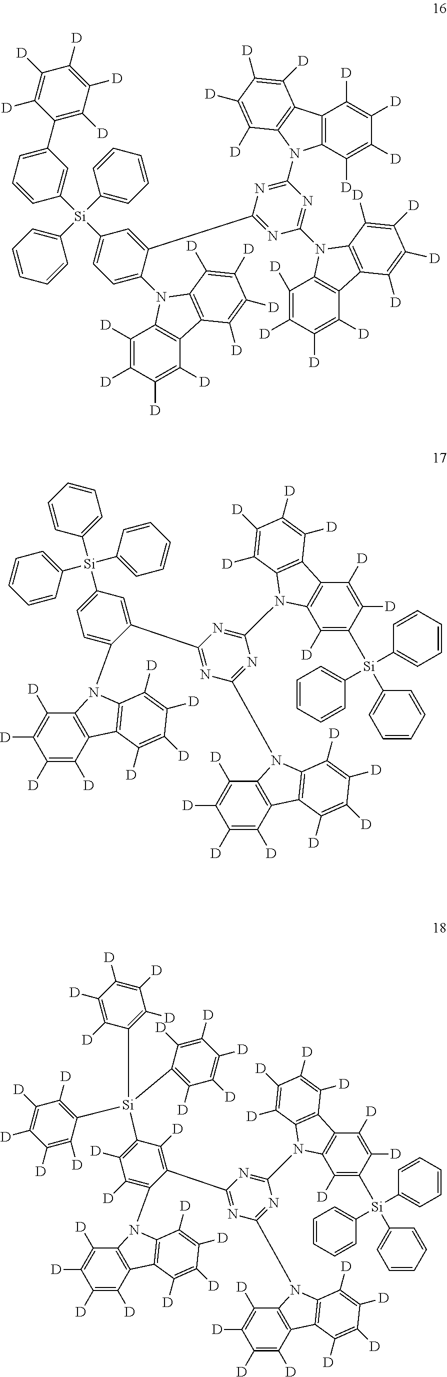 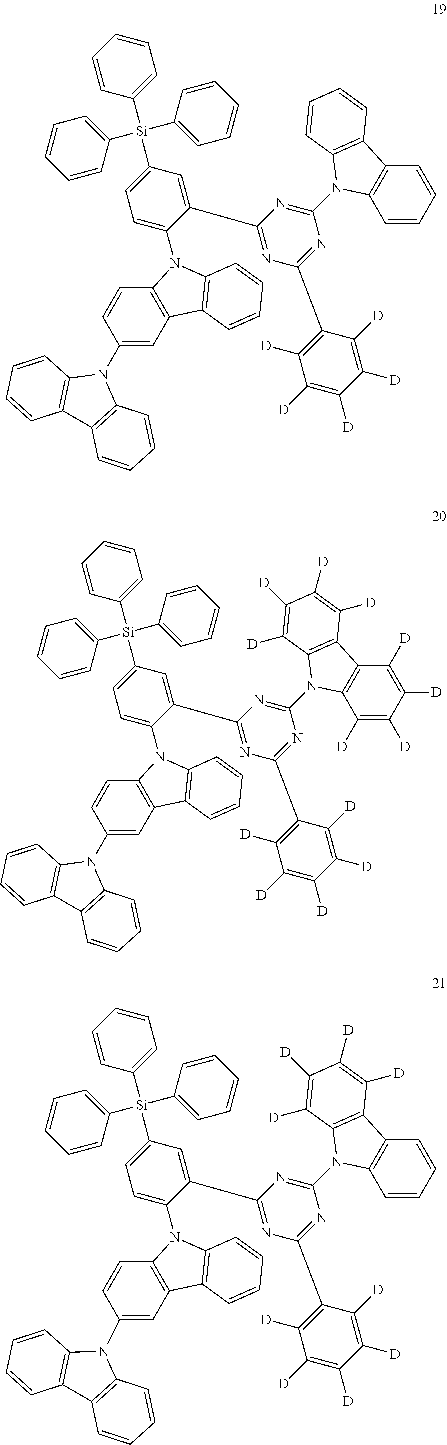 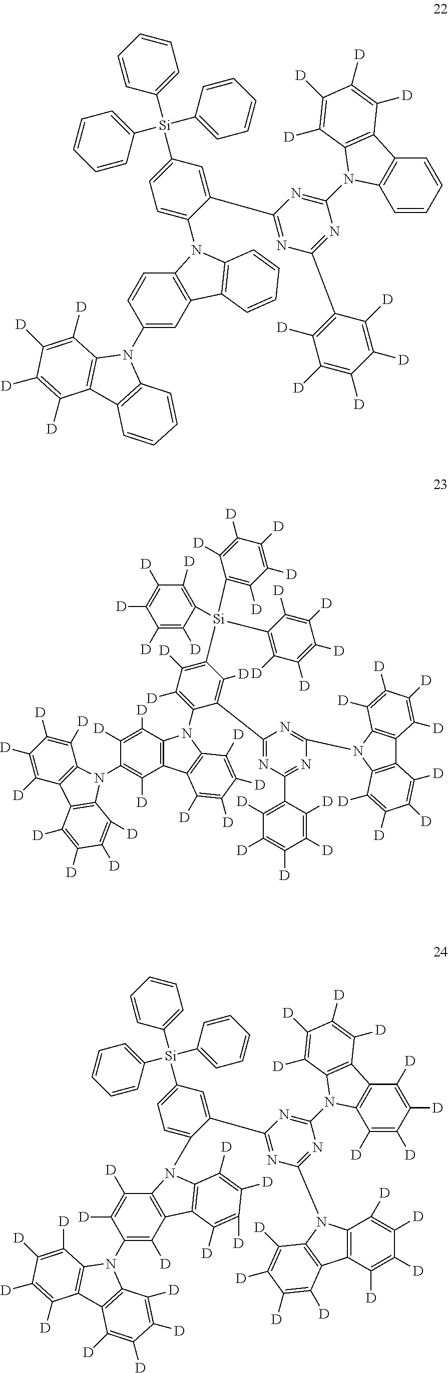 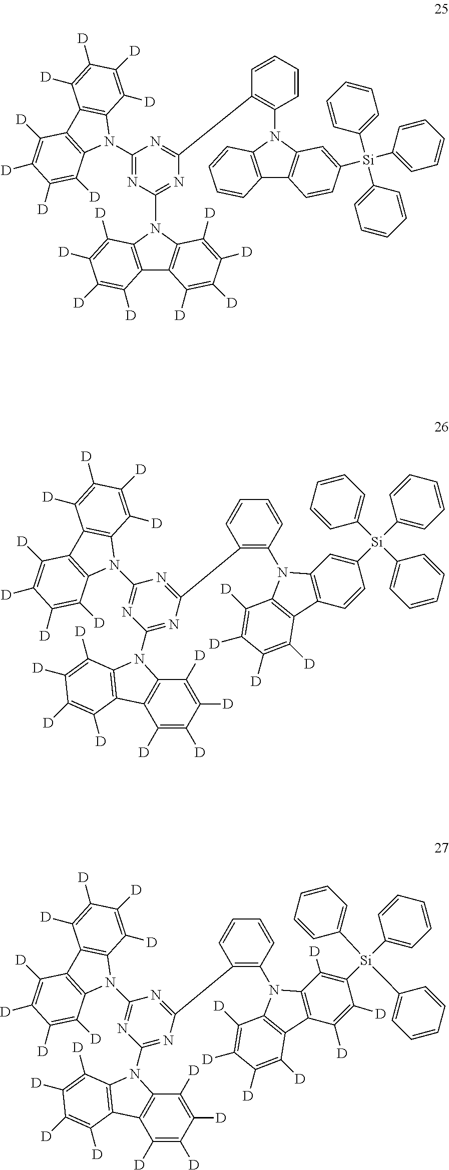 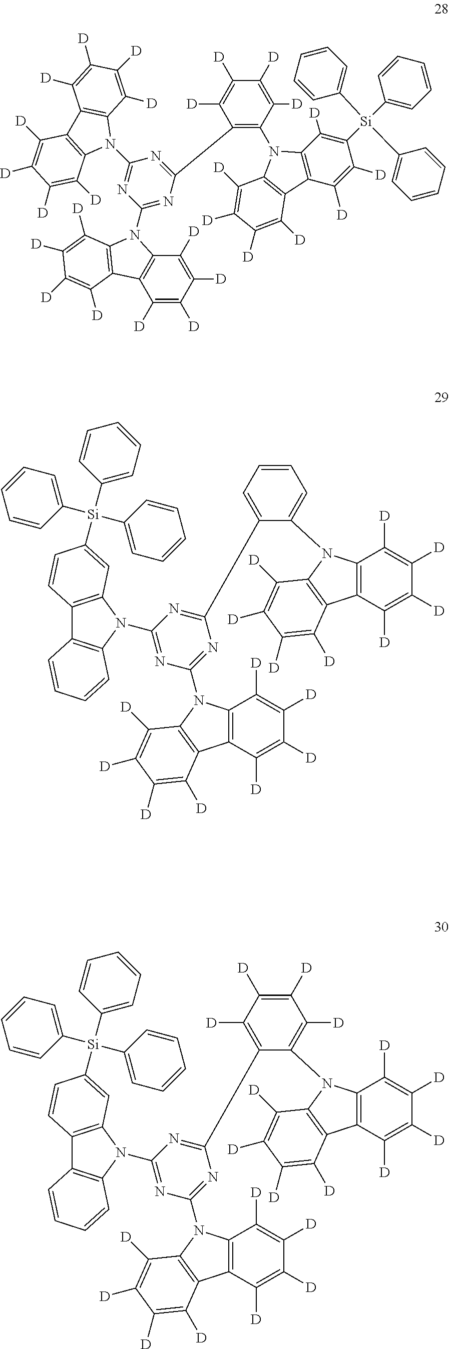 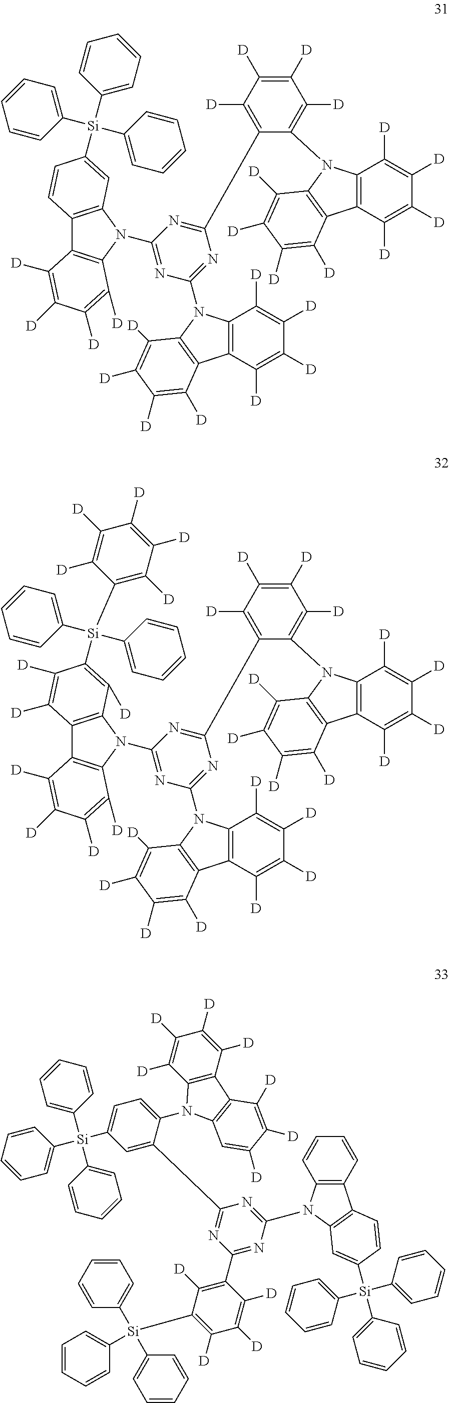 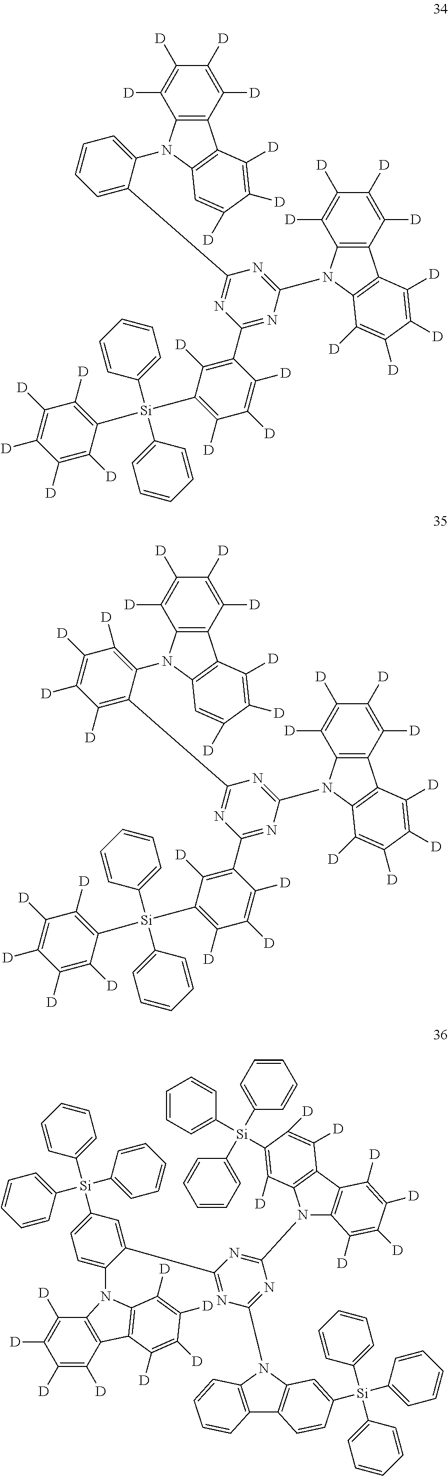 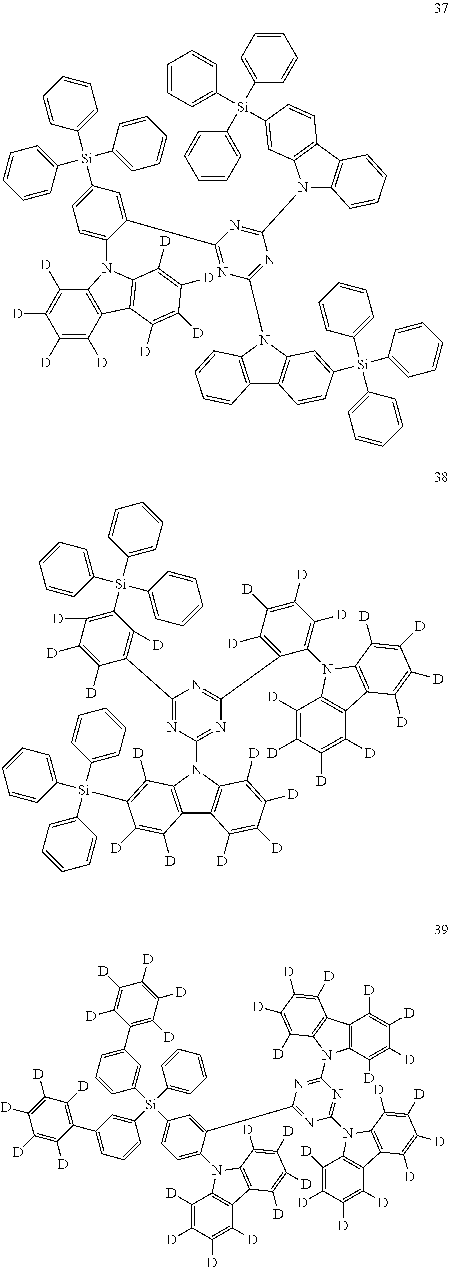 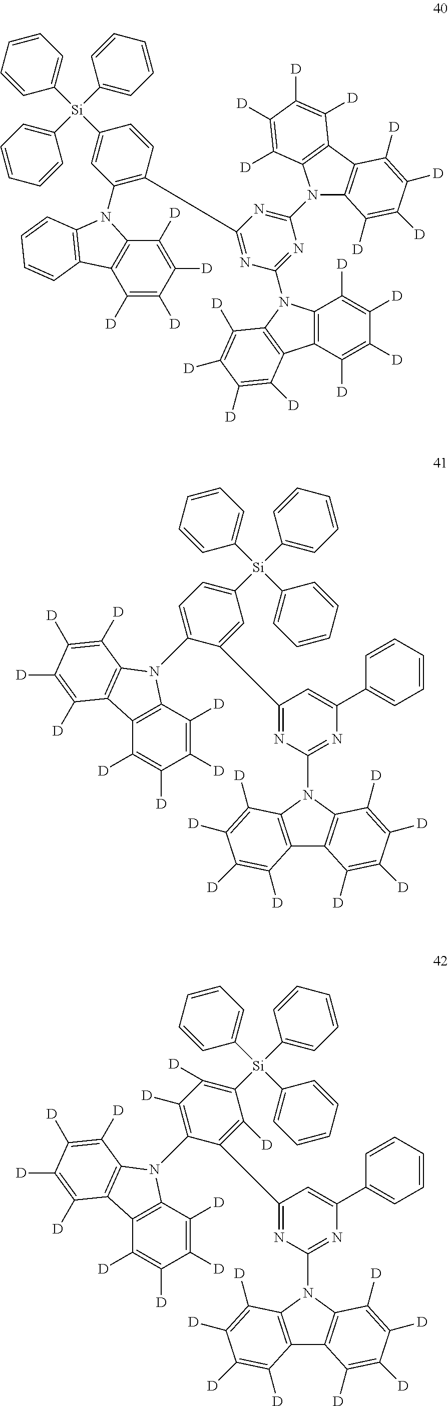 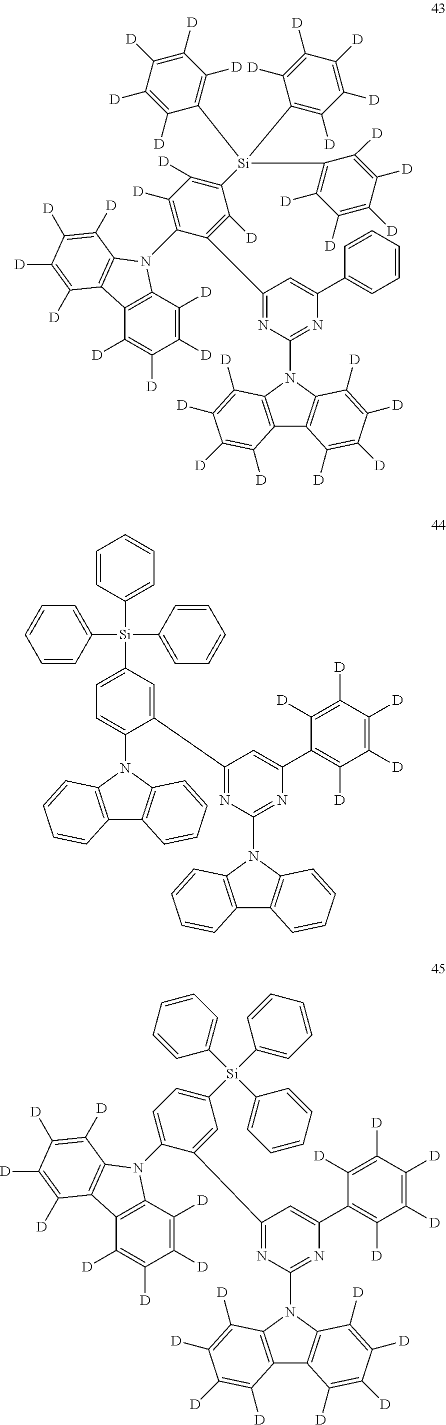 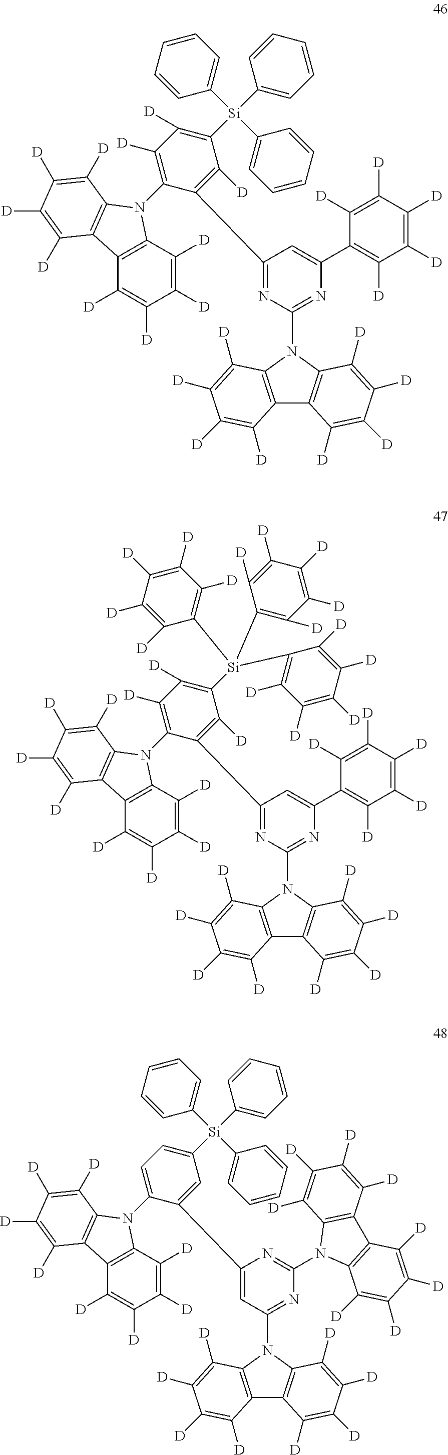 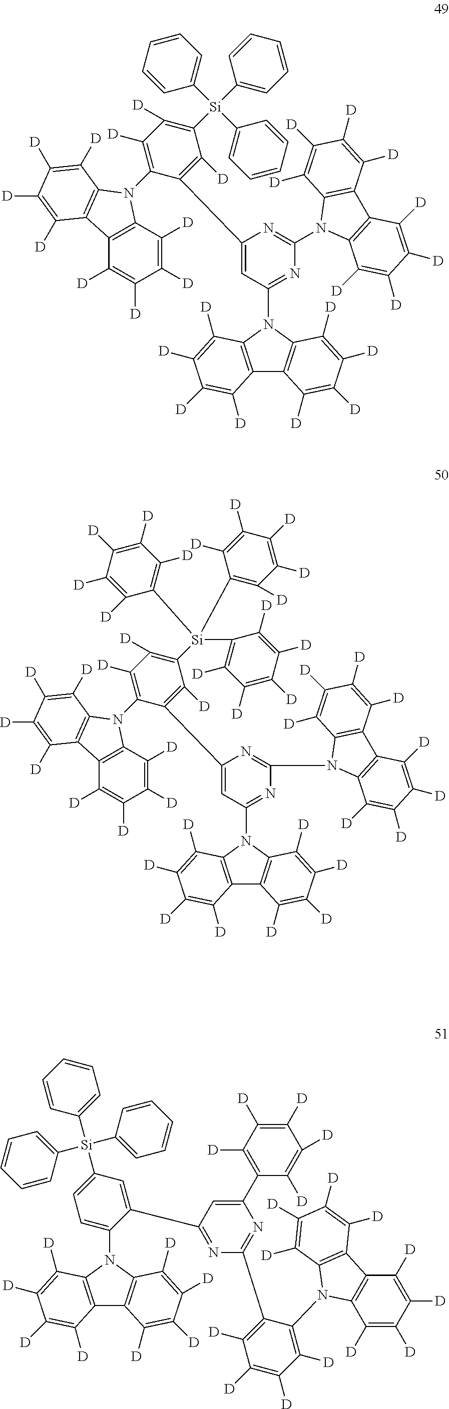 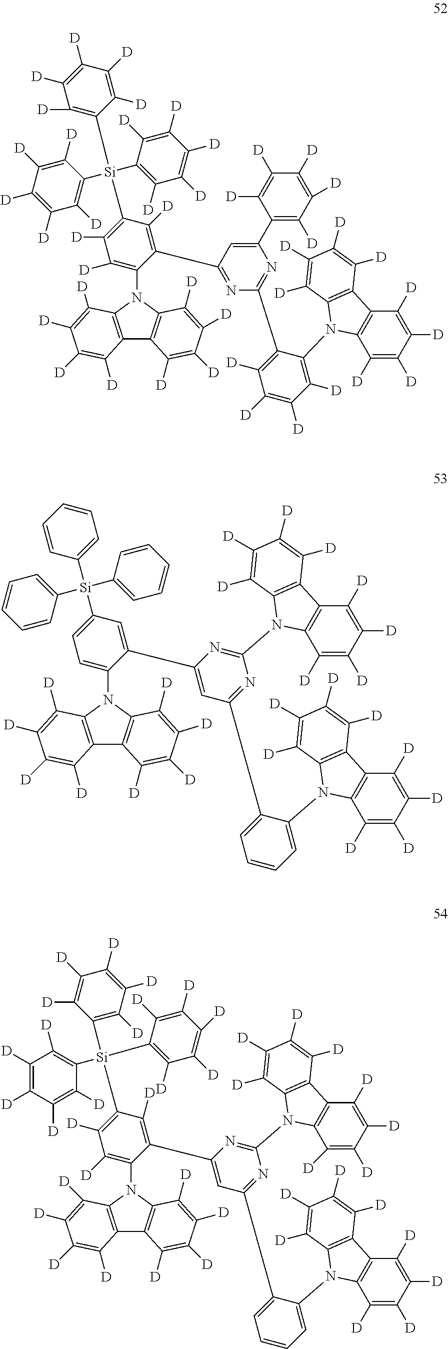 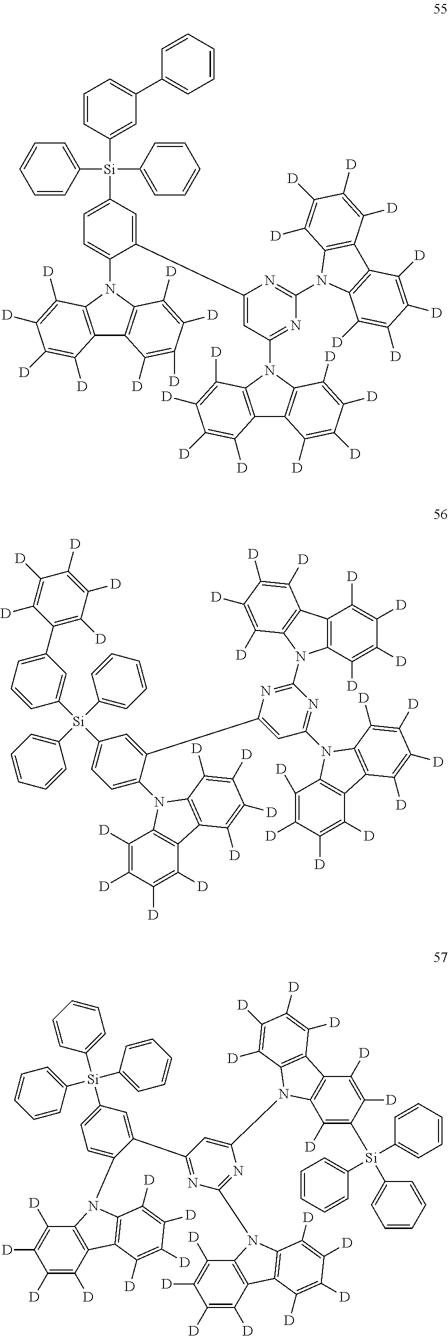 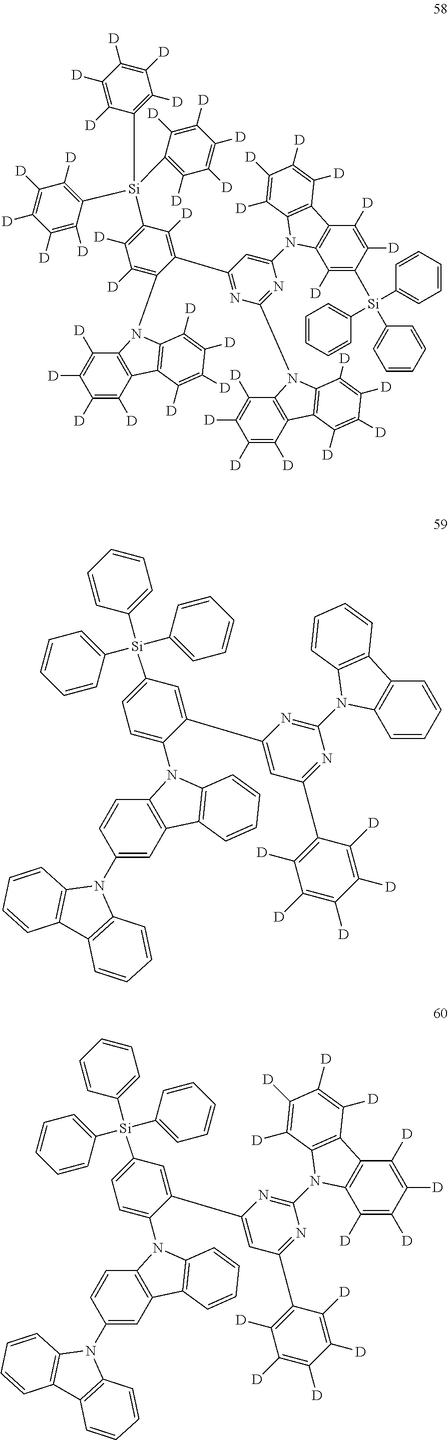 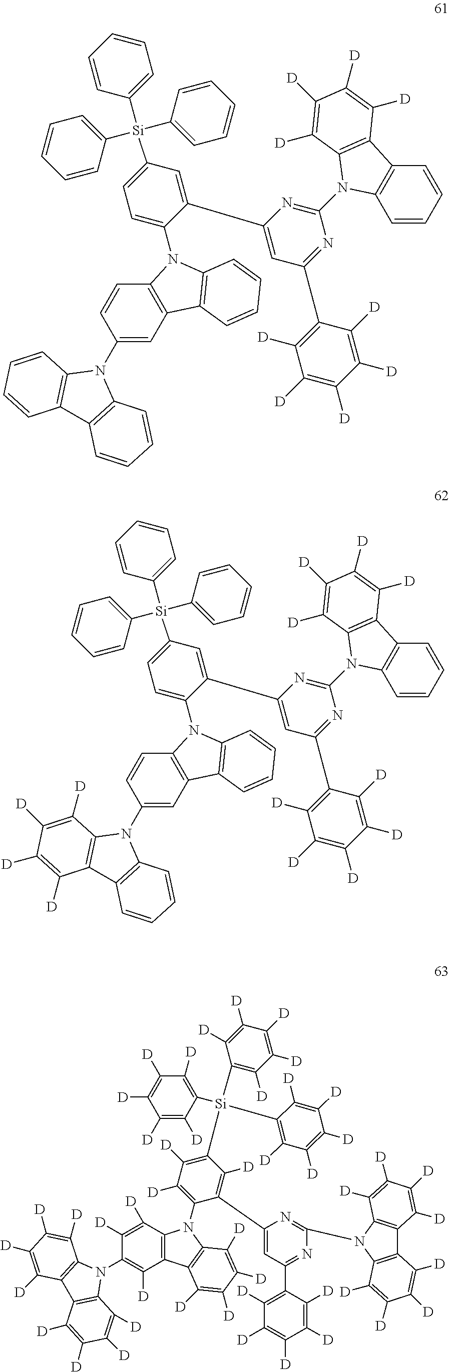 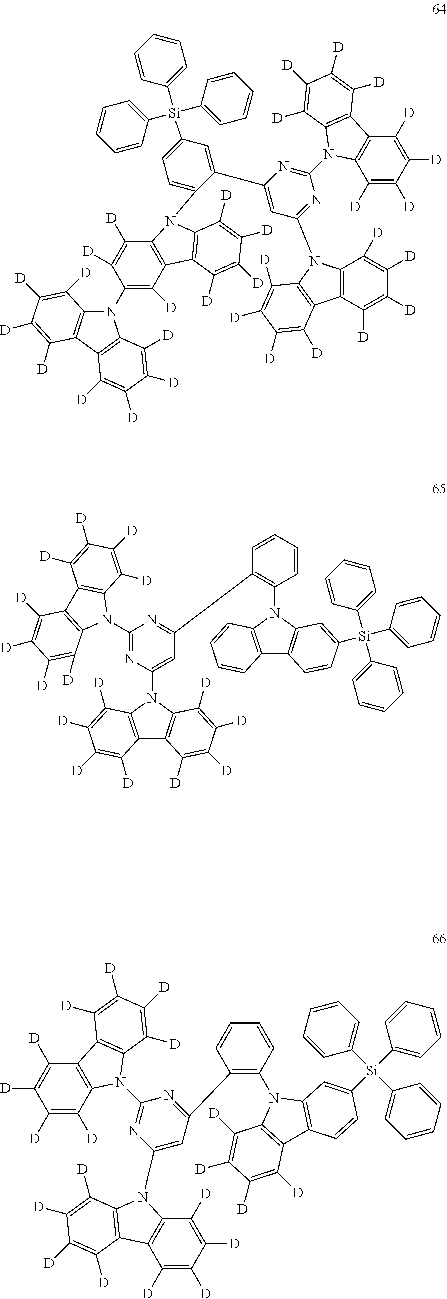 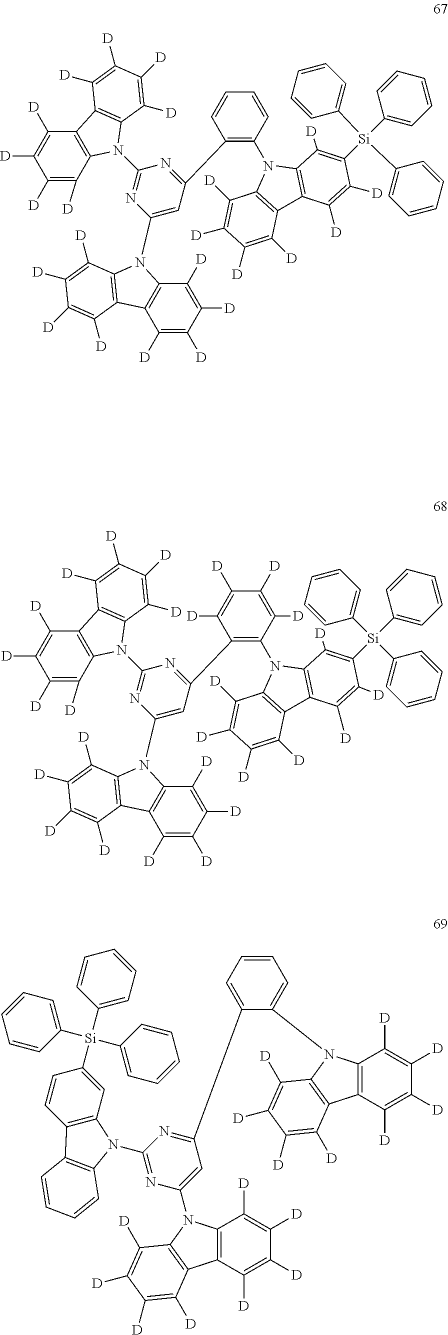 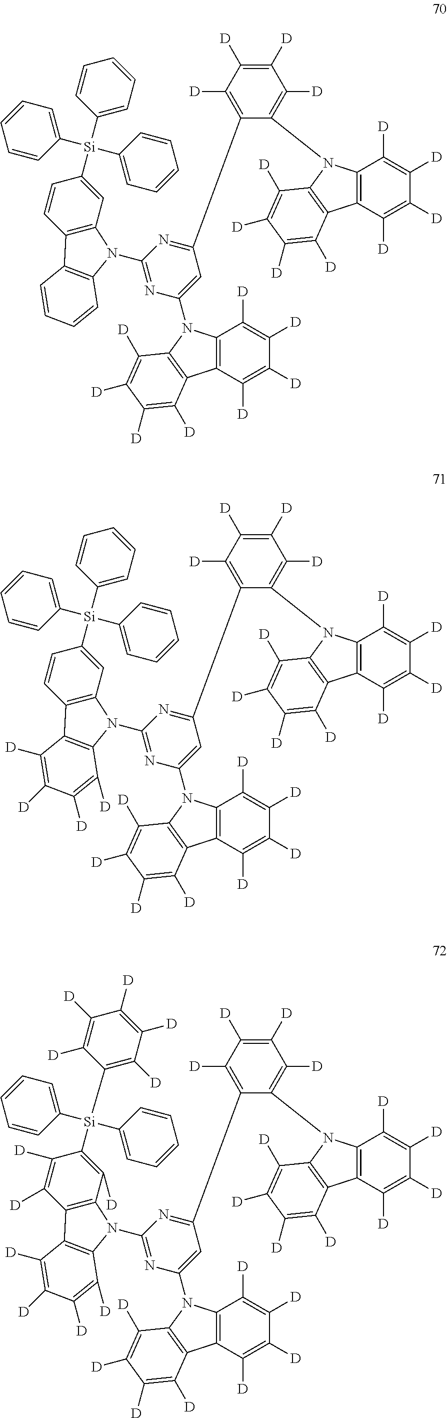 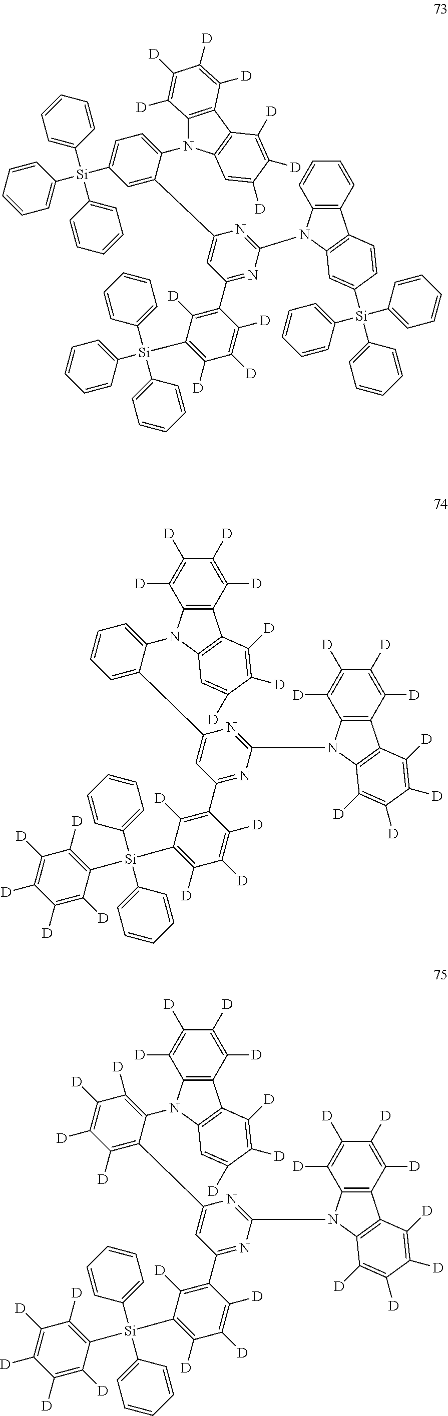 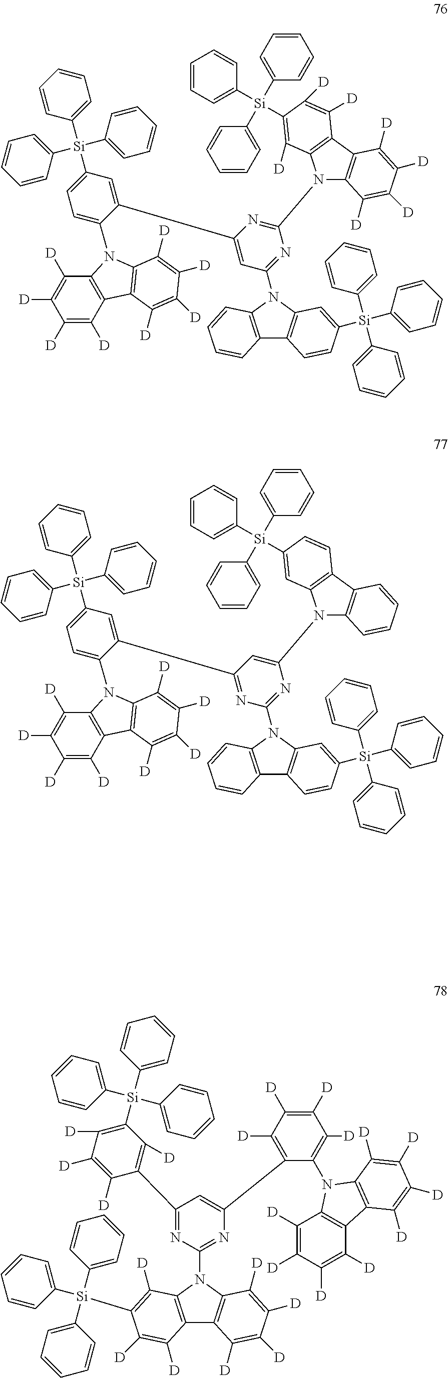 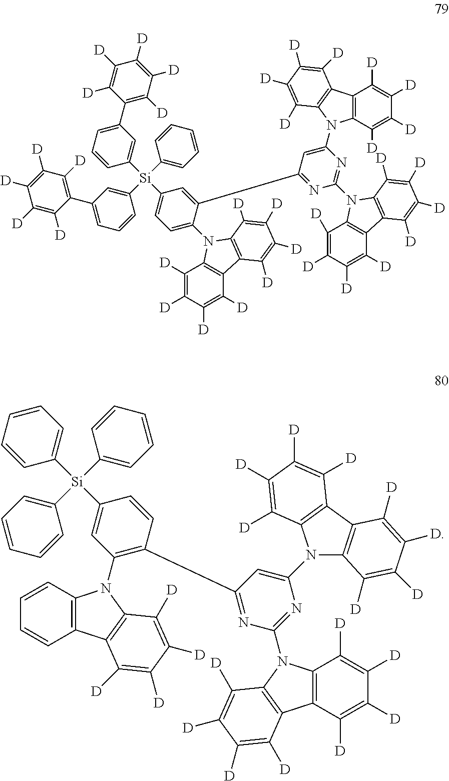
in Compound Group 1, D is a deuterium atom.
